(19) United States
(12) Patent Application Publication
(10) Pub. No.: US 2022/0216411 A1
(43) Pub. Date: Jul. 7, 2022

(54) BORON-CONTAINING CYCLIC EMISSIVE COMPOUNDS AND COLOR CONVERSION FILM CONTAINING THE SAME

(71) Applicant: NITTO DENKO CORPORATION, Osaka (JP)

(72) Inventors: Shijun Zheng, San Diego, CA (US); Stanislaw Rachwal, Oceanside, CA (US); Jeffrey R. Hammaker, San Diego, CA (US); Hiep LUU, San Marcos, CA (US); Eduardo Aguirre, Vista, CA (US); Peng Wang, San Diego, CA (US); Jan Saska, State College, PA (US)

(21) Appl. No.: 17/603,323

(22) PCT Filed: Apr. 11, 2020
(86) PCT No.: PCT/US2020/027848

§ 371 Date: Oct. 12, 2021

Related U.S. Application Data
(60) Provisional application No. 62/833,590, filed on Apr. 12, 2019.
(60) Provisional application No. 62/986,462, filed on Mar. 6, 2020.

(51) Int. Cl. H01L 51/00; C09K 11/02; C07F 5/02; C09K 11/06

(52) U.S. Cl. CPC H01L 51/008; C09K 11/025; F21V 9/30; C09K 11/06; C09K 2211/1025; C07F 5/027

(57) ABSTRACT

The present disclosure relates to novel photoluminescent complexes comprising a BODIPY moiety covalently bonded to a blue light absorbing moiety, a color conversion film comprising the photoluminescent complex, and a back-light unit using the same.

### FIELD

The present disclosure is related to photoluminescent compounds for use in color conversion films, backlight units, and display apparatuses including the same.

### BACKGROUND

In color reproduction the gamut, or color gamut, is a certain complete subset of colors available on a device such as a television or monitor. For example, Adobe™ Red Green Blue (RGB), a wide-gamut color space achieved by using pure spectral primary colors, was developed to provide a broader color gamut and offer a more realistic representation of visible colors viewed through a display. It is believed that a device which could provide a wider gamut could enable the display to portray more vibrant colors.

As high-definition large screen displays become more common, the demand for higher performance, slimmer and highly functional displays have increased. Current light emitting diode (LEDs) are obtained by a blue light source exciting a green phosphor, a red phosphor or a yellow phosphor to obtain a white light source. However, the full width half maximum (FWHM) of the emission peak of the current green and red phosphors are quite large, usually greater than 40 nm, resulting in the green and red color spectrums overlapping and rendering colors that are not fully distinguishable from one another. This overlap leads to poor color rendition and the deterioration of the color gamut.

To correct the deterioration in the color gamut, methods have been developed using films containing quantum dots in combination with LEDs. However, there are problems with the use of quantum dots. First, cadmium-based quantum dots are extremely toxic and are banned from use in many countries due to health safety issues. Second, non-cadmium-based quantum dots have a very low efficiency in converting blue LED light to green and red light. Third, quantum dots require expensive encapsulating processes for protection against moisture and oxygen. Last, the cost of using quantum dots is high, because of the difficulties in controlling size uniformity during the production process.

### SUMMARY

Photoluminescent compounds described herein may be used to improve the contrast between distinguishable colors in televisions, computer monitors, smart devices and many other devices that utilize color displays. The photoluminescent complexes of the present disclosure provide novel color converting complexes with good blue light absorbance and narrow emissions bandwidths, with the full width half maximum [FWHM] of emission band of less than 40 nm. In some embodiments, a photoluminescent complex absorbs light of a first wavelength and emits light of a second wavelength higher than the first wavelength. The photoluminescent complexes disclosed herein can be utilized with a color conversion film for use in light emitting apparatuses. The color conversion films of the present disclosure reduce color deterioration by reducing overlap within the color spectrum, resulting in high quality color rendition.

Some embodiments include a photoluminescent complex, wherein the photoluminescent complex can comprise: a blue light absorbing moiety; a linker moiety; and a boron-dipyrromethene (BODIPY) moiety. In some embodiments, the blue light absorbing moiety can comprise an optionally substituted perylene. In some embodiments, the linker moiety can covalently link the optionally substituted perylene to the BODIPY moiety. In some embodiments, the optionally substituted perylene absorbs light of a first excitation wavelength and transfers an energy to the BODIPY moiety. In some embodiments, the BODIPY moiety absorbs the energy from the optionally substituted perylene and emits a light energy of a second higher wavelength. In some embodiments, the photoluminescent complex has an emission quantum yield greater than 80%.

In some embodiments, the photoluminescent complex can have an emission band with a full width half maximum [FWHM] of up to 40 nm.

In some embodiments, the photoluminescent complex can have a difference between the excitation peak of the blue light absorbing moiety and the emission peak of the BODIPY moiety, of equal to or greater than 45 nm.

In some embodiments, the molar ratio between the blue light absorbing moiety and the BODIPY moiety can be 1:1, 2:1, 3:1, or 1:2. In some embodiments, the photoluminescent complex can be described by Formula 1a:

Z-L-E [Formula 1a].

In other embodiments, the photoluminescent complex can be described by formula 1b:

Z-L-E-L-Z [Formula 1b].

In still other embodiments, the photoluminescent complex can be described by formula 1c:

E-L-Z-L-E [Formula 1c];

In still other embodiments, the photoluminescent complex can be described by formula 1d:

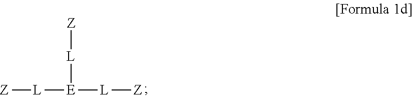

wherein Z represents a blue light absorbing moiety, L represents a linker and E represents a BODIPY moiety. In some embodiments, the blue light absorbing moiety, the linker moiety, and the BODIPY moiety can be selected from specific structures described herein. In some embodiments, the boron-dipyrromethene (BODIPY) derivative can be substituted or unsubstituted. In some embodiments, the ratio between the blue light absorbing moiety and the BODIPY moiety can be 1:1, 2:1, 3:1, or 1:2.

Some embodiments include a color conversion film, wherein the color conversion film may comprise: a color conversion layer, wherein the color conversion layer includes a resin matrix and at least one photoluminescent complex, described herein, dispersed within the resin matrix. In some embodiments, the color conversion film can have a thickness between about 1 μm to about 200 μm. In some embodiments, the color conversion film of the present disclosure can absorb blue light in the wavelength range of about 400 nm to about 480 nm, and emit light in the wavelength range of about 510 nm to about 560 nm. Another embodiment includes a color conversion film that can absorb blue light in the wavelength range of about 400 nm to about 480 nm, and emit light in the wavelength range of about 575 nm to about 645 nm. In some embodiments, the color conversion film can further comprise a transparent substrate layer. In some embodiments, the transparent substrate layer comprises two opposing surfaces, wherein the color conversion layer is disposed on one of the opposing surfaces.

Some embodiments include a method for preparing the color conversion film, wherein the method comprises: dissolving at least one photoluminescent complex, described herein and a binder resin within a solvent; and applying the mixture on one of the transparent substrate's opposing surfaces.

Some embodiments include a backlight unit including a color conversion film described herein.

Some embodiments include a display device including the backlight unit described herein.

The present application provides photoluminescent complexes having excellent color gamut and luminescent properties, a method for manufacturing color conversion films using the photoluminescent complexes, and a backlight unit including the color conversion film. These and other embodiments are described in greater detail below.

### BRIEF DESCRIPTION OF THE DRAWINGS

FIG. 1 is a graph depicting the absorption and emission spectra of one embodiment of a photoluminescent complex.

FIG. 2 is a graph depicting the absorption and emission spectra of one embodiment of a photoluminescent complex.

FIG. 3 is a graph depicting the absorption and emission spectra of one embodiment of a photoluminescent complex.

FIG. 4 is a graph depicting the absorption and emission spectra of one embodiment of a photoluminescent complex.

### DETAILED DESCRIPTION

A novel approach to address the issues presented with the use of quantum dots involves the use of a boron-dipyrromethene (BODIPY) compounds as the emissive materials to replace the quantum dots. BODIPY was chosen due to its narrow FWHM, high fluorescent efficiency, stability to both moisture and oxygen, and low production cost. However, BODIPY materials can have some drawbacks, such as very low absorption of blue LED light, e.g., 450 nm, resulting in inefficient conversion of blue LED light to green and red light. Another drawback of current BODIPY compounds is the FWHM tend to be broad when used in color converting films.

The current disclosure describes a photoluminescent complex and the use of the complex in color conversion films. The photoluminescent complex may be used to improve and enhance the transmission of one or more desired emissive bandwidths within a color conversion film. In some embodiments, the photoluminescent complex can both enhance the transmission of a desired first emissive bandwidth and decrease the transmission of a second emissive bandwidth. For example, a color conversion film can enhance the contrast or intensity between two or more colors, increasing the distinction from one another. The present disclosure includes a photoluminescent complex that can enhance the contrast or intensity between two colors, increasing their distinction from one another.

As used herein, when a compound or chemical structure is referred to as being optionally substituted, it may be unsubstituted, or it may be substituted, meaning it can include one or more substituents. A substituted group is related to the unsubstituted parent structure in that one or more hydrogen atoms on the parent structure have been independently replaced by one or more substituent groups. A substituent group may have one or more substituent groups on the parent group structure. In one or more forms, the substituent groups may independently be F, Cl, Br, I, C₀₋₇H₁₋₁₅O₁₋₂N₀₋₂, C₀₋₇H₁₋₁₅O₀₋₂N₁₋₂, optionally substituted alkyl (including unsubstituted alkyl, such as methyl, ethyl, C₃ alkyl, C₄ alkyl, etc., fluoroalkyl, e.g. CF₃, etc.), alkenyl, or a C₃-C₇ heteroalkyl.

The term “alkyl” group as used herein refers to an aliphatic hydrocarbon group that does not contain any C═C or CEC moieties. The alkyl moiety may be branched, straight chain, or cyclic.

The alkyl moiety may have 1 to 6 carbon atoms. Where it appears herein, a numerical range such as “1 to 6” refers to each integer in the given range. For example, “1 to 6 carbon atoms” means that the alkyl group may have 1 carbon atom, 2 carbon atoms, 3 carbon atoms, etc., up to and including 6 carbon atoms, although the present definition also covers the occurrence of the term “alkyl” where no numerical range is designated. The alkyl group of the compounds designated herein may be designated as “C₁-C₆ alkyl” or similar designations. By way of example only, “C₁-C₆ alkyl” indicates that there are one to six carbon atoms in the alkyl chain, i.e., the alkyl chain is selected from among methyl, ethyl, propyl, iso-propyl, n-butyl, iso-butyl, sec-butyl, and t-butyl. Thus, C₁-C₆ alkyl includes C₁-C₂ alkyl, C₁-C₃ alkyl, C₁-C₄ alkyl, C₁-C₅ alkyl. Alkyl groups can be substituted or unsubstituted. Typical alkyl groups include, but are in no way limited to, methyl, ethyl, propyl, isopropyl, butyl, isobutyl, tertiary butyl, pentyl, hexyl, cyclopropyl, cyclobutyl, cyclopentyl, cyclohexyl, and the like.

An “alkene moiety refers to a group that has at least one carbon-carbon double bond (—C═C—), such as propenyl or butenyl, and an “alkyne” moiety refers to a group that has at least one carbon-carbon triple bond (—C≡C—).

The term “heteroalkyl” as used herein refers an alkyl group, as defined herein, in which one or more of the constituent carbon atoms have been replaced by a nitrogen, oxygen, sulfur, or a halogen (such as F). Examples include but are not limited to, —CH₂—O—CH₃, —CH₂—CH₂—O—CH₃, —CH₂—NH—CH₃, —CH₂—N(CH₃)—CH₃, —CH₂—CH₂—NH—CH₃, —CH₂—CH₂—N(CH₃)—CH₃, —CH₂—S—CH₂—CH₃, —CH₂—CH₂—S(O)—CH₃. In addition, up to two heteroatoms may be consecutive, such as, by way of example, —CH₂—NH—O—CH₃, etc.

The term “aromatic” refers to a planar ring having a delocalized n-electron system containing 4n+2 π-electrons, where n is an integer. Aromatic rings can be formed from five, six, seven, eight, nine, or more than nine atoms. Aromatics can be optionally substituted. The term “aromatic” includes both carbocyclic aryl (e.g., phenyl) and heterocyclic aryl (or “heteroaryl” or heteroaromatic”) group (e.g., pyridine). The term includes monocyclic or fused-ring polycyclic (i.e., rings which share adjacent pairs of carbon atoms) groups.

The term “hydrocarbon ring” refers to a monocyclic or polycyclic radial that contains only carbon and hydrogen atoms and may be saturated. Monocyclic hydrocarbon rings include groups having from 3 to 12 carbon atoms. Illustrative examples of monocyclic groups include the following moieties:

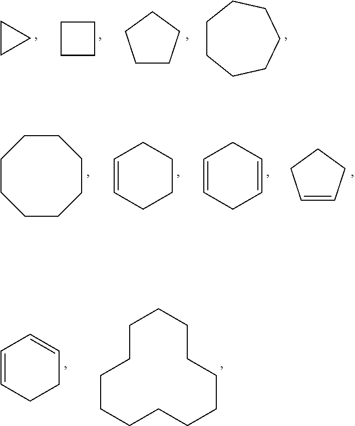

and the like. Illustrative examples polycyclic groups include the following moieties:

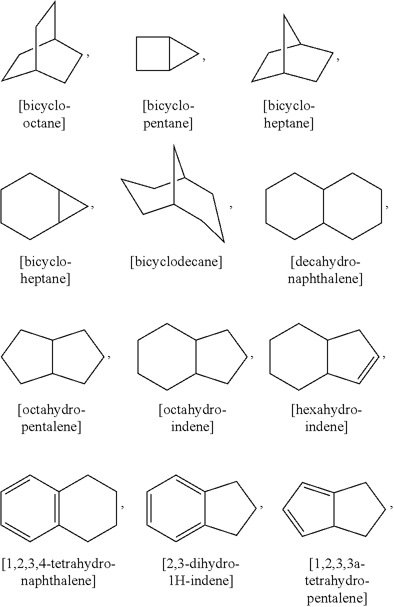

and the like.

The term “aryl” as used herein means an aromatic ring wherein each of the atoms forming the ring is a carbon atom. Aryl rings can be formed by five, six, seven eight, or more than eight carbon atoms. Aryl groups can be substituted or unsubstituted. Examples of aryl groups include, but are not limited to phenyl, naphthalenyl, phenanthrenyl, etc.

The term “heteroaryl” refers to an aryl group that include one or more ring heteroatoms such as nitrogen, oxygen and sulfur, wherein the heteroaryl group has from 4 to 10 atoms in its ring system and with the proviso that the ring of the group does not contain two adjacent nitrogen, oxygen, or sulfur atoms. It is understood that the heteroaryl ring can have additional heteroatoms in the ring. In heteroaryls that have two or more heteroatoms, those two or more heteroatoms can be the same or different from one another. Heteroaryls can be optionally substituted. An N-containing heteroaryl moiety refers to an aryl group in which at least one of the skeletal atoms of the ring is a nitrogen atom. Illustrative examples of heteroaryl groups include the following moieties: pyrrole, imidazole, etc.

The term “halogen” as used herein means fluorine, chlorine, bromine, and iodine.

The term “bond”, “bonded”, “direct bond” or “single bond” as used herein means a chemical bond between two atoms or to two moieties when the atoms joined by the bond are considered to be part of a larger structure.

The term “moiety” as used herein refers to a specific segment or functional group of a molecule.

The term “cyano” or “nitrile” as used herein refers to any organic compound that contains a —CN functional group.

The term “ester” refers to a chemical moiety with the formula —COOR, where R is selected from among alkyl, cycloalkyl, aryl, heteroaryl (bonded through a ring carbon) and heterocyclic (bonded through a ring carbon). Any hydroxy or carboxyl side chain on the compounds described herein can be esterified. The procedures and specific groups to make such esters are known to those skilled in the art and can readily be found in reference sources.

As used herein the term “ether” refers to a chemical moiety that contains an oxygen atom connected to: two alkyl groups; two aryl groups; or one alkyl group and one aryl group; with the general formula of R—O—R′, where the term alkyl and aryl is as defined herein.

As used herein the term “ketone” refers to the chemical moiety that contains a carbonyl group (a carbon-oxygen double bond) connected to: two alkyl groups; two aryl groups; or one alkyl group and one aryl group; with the general formula of RC(═O)R′, wherein the term alkyl and aryl is as defined herein.

The term “BODIPY” as used herein, refers to a chemical moiety with the formula:

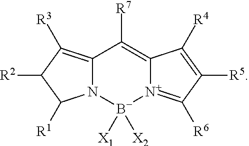

The BODIPY may be composed of dipyrromethene complexed with a di-substituted boron atom, typically a BF₂ unit. The IUPAC name for the BODIPY core is 4,4-difluoro-4-bora-3a,4a-diaza-s-indacene.

In some embodiments, the optionally substituted perylene comprises:

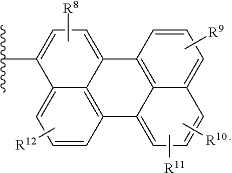

The present disclosure is related to photoluminescent complexes that absorb light energy of a first wavelength and emit light energy of a second higher wavelength. The photoluminescent complexes of the present disclosure comprise an absorbing luminescent moiety and an emitting luminescent moiety that are coupled through a linker such that their distance is optimized for the absorbing luminescent moiety to transfer its energy to the acceptor luminescent moiety, wherein the acceptor luminescent moiety then emits energy at a second wavelength that is larger than the absorbed first wavelength. In some embodiments, the photoluminescent complex can be described by general formula 1a:

Z-L-E [Formula 1a].

In other embodiments, the photoluminescent complex can be described by general formula 1b:

Z-L-E-L-Z [Formula 1b].

In still other embodiments, the photoluminescent complex can be described by general formula 1c:

E-L-Z-L-E [Formula 1c].

In still other embodiments, the photoluminescent complex can be described by general formula 1d:

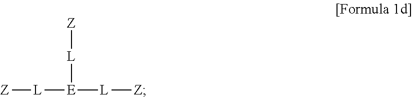

wherein Z represents a blue light absorbing moiety, L represents a linker and E represents a luminescent moiety. In some embodiments, the perylene absorbing moiety, the linker and the BODIPY luminescent moiety are selected from specific structures described herein. The photoluminescent complexes described herein can be incorporated into a color conversion film, greatly increasing the discernibility between colors in the Red Green Blue (RGB) gambit, resulting in increased contrast and higher quality color rendition.

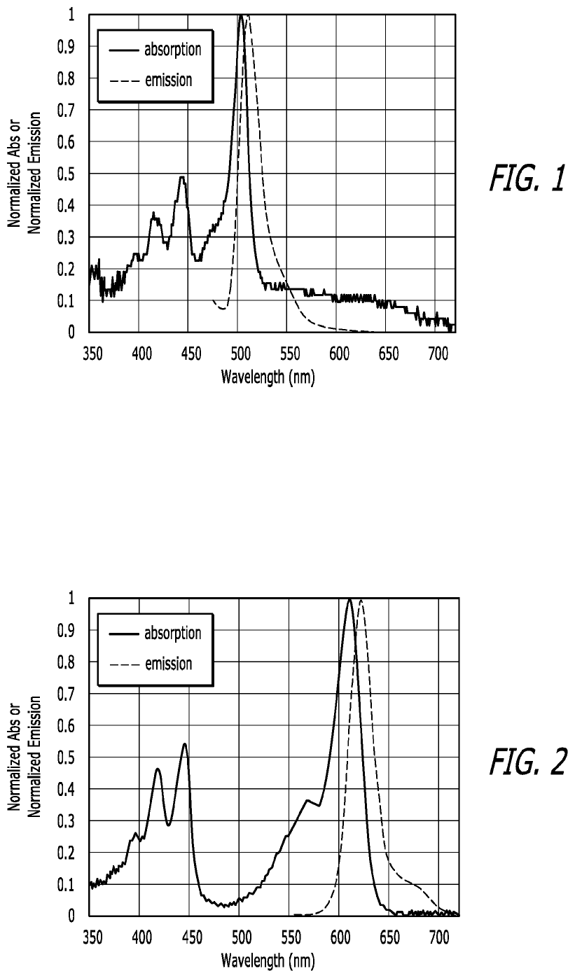

Some photoluminescent complexes comprise: a blue light absorbing moiety; a linker moiety; and a boron-dipyrromethene (BODIPY) moiety. In some embodiments, the linker moiety may covalently link the blue light absorbing moiety to the BODIPY moiety. In some embodiments, the blue light absorbing moiety may be selected from an optionally substituted perylene. In some embodiments, the blue light absorbing optionally substituted perylene is represented as Z in Formulae 1a-1d. In some embodiments, the luminescent BODIPY moiety is represented as E in Formulae 1a-1d. In some embodiments, the blue light absorbing moiety absorbs light of a first excitation wavelength and transfers energy to the BODIPY moiety, and then the BODIPY moiety then emits a light energy of a second wavelength, wherein the light energy of the second wavelength is higher than the first wavelength. It is believed that energy transfer from the excited blue light absorbing moiety to the BODIPY moiety occurs through a Forster resonance energy transfer (FRET). This belief is due to the absorbance/emission spectra of the photoluminescent complexes where there are two major absorption bands, one at the blue light absorbing moiety absorption band and one at the BODIPY absorption band, and only one emission band located at the BODIPY moiety's emission wavelength (see FIGS. 1 and 2).

In an embodiment, the photoluminescent complex can have a high emission quantum yield. In some embodiments, the emission quantum yield can be greater than 50%, 60%, 70%, 80%, or 90%. In some embodiments, the emission quantum yield can be greater than 50%, or 55%, or 60%, or 65%, or 70%, or 75%, or 80%, or 85%, or 90%, or 95%. Emission quantum yield can be measured by dividing the number of photons emitted by the number of photons absorbed, which is equivalent to the emission efficiency of the luminescent moiety. In some embodiments, the absorbing luminescent moiety, may have an emission quantum yield greater than 80%. In some embodiments, the quantum yield can be greater than 0.8 (80%), 0.81 (81%), 0.82 (82%), 0.83 (83%), 0.84 (84%), 0.85 (85%), 0.86 (86%), 0.87 (87%), 0.88 (88%), 0.89 (89%), 0.9 (90%), 0.91 (91%), 0.92 (92%), 0.93 (93%), 0.94 (94%), and/or 0.95 (95%). Quantum yield measurements in film can be made by spectrophotometer, e.g., Quantaurus-QY spectrophotometer (Humamatsu, Inc., Campbell, Calif., USA). In some embodiments, the quantum yield can be about 0.8 (80%) to about 0.81 (81%), about 0.81 (81%) to about 0.82 (82%), about 0.82 (82%) to about 0.83 (83%), about 0.83 (83%) to about 0.84 (84%), about 0.84 (84%) to about 0.85 (85%), about 0.85 (85%) to about 0.86 (86%), about 0.86 (86%) to about 0.87 (87%), about 0.87 (87%) to about 0.88 (88%), about 0.88 (88%) to about 0.89 (89%), about 0.89 (89%) to about 0.9 (90%), about 0.9 (90%) to about 0.91 (91%), about 0.91 (91%) to about 0.92 (92%), about 0.92 (92%) to about 0.93 (93%), about 0.93 (93%) to about 0.94 (94%), about 0.94 (94%) to about 0.95 (95%), or about 0.95 (95%) to about 1 (100%).

In some embodiments, the photoluminescent complex has an emission band, wherein the emission band can have a full width half maximum (FWHM) of less than 40 nm. The FWHM is the width of the emission band in nanometers at the emission intensity that is half of the maximum emission intensity for the band. In some embodiments, the photoluminescent complex has an emission band FWHM value that is less than or equal to about 35 nm, less than or equal to about 30 nm, less than or equal about 25 nm, less than or equal to about 20 nm. In some embodiments, the FWHM is about 40 nm to about 35 nm, about 35 nm to about 30 nm, about 30 nm to about 25 nm, about 25 nm to about 20 nm, or less than about 20 nm.

In some embodiments, the difference between the excitation peak of the blue light absorbing moiety and the emission peak of the BODIPY moiety of photoluminescent complex is at least 45 nm. In some embodiments, the difference between the excitation peak of the blue light absorbing moiety and the emission peak of the BODIPY moiety of photoluminescent complex can be about 45 nm to about 50 nm, about 50 nm to about 55 nm, about 55 nm to about 60 nm, about 60 nm to about 65 nm, about 65 nm to about 70 nm, about 70 nm to about 75 nm, about 75 nm to about 80 nm, about 80 nm to about 85 nm, about 85 to about 90 nm, about 90 nm to about 95 nm, about 95 nm to about 100 nm, or greater than about 100 nm, or any number bound by this range.

The photoluminescent complex of the current disclosure can have a tunable emission wavelength. By modifying the substituents of the BODIPY moiety, the emission wavelength can be tuned between 510 nm to about 560 nm, between about 610 nm to about 645 nm, or any number in a range bounded by any of these values.

In some embodiments, the blue light absorbing moiety can have a peak absorption maximum between about 400 nm to about 470 nm wavelength. In some embodiments, the peak absorption can be between about 400 nm to about 405 nm, about 405 nm to about 410 nm, about 410 nm to about 415 nm, about 415 nm to about 420 nm, about 420 nm to about 425 nm, about 425 nm to about 430 nm, about 430 nm to about 435 nm, about 435 nm, to about 440 nm, about 440 nm to about 445 nm, about 445 nm, to about 450 nm, about 450 nm to about 455 nm, about 455 nm to about 460 nm, about 460 nm to about 465 nm, about 465 nm to about 470 nm or any number in a range bounded by any of these values.

In some embodiments, the photoluminescent complex can have an emission peak between 510 nm and 560 nm. In some embodiments, the emission peak can be between about 510 nm to about 515 nm, about 515 nm to about 520 nm, about 520 nm to about 525 nm, about 525 nm to about 530 nm, about 530 nm to about 535 nm, about 535 nm to about 540 nm, about 540 nm to about 545 nm, about 545 nm to about 550 nm, about 550 nm to about 555 nm, about 555 nm to about 560 nm, or any number in a range bounded by any of these values.

In another embodiment, the photoluminescent complex can have an emission peak between 610 nm to 645 nm. In some embodiments, the emission peak can be between 610 nm to about 615 nm, about 615 nm to about 620 nm, about 620 nm to about 625 nm, about 625 nm to about 630 nm, about 630 nm to about 635 nm, about 635 nm to about 640 nm, about 640 nm to about 645 nm, or any number in a range bounded by any of these values.

Other embodiments include the photoluminescent complex wherein the blue light absorbing moiety and the BODIPY derivative luminescent moiety's spatial distance is optimized through the linker moiety, for transfer of the blue light absorbing moiety's energy to be transferred to the BODIPY derivative luminescent moiety.

The photoluminescent complex of the current disclosure can comprise a BODIPY moiety. The BODIPY moiety can have the following chemical Formula 2;

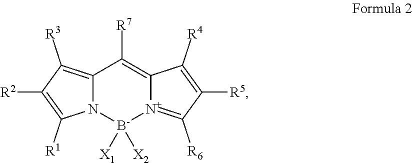

wherein R¹ and R⁶ are independently H or C₁₋₆ H₃₋₁₃O₀₋₂ (such as C₁₋₆ alkyl, including methyl, C₂ alkyl, C₃ alkyl, C₄ alkyl, etc., or an ester such as an alkyl alkenoate, e.g. —CH═CHCO₂CH₂CH₃); R³ and R⁴ are independently H, or a C₁-C₅ alkyl; R² and R⁵ are selected from H, a C₁-C₅ alkyl, a cyano, an aryl alkynyl, an aryl ester, an alkyl ester, or a carboxylate group bound to a linker moiety; R² and R³ may link together to form an additional monocyclic hydrocarbon ring structure, or polycyclic hydrocarbon ring structure; R⁴ and R⁵ may link together to form an additional monocyclic hydrocarbon ring structure, or polycyclic hydrocarbon ring structure; R⁷ is selected from a direct bond to a linker moiety, an aryl group, or an aryl group bound to a linker moiety; X₁ and X₂ are independently selected from a halogen group.

In some embodiments, R¹ and R⁶ can be a H.

In some embodiments, R¹ and R⁶ can be a C₁-C₄ branched or straight chain alkyl. In some embodiments, R¹ and R⁶ can be a methyl. In some embodiments, R¹ and R⁶ can be an ethyl.

In some embodiments, R¹ and R⁶ can be an alkenyl ester. In some embodiments, the alkenyl ester can be an ethenyl butenoate.

In some embodiments, R² and R⁵ can be a H.

In some embodiments, R² and R⁵ can be a nitrile group.

In some embodiments, R² and R⁵ can be an aryl alkynyl. In some embodiments, the aryl alkynyl can be 1-propynyl benzene.

In some embodiments, R² and R⁵ can be an aryl ester. In some embodiments, the aryl ester can be a benzyl ester.

In some embodiments, R² and R⁵ can be an aryl ester. In some embodiments, the alkyl ester can be an ethyl ester.

In some embodiments, R² and R³ may link together to form an additional monocyclic hydrocarbon ring structure, or polycyclic hydrocarbon ring structure. In embodiments, where R² and R³ are linked together to form a monocyclic hydrocarbon ring structure, the structure can be selected from the following:

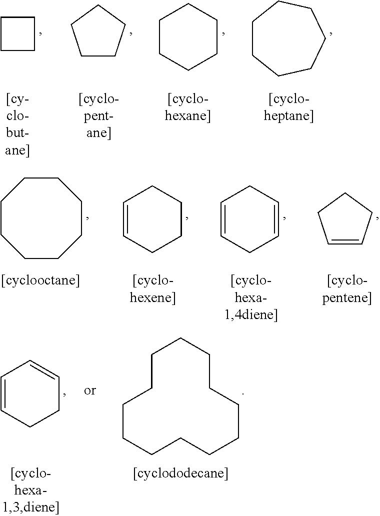

In some embodiments, where R² and R³ are linked together to form a polycyclic hydrocarbon ring structure, the structure can be selected from the following:

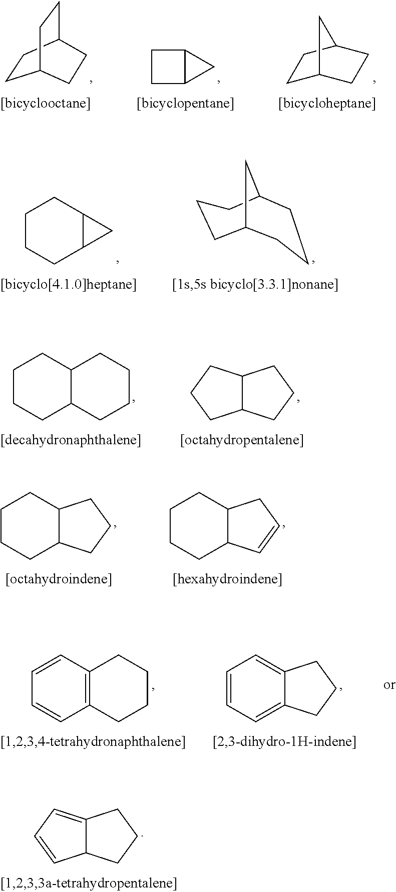

In some embodiments, R⁴ and R⁵ may link together to form an additional monocyclic hydrocarbon ring structure, or polycyclic hydrocarbon ring structure. In embodiments, where R⁴ and R⁵ are linked together to form a monocyclic hydrocarbon ring structure, the structure can be selected from the following:

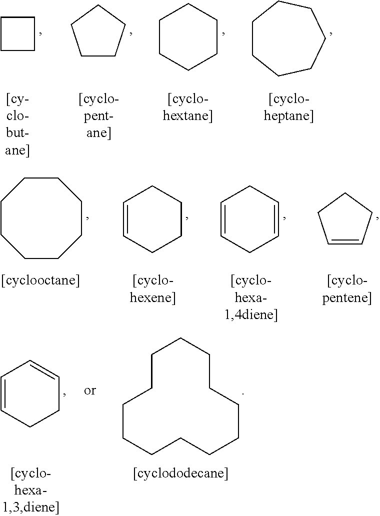

In some embodiments, where R⁴ and R⁵ are link together to form a polycyclic hydrocarbon ring structure, the structure can be selected from the following:

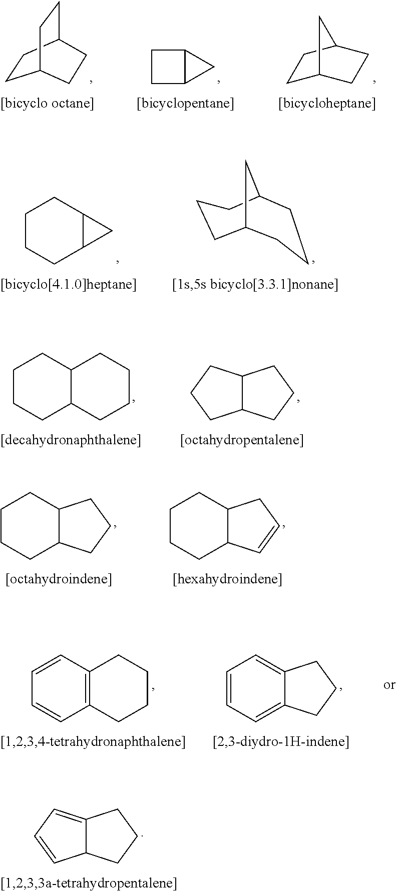

In some embodiments, R⁷ is selected from a direct bond to a linker moiety or an aryl group. When the aryl group is substituted, the substituent can be selected from among: a methyl, a dimethyl, a trimethyl, a fluoro, a difluoro, a trifluoro, a chloro, a dichloro, a trichloro, a methoxy, a dimethoxy, or a trimethoxy group. It is believed that by incorporating any one of the above described substituents on the R⁷ phenyl the BODPIY structure becomes more rigid, preventing flexibility within the structure, resulting in a higher quantum yield. In some embodiments the aryl group is selected from a phenyl or a biphenyl. In some embodiments, R⁷ is a phenyl or biphenyl that is selected from among the following structures:

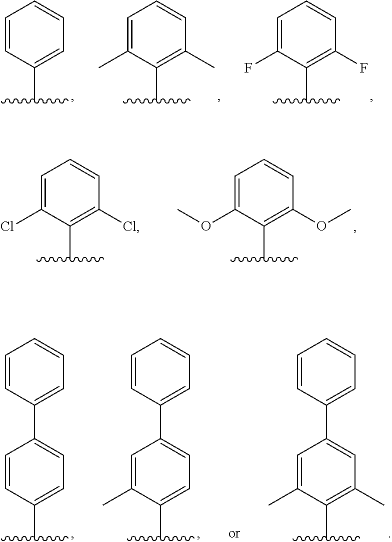

In some embodiments, R⁷ is a phenyl or biphenyl that is positioned between a BODIPY and a linker moiety, that is selected from among the following structures:

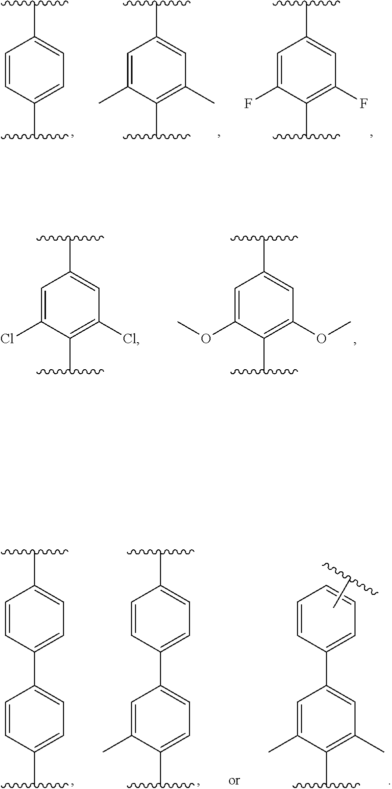

In some embodiments, the distance separating the blue light absorbing moiety and the BODIPY moiety can be about 8 Å or greater. The linker moiety can maintain a distance between the blue light absorbing moiety and the BODIPY moiety.

In some embodiments, the photoluminescent complex comprises a linker moiety, also referred to herein as L, wherein the linker moiety covalently links the blue light absorbing moiety (the optionally substituted perylene) to the BODIPY moiety. In some embodiments, the linker moiety can comprise a single bond between the optionally substituted perylene and the BODIPY moiety. In some embodiments, the linker moiety can comprise an optionally substituted C₂-C₇ ester group. When the linker group comprises an optionally substituted C₂-C₇ ester group, the linker moiety (L) can be selected from among one of the following:

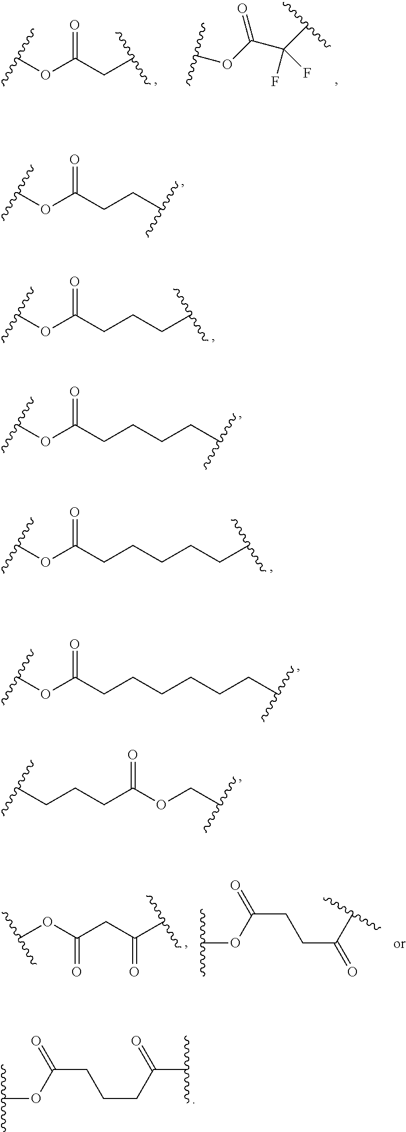

In other embodiments, the linker moiety (L) can comprise an unsubstituted C₂-C₆ ether group. When the linker moiety comprises an unsubstituted C₂-C₆ ether group, the linker moiety can be selected from among one of the following:

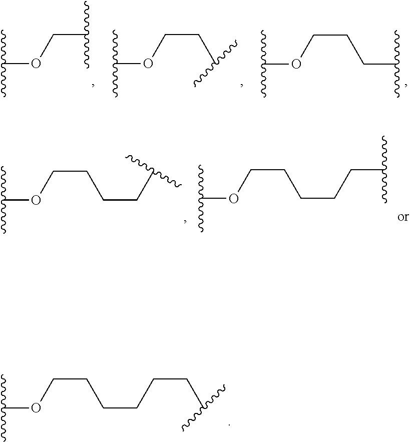

In some embodiments, R² and R⁵ may be an alkyl ester. In some embodiments, R² and R⁵ may be a carboxylate group bound to a linker moiety. In some embodiments, R² and R⁵ may be

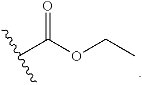 [SMILES: *C(=O)OCC]

In some embodiments, R² and R⁵ may be

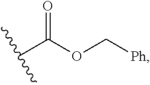

wherein Ph is phenyl. In some embodiments, R² and R⁵ may be a carboxylate group,

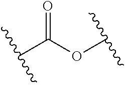 [SMILES: *OC(*)=O]

bound to a linker moiety. In some embodiments, when R² and R⁵ are a carboxylate group, the linker moiety bound to R² and/or R⁵ may be

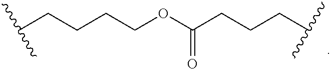 [SMILES: *CCCCOC(=O)CCC*]

In some embodiments, a photoluminescent complex comprises a blue light absorbing moiety. The blue light absorbing moiety can comprise an organic lumiphore. In some embodiments, the absorbing luminescent moiety may have a maximum absorbance in the light in the range of 400 nm to about 480 nm, about 400 nm to about 410 nm, about 410 nm to about 420 nm, about 420 nm to about 430 nm, about 430 nm to about 440 nm, about 440 nm to about 450 nm, about 450 nm to about 460 nm, about 460 nm to about 470 nm, about 470 nm to about 480 nm, or any wavelength that is in a range bounded by any of these values. In some embodiments, the photoluminescent complex can have an absorbance maximum peak of about 450 nm. In other embodiments, the blue light absorbing moiety can have a maximum peak absorbance of about 405 nm. In still other embodiments, the blue light absorbing moiety can have a maximum peak absorbance of about 480 nm.

In some embodiments, the blue light absorbing moiety may be an optionally substituted perylene of Formula 3:

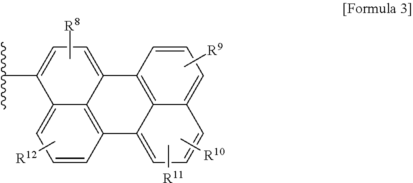

In some embodiments, R⁸, R⁹, R¹¹ and R¹² may be selected from H, a bond to L3, a straight chain C₁-C₆ alkyl, a branched C₃-C₆ alkyl, a cyano (—CN), a trifluoromethyl (—CF₃), or a 4-(trifluoromethyl)phenyl. When R⁹ is a H, a CN, or a CF₃ then R¹⁰ is a H. When R⁹ is a 4-(trifluoromethyl)phenyl then R^{m} may be an H or a direct bond to the 4-(trifluoromethyl)phenyl group forming a bridged substituted aromatic group, wherein the substituted bridged aromatic group forms a (trifluoromethyl)indeno[1,2,3-cd]perylene.

In some embodiments, R⁸, R⁹, R¹¹ and R¹² may independently be a bulky group, such as a bulky alkyl group, e.g. a bulky C₃₋₆ alkyl group. It is believed utilizing a bulky group attached to one or more of the substituents of the perylene, prevents rt-rt double bond stacking within and with other photoluminescent complexes when mixed within a mixture. It is believed that by preventing rt-rt double bond stacking, the photoluminescent complexes maintain the distances between the blue light absorbing moiety and the BODIPY moiety, preventing any deleterious optical effects caused by the rt-rt double bond stacking. Some non-limiting examples of groups bulky, such as bulky C₃₋₆ alkyl groups, include but are not limited to the following structures such as shown below:

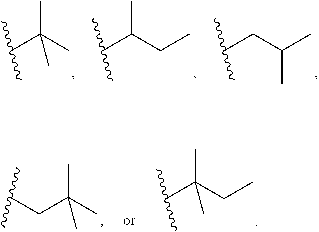

In other embodiments, R⁸, R⁹, R¹¹, and R¹² may independently be cyano (—CN), a trifluoromethyl (—CF₃), or a 4-(trifluoromethyl)phenyl group. It is believed that the addition of cyano, trifluoromethyl, or 4-(trifluoromethyl)phenyl groups at any of the R⁸, R⁹, R¹¹, and R¹² positions, helps increase the photostability of the photoluminescent complexes. Photo-stability (or durability) of organic compounds and complexes is a very common issue. Poor photo-stability of organic photoluminescent complexes is mostly due to the photo-oxidation process. It is believed that the addition of electron-withdrawing groups (also called electron-accepting groups) to the reactive sites on the perylene structure attract electrons by an induction effect or resonance effect from the atomic groups on the photoluminescent complex, resulting in a lower HOMO/LUMO energy level which is unfavorable for the photo-oxidation of the photoluminescent complex.

While any suitable electron-withdrawing group may be used, cyano groups (—CN), fluorine containing alkyl groups, such as, trifluoromethyl groups (—CF₃), or a fluorine containing aryl group, such as a 4-(trifluoromethyl)benzene group, may provide improved stability as compared to other types of electron-withdrawing groups.

Those of skill in the art will also recognize that the perylene may be substituted at any position during the reaction procedure. While the structural formulae provided herein depicts one of many possible regioisomers, it will be understood that these structures are illustrative only, and that the present disclosure is not limited to any particular isomer and any and all possible regioisomers of substituted perylene are intended to fall within the scope of the present disclosure.

In some embodiments, the optionally substituted perylene can be linked to a second boron-dipyrromethene (BODIPY) moiety. In some embodiments, the linker moiety and the second absorbing BODIPY moiety can be covalently linked. In other embodiments, the BODIPY moiety can be covalently linked to two or more blue light absorbing moieties. In some embodiments, the ratio between the blue light absorbing moiety and the BODIPY moiety can be 1:1. In another embodiment, the ratio between the blue light absorbing moiety and the BODIPY moiety can be 2:1. In another embodiment, the ratio between the blue light absorbing moiety and the BODIPY moiety can be 3:1. In still another embodiment, the ratio between the blue light absorbing moiety and the BODIPY moiety can be 1:2.

In some embodiments, the photoluminescent complex is represented by Formula A or B:

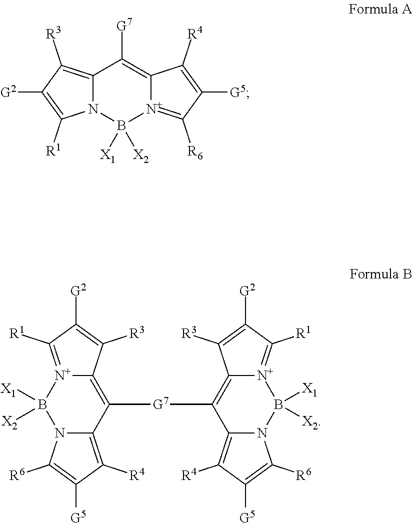

With respect to Formula A or B, the descriptions of R¹, R³, R⁴, R⁸, X₁ and X₂ detailed herein with respect to any other formula are also applicable to Formula A.

With respect to Formula A or B, G² is H, a C₁-C₅ alkyl, CN, an aryl alkynyl, an aryl ester, an alkyl ester, or C(═O)O(CH₂)₄—OC(═O)(CH₂)₃V. Additionally, G² may be any of the groups recited herein for R² or Z¹-L₁-R²—.

With respect to Formula A or B, G⁵ is H, a C₁-C₅ alkyl, CN, an aryl alkynyl, an aryl ester, an alkyl ester, or C(═O)O(CH₂)₄—OC(═O)(CH₂)₃—Z². Additionally, G⁵ may be any of the groups recited herein for R⁵ or —R⁵-L₂-Z².

With respect to Formula A or B, G⁷ is an optionally substituted aryl group, L₃-Z³, —Ar-L₃-Z³, -L₃-Z³-L₃, or —Ar-L₃-Z³-L₃-Ar—, wherein Ar is optionally substituted aryl. Additionally, G⁷ may be any of the groups recited herein for R⁷ or —R⁷-L₃-Z³.

With respect to Formula A, Formula B, or another formula or structural representation depicting L₃, L₃ is a single bond, or a linker moiety containing a —C(═O)O— or a —O— group. Additionally, L₃ may be any of the groups recited herein for L₃ depicted in any other formulas or other structural representations.

With respect to Formula A, Formula B, or another formula or structural representation depicting X₁ and X₂, X₁ and X₂ are independently F, Cl, Br, or I. Additionally, X₁ or X₂ may be any of the groups recited herein for X₁ or X₂ depicted in any other formulas or other structural representations.

With respect to Formula A, Formula B, or another formula or structural representation depicting Z¹, Z², and Z³, Z¹, Z², and Z³, are independently:

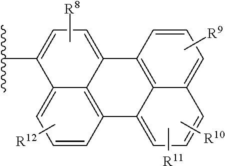

wherein R⁸, R⁹, R¹¹ and R¹² are independently H, a bond to L₁, L₂ or L₃, a branched C₄-C₅ alkyl, CN, CF₃, or a 4-(trifluoromethyl)phenyl; wherein R¹⁹ is H when: R⁹ is H, a branched C₄-C₅ alkyl, CN, F, or CF₃; wherein when R⁹ is a 4-(trifluoromethyl)phenyl, R¹⁰ is H or forms a direct bond to the 4-(trifluoromethyl)phenyl group, forming a (trifluoromethyl)indeno[1,2,3-cd]perylene. Additionally, Z¹, Z², or Z³ may be any of the groups recited herein for Z¹, Z², or Z³ depicted in any other formulas or other structural representations.

In one embodiment of the present specification, the complex represented by formula 1a: Z-L-E [Formula 1a], which may be represented by chemical Formula 4: [Formula 4],

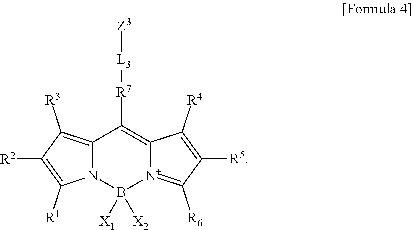

In Formula 4, the definitions of R¹, R², R³, R⁴, R⁵, R⁶, R⁷, X₁, X₂ are the same as those described in chemical Formula 2. L₃ represents the linker moiety as described above herein for R⁷. Z³ represents the blue light absorbing moiety represented by Chemical Formula 3 and the definitions/parameters for Z³ are the same as those of Chemical Formula 3 as described above herein.

In one embodiment of the present specification, the complex represented by Formula 1a, Z-L-E may be represented by chemical Formula 5:

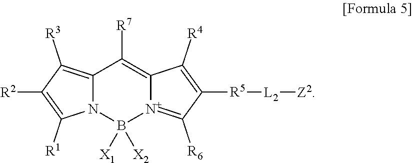

In Formula 5, the definitions of R¹, R², R³, R⁴, R⁶, R⁷, X₁, X₂ are the same as those described in Formula 2. R⁵ is a carboxylate group covalently bound to L₂. L₂ represents the linker moiety as described above herein for R⁵. Z² represents the blue light absorbing moiety represented by Formula 3 and the definitions/parameters for Z² are the same as those of Formula 3 described above herein.

In another embodiment of the present specification, the complex represented by Formula 1b: Z-L-E-L-Z [Formula 1b], which may be represented by chemical Formula 6:

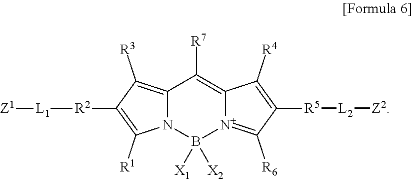

In Formula 6, the definitions of R¹, R², R³, R⁴, R⁵, R⁶, R⁷, X₁, X₂ are the same as those described in Formula 2. R² is a carboxylate group covalently bound to L₁. R⁵ is a carboxylate group covalently bound to L₂. L₁ and L₂ each represent a linker moiety and they are the same as the linker moiety described above herein for R² and R⁵. Z¹ and Z² represent the blue light absorbing moiety represented by Formula 3 and the definitions/parameters for Z¹ and Z² are the same as those of Formula 3 described above herein.

In one embodiment of the present specification the complex represented by formula 1d:

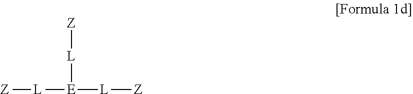

may be represented by Formula 7:

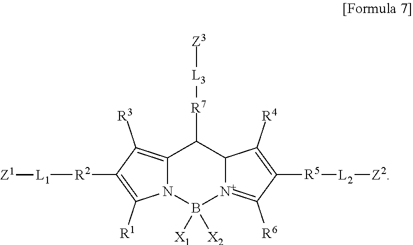

In Formula 7, the definitions of R¹, R², R³, R⁴, R⁵, R⁶, R⁷, X₁, X₂ are the same as those described in Formula 2. L₃ represents the linker moiety as described for R⁷ herein. R² is a carboxylate group covalently bound to L₁. R⁵ is a carboxylate group covalently bound to L₂. L₁ and L₂ each represent a linker moiety and they are the same as the linker moiety described above herein for R² and R⁵. Z¹, Z² and Z³ each represent a blue light absorbing moiety of Formula 3 and the definitions/parameters for Z¹, Z² and Z³ are the same as those of Formula 3, described above herein.

The photoluminescent complex of Formula 1a, 1b, 1c and 1d, may be represented by the following examples, but the present disclosure is not limited by these examples:

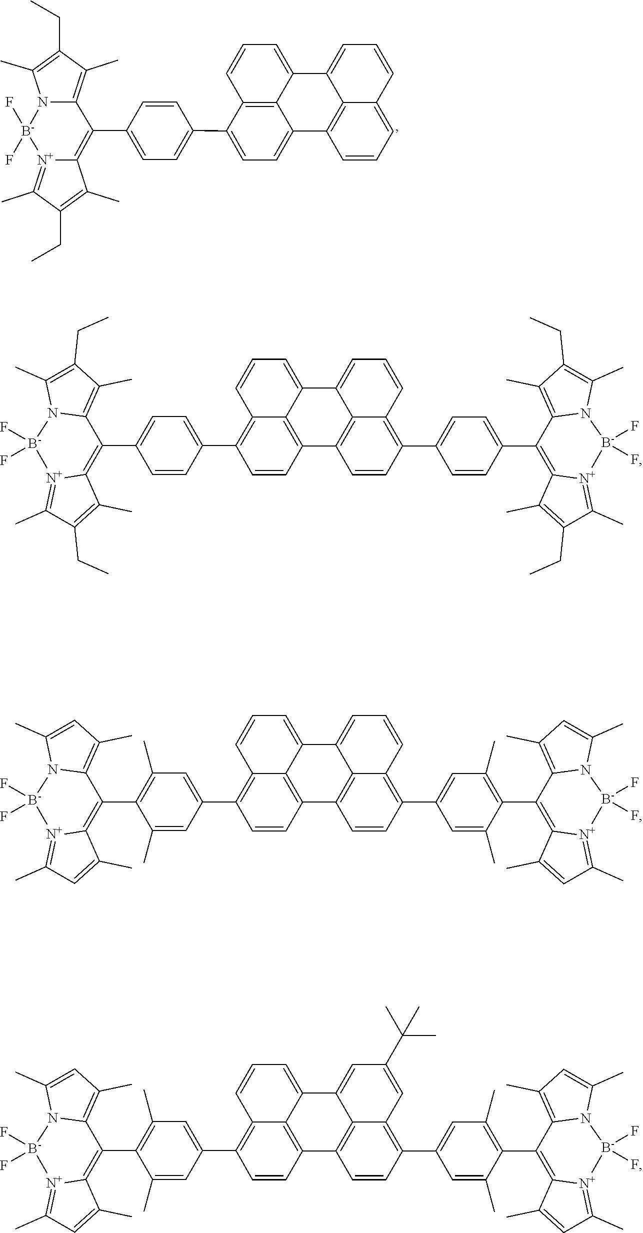

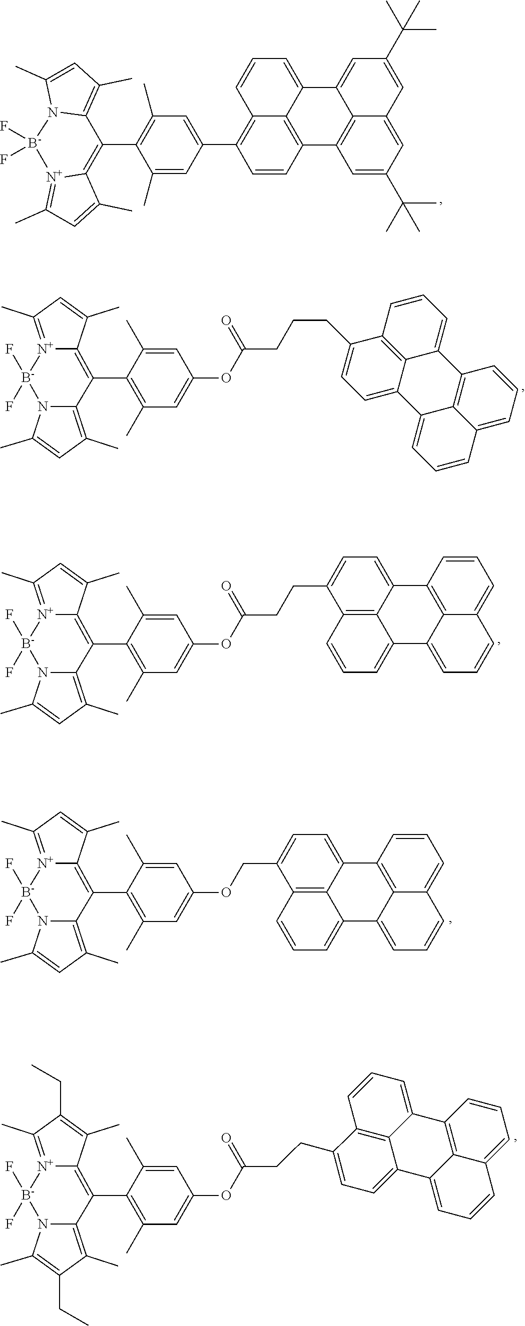

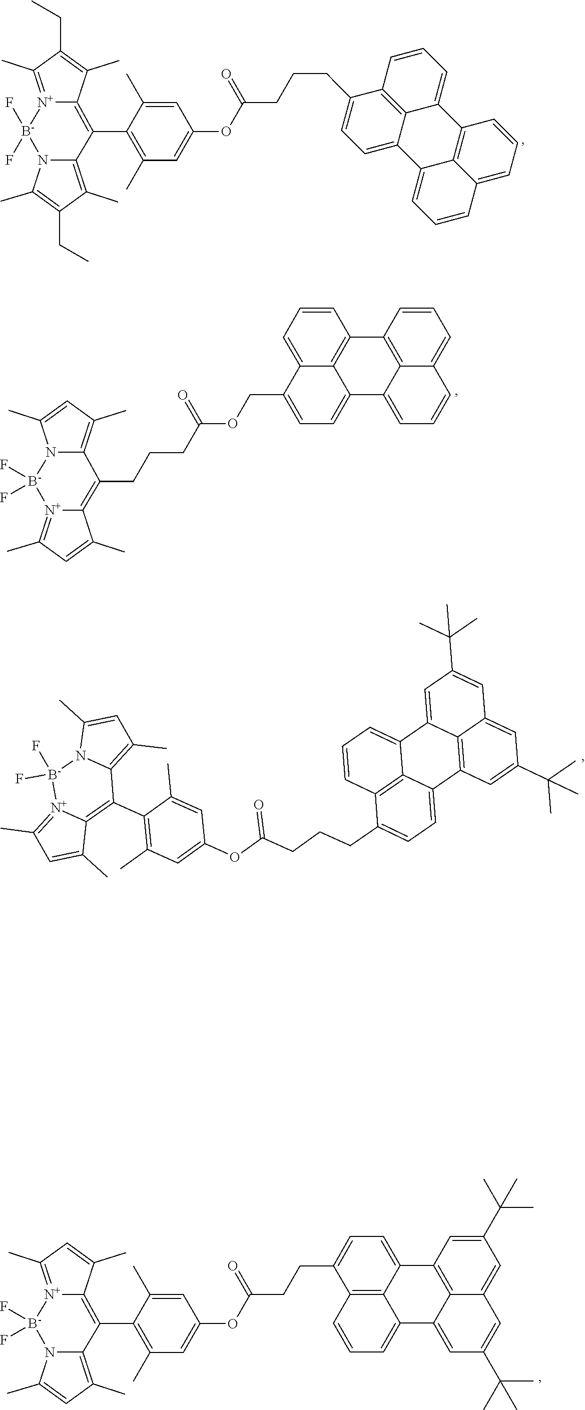 [SMILES: CCC1=C(C)C2=C(c3c(C)cc(OC(=O)CCCc4ccc5c6cccc7cccc(c8cccc4c85)c76)cc3C)c3c(C)c(CC)c(C)n3[B-](F)(F)[N+]2=C1C ; CC1=CC(C)=[N+]2C1=C(CCCC(=O)OCc1ccc3c4cccc5cccc(c6cccc1c63)c54)c1c(C)cc(C)n1[B-]2(F)F ; CC1=CC(C)=[N+]2C1=C(c1c(C)cc(OC(=O)CCCc3ccc4c5cc(C(C)(C)C)cc6cc(C(C)(C)C)cc(c7cccc3c74)c65)cc1C)c1c(C)cc(C)n1[B-]2(F)F ; CC1=CC(C)=[N+]2C1=C(c1c(C)cc(OC(=O)CCc3ccc4c5cc(C(C)(C)C)cc6cc(C(C)(C)C)cc(c7cccc3c74)c65)cc1C)c1c(C)cc(C)n1[B-]2(F)F]

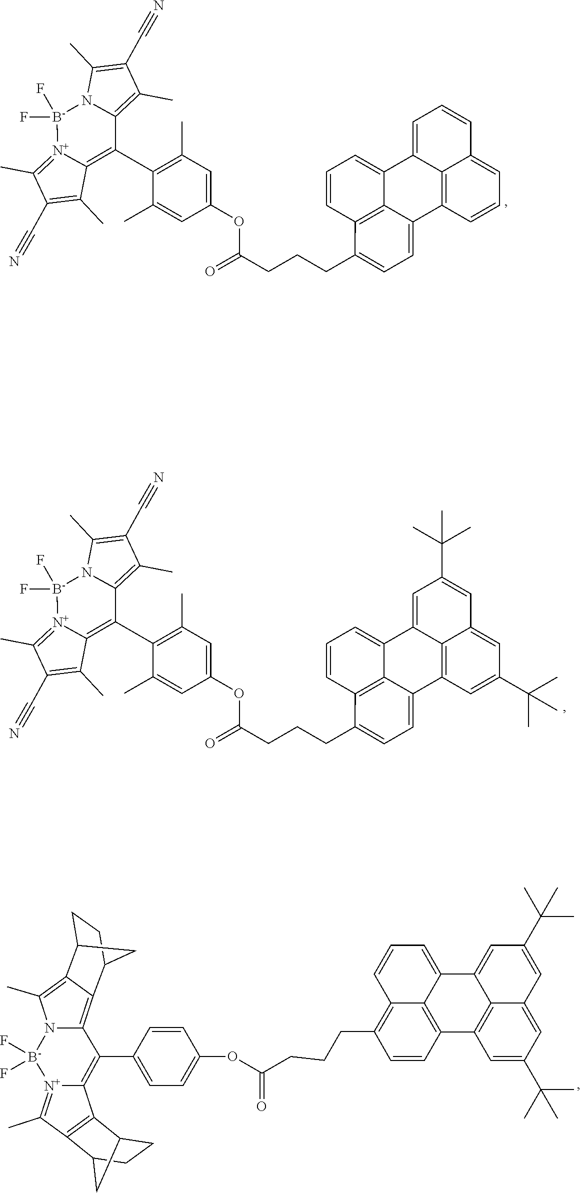 [SMILES: CC1=C(C#N)C(C)=[N+]2C1=C(c1c(C)cc(OC(=O)CCCc3ccc4c5cccc6cccc(c7cccc3c74)c65)cc1C)c1c(C)c(C#N)c(C)n1[B-]2(F)F ; CC1=C(C#N)C(C)=[N+]2C1=C(c1c(C)cc(OC(=O)CCCc3ccc4c5cc(C(C)(C)C)cc6cc(C(C)(C)C)cc(c7cccc3c74)c65)cc1C)c1c(C)c(C#N)c(C)n1[B-]2(F)F ; CC1=[N+]2C(=C(c3ccc(OC(=O)CCCc4ccc5c6cc(C(C)(C)C)cc7cc(C(C)(C)C)cc(c8cccc4c85)c76)cc3)c3c4c(c(C)n3[B-]2(F)F)C2CCC4C2)C2=C1C1CCC2C1]

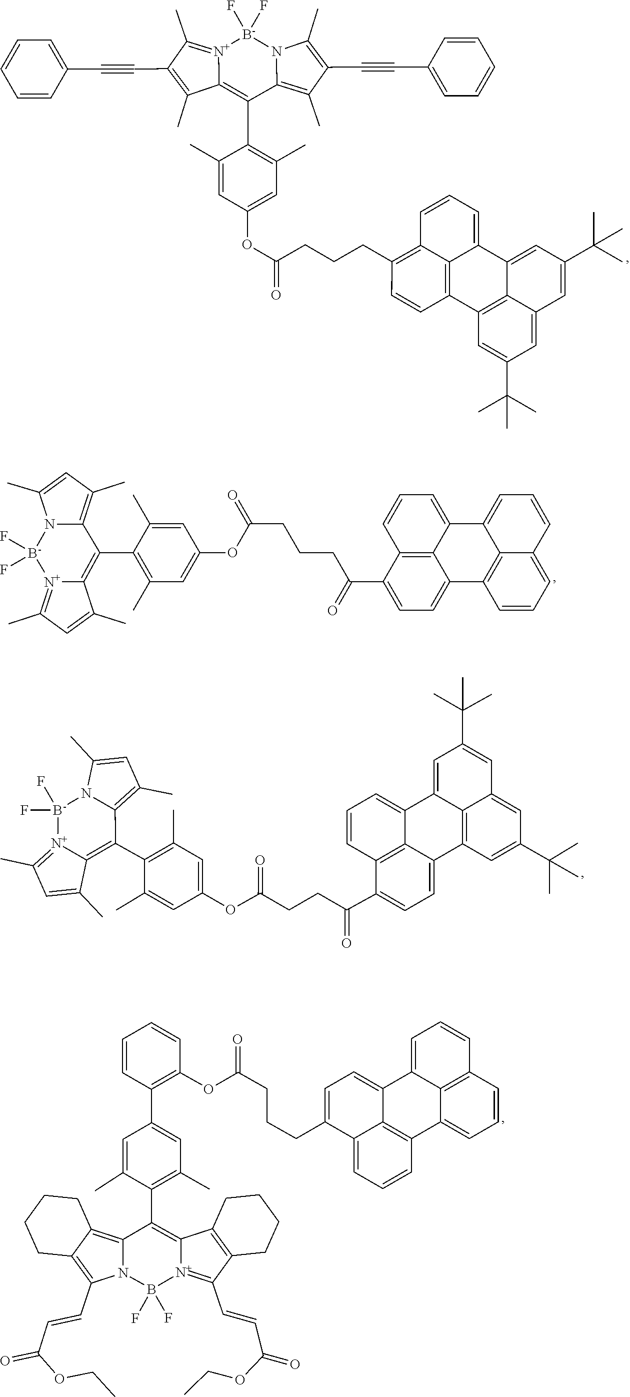

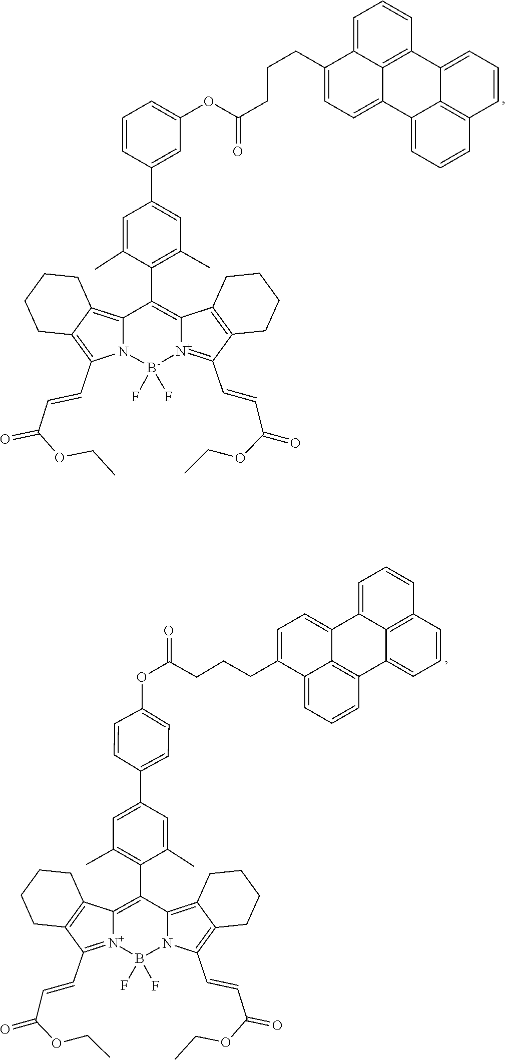

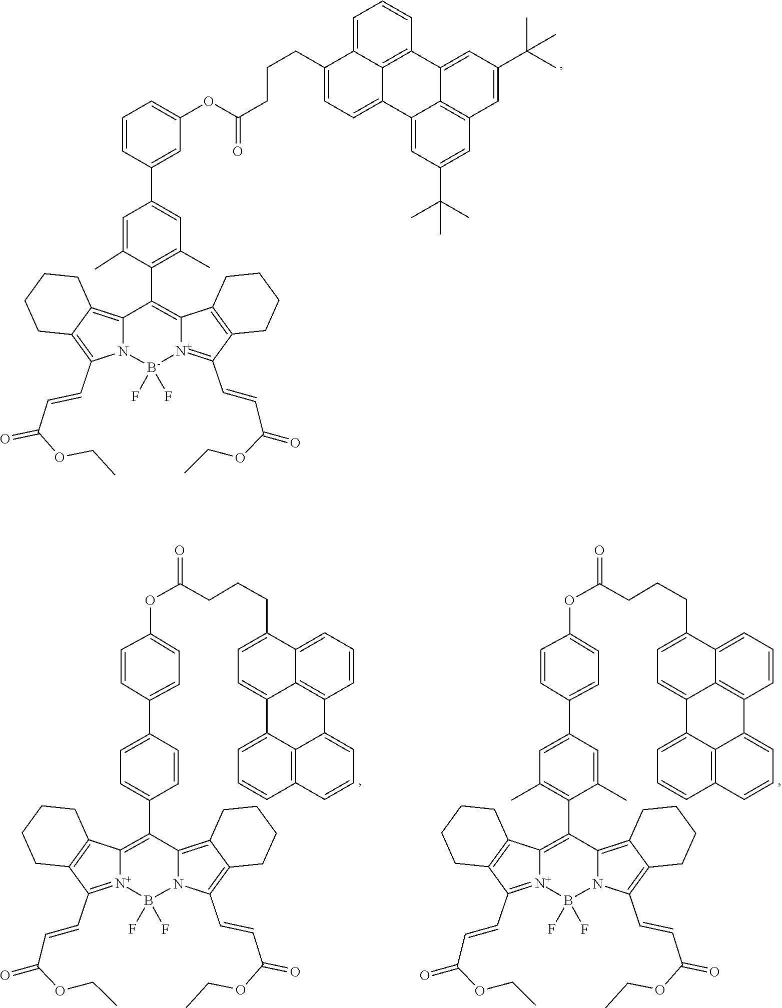

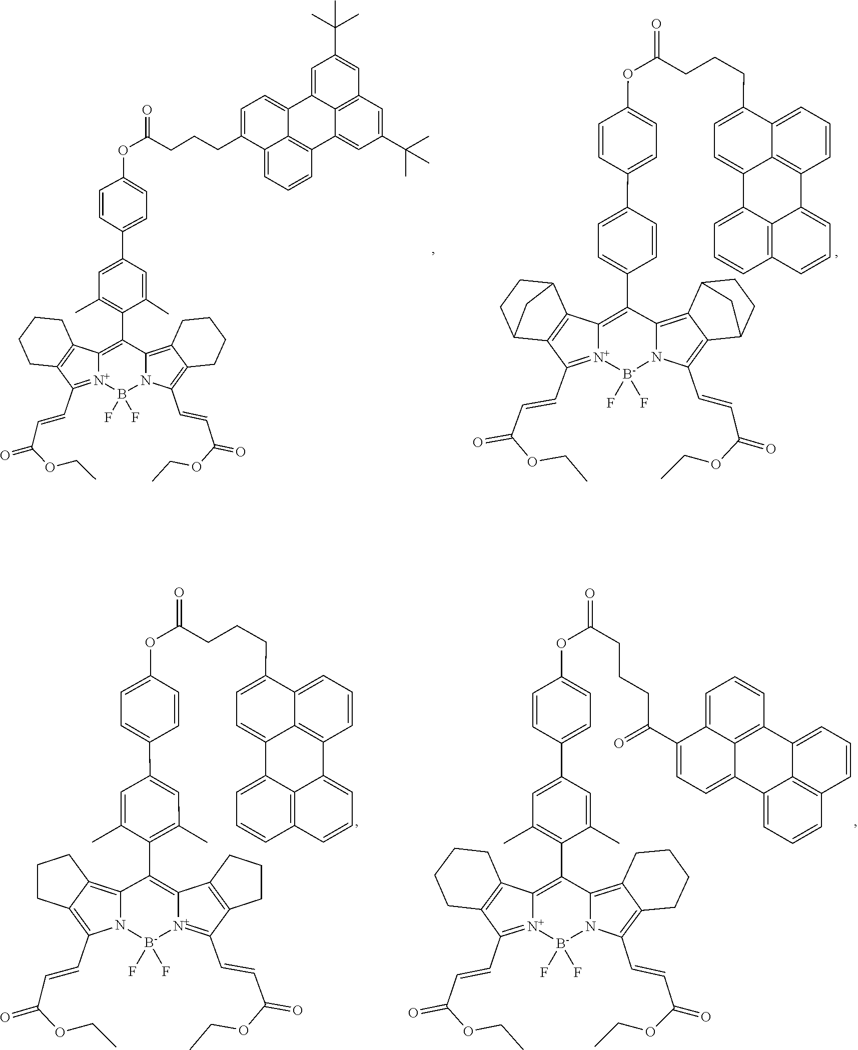

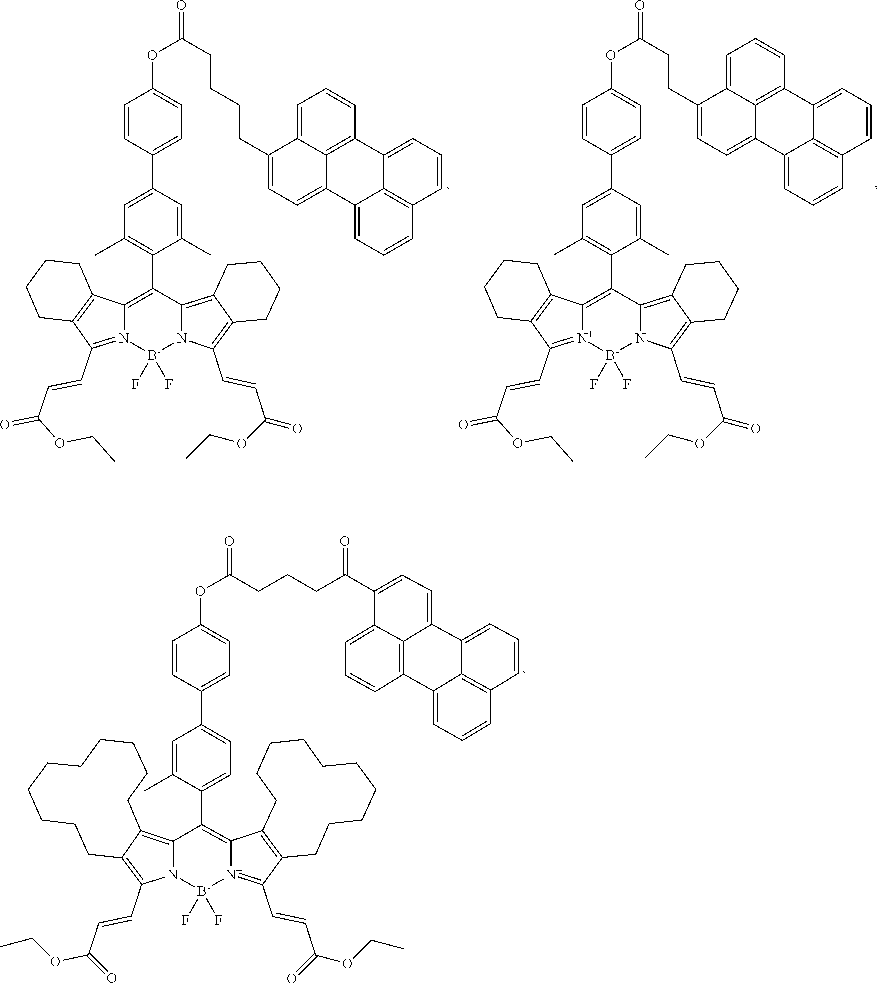 [SMILES: CCOC(=O)/C=C/C1=[N+]2C(=C(c3c(C)cc(-c4ccc(OC(=O)CCCCc5ccc6c7cccc8cccc(c9cccc5c96)c87)cc4)cc3C)c3c4c(c(/C=C/C(=O)OCC)n3[B-]2(F)F)CCCC4)C2=C1CCCC2 ; CCOC(=O)/C=C/C1=[N+]2C(=C(c3c(C)cc(-c4ccc(OC(=O)CCc5ccc6c7cccc8cccc(c9cccc5c96)c87)cc4)cc3C)c3c4c(c(/C=C/C(=O)OCC)n3[B-]2(F)F)CCCC4)C2=C1CCCC2 ; CCOC(=O)/C=C/C1=[N+]2C(=C(c3ccc(-c4ccc(OC(=O)CCCC(=O)c5ccc6c7cccc8cccc(c9cccc5c96)c87)cc4)cc3C)c3c4c(c(/C=C/C(=O)OCC)n3[B-]2(F)F)CCCCCCCCCC4)C2=C1CCCCCCCCCC2]

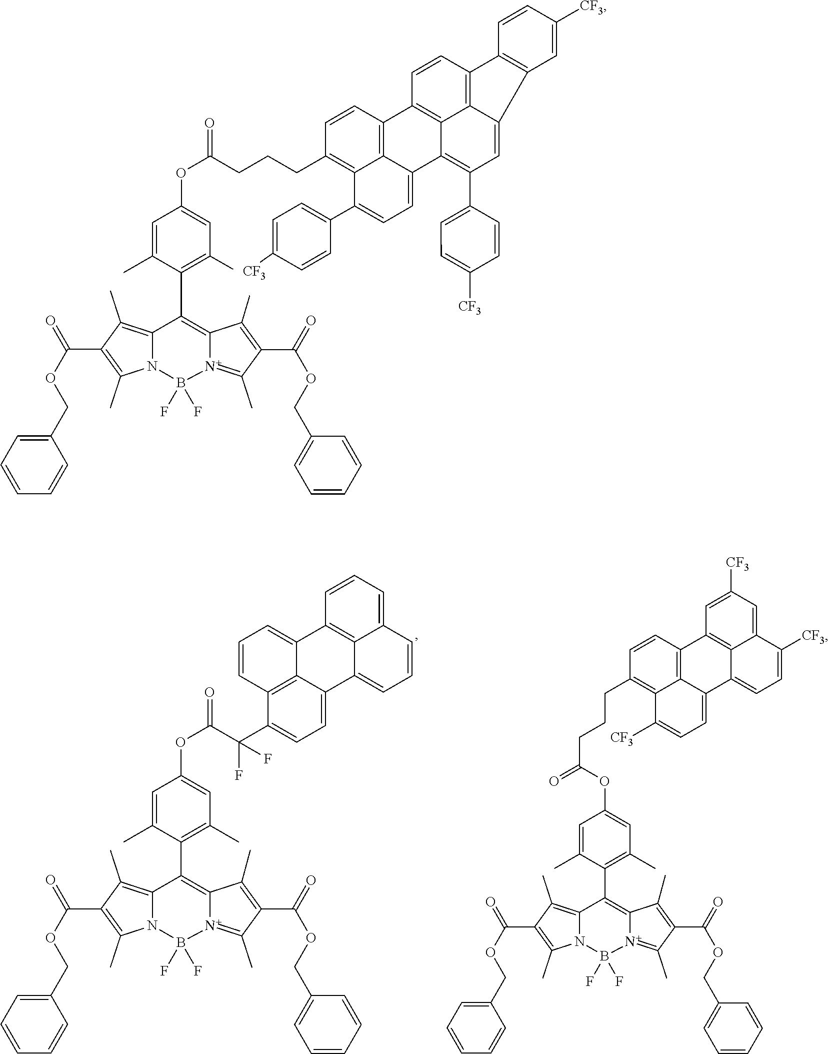

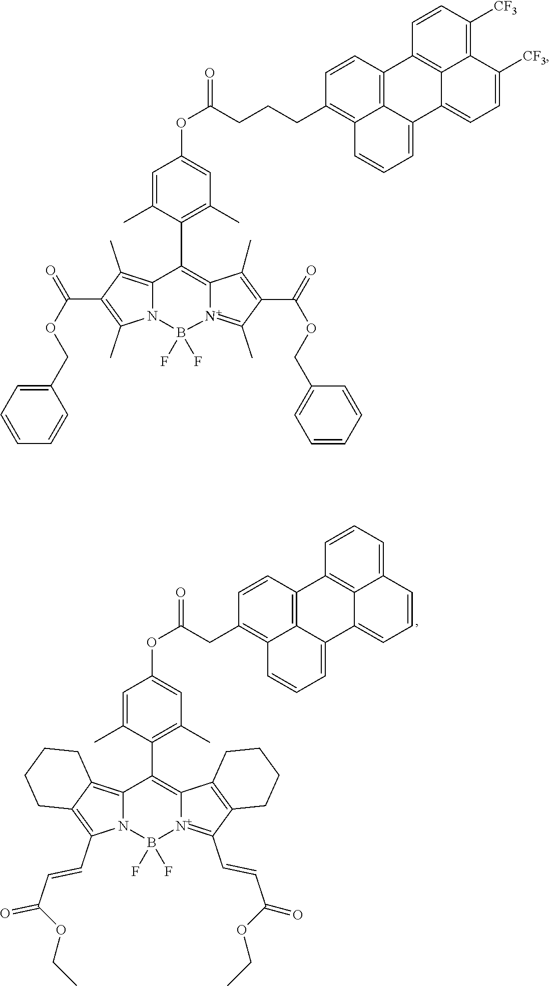

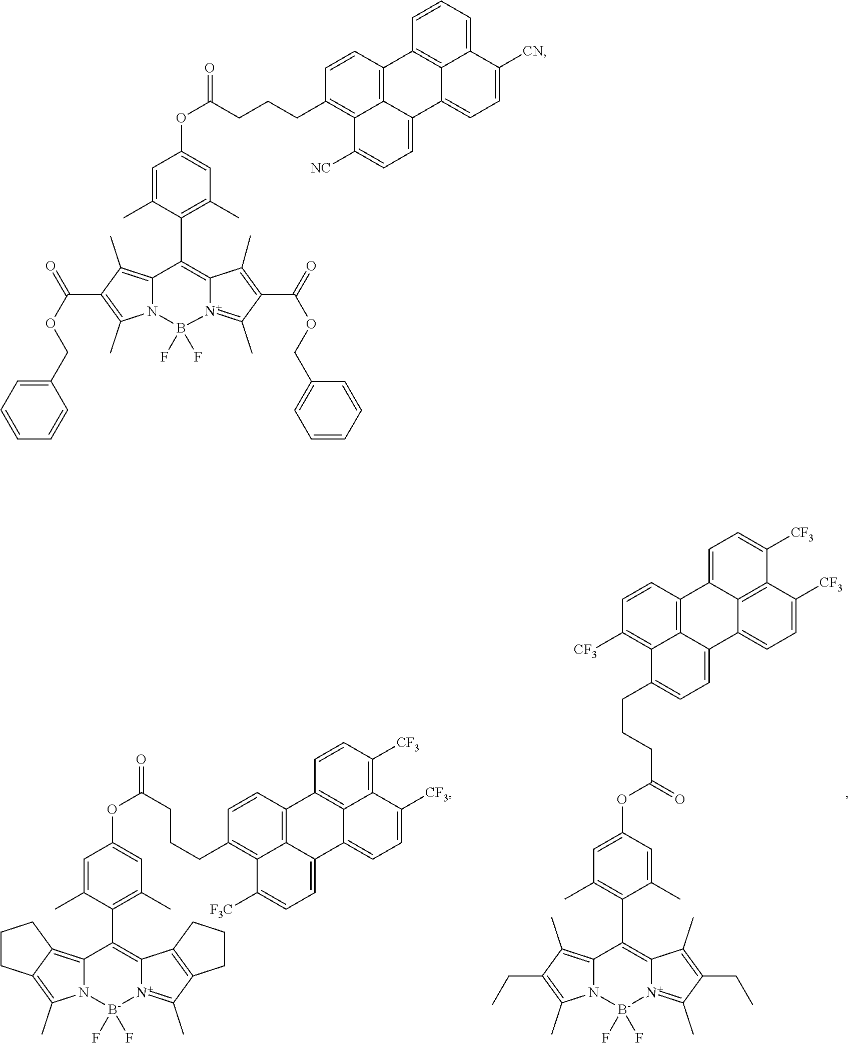

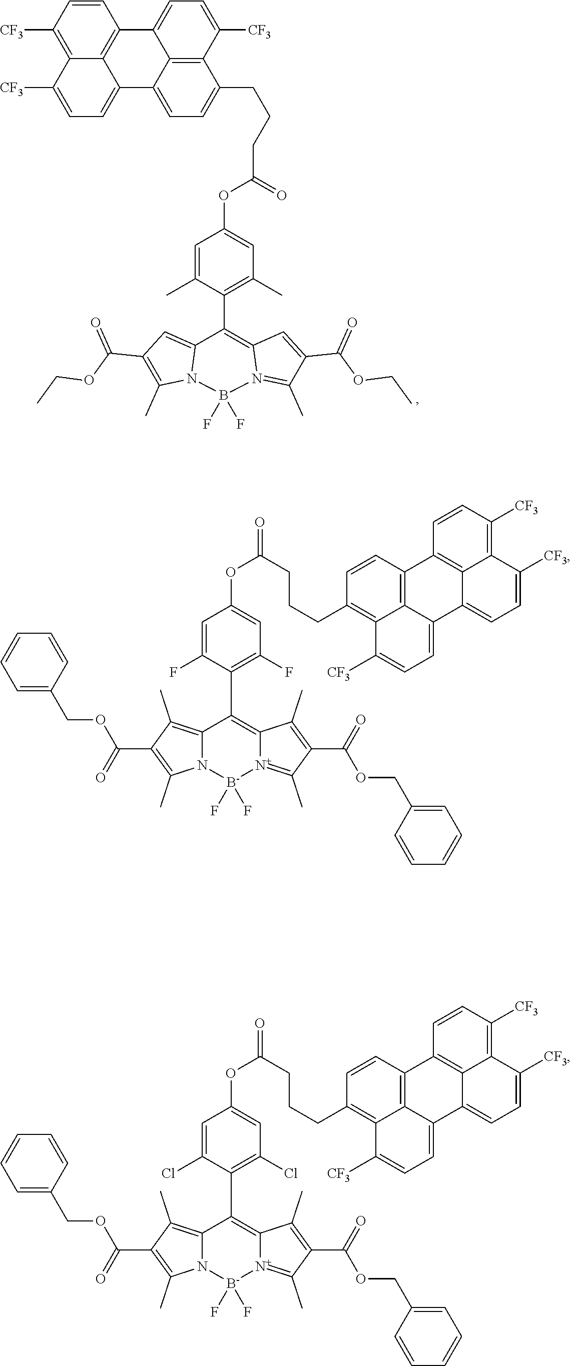

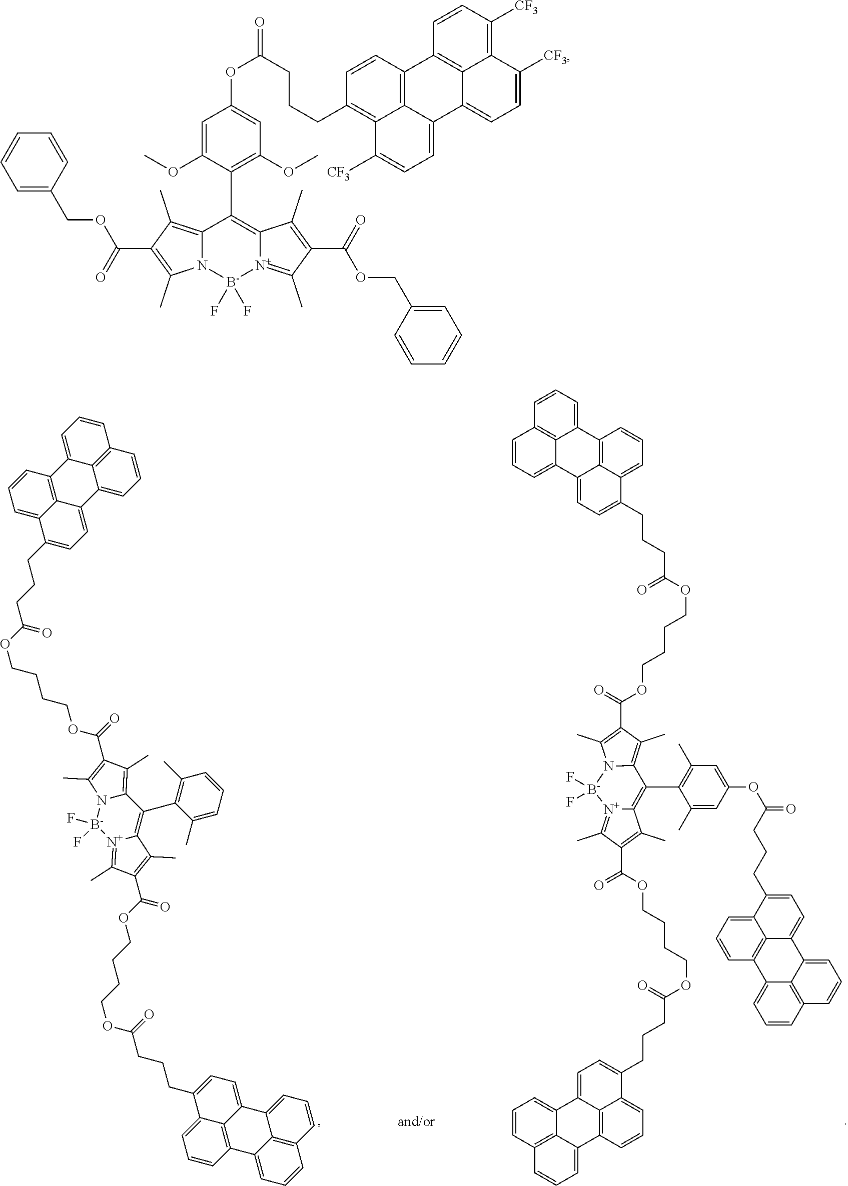

Some embodiments include a color conversion film, wherein the color conversion film comprises: a color conversion layer wherein the color conversion layer includes a resin matrix and a photoluminescent complex, described above, dispersed within the resin matrix. In some embodiments, the color conversion film can be described as comprising one or more of the photoluminescent complexes described herein.

Some embodiments include the color conversion film which may be about 1 μm to about 200 μm thick. In some embodiments, the color conversion film can have a thickness of about 1-5 μm, about 5-10 μm, about 10-15 μm, about 15-20 μm, about 20-40 μm, about 40-80 μm, about 80-120 μm, about 120-160 μm, about 160-200 μm, or about 1-2 μm, about 2-3 μm, about 3-4 μm, about 4-5 μm, about 5-6 μm, about 6-7 μm, about 7-8 μm, about 8-9 μm, about 9-10 μm, about 10-11 μm, about 11-12 μm, about 12-13 μm, about 13-14 μm, about 14-15 μm, about 15-16 μm, about 16-17 μm, about 17-18 μm, about 18-19 μm, about 19-20 μm, or about 1-10 μm, about 10-20 μm, about 20-30 μm, about 30-40 μm, about 40-50 μm, about 50-60 μm, about 60-70 μm, about 70-80 μm, about 80-90 μm, about 90-100 μm, about 100-110 μm, about 110-120 μm, about 120-130 μm, about 130-140 μm, about 140-150 μm, about 150-160 μm, about 160-170 μm, about 170-180 μm, about 180-190 μm, about 190-200 μm, or about 10 μm, about 20 μm, about 30 μm, about 40 μm thick, or any thickness in a range bounded by any of these values.

In some embodiments, the color conversion film can absorb light in the 400 nm to about 480 nm wavelength and can emit light in the range of about 510 nm to about 560 nm and about 610 nm to about 645 nm. In other embodiments, color conversion film can emit light in the 510 nm to about 560 nm range, the 610 nm to about 645 nm range, or any combination thereof.

In some embodiments, the color conversion film can further comprise a transparent substrate layer. The transparent substrate layer has two opposing surfaces, wherein the color conversion layer can be disposed on and in physical contact with the surfaces of the transparent layer that will be adjacent to a light emitting source. The transparent substrate is not particularly limited and one skilled in the art would be able to choose a transparent substrate from those used in the art. Some non-limiting examples of transparent substrates include PE (polyethylene), PP (polypropylene), PEN (polyethylene naphthalate), PC (polycarbonate), PMA (polymethylacrylate), PMMA (Polymethylmethacrylate), CAB (cellulose acetate butyrate), PVC (polyvinylchloride), PET (polyethyleneterephthalate), PETG (glycol modified polyethylene terephthalate), PDMS (polydimethylsiloxane), COC (cycloolefin copolymer), PGA (polyglycolide or polyglycolic acid), PLA (polylactic acid), PCL (polycaprolactone), PEA (polyethylene adipate), PHA (polyhydroxy alkanoate), PHBV (poly(3-hydroxybutyrate-co-3-hydroxyvalerate)), PBE (polybutylene terephthalate), PTT (polytrimethylene terephthalate). Any of the aforedescribed resins can be corresponding/respective monomers and/or polymers.

In some embodiments, the transparent substrate may have two opposing surfaces. In some embodiments, the color conversion film may be disposed on and in physical contact with one of the opposing surfaces. In some embodiments, the side of the transparent substrates without color conversion film disposed thereon, may be adjacent to a light source. The substrate may function as a support during the preparation of the color conversion film. The type of substrates used are not particularly limited, and the material and/or thickness is not limited, as long as it is transparent and capable of functioning as a support. A person skilled in the art could determine which material and thickness to use as a supporting substrate.

Some embodiments include a method for preparing the color conversion film, wherein the method comprises: dissolving a photoluminescent compound, described herein, and a binder resin within a solvent; and applying the mixture on to the surface of the transparent substrate.

The binder resin which can be used with the photoluminescent complex(s) includes resins such as acrylic resins, polycarbonate resins, ethylene-vinyl alcohol copolymer resins, ethylene-vinyl acetate copolymer resins and saponification products thereof, AS resins, polyester resins, vinyl chloride-vinyl acetate copolymer resins, polyvinyl butyral resins, polyvinylphosphonic acid (PVPA), polystyrene resins, phenolic resins, phenoxy resins, polysulfone, nylon, cellulosic resins, and cellulose acetate resins. In some embodiments, the binder resin can be a polyester resin and/or acrylic resin. In some embodiments, the word resin is equivalent to the word polymeric resin, or polymer.

The solvent which can be used for dissolving or dispersing the complex and the resin can include an alkane, such as butane, pentane, hexane, heptane, and octane; cycloalkanes, such as cyclopentane, cyclohexane, cycloheptane, and cyclooctane; alcohols, such as ethanol, propanol, butanol, amyl alcohol, hexanol, heptanol, octanol, decanol, undecanol, diacetone alcohol, and furfuryl alcohol; Cellosolves™, such as Methyl Cellosolve™, Ethyl Cellosolve™ Butyl Cellosolve™, Methyl Cellosolve™ acetate, and Ethyl Cellosolve™ acetate; propylene glycol and its derivatives, such as propylene glycol monomethyl ether, propylene glycol monoethyl ether, propylene glycol monobutyl ether, propylene glycol monomethyl ether acetate, propylene glycol monoethyl ether acetate, propylene glycol monobutyl ether acetate, and dipropylene glycol dimethyl ether; ketones, such as acetone, methyl amyl ketone, cyclohexanone, and acetophenone; ethers, such as dioxane and tetrahydrofuran; esters, such as butyl acetate, amyl acetate, ethyl butyrate, butyl butyrate, diethyl oxalate, ethyl pyruvate, ethyl 2-hydroxybutyrate, ethyl acetoacetate, methyl lactate, ethyl lactate, and methyl 3-methoxypropionate; halogenated hydrocarbons, such as chloroform, methylene chloride, and tetrachloroethane; aromatic hydrocarbons, such as benzene, toluene, xylene, and cresol; and highly polar solvents, such as dimethyl formamide, dimethyl acetamide, and N-methylpyrrolidone.

Some embodiments include a backlight unit, wherein the backlight unit may include the aforedescribed color conversion film.

Other embodiments may include a display device, wherein the device may include the backlight unit described herein.

Unless otherwise indicated, all numbers expressing quantities of ingredients, properties such as molecular weight, reaction conditions, and so forth used in the specification and embodiments are to be understood as being modified in all instances by the term “about.” Accordingly, unless indicated to the contrary, the numerical parameters set forth in the specification and attached embodiments are approximations that may vary depending upon the desired properties sought to be obtained. At the very least, and not as an attempt to limit the application of the doctrine of equivalents. To the scope of the embodiments, each numerical parameter should at least be construed in light of the number of reported significant digits and by applying ordinary rounding techniques.

For the processes and/or methods disclosed, the functions performed in the processes and methods may be implemented in differing order, as may be indicated by context. Furthermore, the outlined steps and operations are only provided as examples and some of the steps and operations may be optional, combined into fewer steps and operations, or expanded into additional steps and operations.

This disclosure may sometimes illustrate different components contained within, or connected with, different other components. Such depicted architectures are merely examples, and many other architectures can be implemented which achieve the same or similar functionality.

The terms used in this disclosure and in the appended embodiments, (e.g., bodies of the appended embodiments) are generally intended as “open” terms (e.g., the term “including” should be interpreted as “including, but not limited to,” the term “having” should be interpreted as “having at least,” the term “includes” should be interpreted as “includes, but not limited to,” etc.). In addition, if a specific number of elements is introduced, this may be interpreted to mean at least the recited number, as may be indicated by context (e.g., the bare recitation of “two recitations,” without other modifiers, means at least two recitations of two or more recitations). As used in this disclosure, any disjunctive word and/or phrase presenting two or more alternative terms should be understood to contemplate the possibilities of including one of the terms, either of the terms, or both terms. For example, the phase “A or B”: will be understood to include the possibilities of “A or B” or “A and B.”

The terms “a,” “an,” “the” and similar referents used in the context of describing the present disclosure (especially in the context of the following embodiments) are to be construed to cover both the singular and the plural, unless otherwise indicated herein or clearly contradicted by context. The use of any and all examples, or related language (e.g., “such as”) provided herein is intended merely to better illuminate the present disclosure and does not pose a limitation on the scope of any embodiments. No language in the specification should be construed as indicating any non-embodied element essential to the practice of the present disclosure.

Groupings of alternative elements or embodiments disclosed herein are not to be construed as limitations. Each group member may be referred to and embodied individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended embodiments.

Certain embodiments are described herein, including the best mode known to the inventors for carrying out the present disclosure. Of course, variations on these described embodiments, will become apparent to those of ordinary skill in the art upon reading the foregoing description. The inventor expects skilled artisans to employ such variations as appropriate, and the inventors intend for the present disclosure to be practiced otherwise than specifically described herein. Accordingly, the embodiments include all modifications and equivalents of the subject matter recited in the embodiments as permitted by applicable law. Moreover, any combination of the above-described elements in all possible variations thereof is contemplated unless otherwise indicated herein or otherwise clearly contradicted by context. In closing, it is to be understood that the embodiments disclosed herein are illustrative of the principles of the embodiments. Other modifications that may be employed are within the scope of the embodiments. Thus, by way of example, but not of limitation, alternative embodiments may be utilized in accordance with the teachings herein. Accordingly, the embodiments are not limited to the embodiments precisely as shown and described.

### Embodiments

Embodiment 1 A photoluminescent complex comprising:
a blue light absorbing moiety, wherein the blue light absorbing moiety comprises an optionally substituted perylene;
a linker moiety; and
a boron-dipyrromethene (BODIPY) moiety;
wherein the linker moiety covalently links the optionally substituted perylene and the BODIPY moiety, wherein the optionally substituted perylene absorbs light energy of a first excitation wavelength and transfers an energy to the BODIPY moiety, wherein the BODIPY moiety absorbs the energy from the optionally substituted perylene and emits a light energy of a second higher wavelength, and wherein the photoluminescent complex has an emission quantum yield greater than 80%.
Embodiment 2 The photoluminescent complex of embodiment 1, wherein the emission band has a full width half maximum (FWHM) of up to 40 nm.
Embodiment 3 The photoluminescent complex of embodiment 1, wherein the photoluminescent complex has a Stokes shift, the distance between the excitation peak of the blue light absorbing moiety and the emission peak of the BODIPY moiety, equal to or greater than 45 nm.
Embodiment 4 The photoluminescent complex of embodiment 1, wherein the complex as an absorbance maximum of about 400 nm to about 480 nm.
Embodiment 5 The photoluminescent complex of embodiment 1 wherein the BODIPY moiety is of the general formula:

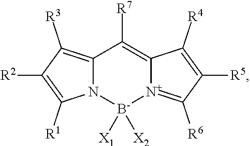

wherein R¹ and R⁶ are independently H, an alkyl, or an alkenyl ester;
R³ and re are independently H, or an C₁-C₅ alkyl;
R² and R⁵, are independently H, an C₁-C₅ alkyl, a cyano, an aryl alkynyl, and alkyl ester, an alkyl ester forming a linker moiety, or an aryl ester;
R² and R³ may link together to form an additional monocyclic hydrocarbon ring structure, or polycyclic hydrocarbon ring structure;
R⁴ and R⁵ may link together to form an additional monocyclic hydrocarbon ring structure, or polycyclic hydrocarbon ring structure;
R⁷ is selected from a direct bond to the linker moiety or an aryl group;
X₁ and X₂ are independently selected from a halogen group.
Embodiment 6 The photoluminescent complex of embodiment 5, wherein R⁷ is selected from:
a direct bond to the linker moiety,

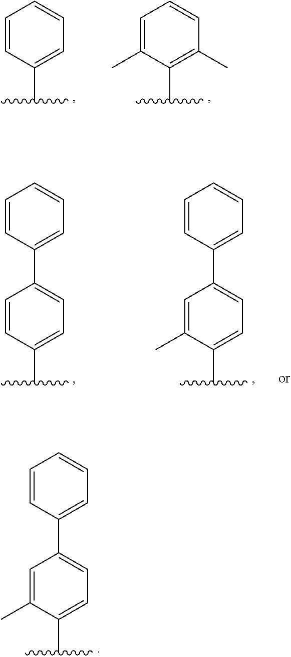

Embodiment 7 The photoluminescent complex of embodiments 1, wherein the linker moiety is selected from: a single bond, an ester group or an ether group.
Embodiment 8 The photoluminescent complex of embodiment 7, wherein the ester group is selected from:

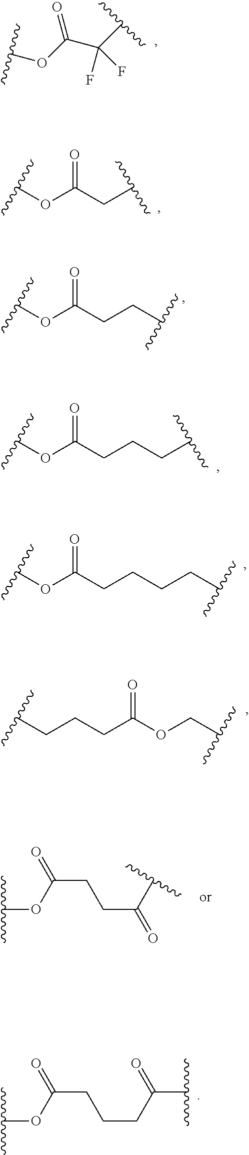

Embodiment 9 The photoluminescent complex of embodiment 7, wherein the ether group is:

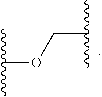 [SMILES: *CO*]

Embodiment 10 The photoluminescent complex of embodiments 1, wherein the optionally substituted perylene is represented by following the general formula:

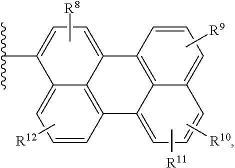

wherein R⁸, R⁹, R¹¹ and R¹² may be selected from H, a branched chain C₄-C₅ alkyl a cyano (CN), a trifluoromethyl (CF₃), or a 4-(trifluoromethyl)phenyl, and R¹⁰ is H when R⁹ is a H, a branched chain C₄-C₅ alkyl a CN, a F or a CF₃, but when R⁹ is a 4-(trifluoromethyl)phenyl then R¹⁰ is a H or forms a direct bond to the 4-(trifluoromethyl)phenyl group forming a bridged substituted aromatic group, wherein the substituted bridged aromatic group forms a(trifluoromethyl)indeno[1,2,3-cd]perylene.
Embodiment 11 The perylene of embodiment 10, wherein the branched chain C₄-C₅ alkyl group is selected from one of the following:

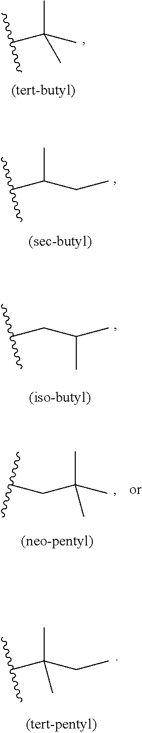

Embodiment 12 The photoluminescent complex of embodiments 1, 2, 3, 4, 5, 6, 7, 8, 9, 10, and 11, wherein the ratio between blue light absorbing moiety and the BODIPY moiety is 1:1, 2:1, 3:1, or 1:2.
Embodiment 13 The photoluminescent complex or embodiment 1, wherein the photoluminescent complex is represented by the following chemical formula [4]:

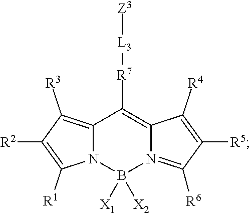

In chemical Formula 4,
the definitions of R¹, R², R³, R⁴, R⁵, R⁶, R⁷, X₁, X₂ and L are the same as those in embodiments, 1, 2, 3, 4, 5, 6, 7, 8, 9, 10 and 11,
Z is selected from the optionally substituted perylene of embodiments 10, and 11.
Embodiment 14 The photoluminescent complex of embodiment 1, wherein the photoluminescent complex is represented by the following chemical Formula 6:

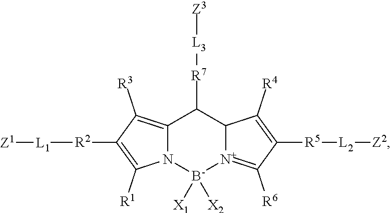

in chemical Formula 6,
the definitions of R¹, R², R³, R⁴, R⁵, R⁶, R⁷, X₁, X₂ and L are the same as those in embodiments, 1, 2, 3, 4, 5, 6, 7, 8, and 9;
L₁ and L₂ are the same or independent from one another and are the selected from: a single bond, a substituted or unsubstituted ester group, or a substituted or unsubstituted ether group; and
Z¹ and Z² are selected from the optionally substituted perylene of embodiments 10, and 11.
Embodiment 15 The photoluminescent complex of embodiment 1, wherein the photoluminescent complex is represented by the following general Formula 7:

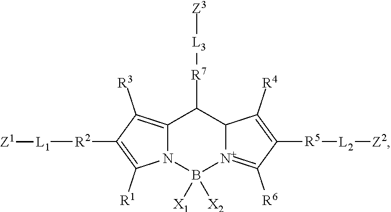

in general Formula 7,
the definitions of R¹, R², R³, R⁴, R⁵, R⁶, R⁷, X₁, X₂, L₁, L₂, and L₃ are the same as those in embodiments 1, 2, 3, 4, 5, 6, 7, 8, and 9; and
Z¹, Z², and Z³ are selected form the optionally substituted perylene of embodiments 10 and 11.
Embodiment 16 The photoluminescent complex of embodiments 1, 2, 3, 4, 5, 6, 7, 8, 9, 10, 11, 12, 13, 14, 15, and 16, wherein the distance between the BODIPY moiety and optionally substituted perylene is about 8 Å or greater.
Embodiment 17 A color conversion film comprising:
a color conversion layer, wherein the color conversion layer includes a resin matrix; and the photoluminescent complex of embodiments 1, 2, 3, 4, 5, 6, 7, 8, 9, 10, 11, 12, 13, 14, and 15, are dispersed within the resin matrix.
Embodiment 18 The color conversion film of embodiment 17, wherein the film has a thickness of between 1 μm to about 200 μm.
Embodiment 19 The color conversion film of embodiment 17, wherein the film absorbs light in about 400 nm to about 480 nm wavelength range and emits light in about 510 nm to about 560 nm wavelength range.
Embodiment 20 The color conversion film of embodiment 17, wherein the film absorbs light in about 400 nm to about 480 nm wavelength range and emits light in about 575 nm to about 645 nm wavelength range.
Embodiment 21 The color conversion film of embodiment 17, further comprising a transparent substrate layer, wherein the transparent substrate layer comprises two opposing surfaces, the color conversion layer is disposed on one of the opposing surfaces.
Embodiment 22 A method for preparing the color conversion film of embodiments 17, 18, 19, 20, and 21, the method comprising:
dissolving the photoluminescent complex of embodiments 1, 2, 3, 4, 5, 6, 7, 8, 9, 10, 11, 12, 13, 14, and 15, and a binder resin within a solvent; and
applying the mixture to one of the transparent substrates opposing surfaces.
Embodiment 23 A backlight unit including the color conversion film of embodiment 17, 18, 19, 20, and 21.
Embodiment 24 A display device including the back-light unit of embodiment 23.

### EXAMPLES

It has been discovered that embodiments of the photoluminescent complexes described herein have improved performance as compared to other forms of dyes used in color conversion films. These benefits are further demonstrated by the following examples, which are intended to be illustrative of the disclosure only but are not intended to limit the scope or underlying principles in any way.

### Example 1.1 Comparative Example 1 (CE-1)

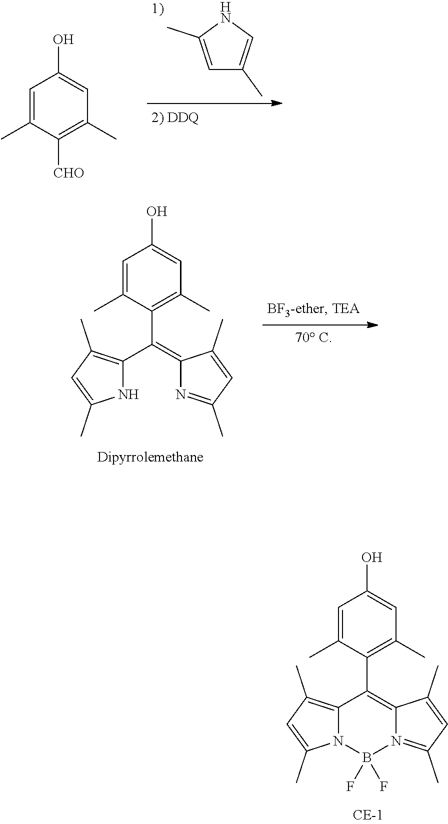

CE-1: 0.75 g of 4-hydroxyl-2,6-dimethylbenzaldehyde (5 mmol) and 1.04 g of 2,4-dimethylpyrrole (11 mmol) was dissolved in 100 mL of anhydrous dichloromethane. The solution was degassed for 30 minutes. Then one drop of trifluoroacetic acid was added. The solution was stirred overnight under argon gas atmosphere at room temperature. To the resulting solution, DDQ (2.0 g) was added and the mixture was stirred overnight. The next day the solution was filtered and then washed with dichloromethane resulting in a dipyrrolemethane (1.9 g). Next, 1.0 g of dipyrrolemethane was dissolved in 60 mL of THF. 5 mL of triethylamine was added to the solution and then degassed for 10 minutes. After degassing, 5 mL of trifluoroboron-diethylether was added slowly followed by heating for 30 minutes at 70° C. The resulting solution was loaded on a silica gel and purified by flash chromatography using dichloromethane as the eluent. The desired fraction was collected and dried under reduced pressure to yield 0.9 g or an orange solid (76% yield). LCMS (APCI+): calculated for C₂₁H₂₄BF₂N₂O (M+H)=369; found: 369. ¹H NMR (400 MHz, Chloroform-d) δ 6.64 (s, 2H), 5.97 (s, 2H), 4.73 (s, 1H), 2.56 (s, 6H), 2.09 (s, 6H), 1.43 (s, 6H).

Example 1.2 Comparative Example 2 (CE-2): was synthesized as described in Wakamiya, Atsushi et al. Chemistry Letters, 37(10), 1094-1095; 2008

### Example 2 Synthesis of Photoluminescent Complexes

### Example 2.1: PC-1

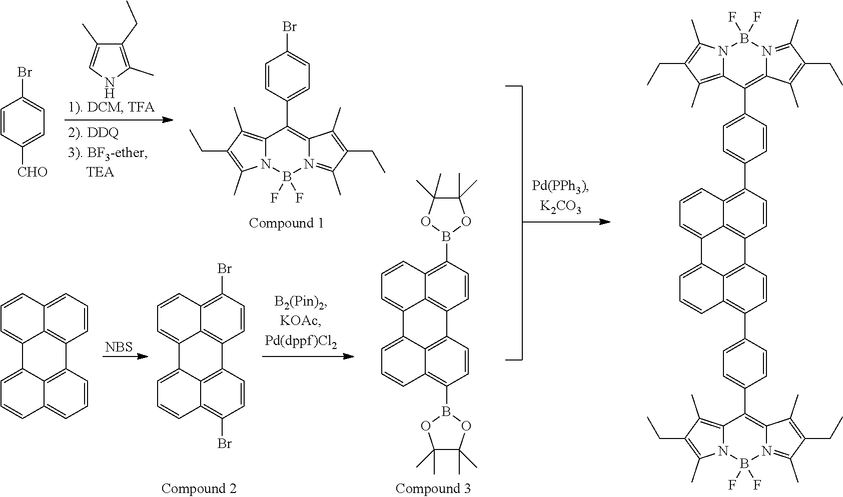

Compound 1.1 was synthesized according to literature procedure: European Journal of Organic Chemistry (2008), (16), 2705-2713.

Compound 1.2 [3,10-dibromoperylene]: Perylene (4.00 g, 16.00 mmol) and N-bromosuccinimide (7.12 g, 40.0 mmol), were dissolved in 1 L flask containing 400 mL dichloromethane and a magnetic stir bar. The solution was then stirred at room temperature for 24 h. The solution was evaporated to dryness under vacuum resulting in a solid. The solid was extracted with chloroform, continuously, for 8 h to remove any unreacted perylene. A 90% yield of (5.9 g) yellow solid was obtained in, LCMS (APCI+): calculated for C₂₀H₂₀Br₂: 407.9; found: 408.

Compound 1.3 [3,10-Bis(4,4,5,5-tetramethyl-1,3,2-dioxaborolan-2-yl)perylene)]: A mixture of Compound 1.2 [3,10-dibromoperylene] (4.10 g, 10 mmol), Bispinacolatodiboron (5.60 g, 22 mmol), potassium acetate (2.94 g, 30 mmol), and Pd(dppf)Cl₂ (0.7 g, 1 mmol) was dried under vacuum then dissolved in anhydrous 1,4-dioxane (100 mL). The mixture was degassed then heated at 90° C. under argon for 2 days. After the mixture was cooled to room temperature, it was loaded onto a silica gel and purified by flash chromatography. The eluents utilized were dichloromethane/hexanes (0-20%). 2.0 g (40% yield) of an orange solid, 3,10-bis(4,4,5,5-tetramethyl-1,3,2-dioxaborolan-2-yl)perylene), was obtained.

PC-1: A mixture of BODIPY compound 1.1 ((500 mg, 1.1 mmol), 3,10-bis(4,4,5,5-tetramethyl-1,3,2-dioxaborolan-2-yl)perylene), compound 1.3, (220 mg, 0.44 mmol), potassium carbonate (0.138 g, 1 mmol) and Pd(PPh₃)₄ (58 mg, 0.05 mmol) were mixed in a 250 mL flask containing 25 mL 1,4-dioxane. The mixture was heated at 100° C. and degassed overnight. Next, the mixture was cooled to room temperature and filtered, resulting in an orange solid. The orange solid was collected and further purified by flash chromatography with hexanes/dichloromethane (1:0.2 to 1:1) as the eluents. After removal of solvents, the PC-1 was obtained as a reddish solid (190 mg, in 43% yield). ¹H NMR (400 MHz, Chloroform-d) δ 8.32 (q, J=6.8 Hz, 2H), 7.77 (d, J=8.4 Hz, 1H), 7.67 (d, J=7.7 Hz, 2H), 7.57-7.48 (m, 2H), 7.45 (d, J=7.6 Hz, 2H), 2.57 (s, 6H), 2.36 (q, J=7.5 Hz, 4H), 1.03 (t, J=7.5 Hz, 6H).

### Example 2.2: PC-2

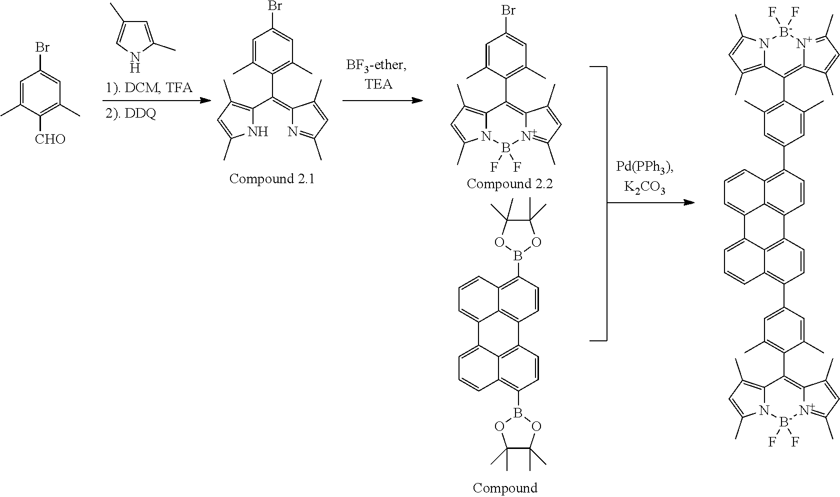

Compound 2.1: 4-bromo-2,6-dimethylbenzaldehyde (1.06 g, 5 mmol) and 2,4-dimethylpyrrole (1.04 g, 11 mmol) were dissolved in anhydrous dichloromethane (100 mL). The solution was degassed for 30 min, then one drop of trifluoroacetic acid was added. The resulting solution was stirred at room temperature overnight while under argon gas. The resulting solution was cooled at 0° C. in an ice-bath. Once cooled, DDQ (1.5 g) was added (solution turned to red immediately). The solution was stirred overnight. The next day the solution was purified by flash chromatography using hexanes/ethyl acetate (8:1) with 0.1% trimethylamine as the eluents. The desired orange fractions were collected and dried under reduced pressure to give a yellow orange solid (1.5 g, in 78% yield). LCMS (APCI+): calculated for C₂₁H₂₄BrN₂ (M+H)=383; found: 383.

Compound 2.2 [BODIPY]: 3.7 mL of trimethylamine was added to a solution of dipyrrolemethane, compound 2.1, (1.5 g, 3.9 mmol) in 50 mL anhydrous toluene. The resulting solution was degassed for 10 min. Next, trifluoroboron-diethylether (5.3 mL) was added slowly while stirring. The resulting solution was stirred at 70° C. for 30 min, then poured into ethyl acetate (200 mL), and washed with brine. The organic phase was collected, dried over Na₂SO₄, concentrated to 30 mL under reduced pressure and then submitted to flash chromatography using dichloromethane/hexanes (0%→70%) as the eluents. The desired fractions were collected and dried under reduced pressure to give an orange solid (1.55 g, in 92% yield). LCMS (APCI+): calculated for C₂₁H₂₃BBrF₂N₂ (M+H)=431; found: 431.

PC-2: Diboronic ester, compound 1.3, (116 mg, 0.23 mmol), BODIPY, compound 2.2, (200 mg, 0.46 mmol), Cs₂CO₃ (227 mg, 0.7 mmol) and Pd(PPh₃)₄ (14 mg, 0.012 mmol) were mixed together in 1,4-dioxane (10 mL). The solution was degassed and heated at 100° C. for 4 h. The solution was purified by flash chromatography using dichloromethane/hexanes (0%-88%) as the eluents. The desired fractions were collected and dried under reduced pressure to give an orange solid (68 mg, in 31% yield). LCMS(APCI+): calculated for C₆₂H₅₄B₂F₄N₄=952; found: 952. ¹H NMR (400 MHz, Chloroform-d) δ 8.29 (t, J=5.6 Hz, 1H), 7.73 (d, J=8.4 Hz, 1H), 7.50 (dd, J=8.1, 4.2 Hz, 1H), 7.33 (s, 1H), 7.26 (s, 3H), 6.05 (s, 1H), 2.60 (s, 3H), 2.26 (s, 3H).

### Example 2.3: PC-3

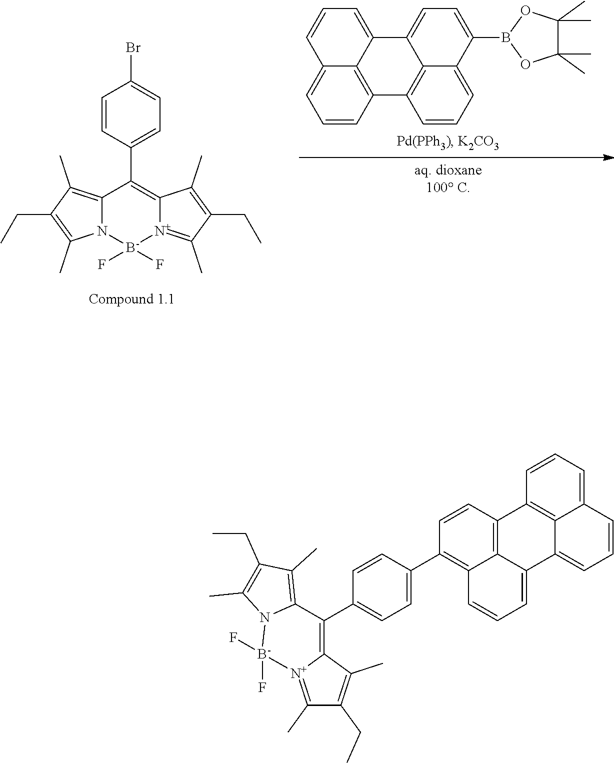 [SMILES: CCC1=C(C)C2=C(c3ccc(Br)cc3)c3c(C)c(CC)c(C)n3[B-](F)(F)[N+]2=C1C ; CC1(C)OB(c2ccc3c4cccc5cccc(c6cccc2c63)c54)OC1(C)C ; CCC1=C(C)C2=C(c3ccc(-c4ccc5c6cccc7cccc(c8cccc4c85)c76)cc3)c3c(C)c(CC)c(C)n3[B-](F)(F)[N+]2=C1C]

PC-3: A mixture of compound 1.1 (270 mg, 0.59 mmol), 4,4,5,5-Tetramethyl-2-(3-perylenyl)-1,3,2-dioxaborolane (302 mg, 0.8 mmol), potassium carbonate (98 mg, 1 mmol) and Pd(PPh₃)₄ (58 mg, 0.05 mmol) were dissolved in 1,4-dioxane (10 mL). The solution was degassed and heated at 100° C. for 6 hours. The resulting mixture was submitted to flash chromatography for purification using dichloromethane/hexanes (0-60%) as the eluents. The desired fractions were collected and dried under reduced pressure to give an orange solid (50 mg, in 14% yield). LCMS (APCI+): calculated for C₄₃H₃₈BF₂N₂ (M+H)=631; found 631.

### Example 2.4: PC-4

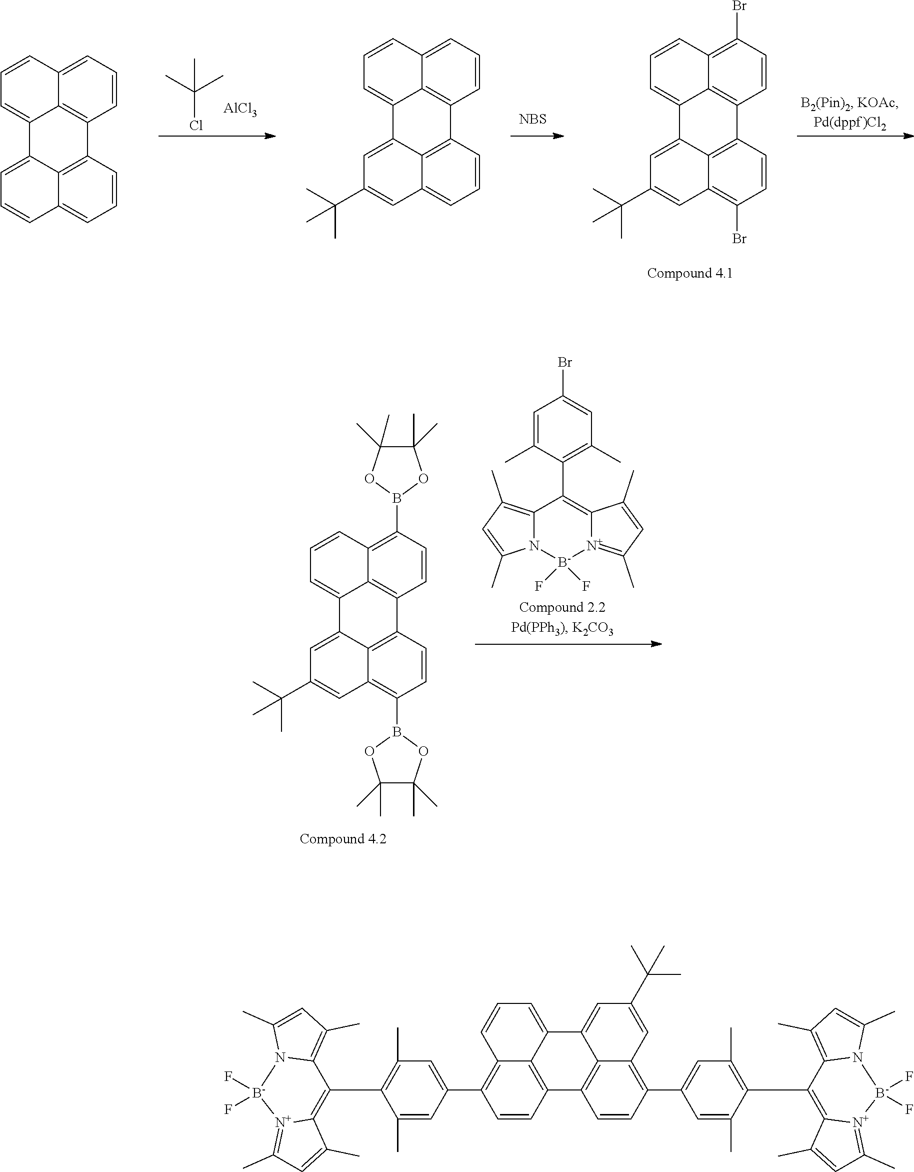

Compound 4.1: 2.0 g of perylene (7.94 mmol) was added to 100 mL o-dichlorobenzene. The solution was stirred at 70° C. for 20 min until the perylene was fully dissolved. The solution was then cooled to 0° C. and 1.05 g of anhydrous AlCl₃ (7.94 mmol) was added. Next, 11 mL of tert-butylchloride was slowly added to the solution. The resulted mixture was warmed up to room temperature and stirred overnight. The whole was poured into dichloromethane (400 mL), washed with water, brine, and dried over Na₂SO₄, concentrated to 100 mL and passed through a silica column with hexanes/dichloromethane (1:1 v/v) used as the eluents. The major fractions were collected and concentrated to 100 mL. Next, 2.85 g of NBS (16 mmol) was added to the solution and stirred at room temperature for 18 h. The resulting mixture was poured into water, the organic phase was separated and washed with brine, then concentrated to 10 mL via vacuum distillation. To the concentrated solution, 50 mL isopropanol and 100 mL methanol were added while stirring. After stirred for 5 min, the mixture was filtered and the desired product, compound 4.1, was obtained as yellow brown solid (3.0 g, in 80% yield).

Compound 4.2: To a 500 mL flask containing 100 mL of anhydrous dioxane 2.33 g of compound 4.1 (5 mmol), 4.06 g bispinacolatodiboron (16 mmol), 2.9 g potassium acetate (30 mmol) and 0.44 g of Pd(dppf)Cl₂ (0.6 mmol) were added and the resulting solution was degassed for 30 min and heated at 90° C. overnight under argon gas. The resulting mixture was poured into ethyl acetate (200 mL), and then washed with brine. The organic phase was collected and dried over Na₂SO₄, then loaded on silica gel and purified by flash chromatography using dichloromethane/hexanes (0%-30%) as the eluents. The desired fractions were collected and dried under reduced pressure to give a yellow solid (1.7 g, in 60% yield).

PC-4: A mixture of compound 2.2 (0.388 g, 0.9 mmol), diboronic ester, compound 4.2, (0.224 g, 0.4 mmol), potassium carbonate (0.138 g, 1 mmol) and Pd(PPh₃)₄ (58 mg, 0.05 mmol) in 1,4-dioxane (25 mL) was degassed for 30 min then heated at 100° C. for 2 days. After cooling to room temperature, the mixture was diluted with 100 mL dichloromethane, then loaded on silica gel and purified by flash chromatography using dichloromethane/hexanes (0%-40%) as the eluents. The desired fractions were collected and dried under reduced pressure to give a red solid (100 mg, in 25% yield). LCMS (APCI+): calculated for C₆₆H₆₃B₂F₄N₄=1009; found: 1009. ¹H NMR (400 MHz, Chloroform-d) δ 8.34-8.19 (m, 4H), 7.77-7.69 (m, 2H), 7.54-7.44 (m, 4H), 7.36-7.30 (m, 4H), 6.04 (s, 4H), 2.60 (s, 12H), 2.26 (s, 12H), 1.39 (s, 9H).

### Example 2.5: PC-5

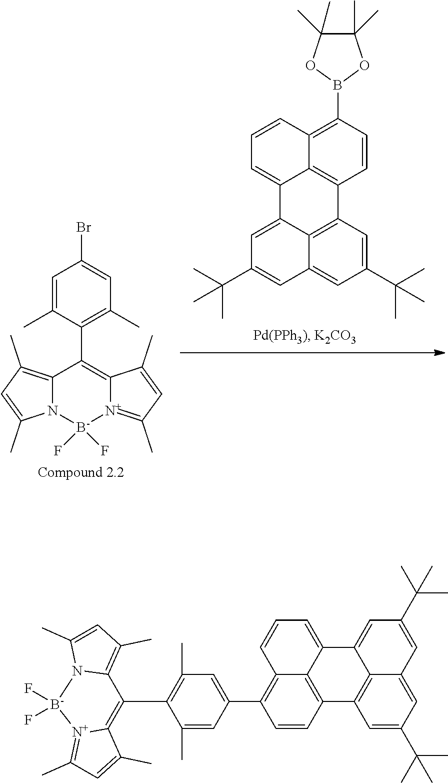 [SMILES: CC1=CC(C)=[N+]2C1=C(c1c(C)cc(Br)cc1C)c1c(C)cc(C)n1[B-]2(F)F ; CC(C)(C)c1cc2cc(C(C)(C)C)cc3c4ccc(B5OC(C)(C)C(C)(C)O5)c5cccc(c(c1)c23)c54 ; CC1=CC(C)=[N+]2C1=C(c1c(C)cc(-c3ccc4c5cc(C(C)(C)C)cc6cc(C(C)(C)C)cc(c7cccc3c74)c65)cc1C)c1c(C)cc(C)n1[B-]2(F)F]

PC-5: A mixture of BODIPY, compound 2.2, (108 mg, 0.25 mmol), 2-(8,11-di-tert-butylperylen-3-yl)-4,4,5,5-tetramethyl-1,3,2-dioxaborolane (120 mg, 0.23 mmol, from TO chemicals), potassium carbonate (55 mg, 0.4 mmol) and Pd(PPh₃)₄ (30 mg, 0.02 mmol) was dried under vacuum for 90 min, then 1,4-dioxane (8 mL) was added and degassed for 30 min. The solution was heated at 100° C. for 40 hrs., then purified by flash chromatography using dichloromethane/hexanes (0→20%) as the eluents. The desired fractions were collected and dried under reduced pressure to give an orange solid (100 mg, in 61% yield). LCMS (APCI+): calculated for C₄₉H₅₀BF₂N₂ (M+H)=715; found: 715. ¹H NMR (400 MHz, Chloroform-d) δ 8.30-8.23 (m, 3H), 7.73-7.63 (m, 3H), 7.50-7.41 (m, 2H), 7.31 (m, 2H), 7.26 (s, 1H), 6.04 (s, 2H), 2.60 (s, 6H), 2.25 (s, 6H), 1.57 (s, 6H), 1.49 (s, 18H).

### Example 2.6: PC-6

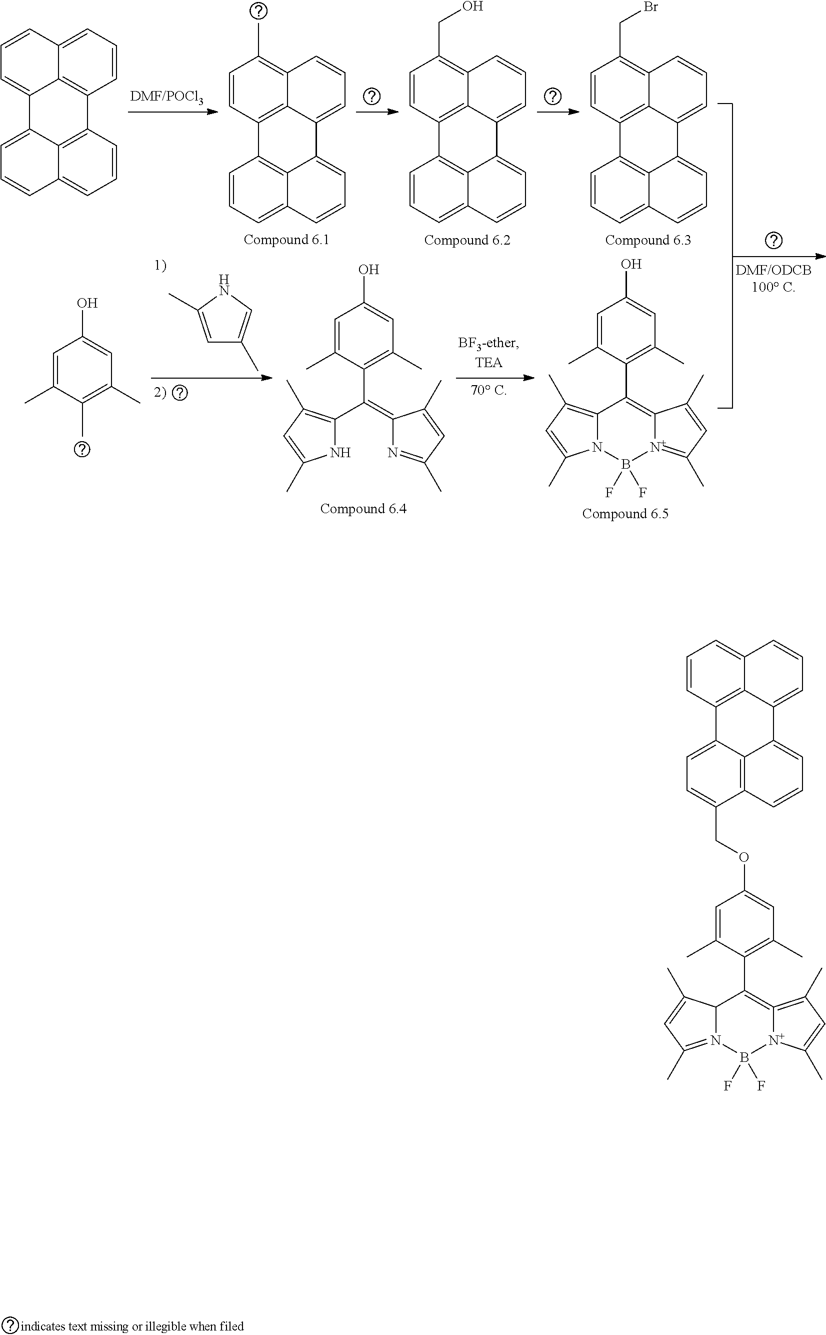

Compound 6.1 (perylene-3-carbaldehyde): 0.75 mL of POCl₃ was added to a suspension of perylene (1.0 g, 3.96 mmol) in 2 mL anhydrous DMF and 2 mL anhydrous o-dichlorobenzene. The resulting solution was then heated at 100° C. overnight. The net morning, the solution was cooled in an ice-bath for 1 hr. Next, the solution was neutralized with 5 mL of 10% NaOAc aqueous solution. Once neutralized the solution was filtered. After filtration, the solid was collected and dried in a vacuum oven for 3 hours. After drying, the solid is re-dissolved in 250 mL dichloromethane, loaded on silica gel and purified by flash chromatography using dichloromethane/hexanes (10%-50%) for the eluents. The desired fractions were collected and dried under reduced pressure to give an orange solid (0.80 g, in 72.2% yield). ¹H NMR (400 MHz, Chloroform-d) δ 10.34 (s, 1H), 9.20 (d, J=8.5 Hz, 1H), 8.38-8.27 (m, 4H), 7.97 (d, J=7.9 Hz, 1H), 7.83 (d, J=8.1 Hz, 1H), 7.80-7.68 (m, 2H), 7.56 (td, J=7.8, 4.2 Hz, 2H).

Compound 6.2 (3-Hydroxymethylperylene): 1.5 mL of 2.0M LiBH₄ in THF was added to a solution of perylene-3-carbaldehyde (0.65 g) in 50 mL of THF. The resulting solution was stirred overnight at room temperature under argon gas. The next day, the solution was diluted with dichloromethane (200 mL), washed with NH₄Cl aqueous solution and brine. The organic phase was collected and concentrated under reduced pressure to give a yellow solid (0.50 g, in 77% yield). ¹H NMR (400 MHz, Chloroform-d) δ 8.21 (ddd, J=15.4, 12.8, 7.6 Hz, 4H), 7.97 (d, J=8.4 Hz, 1H), 7.70 (d, J=8.1 Hz, 2H), 7.61-7.52 (m, 2H), 7.49 (t, J=7.9 Hz, 2H), 5.11 (s, 2H).

Compound 6.3 (3-Bromomethylperylene): 2.5 mL of 1M PBr₃ solution in dichloromethane was added to a suspension of 0.5 g 3-Hydroxymethylperylene, compound 6.2, in 50 mL dichloroethane. The reaction mixture was heated at 80° C. for 2 hours while under argon gas. The solution was evaporated under reduced pressured at room temperature, the residue was stirred with 40 mL MeOH, to precipitate the bromide. The mixture was filtered to give 3-bromomethyperylene, compound 10, as orange solid (0.55 g, in 90% yield). ¹H NMR (400 MHz, CDCl₃): δ=8.28-8.13 (m, 4H), 7.90 (d, 1H, J=7.9 Hz), 7.74 (d, 2H, J=8.0 Hz), 7.64 (t, 1H, J=7.9 Hz), 7.56 (d, 1H, J=7.6 Hz), 7.51 (m, 2H), 4.95 (s, 2H).

Compound 6.4: A solution of 4-hydroxyl-2,6-dimethylbenzaldehyde (0.75 g, 5 mmol), 2,4-dimethylpyrrole (1.04 g, 11 mmol) in 100 mL anhydrous dichloromethane was degassed for 30 min, then a drop of trifluoroacetic acid was added. The solution was stirred overnight at room temperature while under argon gas. To the resulting solution, DDQ (2.0 g, 8.8 mmol) was added and stirred at room temperature overnight. The resulting mixture was filtered and washed with dichloromethane extensively to give a brown solid as desired compound 6.4 (1.6 g, 100% yield). LCMS (APCI+): calculated for C₂₃H₂₅N₂O (M+H)=321; found 321.

Compound 6.5: 5 mL of trimethylamine was added to a solution of dipyrrolemethane, compound 6.4, (1.0 g) in 60 mL THF. The solution was degassed for 10 min, then trifluoroboron-diethylether (5 mL) was added slowly. Next the solution was heated at 70° C. for 30 min. The resulting solution was submitted to flash chromatography (silica gel) using dichloromethane as the eluent. The desired fraction was collected and dried under reduced pressure to give an orange solid (0.9 g, in 76% yield). LCMS (APCI+): calculated for C₂₁H₂₄BF₂N₂O (M+H)=369; found: 369. ¹H NMR (400 MHz, Chloroform-d) δ 6.64 (s, 2H), 5.97 (s, 2H), 4.73 (s, 1H), 2.56 (s, 6H), 2.09 (s, 6H), 1.43 (s, 6H).

PC-6: A solution of compound 6.5 (180 mg, 0.49 mmol), Compound 6.3 [3-Bromomethylperylene] (172 mg, 0.5 mol), anhydrous potassium carbonate (138 mg, 1 mmol) in anhydrous DMF/o-dichlorobenzene (5 mL/5 mL) was stirred at 60° C. overnight while under argon gas. The resulting solution was loaded on silica gel and purified by flash chromatography using dichloromethane/hexanes (0→35%) as the eluents. The desired fraction was collected and dried under reduced pressure to give an orange solid (60 mg, in 20% yield). LCMS (APCI+): calculated for C₄₂H₃₆BF₂N₂O (M+H)=633; found 633. ¹H NMR (400 MHz, Chloroform-d) δ 8.22 (ddd, J=16.0, 13.8, 7.6 Hz, 4H), 7.88 (d, J=8.4 Hz, 1H), 7.71 (d, J=8.1 Hz, 2H), 7.62 (d, J=7.7 Hz, 1H), 7.57 (t, J=7.9 Hz, 1H), 7.50 (t, J=7.8 Hz, 2H), 6.87 (s, 2H), 5.98 (s, 2H), 5.44 (s, 2H), 2.56 (s, 6H), 2.13 (s, 6H), 1.46 (s, 6H).

### Example 2.7 PC-7

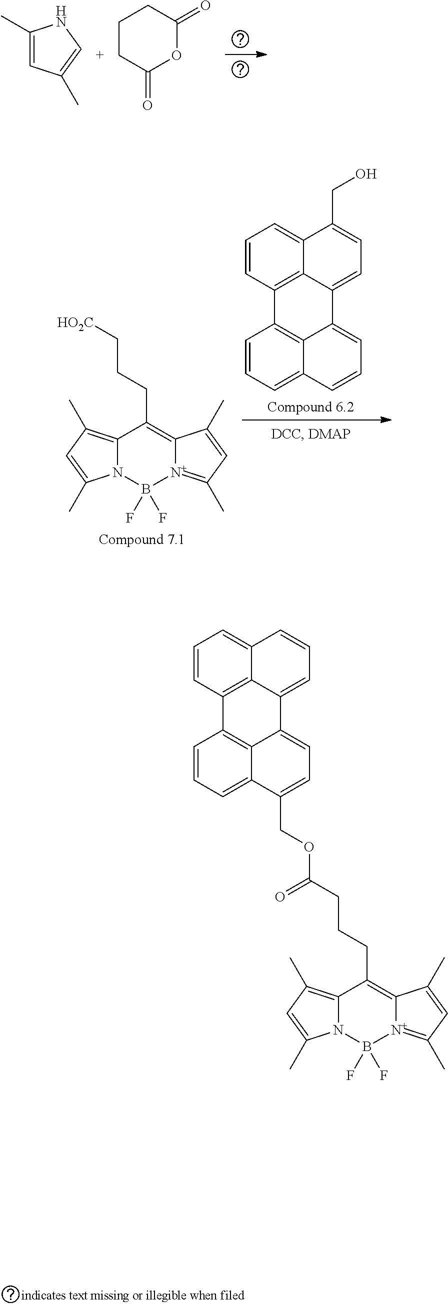

Compound 7.1: 1 mL of trifluoroboron-diethylether was added to a solution of glutaric anhydride (420 mg, 3.68 mmol), 2,4-dimethylpyrrole (0.6 g, 6.3 mmol) in anhydrous THF (25 mL). The solution was then degassed for 30 min and then heated at 70° C. for 12 hours. Next, the solution was cooled to room temperature, 2.5 g of trimethylamine and 2.5 g of trifluoroboron-diethylether were added sequentially into the solution and heated at 50° C. for 4 hrs. After 4 hrs. the solution was washed with a NH₄Cl aqueous solution and extracted with dichloromethane (100 mL×2). The organic phase was dried over Na₂SO₄ and loaded on a silica gel to be purified by flash chromatography using ethyl acetate/hexanes (0%-40%) as the eluents. The desired fraction was collected and dried under reduced pressure to give compound 13 as a red solid (150 mg, in 12% yield). LCMS (APCI+): calculated for C₃₈H₃₄BF₂N₂O₂ (M+H)=599; found: 599. ¹H NMR (400 MHz, Chloroform-d) δ 6.06 (s, 2H), 3.08-2.99 (m, 2H), 2.55 (t, J=8.8 Hz, 2H), 2.52 (s, 6H), 2.43 (s, 6H), 1.97 (m, 2H).

PC-7: A mixture of compound 7.1 (80 mg, 0.24 mmol), Compound 6.2 [3-Hydroxymethylperylene] (68 mg, 0.24 mmol), DCC (62 mg, 0.3 mmol) and DMAP (100 mg, 0.82 mmol) in THF (8 mL) was stirred overnight at room temperature while under argon gas. The solution was loaded on silica gel and purified by flash chromatography using dichloromethane/hexanes (1:1)→dichloromethane/ethyl acetate (1:1) as the eluents. The desired fraction was collected and dried under reduced pressure to give PC-7, as an orange solid (50 mg, in 30% yield). LCMS (APCI−): calculated for C₃₈H₃₂BF₂N₂O₂ (M−)=597; found 597. ¹H NMR (400 MHz, Chloroform-d) δ 8.29-8.15 (m, 4H), 7.84 (d, J=8.3 Hz, 1H), 7.72 (dd, J=7.9, 2.7 Hz, 2H), 7.54 (dt, J=23.6, 7.8 Hz, 4H), 6.03 (s, 2H), 5.55 (s, 2H), 3.05-2.96 (m, 2H), 2.58 (t, J=7.2 Hz, 2H), 2.50 (s, 6H), 2.38 (s, 6H), 2.03-1.95 (m, 2H).

### Example 2.8 PC-8

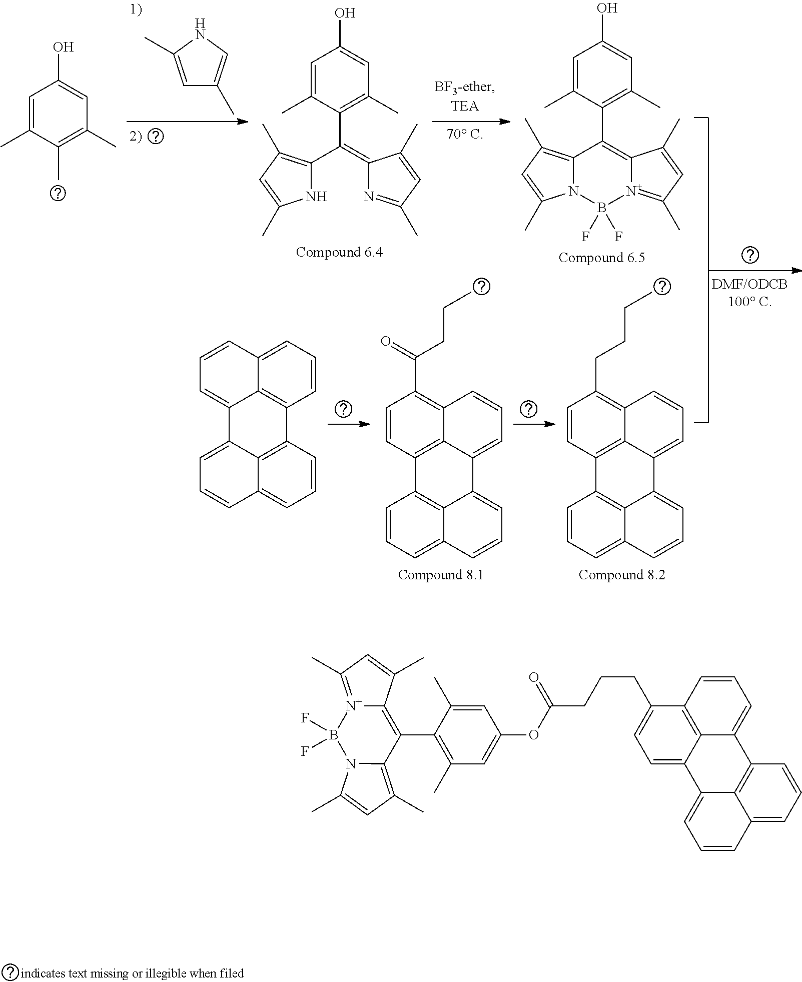

Compound 8.1 (Methyl 4-oxo-4-(perylen-3-yl) butanoate): Under protection of nitrogen atmosphere, 1.34 g of AlCl₃ (10.00 mmol) was added in small portions via a powder dispersion funnel to a mixture of 1.04 mL methyl 4-chloro-4-oxobutanoate (8.45 mmol) in 160 mL DCM anhydrous at 0° C. over 15 minutes. The resulting solution was stirred at 0° C. for 1 hr. Next, 2.00 g perylene (7.9 mmol) in DCM anhydrous was dropwise to the solution while the temperature was maintained at 0° C. The resulting dark purple solution was stirred overnight at room temperature under nitrogen atmosphere. The next day, the solution was poured into a solution of 75 mL ice water, 5 mL 6N HCl aqueous solution and 150 mL DCM. The organic layer was separated; the water layer was reextracted with ethyl acetate (100 ml). The organic layers were combined, dried with MgSO₄ and concentrated. The residue was loaded onto silica gel column. Chromatography was run with DCM, to gain 1.8 g orange color solid product, yield 62%. LCMS (APCI+): calculated for C₂₅H₁₉O₃=367; found: 367.

Compound 8.2 (4-(perylen-3-yl) butanoic acid): A solution of 3.4 g compound 8.1 [methyl 4-oxo-4-(perylen-3-yl) butanoate] (9.28 mmol), 2.7 mL of 98% hydrazine mono hydrate (53 mmol) in 30 mL of diethylene glycol was placed in a pressure bottle and stirred at room temperature. 3.91 g of KOH (powder) (69.8 mmol) was added to the solution. The resulting solution was stirred at 80° C. for 15 minutes then heated to 140° C. and bubbled with a slow stream of argon gas for 2 hrs. The pressure bottle was sealed with a septum, an argon atmosphere was maintained with a balloon and the temperature was increased to 190° C. The solution was then stirred for 16 hrs. while maintaining the 190° C. temperature. Next, the solution was cooled to room temperature, and diluted with 300 mL water and passed through Celite; the resulting filtrate was acidified with 6N HCl. The green color solid was collected by filtering and washed with water. The green color solid product was dried in a vacuum oven, 3.0 g, yield 95%. LCMS (APCI+): calculated for C₂₄H₁₉O₂ (M+H)=339; found: 339. ¹H NMR (400 MHz, DMSO-d₆) δ 11.57 (s, 1H), 8.35 (88, J=10.9, 7.4 Hz, 2H), 8.28 (88, J=12.2, 7.5 Hz, 2H), 7.98 (8, J=8.5 Hz, 1H), 7.76 (t, J=7.5 Hz, 2H), 7.61-7.50 (m, 2H), 7.54-7.47 (m, 1H), 7.38 (88, J=7.9, 3.4 Hz, 1H), 3.49 (8, J=5.2 Hz, 1H), 3.43 (q, J=6.2, 5.2 Hz, 1H), 3.01 (88, J=9.0, 6.6 Hz, 2H), 2.36 (t, J=7.2 Hz, 2H), 1.91 (p, J=7.4 Hz, 2H).

PC-8: Under protection of a nitrogen atmosphere, 412.6 mg of DCC (2.00 mmol) was added to a solution containing 369 mg of BODIPY, compound 6.5, (1.00 mmol), 406 mg of compound 8.2 [4-(perylen-3-yl) butanoic acid] (1.2 mmol), 242 mg of DMAP (2.00 mmol) in 10 mL of THF anhydrous. The resulting solution was stirred at for 16 hrs. at room temperature. Next, water was added follow by 150 mL ethyl acetate. The solution was passed through Celite. The organic layer was separated and concentrated. The crude product was purified by silica gel column chromatography with hexanes:ethyl acetate (9:1) as the eluents, to gain 510 mg of a red orange color solid product, yield 74%. LCMS (APCI+): calculated for C₄₅H₄₀BF₂N₂O₂ (M+H)=689; found: 689. ¹H NMR (400 MHz, Chloroform-d) δ 8.23 (8, J=7.5 Hz, 1H), 8.23-8.12 (m, 3H), 7.94 (8, J=8.4 Hz, 1H), 7.68 (55, J=8.1, 5.0 Hz, 2H), 7.54 (t, J=8.0 Hz, 1H), 7.48 (to, J=7.8, 2.6 Hz, 2H), 7.39 (0, J=7.7 Hz, 1H), 6.87 (s, 2H), 5.97 (s, 2H), 3.19 (t, J=7.6 Hz, 2H), 2.70 (t, J=7.2 Hz, 2H), 2.56 (s, 6H), 2.25 (p, J=7.3 Hz, 2H), 2.12 (s, 6H), 1.39 (s, 6H)

### Example 2.9 PC-9

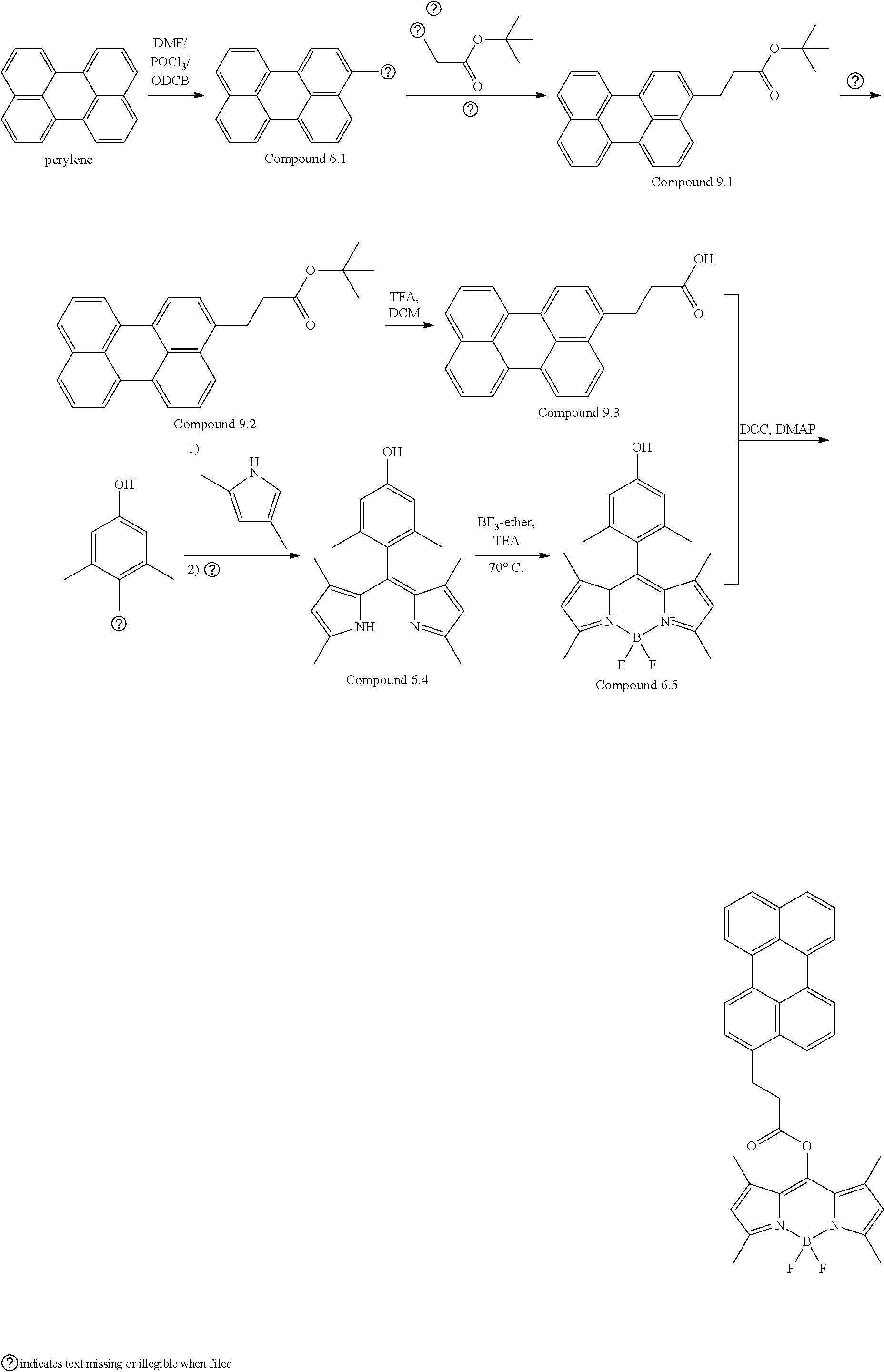

Compound 9.1 (cert-butyl (E)-3-(perylen-3-yl) acrylate): Under protection of an argon atmosphere, 4.55 mL of t-BuOK 1M/THF (4.55 mmol) was added dropwise to a suspension of 2.09 g t-butoxycarbonyl methyl triphenylphosphonium bromide (4.55 mmol) in 5 mL anhydrous THF at 0° C. The resulting solution was stirred for 15 min at 0° C. Next, 0,981 g of compound 6.1 [perylene-3-carbaldehyde], (3.5 mmol) in 100 mL of anhydrous THF was added. The resulting mixture was stirred overnight at room temperature. The solution was worked up with water and CCM, The crude product was purified by SiO₂ column chromatography, using Hexanes as the eluents: DCM, gained 1.13 g orange color solid product, yield 85%. LCMS (APCI+): calculated for C₂₇H₂₃O₂ (M+H)=379; found: 379. ¹H NMR (400 MHz, Chloroform-d) δ 8.30 (δ, J=15.7 Hz, 1H), 8.15 (δδδ, J=17.6, 13.0, 7.8 Hz, 4H), 7.99 (δ, J=8.5 Hz, 1H), 7.69 (δ, J=8.0 Hz, 1H), 7.64 (δδ, J=8.1, 5.0 Hz, 2H), 7.51 (t, J=8.0 Hz, 1H), 7.47 (t, J=8.1 Hz, 2H), 6.42 (δ, J=15.7 Hz, 1H), 3.43 (s, 1H), 1.52 (s, 9H).

Compound 9.2 (tert-butyl (E)-3-(perylen-3-yl) acrylate): A solution of 168 mg of compound 9.1 [tert-butyl (E)-3-(perylen-3-yl)acrylate], (0.433 mmol) and 20 mg of Pd/C 10% w/w in 5 mL of THF:MeOH (9:1) was hydrogenated under 65 psi H₂ atmosphere with a Parr Shaker for 5 hrs. Next, the solution was filtered through Celite and concentrated under reduced pressure to gain 152 mg yellow color solid product, yield 90%. LCMS (APCI+): calculated for C₂₂H₂₅O₂ (M+H)=381; found: 381. ¹H NMR (400 MHz, Chloroform-d) δ 8.28-8.12 (m, 4H), 7.90 (8, J=8.4 Hz, 1H), 7.70 (88, J=8.1, 5.3 Hz, 2H), 7.57 (5, J=8.0 Hz, 1H), 7.54-7.45 (m, 2H), 7.40 (5, J=7.7 Hz, 1H), 3.35 (5, J=8.0 Hz, 2H), 2.71 (5, J=8.0 Hz, 2H), 1.4 (s, 9H).

Compound 9.3 (3-(perylen-3-yl) propanoic add): 10 mL of TFA was added to a solution of 1.52 g of compound 9.2 [tert-butyl (E)-3-(perylen-3-yl)acrylate], (4 mmol) in 50 mL of DCM. The solution was stirred at for 2 hrs. at room temperature. Next, the solvent and TFA were removed under reduced pressure. The crude solid product was washed with Hexanes to gain 1.26 g green yellow color solid product, yield 97%. LCMS (APCI+): calculated for C₂₃H₁₇O₂ (M+H)=325; found: 325. ¹H NMR (400 MHz, DMSO-d6) δ 12.24 (s, 1H), 8.35 (δδδ, J=28.2, 13.1, 7.6 Hz, 4H), 7.94 (δ, J=8.4 Hz, 1H), 7.78 (t, J=7.2 Hz, 2H), 7.61 (t, J=7.9 Hz, 1H), 7.54 (to, J=7.8, 3.5 Hz, 2H), 7.43 (5, J=7.7 Hz, 1H), 3.26 (t, J=7.7 Hz, 2H), 2.67 (t, J=7.6 Hz, 2H).

PC-9: Under protection of a nitrogen atmosphere, 24.2 mg of DCC (0.2 mmol) was added to a solution of 32 mg of compound 6.5 [4-(5,5-difluoro-1,3,7,9-tetramethyl-5H-4|4,5|4-dipyrrolo[1,2-c:2′,1′-f][1,3,2]diazaborinin-10-yl)-3,5-dimethylphenol], (0.1 mmol), 37 mg of compound 9.3 [3-(perylen-3-yl)propanoic acid], (0.1 mmol), 241 mg of DMAP (0.2 mmol) and 5.0 mL of DMF anhydrous. The resulting solution was stirred at for 16 hrs. at room temperature. Water was added follow by 50 mL of DCM. The solution was passed through Celite. The organic layer was separated and concentrated. The crude product was purified by silica g& column chromatography, using Hexanes:DCM as the eluents, to gain 30 mg red orange color solid product, yield 45%. LCMS (APCI+): calculated for C₄₄H₃₈BF₂N₂O₂ (M+H) 675; found: 675. ¹H NMR (400 MHz, Chloroform-d) δ 8.31-8.16 (m, 2H), 7.93 (5, J=8.4 Hz, 0H), 7.72 (δδ, J=8.1, 4.3 Hz, 1H), 7.63-7.49 (m, 1H), 7.53-7.45 (m, 1H), 6.89 (s, 1H), 6.00 (s, 1H), 3.53 (t, J=7.8 Hz, 1H), 3.06 (t, J=7.8 Hz, 1H), 2.58 (s, 6H), 2.16 (s, 6H), 1.43 (s, 6H).

### Example 2.10 PC-10

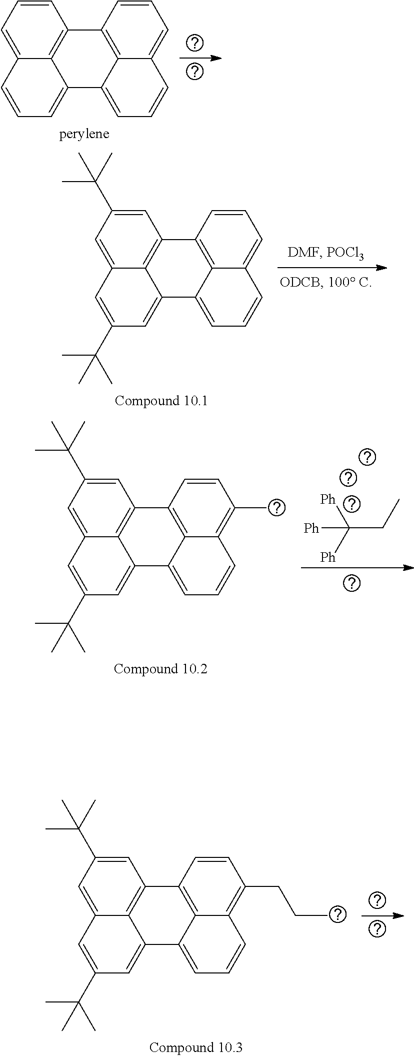

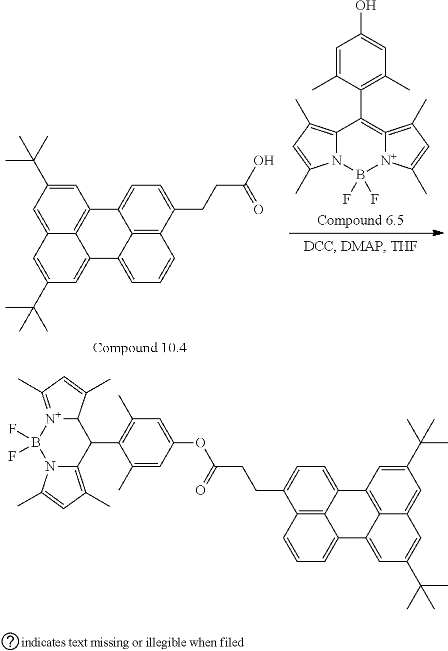

Compound 10.1 (2,5-di-tert-butylperylene): Under protection of Nitrogen atmosphere, 5 g of perylene (19.81 mmol) was dissolved in 300 ml ortho-dichlorobenzene anhydrous in a three neck round bottle flask. The resulting yellow solution was cooled to 0° C. 2.64 g of AlCl₃ (19.81 mmol) was added in small portions via a powder dispensing funnel over 45 minutes following by dropwise addition of 50 of Cert-butylchloride (458 mmol). The resulting green color solution was stirred 24 hrs. at room temperature. The reaction mixture was poured into 100 mL of ice water. The organic layer was separated, concentrated to dryness using a rotary evaporator with its water bath set at 70° C. The residue was re-dispersed into 450 mL of hot hexanes. The yellow solution was cooled and stood at room temperature overnight. The insoluble arterial was filtered and detected by LCMS as tetra butyl analog (M+H=477), the filtrate was a mixture of di and tri t-butyl perylene which was loaded onto silica gel column. Chromatography was run with Hexanes:EtOAc (9:1) to gain 3.75 g pale yellow color solid product of 2,5-di-tert-butylperylene, yield 52%. LCMS (APCI+) calculated for C₂₈H₂₉ (M+H)=365; found 365. ¹H NMR (400 MHz, Chloroform-d) δ 8.30-8.21 (m, 4H), 7.72-7.63 (m, 4H), 7.50 (t, J=7.8 Hz, 2H), 1.50 (s, 18H).

Compound 10.2 (8,11-di-tert-butylperylene-3-carbaldehyde): Under the protection of nitrogen atmosphere, 3.75 g of compound 10.1 [2,5-di-tert-butylperylene], (10.28 mmol), 5.1 mL of DMF anhydrous (66.95 mmol) were dissolved in 5.1 ml ortho-dichlorobenzene anhydrous in a three neck round bottle flask. The resulting yellow mixture was bubbled with argon gas for 15 min. The resulting mixture was stirred for 15 minutes at 100° C.1.9 mL of POCl₃ (20.6 mmol) was added dropwise through a dropping funnel over 1 hour while maintaining the solution at 100° C. The resulting dark red color solution was stirred 24 hours at 100° C. Next, the solution was cooled to room temperature, 100 mL of diluted sodium acetate aqueous solution was added, while stirring at a temperature of 0° C. Once the solution was completely mixed is was allowed to stand at 0 CC for 3 hours. The dark liquid solution was decanted out; the remaining sticky dark color oil was taken to dichloromethane (DCM) then washed with water. The organic layer was separated and concentrated. The residue was loaded onto silica gel column. Chromatography was run with Hexanes:DCM (9:1) as eluents. The fractions containing the desired product was collected, evaporated then recrystallized from hexanes to gain 0.58 g red orange color solid product, yield 14.3%. LCMS (APCI+): calculated for C₂₉H₂₉O (M+H)=393; found 393. ¹H NMR (400 MHz, DMSO-d₆) δ 10.35 (s, 1H), 9.11 (5, J=8.4 Hz, 1H), 8.73 (5, J=7.9 Hz, 1H), 8.67 (5, J=7.7 Hz, 1H), 8.57 (5, J=1.7 Hz, 1H), 8.50 (5, J=1.7 Hz, 1H), 8.17 (5, J=7.8 Hz, 1H), 7.92 (s, 1H), 7.85 (s, 1H), 7.78 (t, =8.0 Hz, 1H), 1.47 (5, J=4.4 Hz, 18H).

Compound 10.3 (tert-butyl (E)-3-(8,11-di-tert-butylperylen-3-yl) acrylate): Under protection of argon atmosphere. 0.305 mL of t-BuOK. 1M/THF (0.305 mmol) was added dropwise to a suspension of 140 mg of t-butoxycarbonyl methyl triphenylphosphonium bromide (0.305 mmol) in 2 mL of anhydrous THF at 0° C. The resulting solution was stirred for 1 hr. at 0° C. Next, a solution containing 100 mg of compound 10.2 (8,11-di-tert-butylperylene-3-carbaldehyde), (0.254 mmol) in 1.0 mL of anhydrous THF was added to the while maintaining the temperature at 0° C. The resulting solution was stirred overnight at 65° C. The reaction solution was worked up with water and ethyl acetate, the crude product was purified by SiO₂ column chromatography, using t Hexanes:DCM as the eluents, resulting in 110 mg of an orange color solid product, yield 88%. LCMS (APCI+): calculated for C₃₅H₃₉O₂ (M+H)=491; found: 491. ¹H NMR (400 MHz, Chloroform-d) δ 8.38 (d, J=15.7 Hz, 1H), 8.28 (t, J=5.8 Hz, 3H), 8.21 (d, J=8.0 Hz, 1H), 8.05 (d, J=8.4 Hz, 1H), 7.76 (d, J=8.0 Hz, 1H), 7.67 (d, J=6.6 Hz, 2H), 7.58 (t, J=7.9 Hz, 1H), 6.48 (d, J=15.8 Hz, 1H), 1.59 (s, 9H), 1.48 (s, 18H). Compound 10.4 (3-(8,11-di-tert-butylperylen-3-yl) propanoic acid): A solution comprising 110 mg of compound 10.3 [tert-butyl (E)-3-(8,11-di-tert-butylperylen-3-yl)acrylate], (0.224 mmol) and 10 mg of Pd/C 10% w/w dissolved in 15 mL of EtOAc:MeOH (9:1) was stirred at room temperature for 2 hrs. under H₂ atmosphere. The solution was filtered through Celite and concentrated under reduced pressure to gain 110 mg yellow color solid product, yield 98%. LCMS (M+H)=493. Next, the 110 mg of solid yellow product was dissolved in 5.0 mL of DCM. Once completely dissolved 1.0 mL of TFA was added and stirred at room temperature for 2 hrs. The DCM and TFA were removed under reduced pressure. The crude solid product was washed with Hexanes to gain 36 mg green yellow color solid product, yield 97%. LCMS (APCI+): calculated for C₃₁H₃₃O₂. (M+H)=437; found: 437. ¹H NMR (400 MHz, Chloroform-d) δ 8.25 (t, J=9.2 Hz, 3H), 8.16 (d, J=7.7 Hz, 1H), 7.85 (d, J=8.4 Hz, 1H), 7.63 (d, J=4.5 Hz, 2H), 7.55 (t, J=8.0 Hz, 1H), 7.39 (d, J=7.7 Hz, 1H), 3.40 (t, J=7.9 Hz, 2H), 2.85 (t, J=7.9 Hz, 2H), 1.47 (s, 18H)

PC-10: Under protection of a nitrogen atmosphere, 30.53 mg of DCC (0.148 mmol) was added to a solution containing 27 mg of compound 6.5 [4-(5,5-difluoro-1,3,7,9-tetramethyl-5H-4|4,5|4-dipyrrolo[1,2-c:2′,1′-f][1,3,2]diazaborinin-10-yl)-3,5-dimethylphenol], (0.074 mmol), 17.9 mg of compound 10.4 [3-(8,11-di-tert-butylperylen-3-yl) propanoic acid], (0.1 mmol), 17.9 mg of DMAP (0.148 μmol) dissolved in 5.0 mL of THF anhydrous. The resulting solution was stirred at room temperature for 16 hrs Water was added follow by 50 mL of ethyl acetate. The resulting solution was passed through Celite. The organic layer was separated and concentrated. The crude product was purified by silica gel column chromatography, using Hexanes:DCM (9:1) as the eluents. Resulting in 43 mg of a red orange color solid product, yield 73%. LCMS (APCI+): calculated for C₅₂H₅₄BF₂N₂O₂ (M+H)=787; found: 787. ¹H NMR (400 MHz, Chloroform-d) δ 8.31-8.16 (m, 2H), 8.19 (5, J=7.6 Hz, 1H), 7.89 (5, J=8.4 Hz, 1H), 7.64 (s, 1H), 7.63 (s, 1H), 7.57 (t, J=7.9 Hz, 1H), 7.45 (5, J=7.7 Hz, 1H), 6.85 (s, 2H), 5.97 (s, 2H), 3.51 (t, J=7.8 Hz, 2H), 3.04 (t, J=7.8 Hz, 2H), 2.56 (s, 6H), 2.13 (s, 6H), 1.48 (s, 9H), 1.47 (s, 9H), 1.40 (s, 6H).

### Example 2.11 PC-11

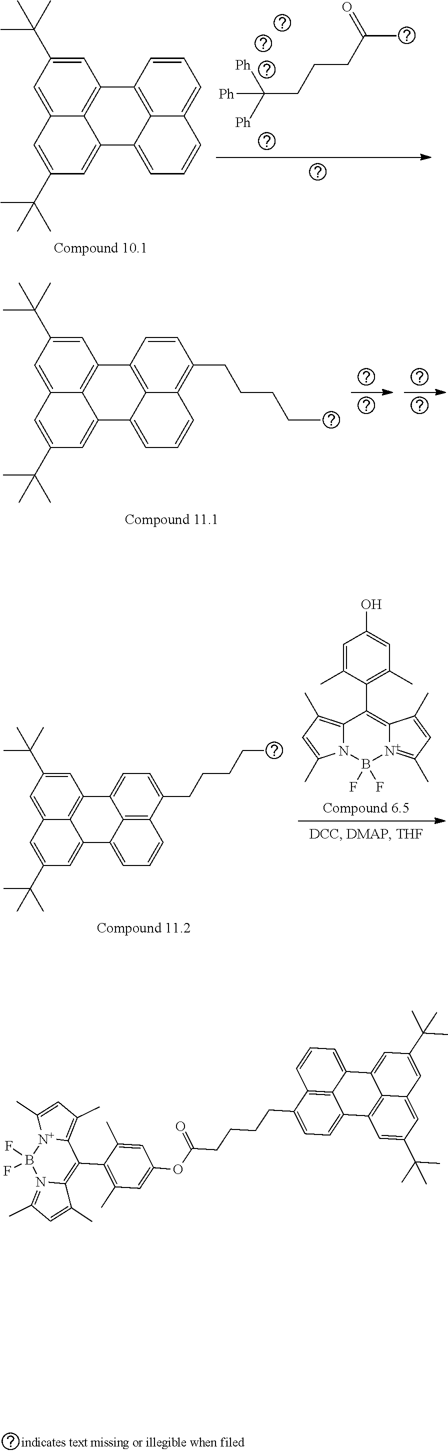

Compound 11.1 (Ethyl (E)-5-(8,11-di-tert-butylperylen-3-yl) pent-4-enoate): Under protection of Argon atmosphere, 1.82 mg of t-BuOK 1M/THF (1.82 mmol) was added dropwise to a suspension containing 832 mg of (4-ethoxy-4-oxobutyl) triphenylphosphonium bromide (1.82 mmol) dissolved in 5 mL of anhydrous THF at 0° C. The resulting solution was stirred of over 1 hour at 0° C. Next, a suspension of 550 mg of compound 10.1 (8,11-di-tert-butylperylene-3-carbaldehyde), (1.4 mmol) dissolved in 20 mL of anhydrous THF was added while maintaining the temperature at 0° C., The resulting solution was stirred overnight at 65° C. The next day the solution was worked up with water and ethyl acetate. The crude product was purified by SiO₂ column chromatography, using Hexanes:DCM as the eluents, resulting in 230 mg of an orange color solid product, yield 33%. LCMS (APCI+): calculated for C₃₅H₃₉O₂ (M+H)=491; found: 491.

Compound 11.2 (5-(8,11-di-tert-butylperylen-3-yl) pentanoic acid): A solution comprising 230 mg of compound 11.1 [ethyl (E)-5-(8,11-di-tert-butylperylen-3-yl)pent-4-enoate], (0.468 mmol) and 10 mg of Pd/C 10% w/w dissolved in 15 mL of EtOAc:MeOH (9:1) was stirred under H₂ atmosphere at room temperature for 2 hrs. The solution was filtered through Celite and concentrated under reduced pressure, resulting in 230 mg yellow color solid product, yield 100%. LCMS (APCI+): calculated for C₃₅H₄₁O₂ (M+H)=493; found: 493.

Next, 5.0 mL of THF and 2 mL of 4M KOH aqueous solution was added to the 230 mg of yellow solid product and stirred at room temperature for 16 hrs. The solution was acidified with HCl 6N aqueous solution. Next, ethyl acetate was added, the organic layer was separated, dried over MgSO₄ and concentrated. The solvents were removed under reduced pressure. The crude solid product was washed with Hexanes, resulting in 176 mg green yellow color solid product, yield 81%. Product was used next step without further purification. LCMS (APCI+): calculated for C₃₃H₃₇O₂ (M+H)=465; found: 465.

PC-11: Under protection of Nitrogen atmosphere, 25.17 mg of DCC (0.122 mmol) was added to a solution containing 22.5 mg of compound 6.5 [4-(5,5-difluoro-1,3,7,9-tetramethyl-5H-4|4,5|4-dipyrrolo[1,2-c:2′,1′-f][1,3,2]diazaborinin-10-yl)-3,5-dimethylphenol], (0.061 mmol), 25 mg of compound 11.2 [5-(8,11-di-tert-butylperylen-3-yl) pentanoic acid], (0.067 mmol) 14.78 mg of DMAP (0.122 mmol) dissolved in 2.0 mL of THF anhydrous. The resulting solution was stirred at room temperature for 16 hrs. Water was added follow by 50 mL of ethyl acetate. The solution was passed through Celite. The organic layer was separated and concentrated. The crude product was purified by silica gel column chromatography, using Hexanes:DCM (9:1) as the eluents resulting in 15 mg of a red orange color solid product, yield 25%, LCMS (APCI+): calculated for C₅₄H₅₈BF₂N₂O₂ (M+H)=815; found: 815. ¹H NMR (400 MHz, Chloroform-d) δ 8.26 (t, J=7.6 Hz, 3H), 8.18 (δ, J=7.6 Hz, 1H), 7.90 (δ, J=8.4 Hz, 1H), 7.65 (δ, J=5.5 Hz, 2H), 7.55 (t, J=7.9 Hz, 1H), 7.39 (δ, J=7.6 Hz, 1H), 6.89 (s, 2H), 5.99 (s, 2H), 3.13 (t, J=7.8 Hz, 3H), 2.66 (t, J=7.8 Hz, 3H), 2.58 (s, 6H), 2.15 (s, 6H), 1.93 (t, J=7.8 Hz, 2H), 1.50 (s, 18H), 1.42 (s, 6H), 1.22-1.03 (m, 2H), 0.92-0.89 (m, 2H).

### Example 2.12 PC-12

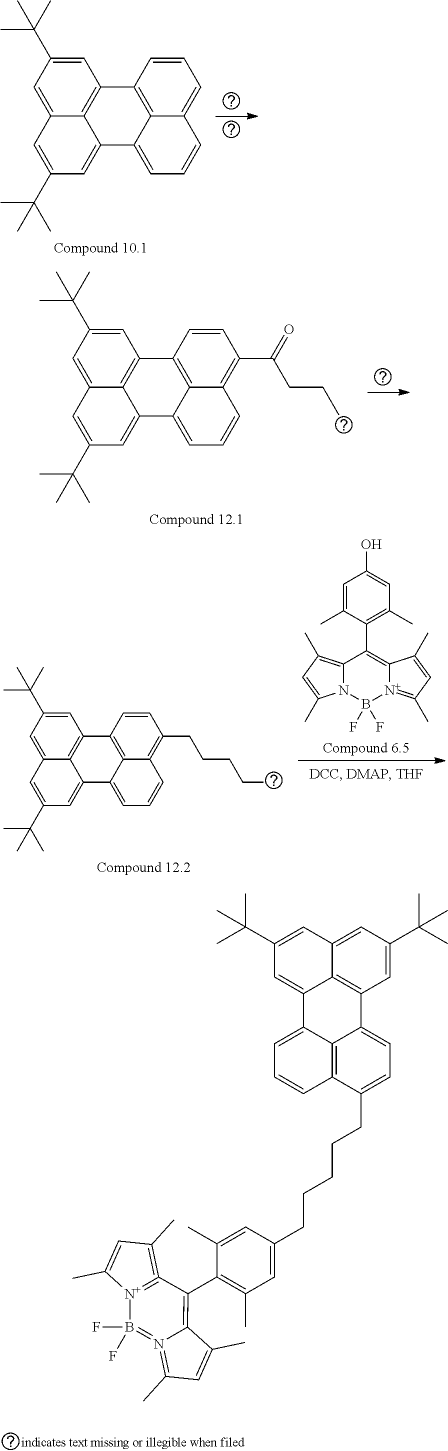

Compound 12.1 (Methyl 4-(8,11-di-tert-butylperylen-3-yl)-4-oxobutanoate): Under protection of Nitrogen atmosphere, 2.63 g of AlCl₃ (19.97 mmol) was added in small portions via a powder dispersion funnel to a suspension of 2.45 mL methyl 4-chloro-4-oxobutanoate (19.97 mmol) in 175 mL of DCM anhydrous at 0° C. over 15 minutes. The resulting solution was stirred at 0° C. over 1 hr. Next, a solution of 5.77 g of compound 10.1 [2,5-di-tert-butylperylene], (15.85 mmol) dissolved in DCM anhydrous was dropwise while maintaining the temperature at 0° C. The resulting dark purple solution was stirred overnight at room temperature under Nitrogen atmosphere. The next day the solution was poured into a mixture of 150 mL of ice water and 300 mL DCM. The organic layer was separated; the water layer was reextracted with 100 mL of ethyl acetate. The organic layers were combined, dried with MgSO₄ and concentrated. The residue was loaded onto silica gel column. Chromatography was run with Hexanes:ethyl acetate (9:1) as the eluents, resulting in 2.7 g of an orange color solid product, yield 35%. LCMS (APCI+): calculated for C₃₃H₃₅O₃ (M+H)=479; found: 479; 1H NMR (400 MHz, Chloroform-d) δ 8.58 (d, J=8.6 Hz, 1H), 8.34-8.27 (m, 3H), 8.23 (d, J=8.0 Hz, 1H), 7.98 (d, J=7.9 Hz, 1H), 7.73 (s, 1H), 7.68 (s, 1H), 7.60 (t, J=8.0 Hz, 1H), 3.75 (s, 3H), 3.41 (t, J=6.5 Hz, 2H), 2.86 (t, J=6.6 Hz, 2H), 1.49 (d, J=3.5 Hz, 18H).

Compound 12.2 (4-(8,11-di-tert-butylperylen-3-yl) butanoic acid): A solution of 470.5 mg of compound 12.1 [methyl 4-(8,11-di-tert-butylperylen-3-yl)-4-oxobutanoate], (0.983 mmol) and 150 μL of 98% hydrazine mono hydrate (2.949 mmol) dissolved in 2 mL of diethylene glycol was placed in a micro wave vial and stirred at room temperature. 275 mg of KOH (powder) (4.91 mmol) was added to the solution and stirred for 15 min at 80° C. Next, the solution was heated to 140° C. and bubbled with a slow stream of argon gas for 2 hours. The vial containing the solution was sealed a septum, an argon atmosphere was maintained with a balloon and the temperature was raised to 190° C. The resulting solution was stirred over 16 hrs. while maintaining the temperature at 190° C. The solution was then cooled to room temperature and diluted with 20 mL of water acidified with 6N HCl. The resulting green color solid was collected by filtering and purified with SiO₂ column chromatography, using DCM:EtOAc (1:1) as the eluent, resulting in 110 mg of a green color solid product, yield 88%. LCMS (APCI+): calculated for C₃₂H₃₅O₂ (M+H)=451; found: 451; ¹H NMR (400 MHz, Chloroform-d) δ 8.27-8.19 (m, 3H), 8.15 (d, J=7.7 Hz, 1H), 7.88 (d, J=8.4 Hz, 1H), 7.62 (d, J=5.2 Hz, 2H), 7.53 (t, J=8.0 Hz, 1H), 7.34 (d, J=7.7 Hz, 1H), 5.30 (s, 1H), 3.09 (t, J=7.7 Hz, 2H), 2.48 (t, J=7.2 Hz, 2H), 2.11 (p, J=7.4 Hz, 2H), 1.47 (s, 18H).

PC-12: Under protection of Nitrogen atmosphere, 74.27 mg of DCC (0.36 mmol) was added to a solution containing 66 mg of compound 6.5 [4-(5,5-difluoro-1,3,7,9-tetramethyl-5H-4|4,5|4-dipyrrolo[1,2-c:2′,1′-f][1,3,2]diazaborinin-10-yl)-3,5-dimethylphenol], (0.18 mmol), 100 mg of compound 12.2 [4-(8,11-di-tert-butylperylen-3-yl)butanoic acid], (0.22 mmol), 43.6 mg of DMAP (0.36 mmol) dissolved in 2.0 mL of THF anhydrous. The resulting solution was stirred for 16 hrs. at room temperature. Water was added follow by 50 mL of ethyl acetate. The solution was next passed through Celite. The organic layer was separated and concentrated. The crude product was purified by silica gel column chromatography, using Hexanes:ethyl acetate (9:1) as the eluents, resulting 43 mg of a red orange color solid product, yield 24%. LCMS (APCI+): calculated for C₅₃H₅₆BF₂N₂O₂ (M+H)=801; found: 801. ¹H NMR (400 MHz, Chloroform-d) δ 8.26 (8, J=7.4 Hz, 1H), 8.24 (s, 1H), 8.22 (s, 1H), 8.18 (8, J=7.7 Hz, 1H), 7.93 (8, J=8.3 Hz, 1H), 7.63 (s, 1H), 7.62 (s, 1H), 7.53 (t, J=7.9 Hz, 1H), 7.4 (8, J=7.4 Hz, 1H), 6.85 (s, 2H), 5.96 (s, 2H), 3.18 (t, J=7.3 Hz, 2H), 2.69 (t, J=7.4 Hz, 2H), 2.55 (s, 6H), 2.25 (t, J=7.4 Hz, 2H), 2.1 (s, 6H), 1.48 (s, 9H), 1.47 (s, 9H), 1.38 (s, 6H).

### Example 2.13 PC-13

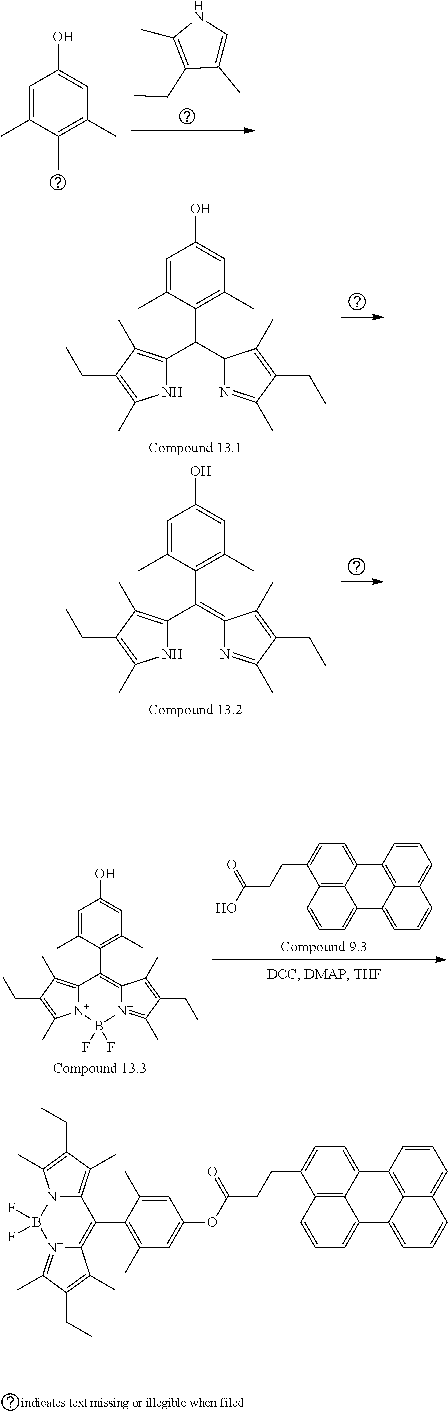

Compound 13.1: A solution of 3.0 g of 3-ethyl-2,4-dimethyl-1H-pyrrole (5.42 g, 44 mmol), 4-Hydroxy-2,6-dimethylbenzaldehyde (20 mmol) was dissolved in 300 mL of anhydrous dichloromethane. The solution was purged with N₂ for 30 minutes, and TFA (3 drops) were added. The resulting solution was stirred for 16 hrs. at room temperature. The TFA and solvent was removed by reduced pressure. The crude product was used for the preceding step without further purification. LCMS (APCI+): calculated for C₂₅H₃₅N₂O (M+H)=379; found: 379.

Compound 13.2:8 g of DDQ (35.2 mmol) was added to the crude compound 13.1 [4-((4-ethyl-3,5-dimethyl-1H-pyrrol-2-yl) (4-ethyl-3,5-dimethyl-2H-pyrrol-2-yl)methyl)-3,5-dimethylphenol], and dissolved in 300 mL of dry DOA. The resulting mixture was stirred at room temperature for 1 hr. The dark solution was loaded onto column of silica gel, CH₂Cl₂/EtOAc was used as the eluent, resulting in 7.53 g of Compound 13.2 (99% yield for two steps). LCMS (APCI+): calculated for C₂₅H₃₃N₂O (M+H)=377; found: 377.

Compound 13.3: To a solution of 7.53 g of compound 13.2 [(2)-4-((4-ethyl-3,5-dimethyl-1H-pyrrol-2-yl) (4-ethyl-3,5-dimethyl-2H-pyrrol-2-ylidene)methyl)-3,5-dimethylphenol], (20.0 mmol) dissolved in 300 ml of anhydrous toluene, 16.72 mL of triethylamine (120 mmol) was added, followed by 24.68 mL of BF₃ etherate (200 mmol). The reaction solution was stirred for 16 hrs. at room temperature and then heated to 70° C. of 1 hr. Next, the solution was cooled to room temperature and 50 mL of NaOH (1M) was added. The layers were separated. The aqueous layer was neutralized with 4 N HCl, and an EtOAc extraction was carried out. The combined organic layers were dried over MgSO₄ and the solvent was removed. The residue was chromatographed on column of silica gel using CH₂Cl₂/EtOAc as the eluent, resulting in pure Compound 13.3 (1.70 g, 20%). LCMS (APCI+): calculated for C₂₅H₃₂BF₂N₂O (M+H)=325; found: 325. ¹H NMR (400 MHz, Chloroform-d) δ 6.56 (s, 2H), 4.77 (s, OH), 2.46 (s, 6H), 2.24 (q, J=7.6 Hz, 4H), 2.01 (s, 6H), 1.27 (s, 6H), 0.92 (t, J=7.5 Hz, 6H).

PC-13: Under protection of a nitrogen atmosphere, 89.3 mg of DCC (0.433 mmol) was added to a solution containing 123 mg of compound 13.3 [4-(2,8-diethyl-5,5-difluoro-1,3,7,9-tetramethyl-5H-4|4,5|4-dipyrrolo[1,2-c:2′,1′ f][1,3,2]diazaborinin-10-yl)-3,5-dimethylphenol], (0.289 mmol), 112 mg of compound 9.3 [3-(perylen-3-yl)propanoic acid], (0.346 mmol), 52.4 mg of DMAP (0.433 mmol) dissolved in 5.0 mL of THF anhydrous. The resulting solution was stirred at RT for 16 hrs. Water was added follow by 50 mL of CCM (50 ml). The mixture was passed through Celite. The organic layer was separated, and concentrated. The crude product was purified by silica gel column chromatography, using Hexanes:DCM as the eluents, resulting in 95 mg of a red orange color solid product, yield 45%. LCMS (APCI+): calculated for C₄₈H₄₇BF₂N₂O₂ (M+H)=732; found: 732; ¹H NMR (400 MHz, Chloroform-d) δ 8.31-8.16 (m, 4H), 7.94 (δ, J=8.4 Hz, 1H), 7.72 (δδ, J=8.1, 4.4 Hz, 2H), 7.59 (t, J=7.92 Hz, 3H), 7.53-7.45 (m, 3H), 6.88 (s, 2H), 3.54 (t, J=7.8 Hz, 2H), 3.07 (t, J=7.8 Hz, 2H), 2.56 (s, 6H), 2.33 (q, J=7.5 Hz, 4H), 2.15 (s, 6H), 1.34 (s, 6H), 1.01 (t, J=7.5 Hz, 6H).

### Example 2.14 PC-14

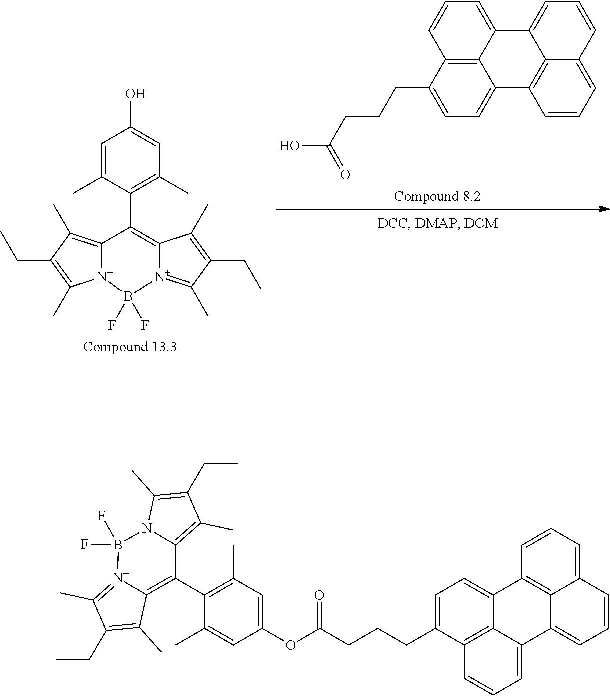

PC-14: Under protection of a nitrogen atmosphere, 212.5 mg of DCC (1.03 mmol) was added to a solution containing 175 mg of compound 13.3 [4-(2,8-diethyl-5,5-difluoro-1,3,7,9-tetramethyl-5H-4|4,5|4-dipyrrolo[1,2-c:2′,1′ f][1,3,2]diazaborinin-10-yl)-3,5-dimethylphenol], (412 mmol), 167 mg of compound 8.2 [4-(perylen-3-yl)butanoic acid], (0.494 mmol), 124.8 mg of DMAP (1.03 mmol) dissolved in 15.0 mL of THF anhydrous. The resulting solution was stirred for 16 hrs. at morn temperature. Water was added follow by 150 mL of Ethyl acetate. The solution was passed through Celite. The organic layer was separated and concentrated. The crude product was purified by silica gel column chromatography, using Hexanes:DCM as the eluents, resulting in 130 mg of a red orange color solid product, yield 42%. LCMS (APCI+): calculated for C₄₉H₄₉BF₂N₂O₂ (M+H)=746; found: 746. ¹H NMR (400 MHz, Chloroform-d) δ 8.20-8.05 (m, 4H), 7.88 (5, J=8.5 Hz, 1H), 7.61 (dd, J=8.1, 5.0 Hz, 2H), 7.48 (t, J=8.0 Hz, 1H), 7.41 (td, J=7.9, 2.4 Hz, 2H), 7.33 (5, J=7.6 Hz, 1H), 6.78 (s, 2H), 5.23 (s, 1H), 3.42 (s, 2H), 3.12 (t, J=7.6 Hz, 2H), 2.63 (t, J=7.2 Hz, 2H), 2.46 (s, 6H), 2.20 (50, J=21.4, 7.4 Hz, 6H), 2.03 (s, 6H), 1.47-1.42 (m, 3H), 1.23 (s, 6H), 0.92 (t, J=7.5 Hz, 6H).

### Example 2.15 PC-15

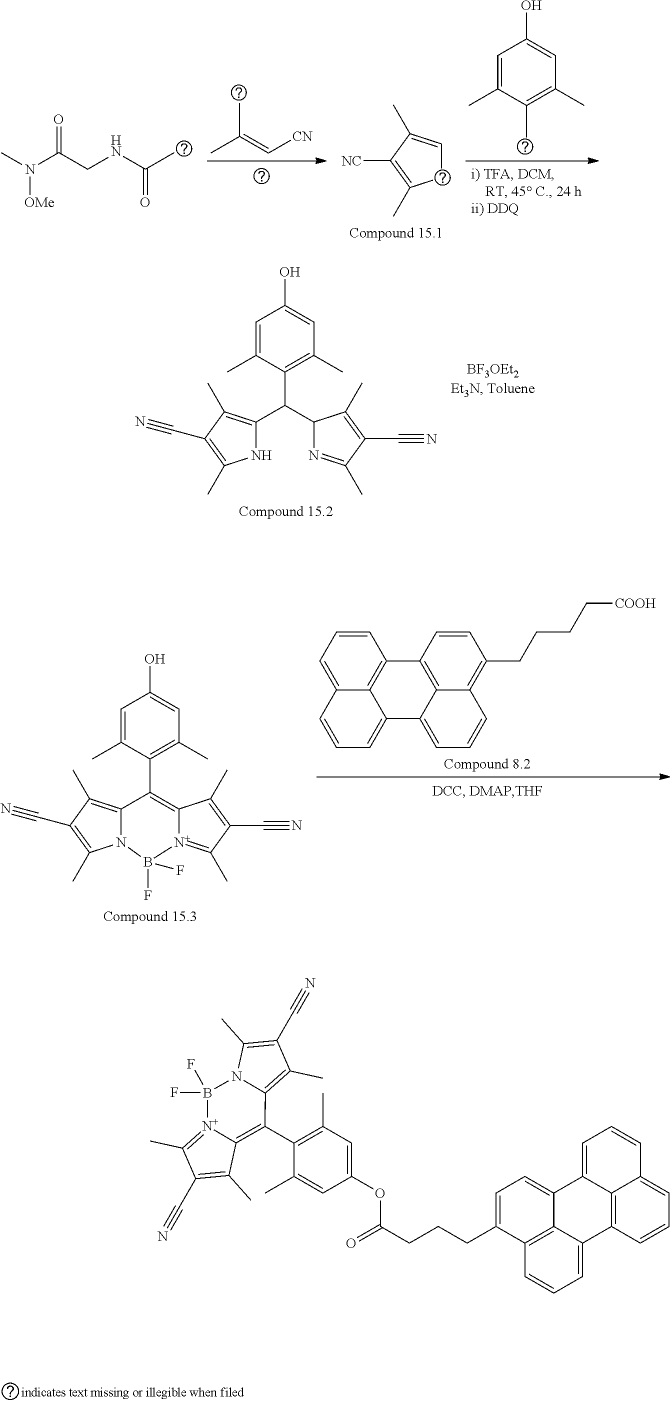

Compound 15.1 (Cyano-2,4-dimethylpyrrole): Was prepared with a four (4) step process. Step 1: 7.6 mL of 25% HBr/AcOH was slowly added to 19.76 g of solid Boc-Gly-n-MeOMeA (90.4 mmol). The solution was stirred at 45 min. at room temperature. Next, 200 mL of diethyl ether was added to the solution resulting in a white precipitate. The precipitate was filtrated to yield 18.03 g or glycine N′-methoxy-N′-methylamide HBr salt, 100% yield. LCMS (M+H): 119. ¹H NMR (DMSO-δ6) δ 8.04 (3H, s), 3.9 (s, 2H), 3.72 (s, 3H), 3.17 (s, 3H).

Step 2: A solution containing 14.85 g of 3-aminocrotonitrile (180.8 mmol) and 17.95 g of glycine N′-methoxy-N′-methylamide HBr salt (90.4 mmol) dissolved in 1 L of dry ethanol was stirred under argon gas for 16 hrs. at room temperature. The resulting solution was concentrated in vacuo to the volume of 50 ml. The solid residue was washed with 40 mL of cold EtOH, resulting in 16.71 g of a white solid. The solid was used for step 3 without further purification. LCMS (M+H) 184. ¹H NMR (DMSO-δ6) δ 6.9 (bs, 1H), 3.89 (s, 2H), 3.78 (s, 1H), 3.7 (s, 3H), 3.12 (s, 3H), 2.03 (s, 3H).

Step 3: To a solution containing 3.89 g of step 2's white powder (21.2 mmol) dissolved in 150 mL of dry THF, 7.5 mL of 3.0 M MeMgBr in Et₂O (1.1 equiv.) was added at −10° C. while under a nitrogen gas atmosphere. The solution was stirred for 50 min. Next, 15 mL of 3.0 M MeMgBr in Et2O (2.1 equiv.) was added and stirred for an additional 2 hrs. at −10° C. under a nitrogen gas atmosphere. After which the solution was quenched with 200 mL of water and extracted with AcOEt. The organic layer was washed with brine and dried over Na₂SO₄. Filtration and evaporation in vacuo. The product was a yellow solid which was used in step 4 without further purification.

Step 4: To a slurry comprising 2.67 g of the yellow solid from step 3 (19.3 mmol) in 75 mL of EtOH was added 273 mg of NaOEt (4.01 mmol, 0.2 equiv.). The slurry was stirred for 30 min. at room temperature. Next, the solution was evaporated in vacuo and the residue was taken up in 100 mL of water and extracted with AcOEt. The organic layer was washed with brine and dried over MgSO₄. Filtration, evaporation in vacuo and purification of the filtrate by silica gel flash chromatography (n-hexane:AcOEt 3:1 were the eluents). Yielding 2.09 g (90%) of Cyano-2,4-dimethylpyrrole as a white solid. LCMS (APCI+); calculated for C₇H₉N₂ (M+H)=121; found: 121. ¹H NMR (CDCl3) δ 8.06 (bs, 1H), 6.37 (1H, s), 2.37 (s, 3H), 2.13 (s, 3H)), 3.74 (1H, s), 2.10 (3H, s), 2.02 (3H, s).

Compound 15.2 ((Z)-5-((4-cyano-3,5-dimethyl-2H-pyrrol-2-ylidene)-(4-hydroxy-2,6-dimethylphenyl)methyl)-2,4-dimethyl-1H-pyrrole-3-carbonitrile) was synthesized with a two (2) step process: Step 1: Under an argon gas atmosphere, 1.12 g of 4-Hydroxy-2,6-dimethylbenzaldehyde (7.49 mmol) was dissolved in 85 mL of dichloromethane/EtOH (9:1). 1.8 g of 2,4-dimethyl-1H-pyrrole-3-carbonitrile (14.98 mmol) was added. Next, the solution was purged with nitrogen for 30 minutes, and TFA (5 drops) were added. The reaction mixture was stirred for 16 hrs, at room temperature. The TFA and solvent was removed by reduced pressure. The crude product was used in step 2 without further purification. LCMS (M+H=373).

Step 2: 8 g of DDC), (35.2 mmol) was added to a solution containing step 1's crude product dissolved in 50 mL of CHCl₃ plus 5 mL of EtOH. The solution was stirred for 1 hr. at room temperature. The solvents were removed under reduced pressure. The dark residue was re dissolved into 50 mL of CHCl₃, passed through a short column of silica gel, CH₂Cl₂/EtOAc (1:1) was used as eluent, resulting in 235 g off white solid. Overall yield of two steps was 85%. LCMS (APCI+): calculated for C₂₃H₂₃N₄O (M+H)=371; found: 371.

Compound 15.3 (5,5-difluoro-10-(4-hydroxy-2,6-dimethylphenyl)-1,3,7,9-tetramethyl-5H-4|4,5|4-dipyrrolo[1,2-c:2′,1′-f][1,3,2]diazaborine-2,8-dicarbonitrile): To a solution containing 23.35 g of compound 15.2, [(Z)-5-((4-cyano-3,5-dimethyl-2H-pyrrol-2-ylidene)-(4-hydroxy-2,6-dimethylphenyl)methyl)-2,4-dimethyl-1H-pyrrole-3-carbonitrile], (6.38 mmol) in 50 mL of anhydrous toluene, 8 mL of triethylamine (52.2 mmol) followed by 10 mL of BF₃-etherate (81 mmol) was added. The solution was stirred for 16 hrs. at room temperature, then heated at 80° C. for 1 hour. Next, the solution was cooled to room temperature and 25 mL of aqueous solution of NaOH (1M) was added, forming an aqueous layer which was separated. The aqueous layer was neutralized with 4 N HCl aqueous solution then extracted with EtOAc. The combined organic layers were dried over MgSO₄ and the solvent was removed. The residue was chromatographed on column of silica gel using Hexanes/EtOAc (1:1) as the eluent, resulting in 1.05 g of product (39% yield). LCMS (APCI+): calculated for C₂₃H₂₂BF₂N₄O (M+H)=419; found: 419. ¹H NMR (400 MHz, Chloroform-d) δ 6.73 (s, 2H), 2.73 (s, 6H), 2.05 (s, 6H), 1.64 (s, 6H).

PC-15: Under protection of a nitrogen atmosphere, 82.5 mg of DCC (0.4 mmol) was added to a solution containing 83.6 mg of compound 15.3 [5,5-difluoro-10-(4-hydroxy-2,6-dimethylphenyl)-1,3,7,9-tetramethyl-5H-4|4,5|4-dipyrrolo[1,2-c:2′,1′-f][1,3,2]diazaborinine-2,8-dicarbonitrile, (0.2 mmol), 81.1 mg of 4-(perylen-3-yl)butanoic acid, compound 8.2, (0.24 mmol), 48.4 mg of DMAP (0.4 mmol) dissolved in 4.0 mL of THF anhydrous. The solution was stirred for 16 hrs. at room temperature. Water was added follow by 50 mL of ethyl acetate. The solution was passed through Celite. The organic layer was separated and concentrated. The crude product was purified by silica gel column chromatography, using Hexanes:EtOAc as the eluent, resulting in 45 mg of a pale yellow color solid product, yield 30%. LCMS(APCI+): calculated for C₄₇H₃₈BF₂N₄O₂ (M+H)=739; found: 739. ¹H NMR (400 MHz, Chloroform-d) δ 8.24 (5, J=7.5 Hz, 1H), 8.24-8.12 (m, 3H), 7.94 (5, J=8.4 Hz, 1H), 7.68 (55, J=8.2, 3.5 Hz, 2H), 7.55 (t, J=7.9 Hz, 1H), 7.48 (t, J=7.3 Hz, 2H), 7.40 (5, J=7.7 Hz, 1H), 6.88 (s, 2H), 3.20 (t, J=7.4 Hz, 2H), 2.72 (s, 6H), 2.70 (5, J=7.1 Hz, 1H), 2.28 (p, J=7.2 Hz, 2H), 2.02 (s, 6H), 1.57 (s, 6H).

### Example 2.16 PC-16

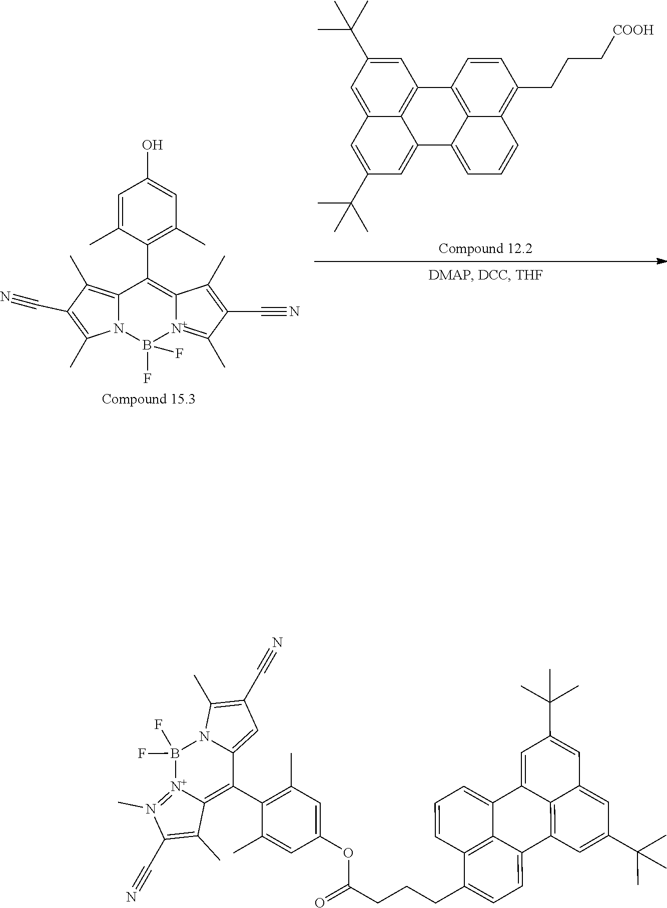

PC-16: Linder protection of a nitrogen gas atmosphere, 41.26 mg of DCC (0.2 mmol) was added to a solution containing 41.8 mg of compound 153, [5,5-difluoro-10-(4-hydroxy-2,6-dimethylphenyl)-1,3,7,9-tetramethyl-5H-4|4,5|4-dipyrrolo[1,2-c:2′,1′-f][1,3,2]diazaborinine-2,9-dicarbonitrile], (0.1 mmol) 59.8 mg of compound 12.2, (4-(8,11-di-tert-butylperylen-3-yl) butanoic acid), (0.132 mmol), 24.33 mg of DMAP (0.2 mmol) dissolved in 4.0 mL of THF anhydrous. The solution was stirred for 16 hrs. at room temperature. Water was added follow by 50 mL ethyl acetate. The solution was passed through Ce lite. The organic layer was separated and concentrated. The crude product was purified by silica gel column chromatography, using Hexanes:EtOAc as the eluent, resulting in 15 mg of a red orange solid product, yield 17%, LCMS(APCI+): calculated for C₅₅H₅₃F₂N₄O₂ (M+H)=850; found: 850. ¹H NMR (400 MHz, Chloroform-d) δ 8.24 (q, J=8.5, 7.1 Hz, 3H), 8.17 (5, J=7.8 Hz, 1H), 7.91 (5, J=8.4 Hz, 1H), 7.63 (5, J=2.2 Hz, 2H), 7.55 (t, J=7.9 Hz, 1H), 7.39 (5, J=7.8 Hz, 1H), 6.89 (s, 2H), 3.20 (t, J=7.4 Hz, 2H), 2.72 (s, 6H), 2.70 (t, J=7.4 Hz, 2H), 2.28 (h, J=7.4 Hz, 2H), 2.04 (s, 6H), 1.56 (s, 6H), 1.47 (s, 18H).

### Example 2.17 PC-17

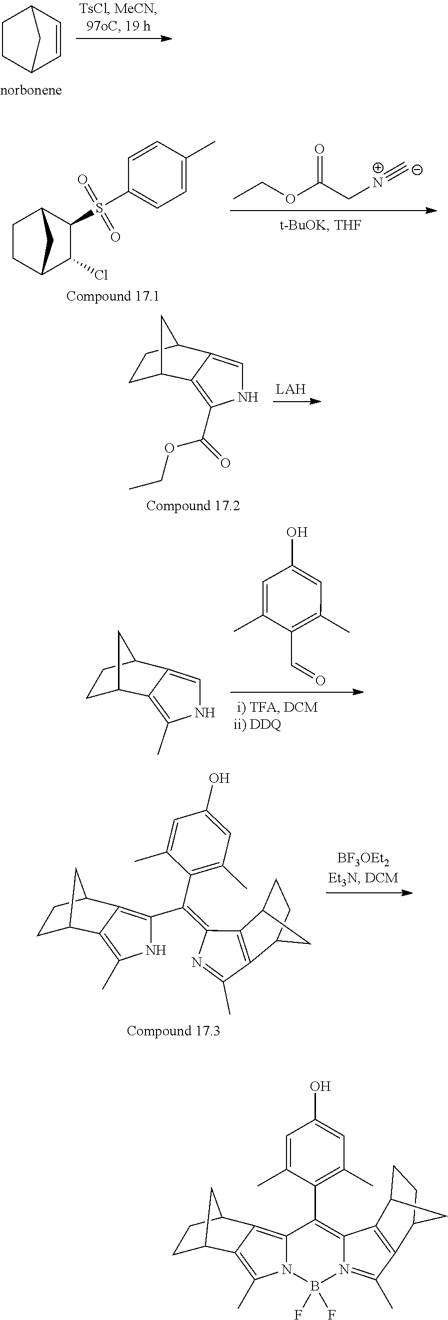

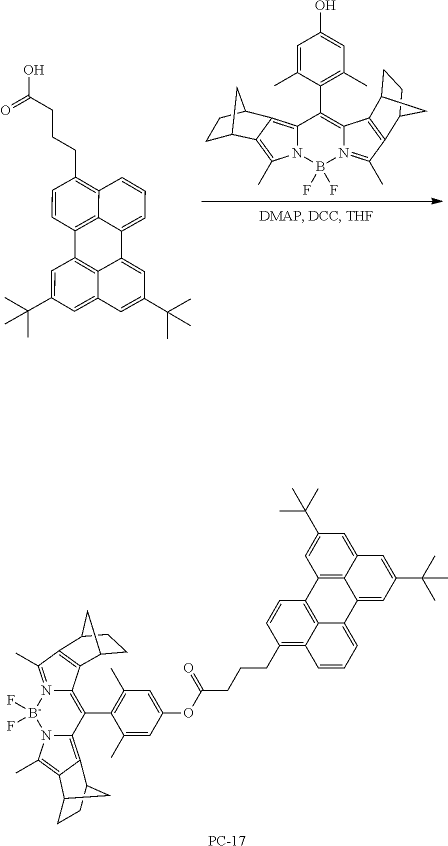

Compound 17.1 ((1R,2R,3R,4S)-2chloro-3-tosylbicyclo[2.2.1]heptane): Step 1: norbornene (34.368 g, 365.0 mmol), sodium 4-methylbenzenesulfinate (108 g, 606.0 mmol), water (400 ml), and DCM (400 ml) was added to a 3 L two neck round-bottomed flask with an oversized stir bar. While the mixture was stirring vigorously, iodine (92.7 g, 365 mmol) was added in portions, allowing the color to fade orange or yellow before adding more (6 portions total over 10 minutes). The two phases mixture was stirred overnight at RT while being protected from the light with aluminum foil. The next day 400 mL of DCM and 400 mL of saturated NaHCO₃ was added to the yellow emulsion and stirred vigorously for 10 minutes until distinct separate layers formed. The water layer was extracted twice with 150 mL of DCM. and the organic layers were combined, washed with 50 mL saturated aqueous NaHSO₃, adding enough water to get layer separation, then washed with 50 mL of brine. The combined organic layers were dried over Na₂SO₄, filtered, concentrated with rotavapor (water bath 60° C.) to give a waxy light yellow solid.

Step 2: To the waxy light-yellow product of step 1, 300 mL of toluene was added. The mixture was stirred and then heated in a H₂O bath until an iodo-sulfonate emulsion formed. The iodo-sulfonate emulsion was transferred to a two neck 3 L round bottomed flask. the slurry remaining in the previous flash was rinsed down with anhydrous toluene (total volume ^{˜}1 L). The suspension was cooled to 0° C., 54 mL (365 mmol) of DBU was added via syringe while vigorously stirring. The reaction was monitored by LCMS and TLC.

When the reaction was complete, the precipitate was filtered, washing with toluene. The filter cake was dissolved in DCM/ethyl acetate and then washed with 1N aqueous HCl. Next the organic layers were combined, dried over NaSO₄, filtered, and concentrated to dryness. The resulting solid was then re-dissolved into hot ethyl acetate, the hexanes were added. The resulting solution was cooled slowly to room temperature. The crystals were filtered off, washed with hexanes resulting in 63 g yellowish crystals with a yield of 88%. The crystals were of sufficient purity to use in the 1521-64 next step. LCMS (APCI+); calculated for C₁₄H₁₆O₂S (M+H)=249; found: 249

### Compound 17.2 ((4S,7R)-1-methyl-4,5,6,7-tetrahydro-2H-4,7-methanoisoindole)

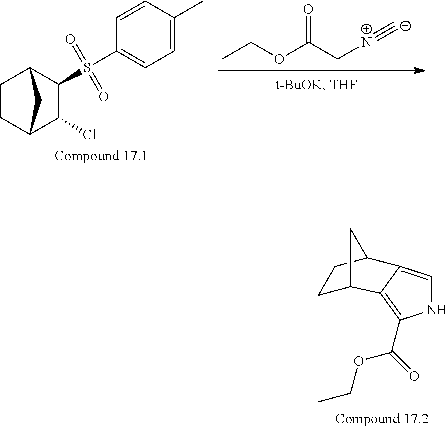

Step 1: Under protection of a nitrogen gas atmosphere, a solution containing NaH 60% dispersion in 2.45 g of (60.82 mmol) Paraffin Liquid was placed in 250 ml round bottle flash, 50 mL of THF anhydrous was added; the suspension was cooled to 0° C. A mixture of 6.04 g of compound 17.1 [2-tosylbicyclo[2.2.1]hept-2-ene] (24.32 mmol) and 6.87 g of ethyl-2-isocyanoacetate (60.82 mmol) in 50 mL of THF anhydrous was added dropwise to the suspension while maintaining a temperature of 0° C. The resulting mixture was stirred at further 1 hour while maintaining a temperature of 0° C. After stirring for 1 hour the cooling ice bath was removed and the mixture was stirred for an additional 16 hours at room temperature under the protection of a nitrogen gas atmosphere. After 16 hours, 2 mL of ethanol was added to quench the reaction. Once quenched, 250 mL of ethyl acetate was added to the mixture and the pH was adjusted to 5-4 with 3N HCl aqueous solution. The organic layer was separated, the water layer was re-extracted with 100 ml ethyl acetate and the resulting organic layer was separated. Organic layers were combined, washed with water, dried over MgSO4 and concentrated. Hexanes were added to the crude solid product to recrystallize to gain 4.75 g of ethyl (4S,7R)-4,5,6,7-tetrahydro-2H-4,7-methanoisoindole-1-carboxylate (100% yield) which was used next step without further purification. LCMS (APCI+); calculated for C₁₂H₁₅NO₂ (M+H)=206; found: 206; ¹H NMR (400 MHz, Chloroform-d) δ 8.33 (s, 1H), 6.52 (δ, J=2.3 Hz, 1H), 4.29 (q, J=7.1 Hz, 2H), 3.58 (s, 1H), 3.28 (s, 1H), 1.96-1.87 (m, 2H), 1.86 (δδ, J=12.5, 5.1 Hz, 2H), 1.35 (td, J=7.1, 1.5 Hz, 3H), 1.17 (dq, J=17.6, 10.0 Hz, 2H).

Step 2: A mixture of 0.734 g of ethyl (4S,7R)-4,5,6,7-tetrahydro-2H-4,7-methanoisoindole-1-carboxylate (4.991 mmol) in 15 mL of THF anhydrous was added cautiously to a stirred slurry mixture of 36.5 mL LAH 2M/THF (73.07 mmol) under the protection of an argon gas atmosphere while at 0° C. Next, the reaction mixture was stirred at refluxed for 2 hours. The reaction was quenched by adding cautiously MeOH at −15° C. then poured into ice water. pH was adjusted to 6-7; 250 mL of ethyl acetate was added, and the mixture was stirred for 30 minutes. The organic layer and water layer sat at room temperature overnight. The organic layer was separated and dried over MgSO4, concentrated to the volume of 10 mL; 50 mL hexanes was added. An off-white solid was collected by filtering with suction and washed with 40 mL hexanes, resulting in 1.71 g of a white solid. The white solid was used for the next step without further purification. LCMS (APCI+); calculated for C₁₀H₁₃N (M+H)=148; found: 148; ¹H NMR (400 MHz, Chloroform-d) δ 7.19-7.14 (m, 1H), 6.24 (s, 1H), 3.23 (s, 1H), 3.20 (s, 1H), 2.19 (8, J=1.5 Hz, 3H), 1.87-1.74 (m, 2H), 1.60 (8, J=8.5 Hz, 2H), 1.19 (dt, J=7.8, 2.1 Hz, 2H).

### Compound 17.3: 4-((1S,4R,10R,13S)-7,7-difluoro-5,9-dimethyl-1,3,4,7,10,11,12,13-octahydro-2H-6|4,7|4-1,4:10,13-dimethano[1,3,2]diazaborinino[4,3-a:6,1-a′]diisoindol-14-yl) phenol

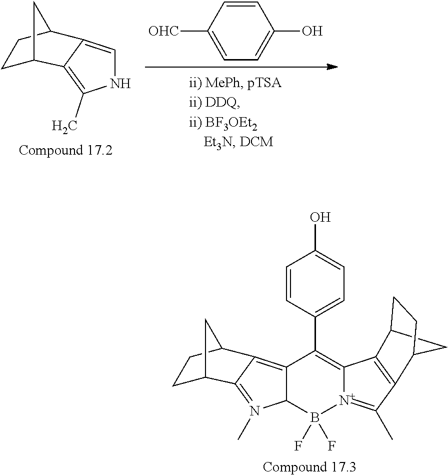

Step 1: A solution of 0.734 g of compound 1.7.2 [(4S,7R)-1-methyl-4,5,6,7-tetrahydro-2H-4,7-methanoisoindole]. (4.991 mmol), 019 g of 4-Hydroxybenzaldehyde (2.43 mmol) in 15 mL of anhydrous toluene, was purged with argon for 15 minutes. Once purged 2.0 mg (cat. amount) of pTSA was added following by 1 mL EtOH. The mixture was stirred at room temperature for 2 days. TLC and LCMS shown starting materials were consumed. The crude product was used in situ in the next step without further purification.

Step 2: 1.7 g DDQ (7.49 mmol) was added to above step. The resulting mixture was stirred at room temperature 2 hours. TLC and LCMS shown starting materials were consumed. The reaction mixture was filtered through Celite. The Celite was washed with 250 mL of DCM. AH the filtrates were combined and concentrated. The crude product was used next step without further purification.

Step 3: The above crude product was re-dissolved into DCM (50 mi), cooled to 0° C. then stirred with triethylamine (10.43 ml, 74.86 mmol) for 15 minutes and then 9.23 mL of BF₃ etherate (74.86 mmol) was added. The resulting reaction mixture was stirred at RT for 16 hours and then heated at 70° C. 1 hour and then cooled at room temperature. Next, 5.0 mL of an aqueous solution of 1N NaOH was added and the layers were separated. The aqueous layer was neutralized with 1N HCl then re-extracted with ethyl acetate. The combined organic layers were dried over MgSO₄ and the solvents were removed by rotavapor. The residue was chromatographed on a column of silica gel using CH₂Cl₂/EtOAc as eluent to afford the pure title product of 0.12 g of red orange solid (110% yield), LCMS (APCI+), calculated for Formula: C₂₇H₂₇BF₂N₂O; found: 445, ¹H NMR (400 MHz, Chloroform-d) δ 7.38 (s, 1H), 7.29-7.22 (m, 2H), 6.93 ( [symbol] , J=8.1 Hz, 2H), 3.19 (s, 1H), 3.18 (s, 1H), 2.53 (s, 6H), 2.49-1.78 (m, 4H), 1.73-1.64 (m, 4H), 1.43-1.32 (m, 4H).

### Compound PC-17:

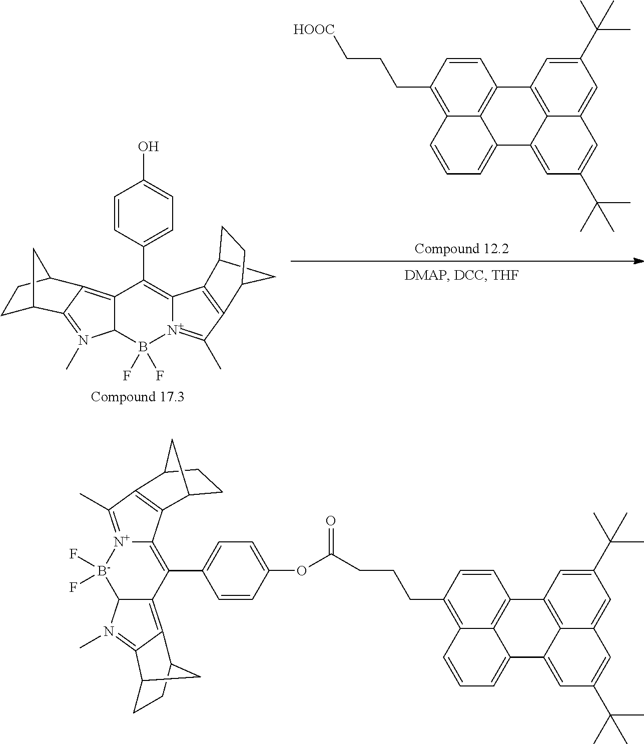

Under protection of a nitrogen gas atmosphere, a mixture of 29.9 mg of DCC (29.9 mg, 0.145 mmol) in THF anhydrous (0.5 ml) was added dropwise to a mixture of compound 17.3 [4-((1S,4R,10R,13S)-7,7-difluoro-5,9-dimethyl-1,3,4,7,10,11,12,13-octahydro-2H-6|4,7|4-1,4:10,13-dimethanol[1,3,2]diazaborinino[4,3-a:6,1-a′]diisoindol-14-yl)phenol], (54 mg, 0.121 mmol), compound 12.2 (4-(8,11-di-tert-butylperylen-3-yl) butanoic acid) (54.5 mg, 0.121 mmol), DMAP (47.5 mg, 0.392 mmol) in THF anhydrous (2.0 ml). The resulting mixture was stirred at RT for 16. Water was added follow by DCM (50 ml). The mixture was passed through Celite. The organic layer was separated, concentrated. The crude product was purified by silica gel column chromatography, the eluent was Hexanes:DCM to gain 70 mg red orange color solid product, yield 65%. LCMS (APCI-0: calculated for C₄₃H₄₇BF₂N₂O₂ (M+H)=877; found: 877, ¹H NMR (400 MHz, Chloroform-d) δ 8.27-8.23 (m, 3H), 8.19 (d, J=7.7 Hz, 1H), 7.93 (d, J=8.4 Hz, 1H), 7.63 (s, 1H), 7.62 (s, 1H), 7.54 (q, J=9.4, 8.7 Hz, 2H), 7.41 (δδ, J=8.1, 4.6 Hz, 2H), 7.21 (δ, J=7.6 Hz, 2H), 3.19 (δ, J=11.5 Hz, 4H), 2.75 (t, J=7.2 Hz, 2H), 2.53 (s, 6H), 2.43-2.41 (m, 2H), 2.29 (q, J=7.6 Hz, 2H), 1.8-1.7 (m, 2H), 1.48 (s, 18H), 1.39 (d, J=8.7 Hz, 2H), 1.26-1.06 (m, 4H).

### Example 2.18 PC-18

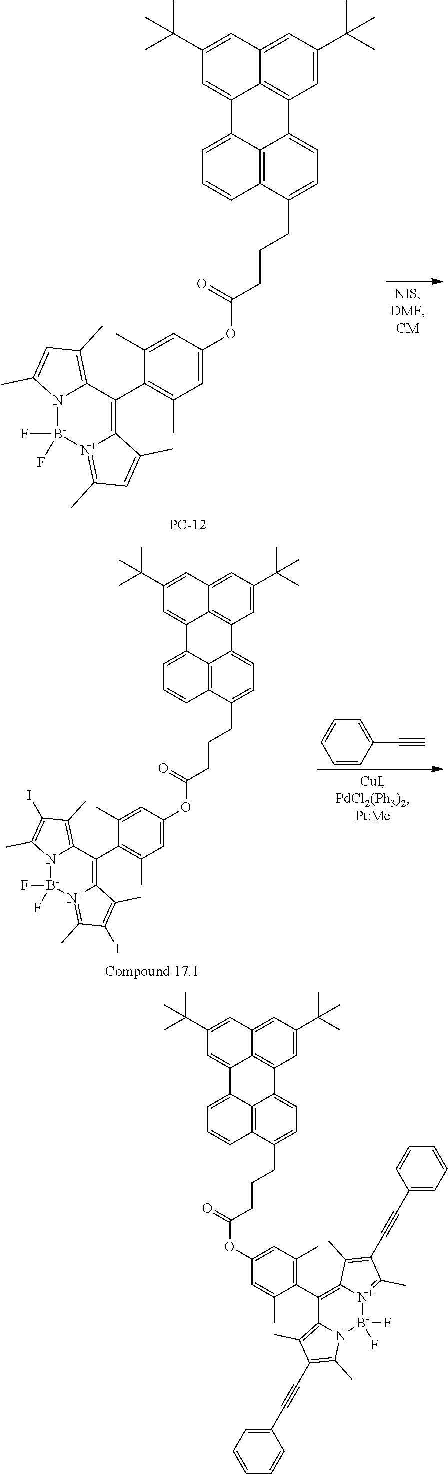

Compound 17.1 (4-(5,5-difluoro-2,8-diiodo-1,3,7,9-tetra methyl-5H-4|4,5|4-dipyrrolo[1,2-c:2′,1′-f][1,3,2]diazaborinin-10-yl)-3,5-dimethyl phenyl 4-(8,11-di-tert-butylperylen-3-yl)butanoate): Under protection of Nitrogen atmosphere, A solution mixture of 21.01 g of N-Iodosuccinimide (0.0993 mmol) in 1 mL DCM was added dropwise to a mixture of 37.4 g of PC-12 (0.046 mmol) in 3 mL of anhydrous DCM/DMF (1:1) (v/v) at RT over 15 minutes. The resulting mixture was stirred at RT for over 1 hour under an Argon atmosphere. The mixture was poured to 2 mL of water. The organic layer was separated while the water layer was re-extracted with 10 mL of ethyl acetate. Next, the organic layers were combined, dried MgSO₄, concentrated. The crude product was used next step without further purification. LCMS (APCI+): calculated for C₅₃H₅₃BF₂I₂N₂O₂ (M+H)=1053; found: 1053.

Compound PC-18 (4-(5,5-difluoro-1,3,7,9-tetramethyl-2,8-bis(phenylethynyl)-5H-4|4,5|4-dipyrrolo[1,2-c:2′,1′-f][1,3,2]diazaborinin-10-yl)-3,5-dimethyl phenyl 4-(8,11-di-tert-butylperylen-3-yl)butanoate): A mixture of 48.4 mg of Compound 17.1 (0.046 mmol), 1.75 mg of CuI (0.0092 mmol), and 2 mL of PdCl₂(PPh₃)₂ in Toluene anhydrous was bubbled with argon gas at room temperature for 15 minutes. 140.98 mg of Phenyl acetylene (1.38 mmol) was added followed by the addition of 1.6 mL of triethyl amine (11.5 mmol) to the mixture. Next, the resulting mixture was stirred at 35° C. for 2.5 hours. The mixture was diluted with 2.0 mL of water and then extracted into 10 mL of ethyl acetate. The organic layer was separated, dried MgSO₄, concentrated and purified by SiO₂ column chromatography, using hexanes: ethyl acetate (9:1) as the eluents. 5 mg of a deep red color solid product resulted with a yield of 10%. LCMS (APCI+): calculated for C₆₉H₆₃BF₂N₂O₂ (M+H)=1002; found: 1002.

### Example 2.19 PC-19

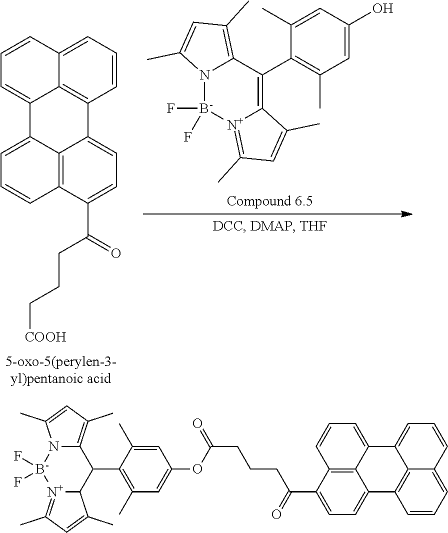

PC-19: Under protection of a Nitrogen atmosphere, a mixture of 87.07 mg DCC (0.422 mmol) dissolved in 1 mL of THF anhydrous was added dropwise to a mixture 77.7 mg of Compound 6.5 (0.211 mmol), 77.3 mg of 5-oxo-5-(perylen-3-yl) pentanoic acid (0.211 mmol) and 51.13 mg of DMAP (0.422 mmol) dissolved in 4.0 mL of THF anhydrous. The resulting mixture was stirred at RT for 16 hours. Next, 1 mL of water was added follow by 15 ml of DCM. The mixture was passed through Celite. The organic layer was separated and concentrated. The crude product was purified by silica gel column chromatography, using Hexanes:DCM as the eluents. 102 mg of a red orange color solid product resulted with a yield of 65%. LCMS (APCI+): calculated for C46H39BF2N2O3 (M+H)=717; found: 717. ¹H NMR (400 MHz, Chloroform-d) δ 8.60 (δ, J=8.5 Hz, 1H), 8.32-8.23 (m, 3H), 8.20 (d, J=8.0 Hz, 1H), 7.94 (d, J=8.0 Hz, 1H), 7.78 (δ, J=8.1 Hz, 1H), 7.73 (δ, J=8.1 Hz, 1H), 7.66-7.57 (m, 1H), 7.53 (t, J=7.8 Hz, 2H), 6.92 (s, 2H), 5.97 (s, 2H), 5.30 (s, 2H), 3.26 (t, J=7.1 Hz, 2H), 2.77 (t, J=7.2 Hz, 2H), 2.56 (s, 6H), 2.29 (p, J=7.1 Hz, 2H), 2.14 (s, 6H), 1.41 (s, 6H).

### Example 2.20 PC-20

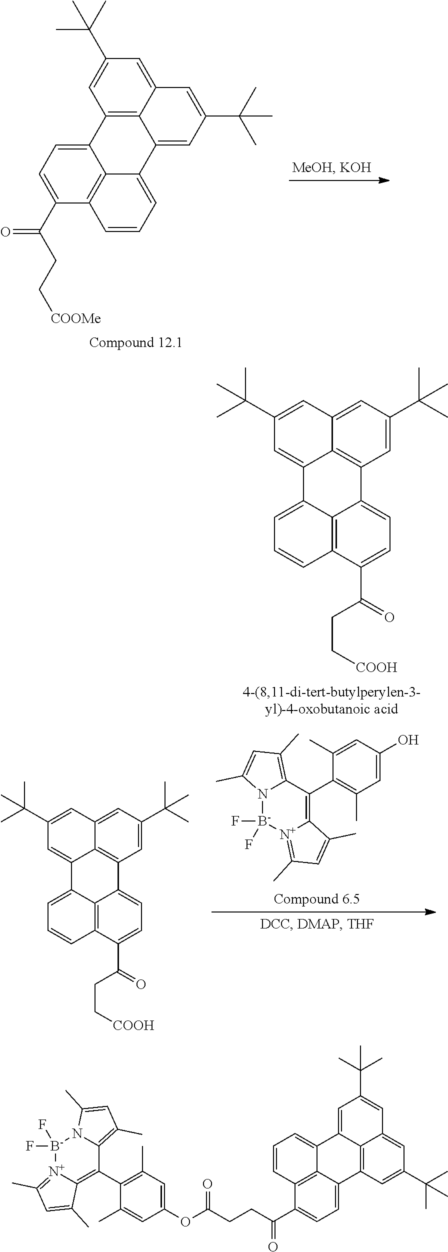

Compound 4-(8,11-di-tert-butylperylen-3-yl)-4-oxobutanoic acid: To a suspension mixture of 500 mg of Compound 12.1 50 mL of MeOH 0.5 g of KOH was added (8.93 mmol). The mixture was stirred at 65° C. for 3 hours. Next, the mixture was cooled to 0° C. and acidified with 15 mL of 2N HCl aqueous solution. The light brown solid was precipitated. The crude product was collected by filtering, and air dried yielding 490 mg. The product was used into next step without further purification. LCMS (APCI+): calculated for C₃₂H₃₂O₃ (M+H)=467; found: 467.

PC-20: Under protection of a nitrogen gas atmosphere, a mixture of 68.91 mg of DCC (0.334 mmol) in 1 mL of THF anhydrous was added dropwise to a mixture 61.49 mg of Compound 6.5 (0.167 mmol), 77.59 mg 4-(8,11-di-tert-butylperylen-3-yl)-4-oxobutanoic acid (0.167 mmol), and 40.47 mg DMAP (0.334 mmol) dissolved in 4 mL of THF anhydrous. The resulting mixture was stirred at RT for 16 hours. 1 mL of water was added follow by 15 mL of DCM. The mixture was passed through Celite. The organic layer was separated and concentrated. The crude product was purified by silica gel column chromatography, using Hexanes:DCM as the eluents. Resulting in 78 mg of red orange color solid product with a yield of 57%. LCMS (APCI+): calculated for C₅₂H₅₃BF₂N₂O₃ (M+H)=816; found: 816, ¹H NMR (400 MHz, Chloroform-d) δ 8.65 (d, J=8.5 Hz, 1H), 8.35-8.28 (m, 3H), 8.24 (8, J=8.0 Hz, 1H), 8.03 (δ, J=8.0 Hz, 1H), 7.74 (δ, J=1.7 Hz, 1H), 7.69 (δ, J=1.6 Hz, 1H), 7.62 (δδ, J=8.6, 7.6 Hz, 1H), 6.98 (s, 2H), 5.97 (s, 2H), 3.54 (t, J=6.3 Hz, 2H), 3.10 (t, J=6.3 Hz, 2H), 2.56 (s, 6H), 2.15 (s, 6H), 1.49 (d, J=3.1 Hz, 18H), 1.42 (s, 6H).

### Example 2.21 PC-21

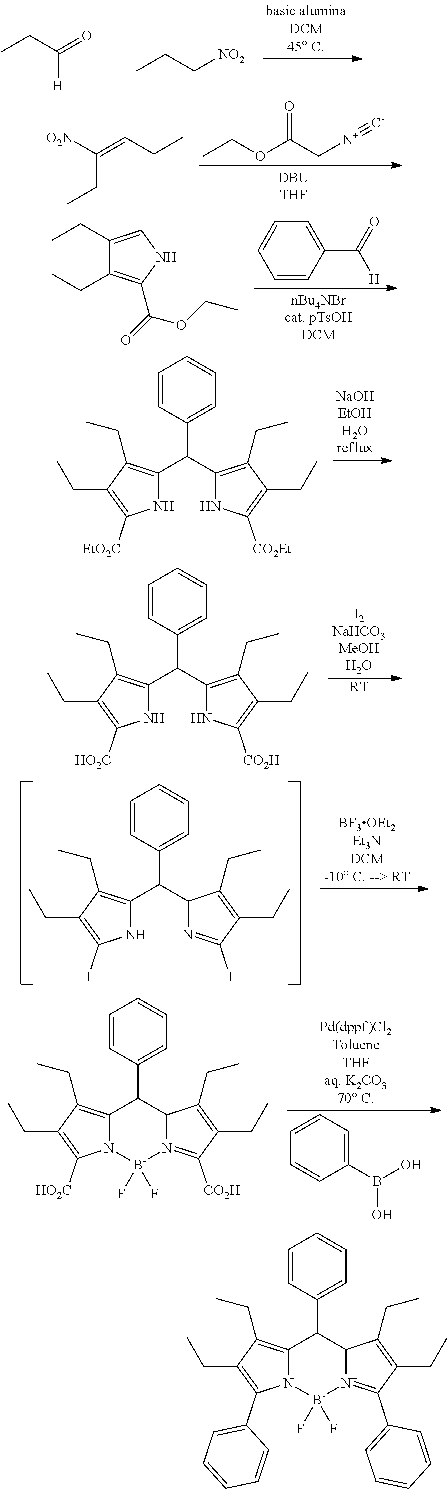

Compound 21.1 ((E)-3-nitrohex-3-ene): A 1 L round bottom flask was charged with a stir bar and flushed with argon. To this flask was added basic alumina (160 g), anhydrous dichloromethane (400 mL), propionaldehyde (400 mmol, 28.7 mL) and 1-nitropropane (400 mmol, 35.6 mL). The flask was fitted with a long, finned air-condenser and placed in an oil bath at 45° C. The mixture was stirred under argon atmosphere for 3 days, then cooled to room temperature. The reaction mixture was filtered, washing the filter cake with dichloromethane. The filtrate was concentrated by rotary evaporation to a yellow oil. This material was purified by flash chromatography on silica gel with 10% ethyl acetate/hexanes to give a yellow oil, 12.19 g (23.6% yield). ¹H NMR (400 MHz, Chloroform-d) δ 7.05 (t, J=7.9 Hz, 1H), 2.61 (q, J=7.4 Hz, 2H), 2.25 (p, J=7.7 Hz, 2H), 1.12 (td, J=7.5, 4.6 Hz, 6H).

Compound 21.2 (ethyl 3,4-diethyl-1H-pyrrole-2-carboxylate): A 250 mL round bottom flask was charged with a stir bar and flushed with argon. To this flask was added ethyl isocyanoacetate (38.7 mmol, 4.38 g) and (E)-3-nitrohex-3-ene (38.7 mmol, 5.00 g). Anhydrous THF was added via syringe (50 mL). then DBU (38.7 mmol, 5.8 mL) was added dropwise with stirring over 30 seconds (exothermic reaction occurs). The reaction was stirred overnight at room temperature. The reaction mixture was diluted with dichloromethane (200 mL) and partitioned with brine (200 mL). The layers were separated, the aqueous layer was extracted with dichloromethane (50 mL) and the combined organic layers were dried over MgSO₄. The filtrate was concentrated by rotary evaporation to give the crude product. This material was purified by flash chromatography on silica gel using an ethyl acetate/hexanes gradient (5%→30% over 10 CV). Gives 5.00 g, 66% yield. ¹H NMR (400 MHz, Chloroform-d) δ 8.73 (s, 1H), 6.67 (d, J=2.9 Hz, 1H), 4.31 (q, J=7.1 Hz, 2H), 2.75 (q, J=7.5 Hz, 2H), 2.45 (q, J=7.6 Hz, 2H), 1.35 (t, J=7.1 Hz, 3H), 1.19 (t, J=7.5 Hz, 3H), 1.14 (t, J=7.5 Hz, 3H).

Compound 21.3 (diethyl 5,5′-(phenylmethylene)bis(3,4-diethyl-1H-pyrrole-2-carboxylate)): A 500 mL round bottom flask was charged with a stir bar and flushed with argon. To this flask was added tetra-(n-butyl)ammonium bromide (0.858 mmol, 277 mg), p-toluenesulfonic acid monohydrate (6.13 mmol, 1166 mg), and Compound 21.2 (61.3 mmol, 11.96 g). Anhydrous dichloromethane was added (200 mL), followed by benzaldehyde (36.8 mmol, 3.7 mL). The flask was sealed and stirred under argon at room temperature overnight. The crude reaction mixture was partitioned with saturated aqueous sodium bicarbonate (100 mL). The layers were separated, the organic layer was dried over MgSO₄, filtered, and concentrated by rotary evaporation. The crude product was purified by flash chromatography using a dichloromethane/ethyl acetate gradient (1%→4%→10% to give 14.1 g (96% yield). MS (APCI) calculated for C₂₉H₃₈N₂O₄ (M−H)=477; found=477. ¹H NMR (400 MHz, Chloroform-d) δ 8.24 (s, 2H), 7.40-7.30 (m, 3H), 7.12 (d, J=7.0 Hz, 2H), 5.57 (s, 1H), 4.28 (q, J=7.1 Hz, 4H), 2.74 (q, J=7.4 Hz, 4H), 2.32 (q, J=7.5 Hz, 4H), 1.33 (t, J=7.1 Hz, 6H), 1.17 (t, J=7.4 Hz, 6H), 0.92 (t, J=7.5 Hz, 6H).

Compound 21.4 (1,2,8,9-tetraethyl-5,5-difluoro-3,7-diiodo-10-phenyl-5H-4|4,5|4-dipyrrolo[1,2-c:2′,1′-f][1,3,2]diazaborinine): A 1 L round bottom flask was charged with a stir bar. To this flask was added NaOH (6.00 g) and water (30 mL). The mixture was stirred to obtain a solution and the flask was flushed with argon. Compound 21.3 (29.4 mmol, 14.09 g) was added to the reaction flask, followed by ethanol (200 proof, 300 mL). The flask was fitted with a finned air condenser and heated in an oil bath at 90° C. under argon atmosphere. After heating overnight, the reaction mixture was cooled to room temperature and transferred to a 1 L Erlenmeyer flask. The pH was adjusted to 4 with 6N aqueous HCl solution with stirring in an ice-water bath. The mixture was diluted to a total volume of 1 L with water and the precipitate collected via suction filtration. The damp precipitate was placed in a 3 L 2 neck round bottom flask and the flask charged with a stir bar. The flask was flushed with argon. A solution of sodium bicarbonate (188.2 mmol, 15.81 g) was made in water (300 mL) and added to the reaction flask. Methanol (900 mL) was added with stirring to get a solution. To the flask was added iodine (58.8 mmol, 14.92 g) with vigorous stirring under an argon atmosphere. The reaction mixture was stirred overnight at room temperature. The precipitated intermediate was filtered off and washed with water. The product was dried by suction, then in a vacuum oven at 50° C. The dried precipitate was dissolved in anhydrous dichloromethane (500 mL) in an argon-flushed 1 L 2 neck round bottom flask charged with a stir bar. The flask was sealed with a septum and cooled to −10° C. (water-ice/methanol bath) under argon atmosphere. To this flask was added BF₃.OEt₂ (571.2 mmol, 70.5 mL) via syringe with vigorous stirring. The flask was fitted with a dropping funnel and anhydrous triethylamine (331.5 mmol, 46.2 mL) was placed in the dropping funnel. The triethylamine was added dropwise over 5 minutes with vigorous stirring. The cooling bath was removed, and the reaction mixture was stirred under argon atmosphere and allowed to warm to room temperature. The reaction was stirred overnight. The reaction was quenched by adding aqueous 1N HCl (200 mL). The layers were separated, and the organic layer was washed sequentially with aqueous 1N HCl (200 mL), saturated aqueous sodium bicarbonate (3×200 mL), and brine (200 mL). The organic layer was dried over MgSO₄, filtered, and concentrated by rotary evaporation. To this crude, purple-black liquid was added methanol. This mixture was concentrated to dryness on Celite, then purified by flash chromatography using a hexanes/toluene gradient (80% toluene/hexanes→100% toluene). Gives 640 mg (4.0% yield from Compound 1.3) of a reddish, somewhat metallic solid. MS (APCI) calculated for C₂₃H₂₅BF₂I₂N₂ (M−H)=631; found=631. ¹H NMR (400 MHz, Chloroform-d) δ 7.58-7.48 (m, 1H), 7.49-7.37 (m, 4H), 2.35 (q, J=7.7 Hz, 4H), 2.34 (q, J=7.5 Hz, 4H), 1.18 (t, J=7.5 Hz, 6H), 1.06 (t, J=7.5 Hz, 6H).

PC-21 (1,2,8,9-tetraethyl-5,5-difluoro-3,7,10-triphenyl-5H-4|4,5|4-dipyrrolo[1,2-c:2′,1′-f][1,3,2]diazaborinine): A 250 mL 2 neck round bottom flask was charged with a stir bar and fitted with a reflux condenser, and flushed with argon. To this flask was added compound 21.4 (1.01 mmol, 640 mg), Pd(dppf)Cl₂ (0.067 mmol, 49 mg), and phenylboronic acid (5.05 mmol, 616 mg). Inhibitor-free THF (20 mL) and toluene (20 mL) were added, followed by aqueous 1.0 M K₂CO₃ (5.05 mmol, 5.05 mL). The flask was purged of oxygen by vacuum/backfill argon cycles three times. The flask was heated in an oil bath at 70° C. for four hours. An additional portion of phenylboronic acid (5.05 mmol, 616 mg) and aqueous K₂CO₃ (5.05 mL) were added and the reaction heated at 70° C. for an additional 2 hours. The reaction mixture was cooled to room temperature and partitioned with ethyl acetate (150 mL). The mixture was washed with saturated aqueous sodium bicarbonate (3×25 mL) and brine (25 mL). The reaction mixture was dried over MgSO₄, filtered, and concentrated to dryness on a rotary evaporator. The crude product was purified by flash chromatography using an ethyl acetate/hexanes gradient (30% ethyl acetate/hexanes (1 CV)→100% ethyl acetate/hexanes (10 CV). The fractions containing product were concentrated in vacuo and triturated with methanol to remove a co-eluting impurity. Gives 159 mg (30% yield). MS (APCI) calculated for C₃₅H₃₅BF₂N₂ (M−H)=531; found=531. ¹H NMR (400 MHz, Chloroform-d) δ 7.58-7.40 (m, 9H), 7.39-7.29 (m, 6H), 2.17 (q, J=7.4 Hz, 4H), 1.66 (q, J=7.4 Hz, 4H), 0.80 (t, J=7.5 Hz, 6H), 0.73 (t, J=7.4 Hz, 6H).

### Example 2.22 PC-22

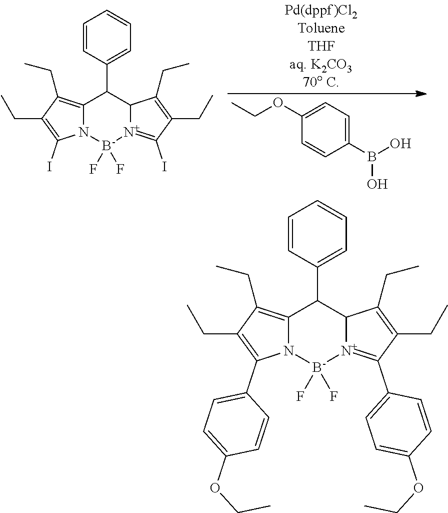

PC-22 (3,7-bis(4-ethoxyphenyl)-1,2,8,9-tetraethyl-5,5-difluoro-10-phenyl-5H-4|4,5|4-dipyrrolo[1,2-c:2′,1′-f][1,3,2]diazaborinine): This compound was synthesized from compound 21.4 in a manner similar to PC-21 using 4-ethoxyphenylboronic acid. MS (APCI) calculated for C₃₉H₄₃BF₂N₂O₂ (M−H)=619; found=619. ¹H NMR (400 MHz, Chloroform-d) δ 7.49-7.38 (m, 5H), 7.31 (d, J=8.7 Hz, 4H), 6.80 (d, J=8.7 Hz, 4H), 3.96 (q, J=7.0 Hz, 4H), 2.12 (q, J=7.5 Hz, 4H), 1.57 (q, J=7.4 Hz, 4H), 1.34 (t, J=7.0 Hz, 6H), 0.74 (t, J=7.5 Hz, 6H), 0.65 (t, J=7.4 Hz, 6H).

### Example 2.23 PC-23

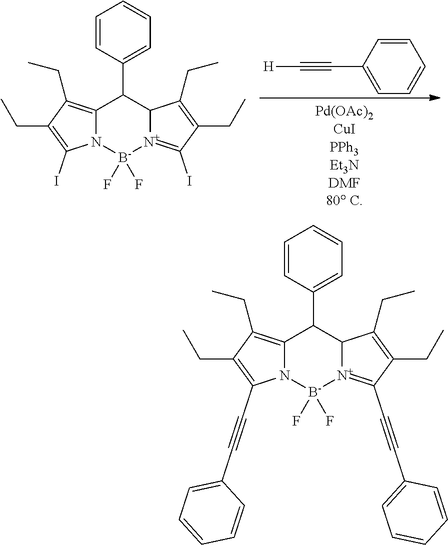

PC-23: Charged a 25 mL 2 neck round bottom flask with Compound 21.4 (0.286 mmol, 180 mg), CuI (0.014 mmol, 2.7 mg), Pd(OAc)₂ (0.014 mmol, 3.2 mg), triphenylphosphine (0.003 mmol, 7.5 mg), and a stir bar. The flask was flushed with argon. To this flask was added anhydrous triethylamine (1 mL) and anhydrous DMF (1 mL). The sealed flask was placed in an oil bath at 80° C. and stirred at this temperature overnight. The cooled reaction mixture was diluted with aqueous 1N HCl (50 mL) and extracted with ether (3×40 mL). The combined organic layers were washed with water (3×40 mL) and brine (40 mL), then dried over MgSO₄, filtered, and concentrated in vacuo. This material was purified by flash chromatography (toluene/hexanes gradient, 70% toluene/hexanes→100% toluene (3 CV)→100% toluene). Gives 69 mg (41% yield). MS (APCI) calculated for C₃₉H₃₅BF₂N₂ (M−H)=579; found=579. ¹H NMR (400 MHz, Chloroform-d) δ 7.73-7.66 (m, 4H), 7.55-7.42 (m, 5H), 7.41-7.36 (m, 6H), 2.50 (q, J=7.5 Hz, 4H), 1.62 (q, J=7.4 Hz, 4H), 1.20 (t, J=7.5 Hz, 6H), 0.69 (t, J=7.4 Hz, 6H).

### Example 2.24 PC-24

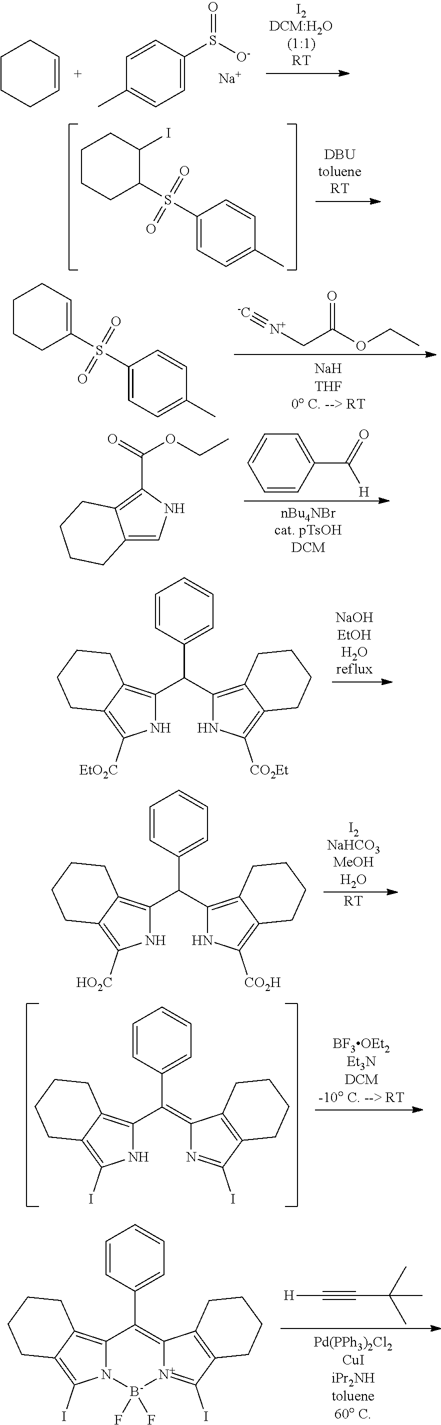

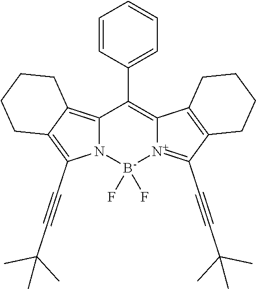 [SMILES: CC(C)(C)C#CC1=[N+]2C(=C(c3ccccc3)c3c4c(c(C#CC(C)(C)C)n3[B-]2(F)F)CCCC4)C2=C1CCCC2]

Compound 24.1 (1-((2-iodocyclohexyl)sulfonyl)-4-methylbenzene): A 500 mL round bottom flask was charged with a stir bar and dichloromethane (80 mL). To this flask was added cyclohexene (73.1 mmol, 7.4 mL), sodium p-toluenesulfonate (121.3 mmol, 21.62 g), and water (80 mL). The biphasic mixture was stirred very vigorously and iodine (73.1 mmol, 18.55 g) was added portions over 10 minutes, allowing the color to fade to yellowish before addition of the next portion. The mixture was stirred at room temperature for 4 hours. The reaction mixture was diluted with dichloromethane (80 mL). This mixture was partitioned with saturated aqueous sodium bicarbonate (100 mL) and the layers separated. The organic layer was washed with saturated aqueous sodium bisulfite (10 mL) and brine (10 mL). The organic layer was dried over MgSO₄, filtered, and concentrated in vacuo to give a colorless oil that darkens very rapidly. Used immediately in the next step.

Compound 24.2 (1-(cyclohex-1-en-1-ylsulfonyl)-4-methylbenzene): Compound 24.1 (73.1 mmol) from the previous step was diluted in anhydrous toluene (200 mL) in a 250 mL round bottom flask charged with a stir bar. To this flask was added DBU (73.1 mmol, 10.8 mL) over a period of 1 minute with vigorous stirring. A precipitate forms. After 30 minutes, the precipitate was filtered off, washing with toluene. The combined organic layers were extracted with aqueous 1N HCl (20 mL), water (20 mL), saturated aqueous sodium bicarbonate (40 mL), and brine (40 mL). The organic layer was dried over MgSO₄, filtered, and concentrated in vacuo. The crude product was pure enough for subsequent reactions. Gives 14.46 g (84% yield). ¹H NMR (400 MHz, Chloroform-d) δ 7.76 (d, J=8.3 Hz, 2H), 7.34 (d, J=8.0 Hz, 2H), 7.08-7.01 (m, 1H), 2.45 (s, 3H), 2.27 (dp, J=8.5, 3.0, 2.5 Hz, 2H), 2.18 (tq, J=6.3, 2.2 Hz, 2H), 1.73-1.62 (m, 2H), 1.62-1.54 (m, 4H).

Compound 24.3 (ethyl 4,5,6,7-tetrahydro-2H-isoindole-1-carboxylate): A 1 L 2 neck round bottom flask was fitted with an addition funnel and charged with a stir bar. The flask was flushed thoroughly with argon, then sodium hydride (95%, 153 mmol, 3.672 g) was to the flask, followed by anhydrous THF (125 mL). A solution of Compound 24.2 (61.2 mmol, 14.46 g) and ethyl isocyanoacetate (153 mmol, 16.7 mL) in anhydrous THF (125 mL) was added to the addition funnel. The reaction flask was placed in an ice-water bath and the solution was added dropwise with vigorous stirring over 15 minutes. The reaction mixture was stirred at 0° C. for 2 hours, then the cooling bath was removed. The reaction mixture was stirred under argon for 80 hours, then the reaction was quenched by the addition of methanol (30 mL). Saturated aqueous sodium bicarbonate (30 mL) was added and the volatiles were removed on a rotary evaporator. The residue was partitioned with ethyl acetate (125 mL), brine (30 mL) and water (100 mL). The layers were separated. The aqueous layer was extracted with dichloromethane (50 mL) and the combined organic layers were washed with brine (50 mL). The organic layers were dried over MgSO₄, filtered, and concentrated in vacuo. The crude product was purified by flash chromatography using an ethyl acetate/hexanes gradient (15% ethyl acetate/hexanes (1 CV)→30% ethyl acetate/hexanes (10 CV)). Gives a waxy white solid, 7.76 g (66% yield). ¹H NMR (400 MHz, Chloroform-d) δ 8.75 (s, 1H), 6.64 (d, J=2.9 Hz, 1H), 4.29 (q, J=7.1 Hz, 2H), 2.81 (t, J=6.0 Hz, 2H), 2.54 (t, J=5.8 Hz, 2H), 1.80-1.67 (m, 4H), 1.34 (t, J=7.1 Hz, 3H).

Compound 24.4 (diethyl 3,3′-(phenylmethylene)bis(4,5,6,7-tetrahydro-2H-isoindole-1-carboxylate)): Using a similar procedure to Compound 21.3 on Compound 24.3 (40.2 mmol, 7.76 g), the product was isolated after flash chromatography, 9.30 g (98% yield). MS (APCI) calculated for C₂₉H₃₄N₂O₄ (M−H)=473; found=473. ¹H NMR (400 MHz, Chloroform-d) δ 7.37-7.27 (m, 3H), 7.11 (d, J=6.9 Hz, 2H), 5.39 (s, 1H), 4.24 (q, J=7.1 Hz, 4H), 2.79 (t, J=6.1 Hz, 4H), 2.25-2.10 (m, 4H), 1.77-1.61 (m, 8H), 1.31 (t, J=7.1 Hz, 6H).

Compound 24.5 (7,7-difluoro-5,9-diiodo-14-phenyl-1,3,4,7,10,11,12,13-octahydro-2H-6|4,7|4-[1,3,2]diazaborinino[4,3-a:6,1-a′]diisoindole): Using a similar procedure to ethyl (E)-3-(4,4,5,5-tetramethyl-1,3,2-dioxaborolan-2-yl)acrylate on Compound 24.4 (15.4 mmol, 7.30 g). Gives 2.12 g (22% yield). MS (APCI) calculated for C₂₃H₂₁BF₂I₂N₂ (M−H)=627; found=627. ¹H NMR (400 MHz, Chloroform-d) δ 7.49 (dd, J=5.0, 2.0 Hz, 3H), 7.29-7.21 (m, 2H), 2.30 (t, J=6.3 Hz, 4H), 1.65-1.50 (m, 8H), 1.46-1.33 (m, 4H).

PC-24 (5,9-bis(3,3-dimethylbut-1-yn-1-yl)-7,7-difluoro-14-phenyl-1,3,4,7,10,11,12,13-octahydro-2H-6|4,7|4-[1,3,2]diazaborinino[4,3-a:6,1-a′]diisoindole): Compound 24.5 (0.200 mmol, 126 mg), Pd(PPh₃)₂Cl₂ (0.020 mmol, 14.0 mg), CuI (0.060 mmol, 11.4 mg), and a stir bar were charged into a vial. To this vial was added diisopropylamine (2 mL) and toluene (2 mL). The vial was sealed with a septum and purged of oxygen by vacuum/backfill argon cycles (three times). The vial was heated at 60° C. for 1 minute, then t-butylacetylene (6.00 mmol, 736 uL) was added via syringe. The reaction was heated at 60° C. overnight. Workup and purification similar to Compound 3 gave 81 mg of product (75% yield). MS (APCI) calculated for C₃₅H₃₉BF₂N₂ (M−H)=535; found=535. ¹H NMR (400 MHz, Chloroform-d) δ 7.49-7.40 (m, 3H), 7.25-7.17 (m, 2H), 2.40 (t, J=6.3 Hz, 4H), 1.66-1.48 (m, 8H), 1.45-1.31 (m, 22H).

### Example 2.25 PC-25

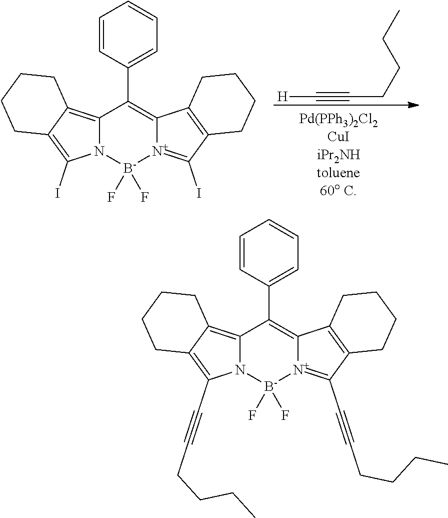

PC-25 (7,7-difluoro-5,9-di(hex-1-yn-1-yl)-14-phenyl-1,3,4,7,10,11,12,13-octahydro-2H-6|4,7|4-[1,3,2]diazaborinino[4,3-a:6,1-a′]diisoindole): PC-25 was synthesized from Compound 24.5 (0.200 mmol, 126 mg) and 1-hexyne in a similar manner to PC-24 to give 43 mg (40% yield). MS (APCI) calculated for C₃₅H₃₉BF₂N₂ (M−H)=535; found=535. ¹H NMR (400 MHz, THF-d₈) δ 7.42-7.35 (m, 3H), 7.24-7.17 (m, 2H), 2.47 (t, J=6.8 Hz, 4H), 2.33-2.25 (m, 4H), 1.59-1.40 (m, 16H), 1.34-1.23 (m, 4H), 0.86 (t, J=7.2 Hz, 6H).

### Example 2.26 PC-26

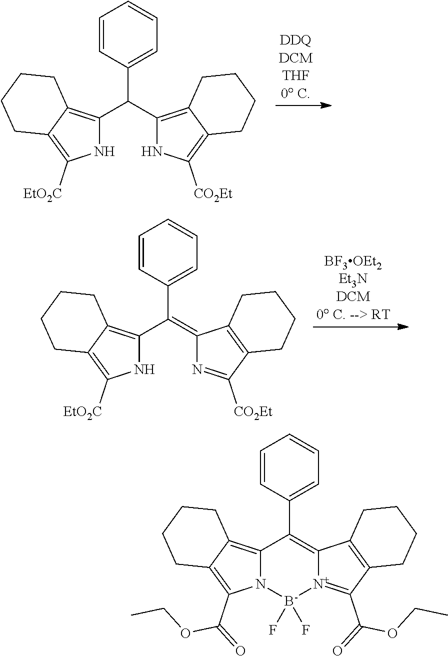

PC-26 (diethyl 7,7-difluoro-14-phenyl-1,3,4,7,10,11,12,13-octahydro-2H-6|4,7|4-[1,3,2]diazaborinino[4,3-a:6,4-a′]diisoindole-5,9-dicarboxylate): A 1 L 3-neck round bottom flask was charged with a stir bar and flushed with argon. To this flask was added Compound 24.4 (19.00 mmol, 9.00 g) and anhydrous dichloromethane (380 mL). The flask was fitted with an addition funnel. The addition funnel was charged with DDQ (22.8 mmol, 5.176 g) and anhydrous THF (380 mL). The reaction flask was cooled in an ice-water bath and the solution of DDQ was added dropwise over a period of 20 minutes with vigorous stirring. Once LCMS indicated full oxidation, anhydrous triethylamine (114 mmol, 15.9 mL) was added via syringe at 0° C. with stirring, followed by BF₃.OEt₂ (190 mmol, 23.5 mL). The mixture was stirred and allowed to warm slowly to room temperature over 2 hours. The water bath was removed, and the addition funnel was removed and replaced with a finned air condenser. The reaction was heated in an oil bath at 40° C. overnight. After 16 hours, the temperature of the oil bath was raised to 50° C. for 24 hours, then 60° C. for 10 hours. The reaction mixture was stirred at room temperature for a further 72 hours. The volatiles were removed by rotary evaporation and the residue was dissolved in ethyl acetate (600 mL). The organic layer was washed with aqueous 2N HCl (2×300 mL) and brine (100 mL). The organic layer was dried over MgSO₄, filtered, and evaporated in vacuo. The crude product was purified by flash chromatography using an ethyl acetate/hexanes gradient (20% ethyl acetate/hexanes (1 CV)→60% ethyl acetate/hexanes (5 CV)). The product fractions were collected and evaporated to dryness. This material was triturated with 1:1 DCM:hexanes (300 mL) and a white solid removed by filtration. The DCM was boiled off and the solid product collected by filtration. Gives 5.978 g (61% yield). MS (APCI) calculated for C₂₉H₃₁BF₂N₂O₄ (M−H)=519; found=519. ¹H NMR (400 MHz, Chloroform-d) δ 7.55-7.49 (m, 3H), 7.25-7.20 (m, 2H), 4.44 (q, J=7.1 Hz, 4H), 2.57 (t, J=6.3 Hz, 4H), 1.70-1.48 (m, 8H), 1.47-1.34 (m, 10H).

### Example 2.27 PC-27

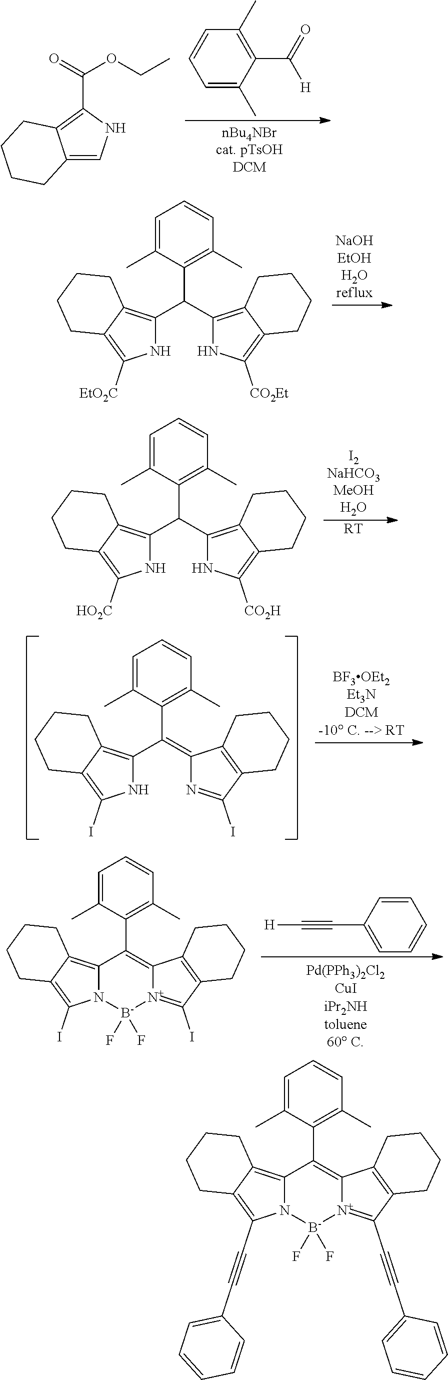

Compound 27.1 (Diethyl 3,3′-((2,6-dimethylphenyl)methylene)bis(4,5,6,7-tetrahydro-2H-isoindole-1-carboxylate)): Compound 24.3 (30.0 mmol, 5.798 g) was reacted with 2,6-dimethylbenzaldehyde (18.0 mmol, 2.41 mL) in a manner similar to that of Compound 24.4 except the reaction was heated to 40° C. until the reaction was complete. After purification by flash chromatography on silica gel, the product was isolated 6.978 g, 93% yield. MS (APCI) calculated for C₃₁H₃₈N₂O₄ (M−H)=501; found=501. ¹H NMR (400 MHz, Chloroform-d) δ 8.26 (s, 2H), 7.16-7.08 (m, 1H), 7.04 (d, J=7.5 Hz, 2H), 5.73 (s, 1H), 4.31-4.19 (m, 4H), 2.79 (t, J=5.8 Hz, 4H), 2.23-2.11 (m, 2H), 2.04 (s, 6H), 2.01-1.86 (m, 2H), 1.80-1.58 (m, 8H), 1.32 (t, J=7.1 Hz, 6H).

Compound 27.2 (14-(2,6-Dimethylphenyl)-7,7-difluoro-5,9-diiodo-1,3,4,7,10,11,12,13-octahydro-2H-6|4,7|4-[1,3,2]diazaborinino[4,3-a:6,1-a′]diisoindole): Compound 27.2 was synthesized in a manner similar to Compound 24.4. From Compound 27.1 (9.34 mmol, 4.17 g) to give 2.45 g (40% yield) after several steps and purification by flash chromatography on silica gel. MS (APCI) calculated for C₂₅H₂₅BF₂I₂N₂ (M−H)=655; found=655. ¹H NMR (400 MHz, Chloroform-d) δ 7.31-7.22 (m, 1H), 7.12 (d, J=7.5 Hz, 2H), 2.31 (t, J=6.3 Hz, 4H), 1.65-1.56 (m, 4H), 1.52-1.46 (m, 4H), 1.46-1.37 (m, 4H).

PC-27 (14-(2,6-Dimethylphenyl)-7,7-difluoro-5,9-bis(phenylethynyl)-1,3,4,7,10,11,12,13-octahydro-2H-6|4,7|4-[1,3,2]diazaborinino[4,3-a:6,1-a′]diisoindole): PC-27 was synthesized from Compound 27.2 (0.200 mmol, 131 mg) in a manner similar to Compound 25 using triethylamine (3 mL) and toluene (3 mL) as solvents at 60° C. to give 48 mg (40% yield) after flash chromatography. MS (APCI) calculated for C₄₁H₃₅BF₂N₂ (M−H)=603; found=603. ¹H NMR (400 MHz, Chloroform-d) δ 7.71-7.64 (m, 1H), 7.41-7.34 (m, 2H), 7.30-7.23 (m, 1H), 7.21-7.10 (m, 4H), 2.55 (t, J=6.2 Hz, 4H), 2.15 (s, 6H), 1.68-1.59 (m, 4H), 1.59-1.52 (m, 4H), 1.51-1.43 (m, 4H).

### Example 2.28 PC-28

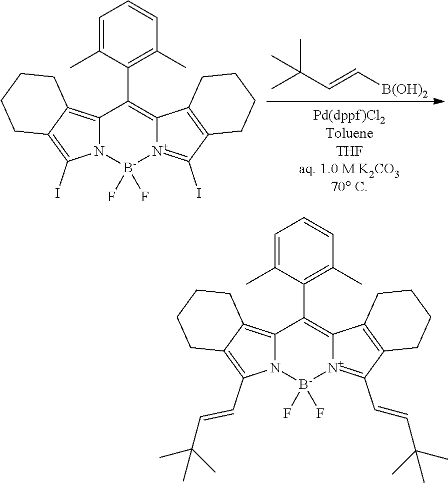

PC-28 (5,9-bis((E)-3,3-dimethylbut-1-en-1-yl)-14-(2,6-dimethylphenyl)-7,7-difluoro-1,3,4,7,10,11,12,13-octahydro-2H-6|4,7|4-[1,3,2]diazaborinino[4,3-a:6,1-a′]diisoindole): PC-28 was synthesized from Compound 27.2 (0.200 mmol, 131 mg) and (E)-(3,3-dimethylbut-1-en-1-yl)boronic acid ((1.00 mmol, 128 mg) in a manner similar to Compound 21 to give 54 mg (47% yield). MS (APCI) calculated for C₃₇H₄₇BF₂N₂ (M−H)=567; found=567. ¹H NMR (400 MHz, Chloroform-d) δ 7.26-7.15 (m, 1H), 7.12-7.01 (m, 4H), 6.41 (d, J=16.7 Hz, 2H), 2.55 (t, J=6.2 Hz, 4H), 2.12 (s, 6H), 1.66-1.55 (m, 4H), 1.55-1.48 (m, 4H), 1.47-1.37 (m, 4H), 1.18 (s, 18H).

### Example 2.29 PC-29

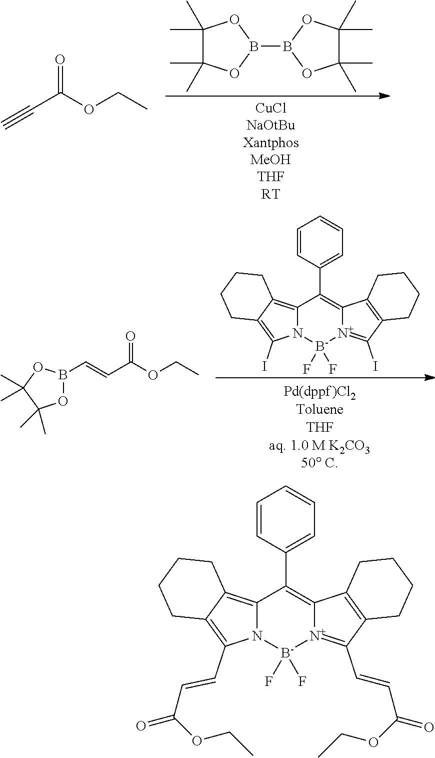

Compound 29.1 (ethyl (E)-3-(4,4,5,5-tetramethyl-1,3,2-dioxaborolan-2-yl)acrylate): An oven-dried 250 mL 2-neck round bottom flask and stir bar were cooled to room temperature under argon. To this flask was added anhydrous THF (30 mL), followed by CuCl (1.8 mmol, 178 mg), NaOtBu (3.6 mmol, 346 mg), and xantphos (1.8 mmol, 1.042 g). The reaction was stirred at room temperature for 3 hours, then 4,4,4′,4′,5,5,5′,5′-octamethyl-2,2′-bi(1,3,2-dioxaborolane) (66.0 mmol, 16.757 g) was added, followed by an additional aliquot of anhydrous THF (30 mL). The reaction mixture was stirred for 15 minutes at room temperature, then ethyl propiolate (60.0 mmol, 6.0 mL) was added, followed by anhydrous methanol (120 mmol, 4.85 mL). Stirring was continued under argon at room temperature. The reaction was monitored by ¹H NMR (loss of alkyne C—H), approximately 24 hours. The reaction mixture was filtered to remove insoluble material. The filtrate was concentrated in vacuo to give an oil which was purified by flash chromatography (ethyl acetate/hexanes gradient, 100% hexanes (1 CV)→40% ethyl acetate/hexanes (5 CV)→70% ethyl acetate/hexanes (2 CV). Fractions containing product were collected and concentrated in vacuo to give a light yellowish oil, 10.557 g (80% yield). ¹H NMR (400 MHz, Chloroform-d) δ 6.77 (d, J=18.2 Hz, 1H), 6.63 (d, J=18.2 Hz, 1H), 4.21 (q, J=7.1 Hz, 2H), 1.32-1.25 (m, 15H).

PC-29 (diethyl 3,3′-(7,7-difluoro-14-phenyl-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-29 was synthesized from Compound 24.5 (0.200 mmol, 131 mg) and Compound 29.1 (1000 μmol, 226 mg) in a manner similar to PC-28 at 50° C. to give 99 mg (87% yield). MS (APCI) calculated for C₃₃H₃₅BF₂N₂O₄ (M−H)=571; found=571. ¹H NMR (400 MHz, Chloroform-d) δ 8.21 (d, J=16.4 Hz, 2H), 7.59-7.42 (m, 3H), 7.30-7.22 (m, 2H), 6.48 (d, J=16.4 Hz, 2H), 4.31 (q, J=7.1 Hz, 4H), 2.59 (t, J=6.3 Hz, 4H), 1.72-1.57 (m, 8H), 1.47-1.40 (m, 4H), 1.37 (t, J=7.1 Hz, 6H).

### Example 2.30 PC-30

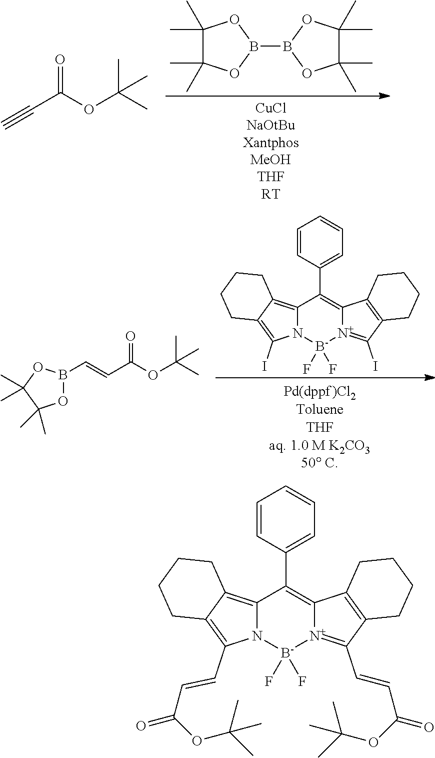

Compound 30.1 (tert-butyl (E)-3-(4,4,5,5-tetramethyl-1,3,2-dioxaborolan-2-yl)acrylate): Compound 30.1 was synthesized from tert-butylpropiolate (30.0 mmol, 4.12) mL in a manner similar to Compound 29.1 to give 4.547 g (60% yield) as a waxy white solid. ¹H NMR (400 MHz, Chloroform-d) δ 6.68 (d, J=18.2 Hz, 1H), 6.57 (d, J=18.2 Hz, 1H), 1.48 (s, 9H), 1.28 (s, 12H).

PC-30 (di-tert-butyl 3,3′-(7,7-difluoro-14-phenyl-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-30 was synthesized in a manner similar to Compound 29 from Compound 24.5 (0.167 mmol, 105 mg) and Compound 30.1 (0.418 mmol, 106 mg) at 50° C. to give 61 mg (58% yield). MS (APCI) calculated for C₃₇H₄₃BF₂N₂O₄ (M−H)=627; found=627. ¹H NMR (400 MHz, Chloroform-d) δ 8.13 (d, J=16.4 Hz, 2H), 7.56-7.46 (m, 3H), 7.32-7.21 (m, 2H), 6.40 (d, J=16.4 Hz, 2H), 2.58 (t, J=6.3 Hz, 4H), 1.69-1.57 (m, 8H), 1.55 (s, 18H), 1.47-1.34 (m, 4H).

### Example 2.31 PC-31

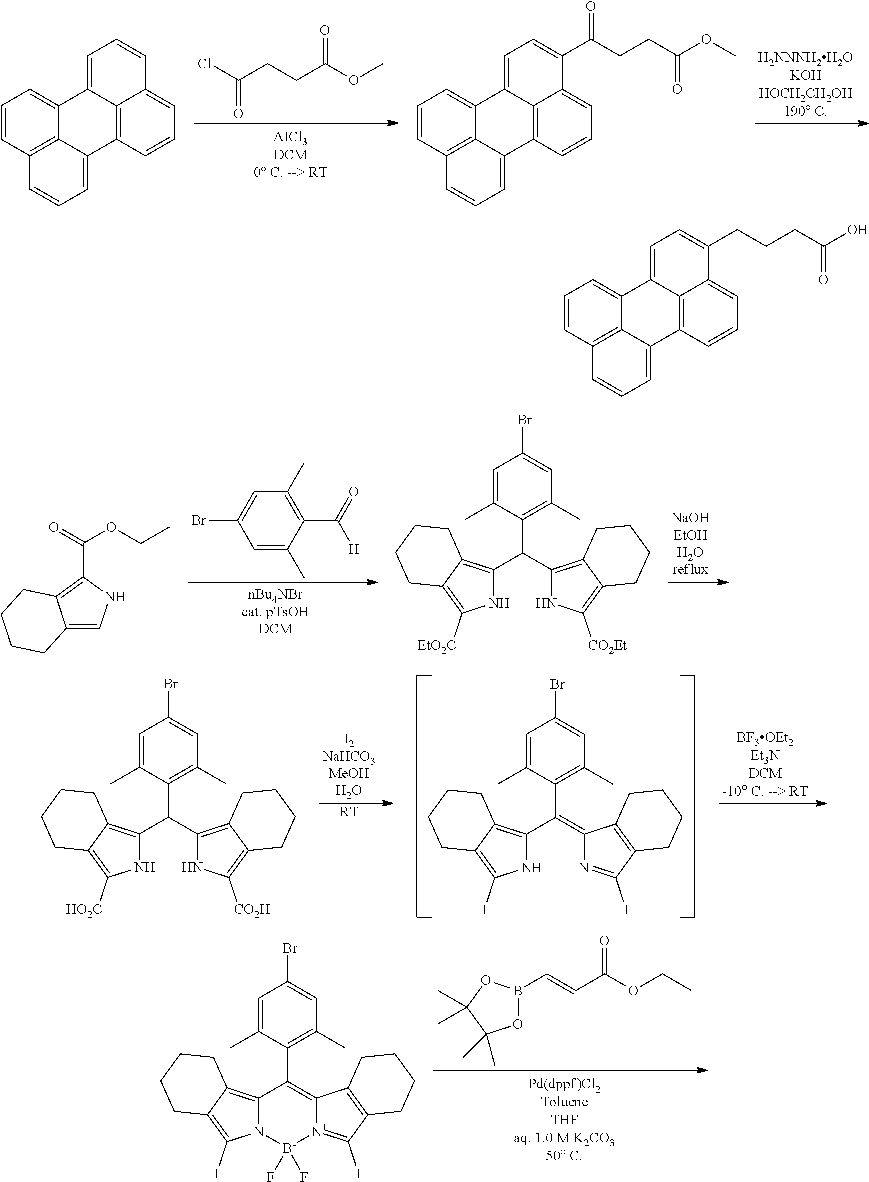

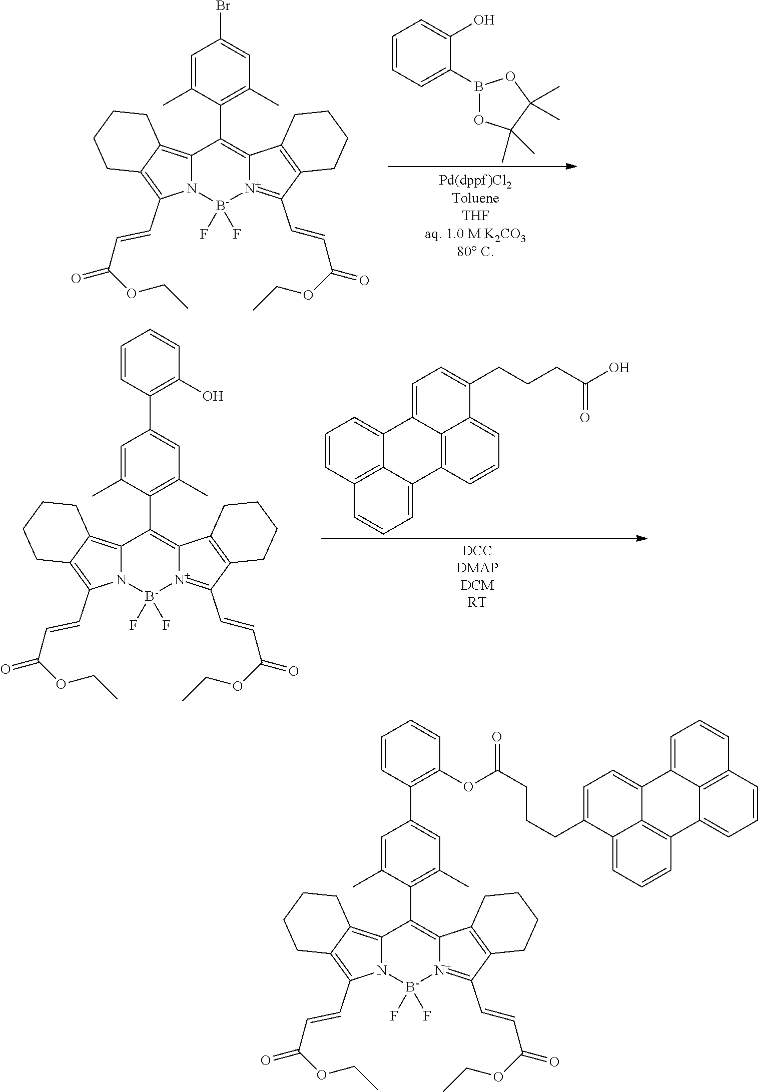

Compound 31.1 (methyl 4-oxo-4-(perylen-3-yl) butanoate): A solution of methyl 4-chloro-4-oxobutanoate (8.45 mmol, 1.04 mL) in anhydrous dichloromethane (160 mL) was cooled to 0° C. under nitrogen. This solution was treated with AlCl₃ (10.00 mmol, 1.34 g) in small portions via a powder dispersion funnel over 15 minutes. This solution was stirred at 0° C. for 1 hour, then a solution of perylene (7.9 mmol, 2.00 g) in anhydrous DCM was added to the reaction mixture dropwise with stirring at 0° C. The resulting dark purple solution was stirred at room temperature for 24 hours under nitrogen. The reaction mixture was added to a mixture of ice-cold water (75 mL), aqueous 6N HCl (5 mL), and dichloromethane (150 mL). The layers were separated, and the aqueous layer was extracted with ethyl acetate (100 mL). The combined organic layers were dried over MgSO₄, filtered, and concentrated in vacuo. The product was purified by flash chromatography using dichloromethane eluent to give 1.8 g of an orange solid (62% yield). MS (APCI): calculated for C₂₆H₁₉O₃ (M+H)=367; found: 367.

Compound 31.2 (4-(perylen-3-yl) butanoic acid): To a solution of Compound 31.1 (9.28 mmol, 3.4 g) in ethylene glycol (30 mL) in a pressure bottle was added 98% hydrazine hydrate (53 mmol, 2.7 mL). To this mixture was added powdered KOH (69.8 mmol, 3.91 g). The resulting mixture was stirred at 80° C. for 15 minutes, then heated to 140° C. and sparged with argon via a slow bubbling for 2 hours. The argon atmosphere was maintained with a balloon and the reaction was heated at 190° C. for 16 hours. The reaction mixture was cooled to room temperature and diluted with water. The reaction mixture was filtered through Celite and the filtrate acidified with aqueous 6N HCl. The green solid was collected by filtration and washed with water. The resulting solid was dried in a vacuum oven to give 3.0 g (95% yield). MS (APCI): calculated for C₂₆H₁₉O₃(M+H)=339; found: 339. ¹H NMR (400 MHz, DMSO-d₆) δ 12.03 (s, 1H), 8.38 (d, J=7.6 Hz, 1H), 8.35 (d, J=7.5 Hz, 1H), 8.32 (d, J=7.6 Hz, 1H), 8.29 (d, J=7.8 Hz, 1H), 7.99 (d, J=8.4 Hz, 1H), 7.77 (t, J=7.4 Hz, 2H), 7.59 (t, J=7.9 Hz, 1H), 7.54 (t, J=7.8 Hz, 1H), 7.53 (t, J=7.8 Hz, 1H), 7.40 (d, J=7.7 Hz, 1H), 3.02 (t, J=7.6 Hz, 2H), 2.37 (t, J=7.2 Hz, 2H), 1.91 (d, J=7.3 Hz, 2H).

Compound 31.3 (diethyl 3,3′-((4-bromo-2,6-dimethylphenyl)methylene)bis(4,5,6,7-tetrahydro-2H-isoindole-1-carboxylate)): Compound 31.3 was synthesized from Compound 24.3 (13.36 mmol, 2.582 g) and 4-bromo-2,6-dimethylbenzaldehyde (8.02 mmol, 1.708 g) in a manner similar to the synthesis of Compound 24.4 with extended reflux at 50° C. to drive the reaction to completion. After purification by flash chromatography on silica gel, gives 3.63 g (94% yield). MS (APCI) calculated for C₃₁H₃₂BrN₂O₄ (M−H)=579; found=579. ¹H NMR (400 MHz, Methylene Chloride-d₂) δ 8.33 (s, 2H), 7.23 (s, 2H), 5.70 (s, 1H), 4.27-4.12 (m, 4H), 2.85-2.69 (m, 4H), 2.22-2.07 (m, 2H), 2.02 (s, 6H), 2.01-1.88 (m, 2H), 1.82-1.57 (m, 8H), 1.29 (t, J=7.1 Hz, 6H).

Compound 31.4 (14-(4-bromo-2,6-dimethylphenyl)-7,7-difluoro-5,9-diiodo-1,3,4,7,10,11,12,13-octahydro-2H-6|4,7|4-[1,3,2]diazaborinino[4,3-a:6,1-a′]diisoindole): Compound 31.4 was synthesized from Compound 31.3 (6.25 mmol, 3.63 g) in a manner similar to Compound 27.2 to give 3.294 g (72% yield). MS (APCI) calculated for C₂₅H₂₄BBrF₂I₂N₂ (M−H)=733; found=733.

Compound 31.5 (diethyl 3,3′-(14-(4-bromo-2,6-dimethylphenyl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): Compound 31.5 was synthesized from Compound 31.4 (0.200 mmol, 147 mg) and Compound 29.1 (0.440 mmol, 99 mg) in a manner similar to PC-29 to give 117 mg of product (86% yield). MS (APCI) calculated for C₃₅H₃₈B_{Br}F₂N₂O₄ (M−H)=677; found=677. ¹H NMR (400 MHz, Chloroform-d) δ 8.20 (d, J=16.4 Hz, 2H), 7.34 (s, 2H), 6.48 (d, J=16.4 Hz, 2H), 4.31 (q, J=7.1 Hz, 4H), 2.60 (t, J=6.1 Hz, 4H), 2.12 (s, 6H), 1.73-1.56 (m, 8H), 1.54-1.46 (m, 4H), 1.37 (t, J=7.1 Hz, 6H).

Compound 31.6 (diethyl 3,3′-(7,7-difluoro-14-(2′-hydroxy-3,5-dimethyl-[1,1′-biphenyl]-4-yl)-1,3,4,7,10,11,12,13-octahydro-2H-6|4,7|4-[1,3,2]diazaborinino[4,3-a:6,1-a′]diisoindole-5,9-diyl)(2E,2′E)-diacrylate): Compound 31.6 was synthesized from Compound 31.5 (0.144 mmol, 98 mg) and 2-(4,4,5,5-tetramethyl-1,3,2-dioxaborolan-2-yl)phenol (0.720 mmol, 159 mg) in a manner similar to that used for Compound 31.5 except the temperature was raised to 80° C. to afford reaction at the bromine atom. After flash chromatography, isolated 73 mg (73% yield) of the product). MS (APCI) calculated for C₄₁H₄₃BF₂N₂O₅ (M−H)=691; found=691. ¹H NMR (400 MHz, Chloroform-d) δ 8.22 (d, J=16.4 Hz, 2H), 7.36-7.27 (m, 4H), 7.08-6.95 (m, 2H), 6.50 (d, J=16.4 Hz, 2H), 4.32 (q, J=7.1 Hz, 4H), 2.66-2.56 (m, 4H), 2.20 (s, 6H), 1.74-1.60 (m, 8H), 1.54-1.44 (m, 4H), 1.37 (t, J=7.1 Hz, 6H).

PC-31 (diethyl 3,3′-(14-(3,5-dimethyl-2′-((4-(perylen-3-yl)butanoyl)oxy)-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): A 40 mL screw-cap vial was charged with Compound 31.6 (0.091 mmol, 63 mg), Compound 31.2 (0.109 mmol, 37 mg), DMAP (0.182 mmol, 22 mg) and a stir bar. The vial was sealed with a screw-cap septum and flushed with argon. To this vial was added anhydrous THF (6 mL), followed by DCC (0.182 mmol, 38 mg). After stirring overnight at room temperature under argon, water (35 mL) was added and the resulting precipitate was filtered off, washing with water. The wet precipitate was dissolved in DCM, separated from water, dried over MgSO₄, filtered and concentrated in vacuo. The product was purified by flash chromatography using an ethyl acetate/DCM gradient (100% DCM (1 CV)→10% ethyl acetate/DCM (10 CV)). The fractions containing product were concentrated in vacuo to give 62 mg (67% yield). MS (APCI) calculated for C₆₅H₅₉BF₂N₂O₆ (M−H)=1011; found=1011. ¹H NMR (400 MHz, Chloroform-d) δ 8.24-8.14 (m, 4H), 8.11 (d, J=7.5 Hz, 1H), 8.07 (d, J=7.7 Hz, 1H), 7.82 (d, J=8.4 Hz, 1H), 7.67 (d, J=8.3 Hz, 1H), 7.66 (d, J=8.4 Hz, 1H), 7.53-7.27 (m, 7H), 7.15 (d, J=7.9 Hz, 1H), 6.39 (d, J=16.4 Hz, 2H), 4.33 (q, J=7.1 Hz, 4H), 3.09 (t, J=7.5 Hz, 2H), 2.53-2.42 (m, 6H), 2.13 (s, 6H), 2.17-2.06 (m, 2H), 1.59-1.45 (m, 4H), 1.38 (t, J=7.1 Hz, 6H), 1.35-1.22 (m, 8H).

### Example 2.32 PC-32

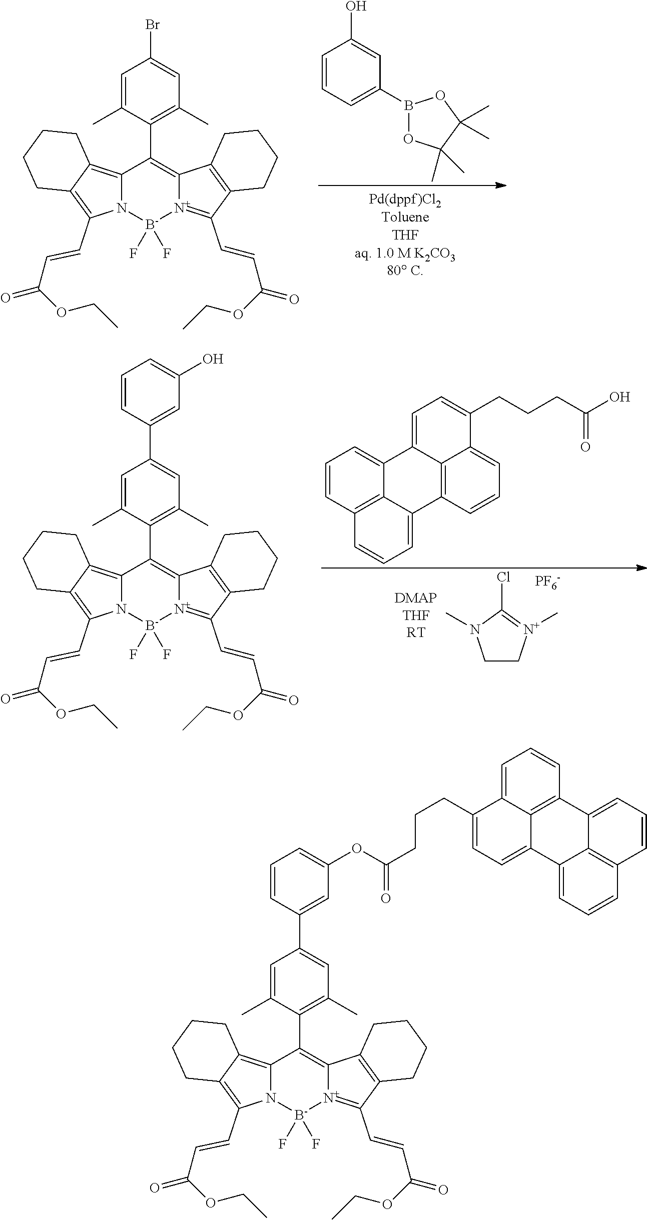

Compound 32.1 (diethyl 3,3′-(7,7-difluoro-14-(3′-hydroxy-3,5-dimethyl-[1,1′-biphenyl]-4-yl)-1,3,4,7,10,11,12,13-octahydro-2H-6|4,7|4-[1,3,2]diazaborinino[4,3-a:6,1-a′]diisoindole-5,9-diyl)(2E,2′E)-diacrylate): Compound 32.1 was synthesized from Compound 31.5 (0.200 mmol, 136 mg) and 3-(4,4,5,5-tetramethyl-1,3,2-dioxaborolan-2-yl)phenol (1.00 mmol, 220 mg) in a manner similar to Compound 31.6 to give 92 mg (66% yield). MS (APCI) calculated for C₄₁H₄₃BF₂N₂O₅ (M−H)=691; found=691.

PC-32 (diethyl 3,3′-(14-(3,5-dimethyl-3′-((4-(perylen-3-yl)butanoyl)oxy)-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-32 was synthesized from Compound 32.1 (0.050 mmol, 35 mg) and Compound 31.2 (0.060 mmol, 20 mg) in a manner similar to PC-31 except 2-chloro-1,3-dimethyl-4,5-dihydro-1H-imidazol-3-ium hexafluorophosphate (0.100 mmol, 28 mg) was used as the coupling reagent to give the product 13.0 mg (26% yield). MS (APCI) calculated for C₆₅H₅₉BF₂N₂O₆ (M−H)=1011; found=1011.

### Example 2.33 PC-33

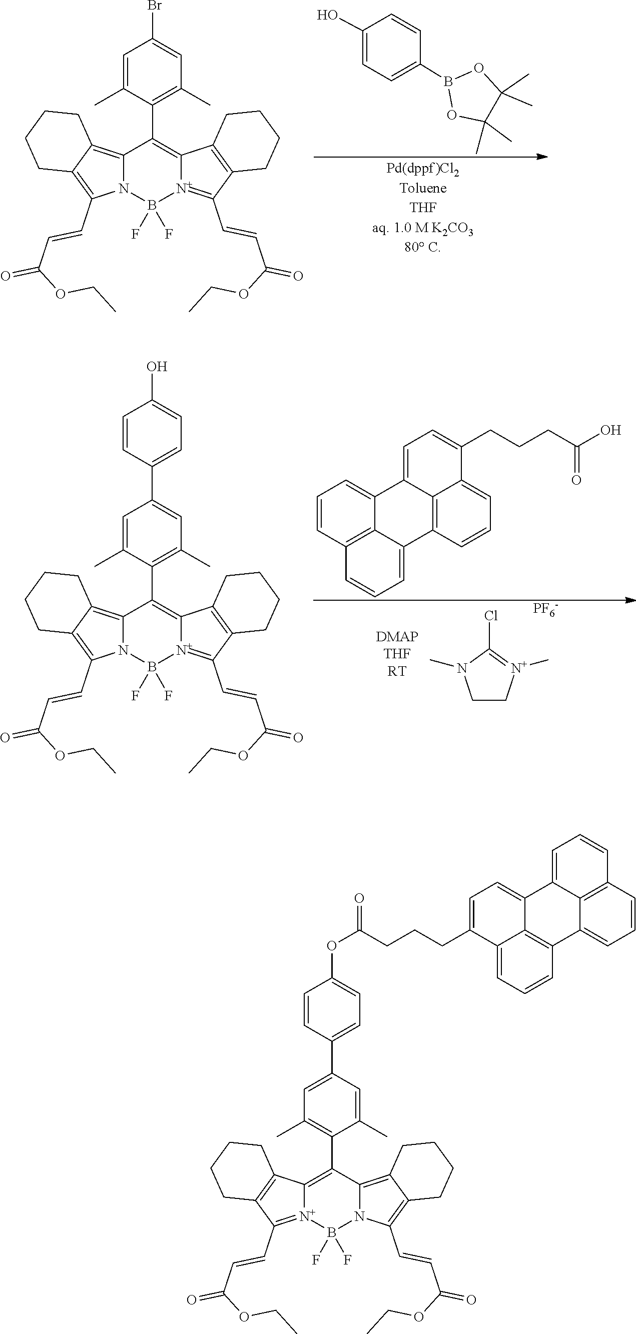

Compound 33.1 (diethyl 3,3′-(7,7-difluoro-14-(4′-hydroxy-3,5-dimethyl-[1,1′-biphenyl]-4-yl)-1,3,4,7,10,11,12,13-octahydro-2H-6|4,7|4-[1,3,2]diazaborinino[4,3-a:6,1-a′]diisoindole-5,9-diyl)(2E,2′E)-diacrylate): Compound 33.1 was synthesized in the same manner as Compound 32.1 to give the product 73 mg (53% yield). MS (APCI) calculated for C₄₁H₄₃BF₂N₂O₅ (M−H)=691; found=691.

PC-33 (diethyl 3,3′-(14-(3,5-dimethyl-4′-((4-(perylen-3-yl)butanoyl)oxy)-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-33 was synthesized from Compound 33.1 (0.094 mmol, 65 mg) in the same manner as PC-32 to give 34 mg (36% yield) of product). MS (APCI) calculated for C₆₅H₅₉BF₂N₂O₆ (M−H)=1011; found=1011.

### Example 2.34 PC-34

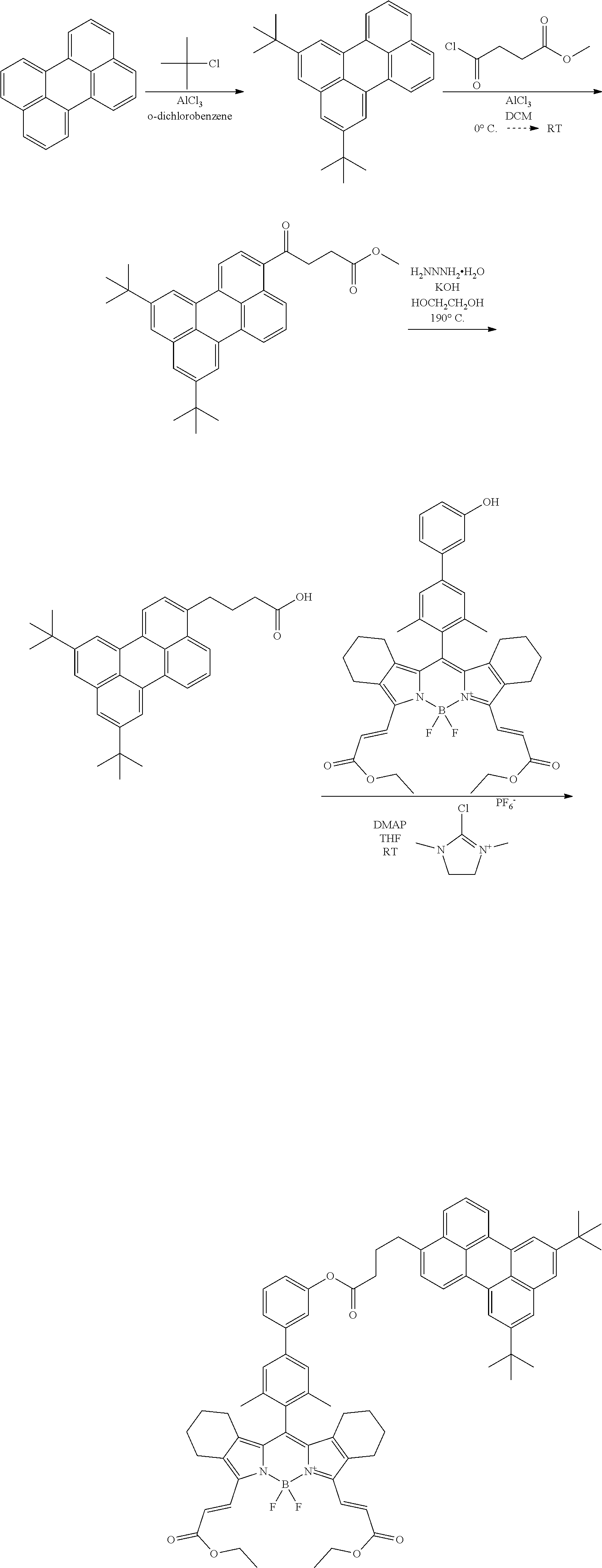

Compound 34.1 (2,5-di-tert-butylperylene): A 3 neck flask was flushed with nitrogen and charged with a stir bar. To this flask was added anhydrous orthodichlorobenzene (300 mL) followed by perylene (19.81 mmol, 5.00 g). The reaction was cooled to 0° C. in an ice-water bath. AlCl₃ (19.81 mmol, 2.64 g) was added in small portions via a powder dispensing funnel over a period of 45 minutes, followed by the dropwise addition of t-butylchloride (458 mmol, 50 mL). The cooling bath was removed, and the reaction was stirred at room temperature for 24 hours. The reaction was quenched by pouring into 100 mL of ice-cold water. The organic layer was separated and concentrated to dryness on a rotary evaporator. The residue was dispersed into hot hexanes (450 mL), then allowed to cool overnight at room temperature. The precipitate was collected by filtration. The precipitate was purified by flash chromatography on silica gel using ethyl acetate/hexanes as eluent (1:9) to give the product, 3.75 g (52% yield). MS (APCI) calculated for C₂₈H₂₉ (M+H)=365; found 365. ¹H NMR (400 MHz, Chloroform-d) δ 8.30-8.21 (m, 4H), 7.72-7.63 (m, 4H), 7.50 (t, J=7.8 Hz, 2H), 1.50 (s, 18H).

Compound 34.2 (methyl 4-(8,11-di-tert-butylperylen-3-yl)-4-oxobutanoate): Compound 34.2 was synthesized in a manner similar to Compound 31.1. From Compound 34.1 (15.85 mmol, 5.77 g) to give 2.7 g (35% yield). MS (APCI): calculated for C₃₃H₃₅O₃ (M+H)=479; found: 479. ¹H NMR (400 MHz, Chloroform-d) δ 8.58 (d, J=8.6 Hz, 1H), 8.33-8.28 (m, 3H), 8.23 (d, J=8.0 Hz, 1H), 7.98 (d, J=7.9 Hz, 1H), 7.73 (s, 1H), 7.68 (s, 1H), 7.60 (t, J=8.0 Hz, 1H), 3.75 (s, 3H), 3.41 (t, J=6.5 Hz, 2H), 2.86 (t, J=6.6 Hz, 2H), 1.49 (s, 9H), 1.48 (s, 9H).

Compound 34.3 (4-(8,11-di-tert-butylperylen-3-yl)butanoic acid): Compound 34.3 was synthesized from Compound 34.2 (0.983 mmol, 471 mg) in a manner similar to Compound 31.2 to give 110 mg (25% yield). MS (APCI): calculated for C₃₂H₃₅O₂ (M+H)=451; found: 451. ¹H NMR (400 MHz, Chloroform-d) δ 8.27-8.20 (m, 3H), 8.15 (d, J=7.7 Hz, 1H), 7.88 (d, J=8.4 Hz, 1H), 7.63 (s, 1H), 7.62 (s, 1H), 7.53 (t, J=8.0 Hz, 1H), 7.34 (d, J=7.6 Hz, 1H), 3.09 (t, J=7.7 Hz, 2H), 2.48 (t, J=7.2 Hz, 2H), 2.11 (p, J=6.9 Hz, 2H), 1.47 (s, 18H).

PC-34 (diethyl 3,3′-(14-(3′-((4-(8,11-di-tert-butylperylen-3-yl)butanoyl)oxy)-3,5-dimethyl-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-34 was synthesized from Compound 32.1 (0.060 mmol, 42 mg) and Compound 34.3 (0.072 mmol, 32 mg) in manner similar to PC-32 to give product, 36 mg (53% yield). MS (APCI): calculated for C₇₃H₇₅BF₂N₂O₆ (M−H)=1123; found: 1123.

### Example 2.35 PC-35

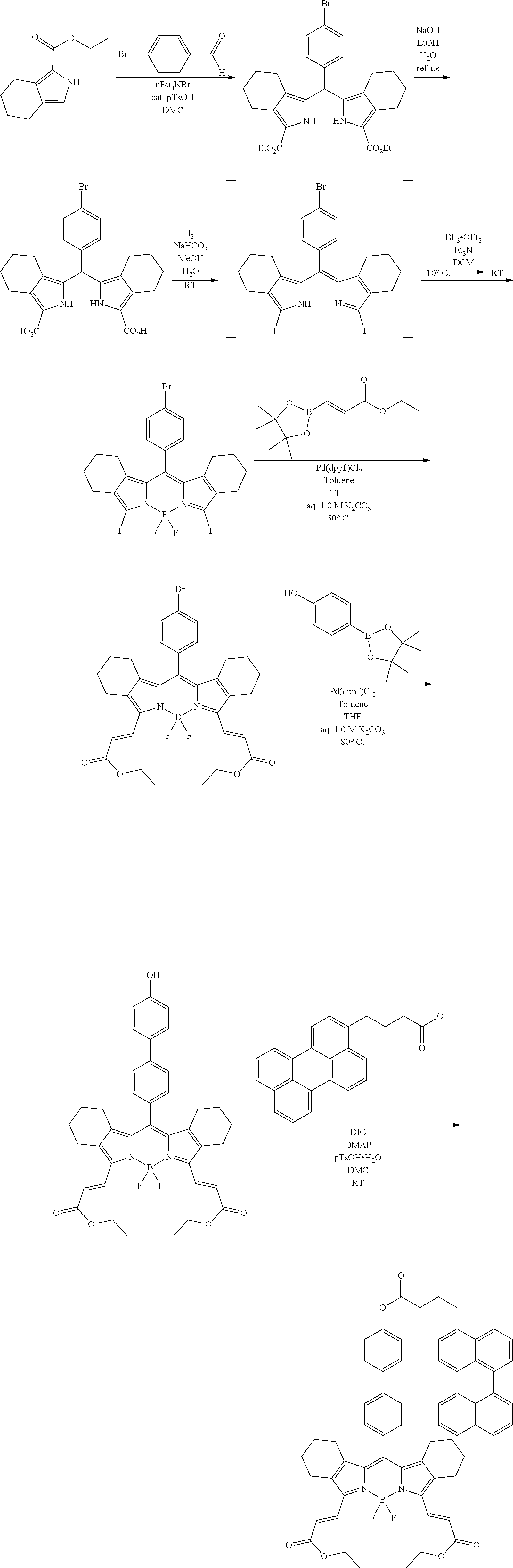

Compound 35.1 (diethyl 3,3′-((4-bromophenyl)methylene)bis(4,5,6,7-tetrahydro-2H-isoindole-1-carboxylate)): Compound 35.1 was synthesized from Compound 24.3 (10.0 mmol, 1.933 g) and 4-bromobenzaldehyde (6.00 mmol, 1110 mg) in a manner similar to Compound 24.4. The reaction mixture was evaporated to dryness and the residue was subjected to saponification without further purification. MS (APCI): calculated for C₂₉H₃₃BrN₂O₄ (M−H)=551; found: 551.

Compound 35.2 (14-(4-bromophenyl)-7,7-difluoro-5,9-diiodo-1,3,4,7,10,11,12,13-octahydro-2H-6|4,7|4-[1,3,2]diazaborinino[4,3-a:6,1-a′]diisoindole): The crude mixture from Compound 35.1 (assume 5.0 mmol) was treated in a manner similar to Compound 24.5 to give, after several steps, the product, 1.888 g (64% yield from Compound 24.3). MS (APCI): calculated for C₂₃H₂₀BBrF₂I₂N₂ (M−H)=705; found: 705.

Compound 35.3 (diethyl 3,3′-(14-(4-bromophenyl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): Compound 35.3 was synthesized from Compound 35.2 (0.500 mmol, 353 mg) in a manner similar to Compound 29 to give the product, 178 mg (55% yield). MS (APCI): calculated for C₃₃H₃₄BBrF₂N₂O₄ (M−H)=649; found: 649.

Compound 35.4 (diethyl 3,3′-(7,7-difluoro-14-(4′-hydroxy-[1,1′-biphenyl]-4-yl)-1,3,4,7,10,11,12,13-octahydro-2H-6|4,7|4-[1,3,2]diazaborinino[4,3-a:6,1-a′]diisoindole-5,9-diyl)(2E,2′E)-diacrylate): Compound 35.4 was synthesized from Compound 35.3 (0.263 mmol, 171 mg) in a manner similar to Compound 32.1 to give the product, 158 mg (90% yield). MS (APCI): calculated for C₃₉H₃₉BF₂N₂O₅ (M−H)=663; found: 663.

PC-35 (diethyl 3,3′-(7,7-difluoro-14-(4′-((4-(perylen-3-yl)butanoyl)oxy)-[1,1′-biphenyl]-4-yl)-1,3,4,7,10,11,12,13-octahydro-2H-6|4,7|4-[1,3,2]diazaborinino[4,3-a:6,1-a′]diisoindole-5,9-diyl)(2E,2′E)-diacrylate): A 40 mL screw cap vial was flushed with argon and charged with Compound 35.4 (0.107 mmol, 71 mg), Compound 31.2 (0.214 mmol, 72 mg), DMAP (0.214 mmol, 26 mg), pTsOH.H₂O (0.193 mmol, 36 mg) and a stir bar. The vial was sealed with a screw-cap septum, anhydrous DCM (4 mL) was added and the mixture stirred to effect solution. To the stirred reaction was added DIC (0.642 mmol, 0.100 mL) and the mixture stirred under argon overnight. The reaction mixture was diluted with ethyl acetate (150 mL) and extracted with aqueous 3N HCl (25 mL). The organic layer was washed with aqueous saturated sodium bicarbonate (25 mL), brine (15 mL), dried over MgSO₄, filtered and concentrated in vacuo. This material was purified by flash chromatography on silica gel (100% DCM (3 CV)→1% EtOAc/DCM (0 CV)→10% EtOAc/DCM (10 CV)). Gives 84 mg (80% yield). MS (APCI): calculated for C₆₃H₅₅BF₂N₂O₆ (M−H)=983; found: 983.

### Example 2.36 PC-36

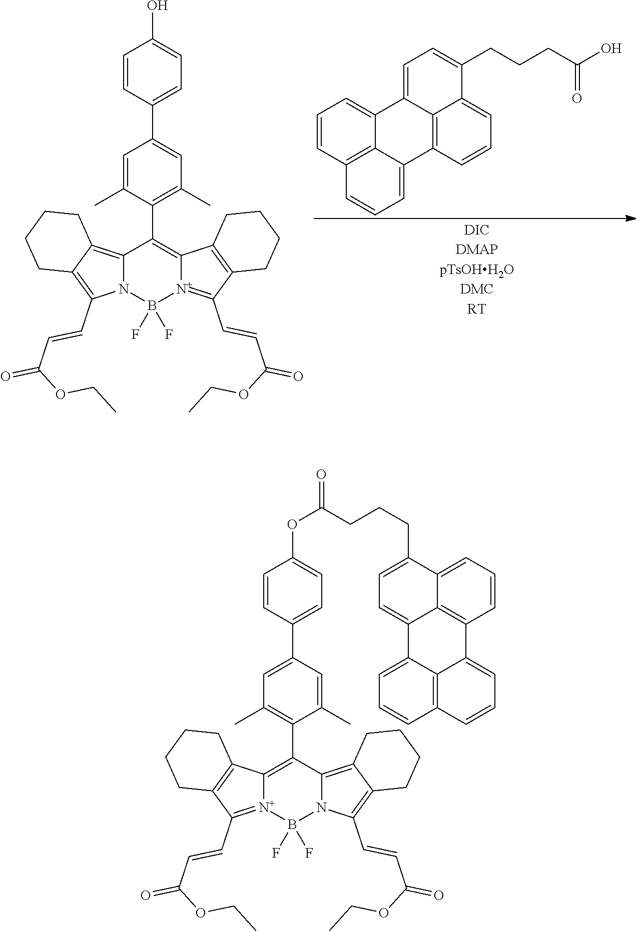

PC-36 (diethyl 3,3′-(14-(3,5-dimethyl-4′-((4-(perylen-3-yl)butanoyl)oxy)-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): was synthesized from Compound 33.1 (0.077 mmol, 51 m) and Compound 31.2 in a manner similar to Compound 35 to give 60 mg (79% yield). MS (APCI): calculated for C₆₅H₅₉BF₂N₂O₆ (M−H)=1011; found: 1011.

### Example 2.37 PC-37

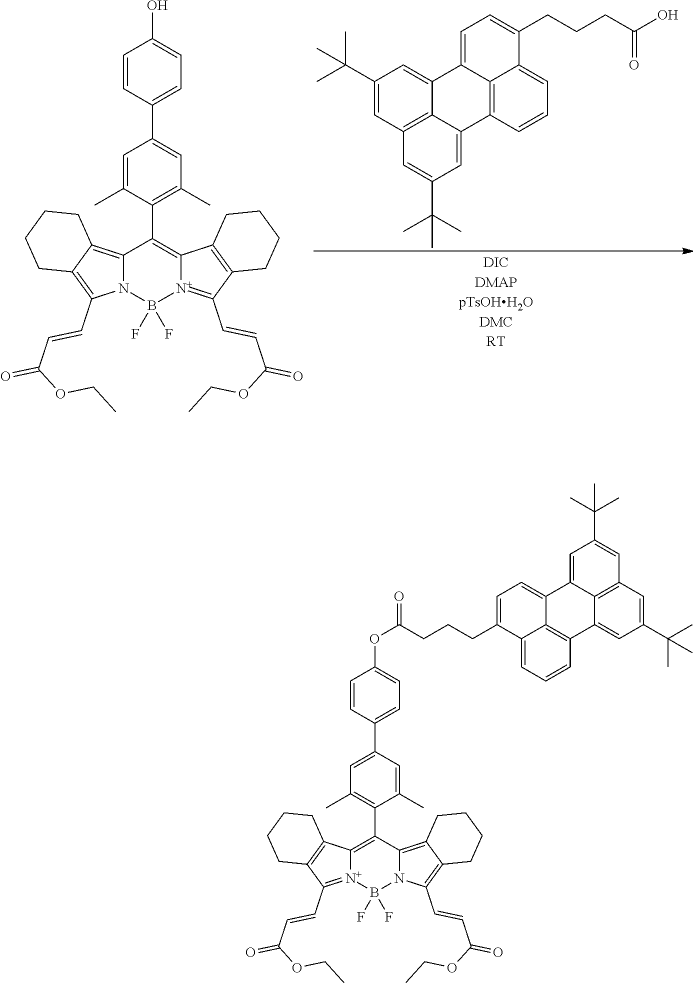

PC-37 (diethyl 3,3′-(14-(4′-((4-(8,11-di-tert-butylperylen-3-yl)butanoyl)oxy)-3,5-dimethyl-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-37 was synthesized from Compound 33.1 (0.060 mmol, 42 mg) and Compound 34.3 (0.072 mmol, 33 mg) in a manner similar to Compound 35 to give 61 mg (90% yield). MS (APCI): calculated for C₇₃H₇₅BF₂N₂O₆(M−H)=1023; found: 1023.

### Example 21.38 PC-38

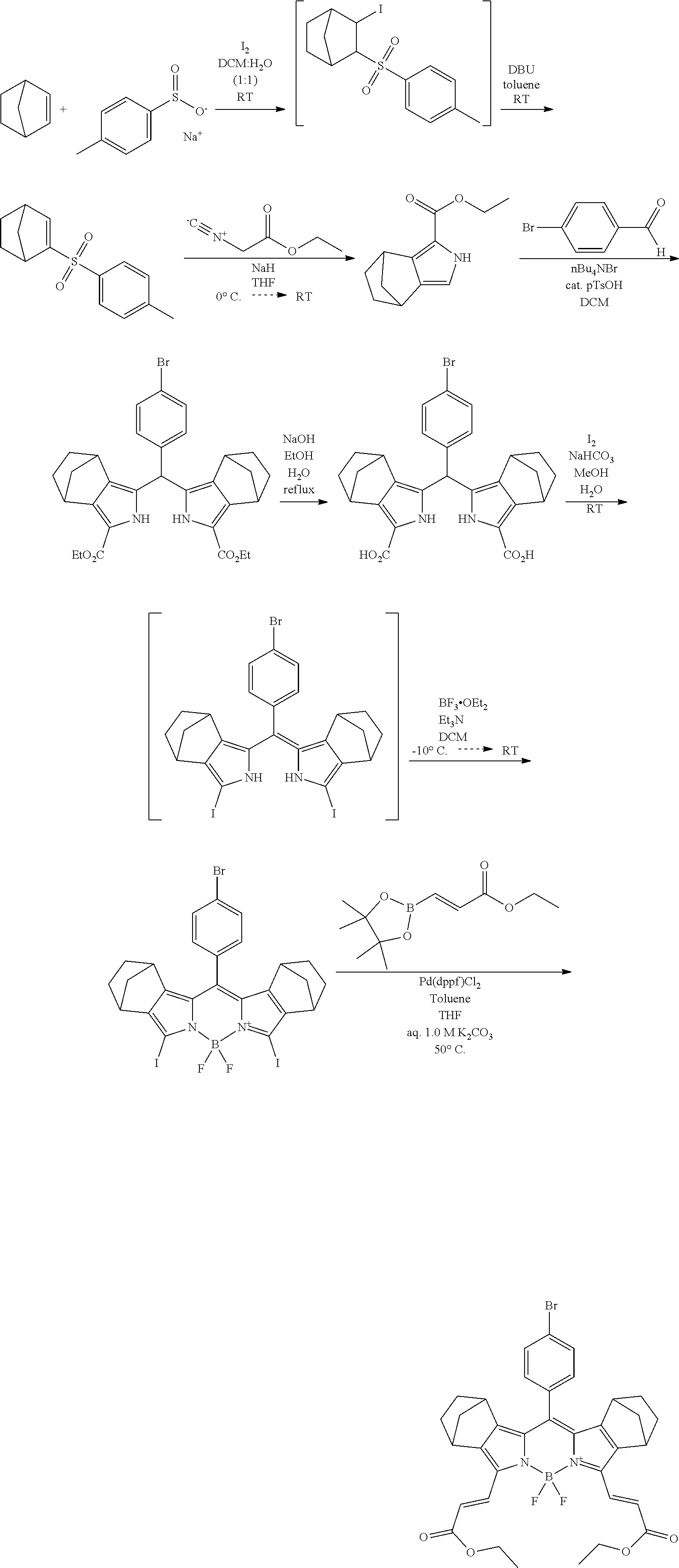

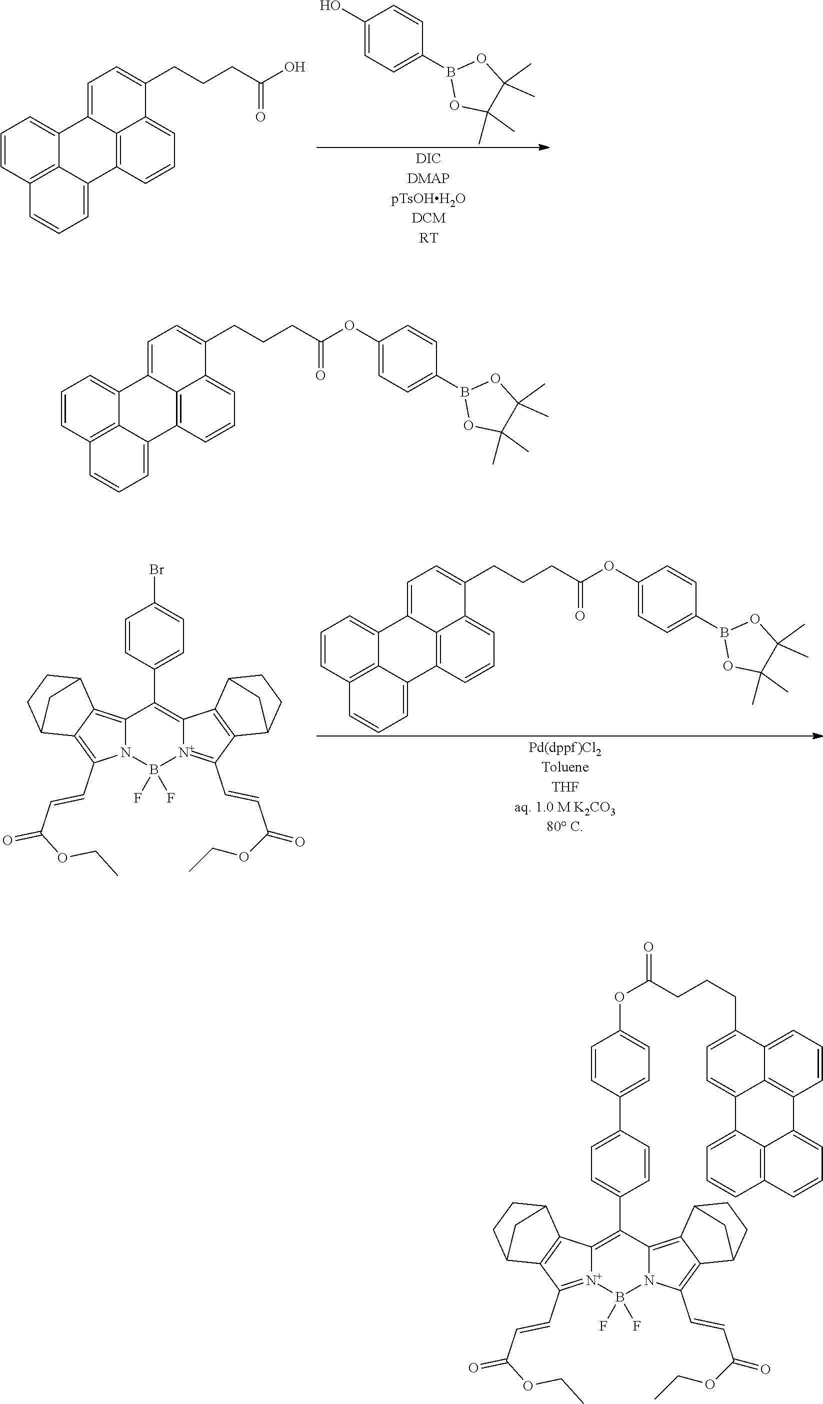

Compound 38.1 (2-tosylbicyclo[2.2.1]hept-2-ene): Compound 38.1 was synthesized from norbornene (365 mmol, 34.368 g), sodium p-toluenesulfonate (606 mmol, 108 g) and iodine (365 mmol, 92.7 g) in a manner similar to Compound 24.2, 82.16 g, 91% yield after crystallization and flash purification on silica gel. MS (APCI): calculated for C₁₄H₁₆O₂S (M−H)=247; found: 247.

Compound 38.2 (ethyl 4,5,6,7-tetrahydro-2H-4,7-methanoisoindole-1-carboxylate): Compound 38.2 was synthesized from Compound 38.1 (90.0 mmol, 22.351 g) in a similar manner to Compound 24.3 to give 15.798 g (86% yield) after purification by flash chromatography on silica gel. MS (APCI): calculated for C₁₂H₁₅NO₂ (M−H)=204; found: 204.

Compound 38.3 (diethyl 3,3′-((4-bromophenyl)methylene)bis(4,5,6,7-tetrahydro-2H-4,7-methanoisoindole-1-carboxylate)): Compound 38.3 was synthesized from. Compound 38.2 (20.0 mmol, 4.105 g) and 4-bromobenzaldehyde (12.0 mmol, 2.220 g) in a manner analogous to Compound 31.3. The reaction was heated at 50° C. under argon atmosphere and monitored by LCMS until the reaction was complete. The crude product was isolated by evaporation and used without further purification in the next step. MS (APCI): calculated for C₃₁H₃₃BrN₂O₄ (M−H)=575; found: 575.

Compound 38.4 (14-(4-bromophenyl)-7,7-difluoro-5,9-diiodo-1,3,4,7,10,11,12,13-octahydro-2H-6|4,7|4-1,4:10,13-dimethano[1,3,2]diazaborinino[4,3-a:6,1-a′]diisoindole): Compound 38.4 was synthesized from the crude reaction product (Compound 38.3, assumed 10.0 mmol) in a manner similar to Compound 35.2 to give 4.138 g (57% yield). MS (APCI): calculated for C₂₅H₂₀BBrF₂I₂N₂ (M−H)=729; found: 729.

Compound 38.5 (diethyl 3,3′-(14-(4-bromophenyl)-7,7-difluoro-1,3,4,7,10,11,12,13-octahydro-2H-6|4,7|4-1,4:10,13-dimethano[1,3,2]diazaborinino[4,3-a:6,1-a′]diisoindole-5,9-diyl)(2E,2′E)-diacrylate): Compound 38.5 was synthesized from Compound 38.4 (1.00 mmol, 731 mg) in a manner similar to Compound 35.3 to give 272 mg (40% yield). MS (APCI): calculated for C₄₁H₃₉BF₂N₂O₅ (M−H)=687; found: 687.

Compound 38.6 (4-(4,4,5,5-tetramethyl-1,3,2-dioxaborolan-2-yl)phenyl 4-(perylen-3-yl)butanoate): Compound 38.6 was synthesized from Compound 31.2 and 4-(4,4,5,5-tetramethyl-1,3,2-dioxaborolan-2-yl)phenol in a manner similar to Compound 37. MS (APCI): calculated for C₃₆H₃₃BO₄ (M−H)=539; found: 539.

PC-38 (diethyl 3,3′-(7,7-difluoro-14-(4′-((4-(perylen-3-yl)butanoyl)oxy)-[1,1′-biphenyl]-4-yl)-1,3,4,7,10,11,12,13-octahydro-2H-6|4,7|4-1,4:10,13-dimethano[1,3,2]diazaborinino[4,3-a:6,1-a′]diisoindole-5,9-diyl)(2E,2′E)-diacrylate): PC-38 was synthesized from Compound 38.5 (0.100 mmol, 68 mg) and Compound 38.6 (0.150 mmol, 81 mg) in a manner analogous to Compound 35.4 to give a quantitative yield of product. MS (APCI): calculated for C₆₅H₅₅BF₂N₂O₆ (M−H)=1007; found: 1007.

### Example 2.39 PC-39

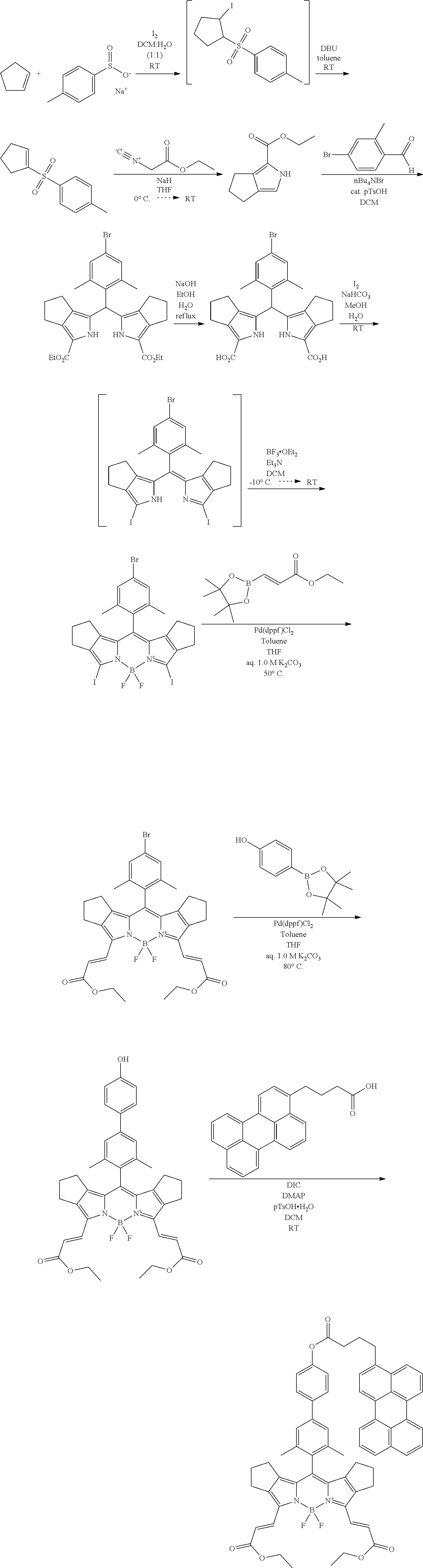

Compound 39.1 (1-(cyclopent-1-en-1-ylsulfonyl)-4-methylbenzene): Compound 39.1 was synthesized from cyclopentene (365 mmol, 32.3 mL), sodium p-toluenesulfonate (606 mmol, 108 g), and iodine (365 mmol, 92.7 mmol) in a manner similar to Compound 38.1 to give product 66.47 g (82% yield) after crystallization. MS (APCI): calculated for C₁₂H₁₄O₂S (M−H)=221; found: 221.

Compound 39.2 (ethyl 2,4,5,6-tetrahydrocyclopenta[c]pyrrole-1-carboxylate): Compound 39.2 was synthesized from Compound 39.1 (90.0 mmol, 20.0 g) in a manner similar to Compound 38.2 to give product 11.560 g (72% yield) after flash chromatography on silica gel. MS (APCI): calculated for C₁₀H₁₃NO₂ (M−H)=178; found: 178.

Compound 39.3 (diethyl 3,3′-((4-bromo-2,6-dimethylphenyl)methylene)bis(2,4,5,6-tetrahydrocyclopenta[c]pyrrole-1-carboxylate)): Compound 39.3 was synthesized from Compound 39.2 (10.0 mmol, 1.792 g) and 2,6-dimethyl-4-bromobenzaldehyde (6.00 mmol, 1.279 g) in a manner similar to Compound 38.3. The crude product was purified by flash chromatography on silica gel (100% DCM (1 CV)→5% EtOAc/DCM (5 CV)→15% EtOAc/DCM (5 CV)) to give 2.310 g (84% yield). MS (APCI): calculated for C₂₉H₃₃BrN₂O₄ (M−H)=551; found: 551.

Compound 39.4 (12-(4-bromo-2,6-dimethylphenyl)-6,6-difluoro-4,8-diiodo-2,3,6,9,10,11-hexahydro-1H-5|4,6|4-cyclopenta[3,4]pyrrolo[1,2-c]cyclopenta[3,4]pyrrolo[2,1-f][1,3,2]diazaborinine): Compound 39.4 was synthesized from Compound 22.3 (4.17 mmol, 2.310 g) in a manner similar to Compound 38.4 to give product after purification by flash chromatography on silica gel, 1.522 g (52% yield). MS (APCI): calculated for C₂₃H₂₀BBrF₂I₂N₂ (M−H)=705; found: 705.

Compound 39.5 (diethyl 3,3′-(12-(4-bromo-2,6-dimethylphenyl)-6,6-difluoro-2,3,6,9,10,11-hexahydro-1H-5|4,6|4-cyclopenta[3,4]pyrrolo[1,2-c]cyclopenta[3,4]pyrrolo[2,1-f][1,3,2]diazaborinine-4,8-diyl)(2E,2′E)-diacrylate): Compound 39.5 was synthesized from Compound 39.4 (0.500 mmol, 353 mg) in a manner similar to Compound 38.5 to give product after purification by flash chromatography on silica gel, 66 mg (20% yield). MS (APCI): calculated for C₃₃H₃₄BBrF₂N₂O₄ (M−H)=649; found: 649.

Compound 39.6 (diethyl 3,3′-(6,6-difluoro-12-(4′-hydroxy-3,5-dimethyl-[1,1′-biphenyl]-4-yl)-2,3,6,940,11-hexahydro-1H-5|4,6|4-cyclopenta[3,4]pyrrolo[1,2-c]cyclopenta[3,4]pyrrolo[2,1-f][1,3,2]diazaborinine-4,8-diyl)(2E,2′E)-diacrylate): Compound 39.6 was synthesized from Compound 39.5 (0.077 mmol, 50 mg) and 4-(4,4,5,5-tetramethyl-1,3,2-dioxaborolan-2-yl)phenol (0.538 mmol, 118 mg) in a manner similar to Compound 35.4 to give product in quantitative yield after purification by flash chromatography on silica gel. MS (APCI): calculated for C₃₉H₃₉BF₂N₂O₅ (M−H)=663; found: 663.

PC-39 (diethyl 3,3′-(12-(3,5-dimethyl-4′-((4-(perylen-3-yl)butanoyl)oxy)-[1,1′-biphenyl]-4-yl)-6,6-difluoro-2,3,6,9,10,11-hexahydro-1H-5|4,6|4-cyclopenta[3,4]pyrrolo[1,2-c]cyclopenta[3,4]pyrrolo[2,14][1,3,2]diazaborinine-4,8-diyl)(2E,2′E)-): PC-39 was synthesized from Compound 39.6 (0.077 mmol, 51 mg) and Compound 31.2 (0.538 mmol, 182 mg) in a manner similar to Compound 38.6 to give product after purification by flash chromatography on silica gel, 60 mg (79% yield). MS (APCI): calculated for C₆₃H₅₅BF₂N₂O₆ (M−H)=983; found: 983.

### Example 2.40 PC-40

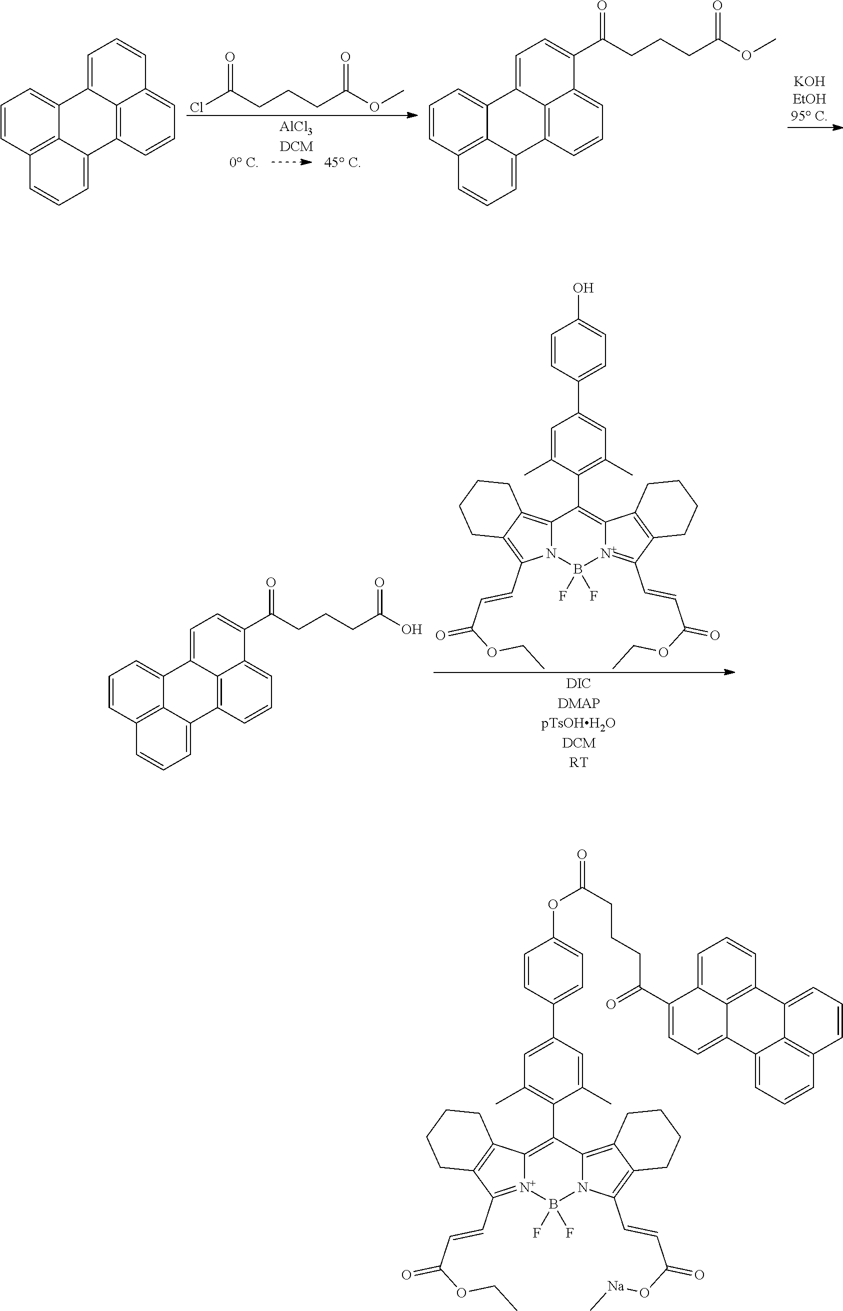

Compound 40.1 (methyl 5-oxo-5-(perylen-3-yl)pentanoate): A 3 L 2 neck round bottomed flask was charged with a stir bar and flushed thoroughly with argon. AlCl₃ (34.7 mmol, 4.624 g) was added to the flask, followed by anhydrous dichloromethane (600 mL). The reaction mixture was cooled to 0° C. with an ice-water bath and methyl 5-chloro-5-oxopentanoate (30.4 mmol, 5.00 g) was added via syringe with stirring under argon. This mixture was stirred at 0° C. for one hour, then perylene (28.9 mmol, 7.300 g) was added with stirring. The cooling bath was removed, and the reaction mixture was stirred at room temperature for two hours. The flask was fitted with a finned air condenser and heated in a heating block set at 45° C. with stirring overnight under argon. The reaction mixture was cooled to room temperature and quenched with the addition of crushed ice (600 mL, loosely packed). To this mixture was added aqueous 6N HCl (100 mL). Stirring was continued until all ice had melted. The layers were separated, and the aqueous layer was extracted with DCM (2×200 mL). The combined organic layers were dried over MgSO₄, filtered, and concentrated in vacuo. The crude reaction was purified by flash chromatography on silica gel (100% DCM (3 CV)→5% EtOAc/DCM (10 CV)). The fractions containing product were collected and concentrated in vacuo to give 3.810 g, 35% yield. MS (APCI): calculated for C₂₆H₂₀O₃ (M+H)=381; found: 381.

Compound 40.2 (5-oxo-5-(perylen-3-yl)pentanoic acid): A 250 mL 2 neck round bottomed flask was charged with a stir bar and flushed with argon. To this flask was added Compound 40.1 (3.00 mmol, 1.141 g) and KOH (30.0 mmol, 1.683 g), followed by ethanol (200 proof, 200 mL). The flask was fitted with a finned air condenser and heated in a heat block at 95° C. under argon with stirring for two hours. The reaction mixture was cooled to room temperature and diluted with water (to 500 mL total volume) in an Erlenmeyer flask and quenched with aqueous 6N HCl (5 mL). The resulting precipitate was collected and concentrated in vacuo to give 1.013 g (92% yield). MS (APCI): calculated for C₂₅H₁₈O₃ (M−H)=365; found: 365.

PC-40 (diethyl 3,3′-(14-(3,5-dimethyl-4′-((5-oxo-5-(perylen-3-yl)pentanoyl)oxy)-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-40 was synthesized from Compound 40.2 (0.400 mmol, 147 mg) and Compound 33.1 (0.100 mmol, 69 mg) in a manner similar to Compound 39 to give product after purification by flash chromatography on silica gel, 67 mg (64% yield). MS (APCI): calculated for C₆₆H₅₉BF₂N₂O₇ (M−H)=1039; found: 1039.

### Example 2.41 PC-41

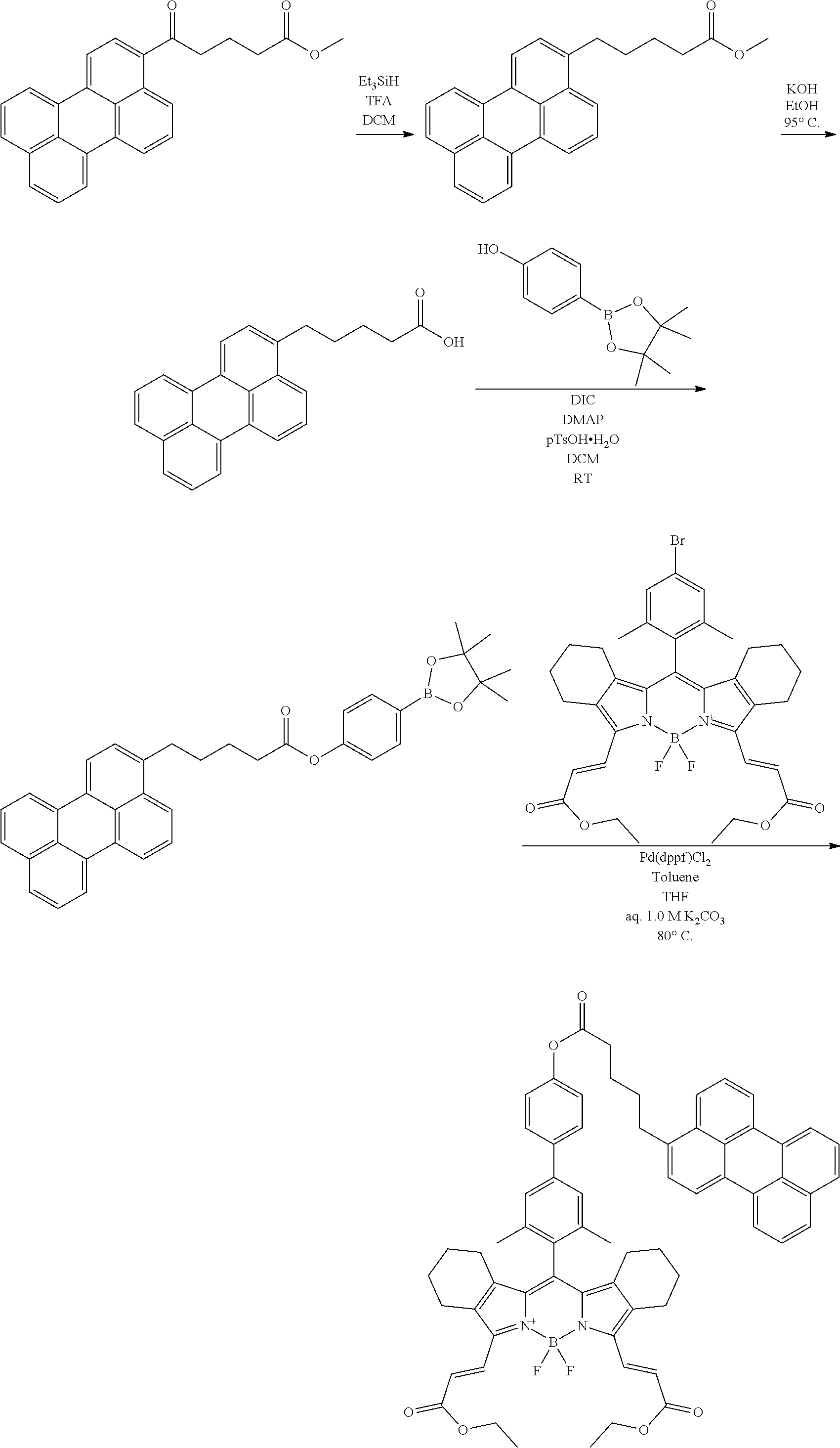

Compound 41.1 (5-(perylen-3-yl)pentanoic acid): A 40 mL screw-cap vial was charged with Compound 40.1 (3.00 mmol, 1.141 g) and a stir bar. The vial was flushed with argon. To this vial was added trifluoroacetic acid (10 mL) and anhydrous dichloromethane (10 mL). The vial was sealed with a screw-cap septum and triethylsilane (6.6 mmol, 1.05 mL) was added with stirring. The reaction was stirred at room temperature under argon for three days, at which point the reduction is complete by LCMS. The reaction mixture was concentrated in vacuo and azeotroped with toluene to remove residual trifluoroacetic acid. The crude ester was saponified in a manner similar to Compound 40.2 to give the precipitated product, 1.025 g (97% yield). MS (APCI): calculated for C₂₅H₂₀O₂ (M−H)=351; found: 351.

Compound 41.2 (4-(4,4,5,5-tetramethyl-1,3,2-dioxaborolan-2-yl)phenyl 5-(perylen-3-yl)pentanoate): Compound 41.1 (1.45 mmol, 512 mg) and 4-(4,4,5,5-tetramethyl-1,3,2-dioxaborolan-2-yl)phenol (2.18 mmol, 480 mg) were esterified in a manner similar to PC-40 to give product after purification by flash chromatography on silica gel, 614 mg (76% yield). MS (APCI): calculated for C₃₇H₃₅BO₄ (M−H)=553; found: 553.

PC-41 (diethyl 3,3′-(14-(3,5-dimethyl-4′-((5-(perylen-3-yl)pentanoyl)oxy)-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-41 was synthesized from Compound 41.2 (0.150 mmol, 83 mg) and Compound 31.3 (0.100 mmol, 68 mg) in a manner similar to Compound 38 to give product after purification by flash chromatography on silica gel, 46 mg (45% yield). MS (APCI): calculated for C₆₆H₆₁BF₂N₂O₆ (M−H)=1025; found: 1025.

### Example 2.42 PC-42

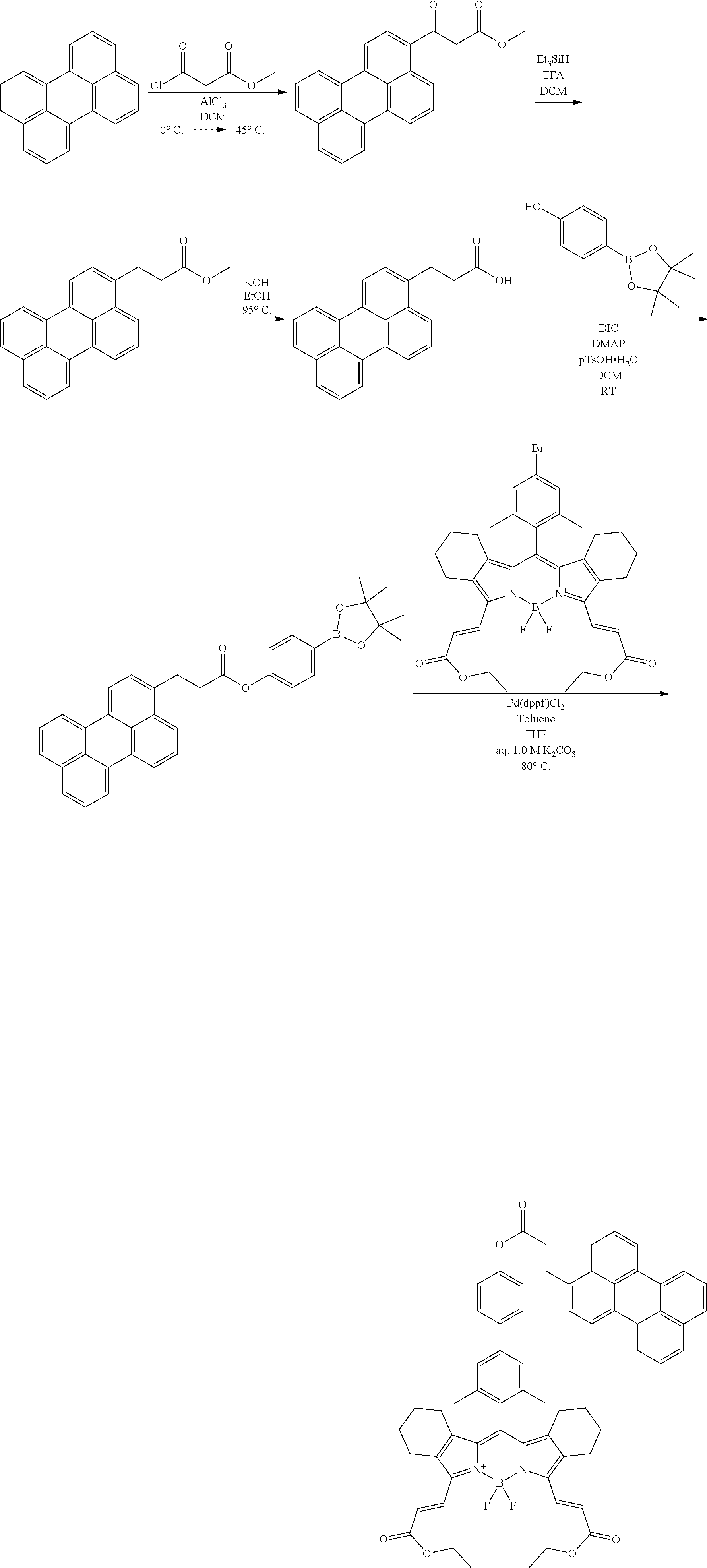

Compound 42.1 (methyl 3-oxo-3-(perylen-3-yl)propanoate): A 500 mL 3 neck round bottom flask was charged with a stir bar and flushed with argon. To this flask was added AlCl₃ (9.52 mmol, 1.27 g, followed by anhydrous dichloromethane (160 mL). The solution was stirred at room temperature and methyl 3-chloro-3-oxopropanoate (8.30 mmol, 0.890 mL) was added, followed by perylene (7.92 mmol, 1.99 g). The reaction was stirred at room temperature under argon overnight. The following morning, the flask was fitted with a finned air condenser and heated with a heat block to 45° C. and stirred at this temperature over the weekend under argon. Added another portion of methyl 3-chloro-3-oxopropanoate (8.30 mmol, 0.890 mL) and continued stirring at 45° C. under argon overnight. The reaction was quenched by the addition of water (100 mL) and aqueous 6N HCl (100 mL) and diluted with dichloromethane (100 mL). The layers were separated (emulsion) and the water layer extracted with DCM (2×200 mL, emulsion), then DCM (4×100 mL). The organic layers were dried with MgSO₄, filtered, and concentrated in vacuo. The product was purified by flash chromatography on silica gel (100% DCM (3 CV)→1% EtOAc/DCM (0 CV)→1% EtOAc/DCM (3 CV)→10% EtOAc/DCM (8 CV)) to give product, 1.905 g (68% yield). MS (APCI): calculated for C₂₄H₁₆O₃ (M+H)=353; found: 353.

Compound 42.2 (3-(perylen-3-yl)propanoic acid): Compound 42.1 (3.10 mmol, 1.091 g) was reduced with triethylsilane and saponified in a manner similar to Compound 41.1. The resulting acid had very poor solubility and required hot THF to dissolve in reasonable volumes. Gives 682 mg (68% yield over 2 steps). MS (APCI): calculated for C₂₃H₁₆O₂ (M−H)=323; found: 323.

Compound 42.3 (4-(4,4,5,5-tetramethyl-1,3,2-dioxaborolan-2-yl)phenyl 3-(perylen-3-yl)propanoate): Compound 42.3 was synthesized from Compound 42.2 (1.67 mmol, 543 mg) and 4-(4,4,5,5-tetramethyl-1,3,2-dioxaborolan-2-yl)phenol (2.51 mmol, 553 mg) in a manner similar to Compound 41.2 to give product after purification by flash chromatography on silica gel, 434 mg (49% yield). MS (APCI): calculated for C₃₅H31B04 (M−H)=525; found: 525.

PC-42 (diethyl 3,3′-(14-(3,5-dimethyl-4′-((3-(perylen-3-yl)propanoyl)oxy)-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate): PC-42 was synthesized from Compound 42.3 (0.150 mmol, 79 mg) and Compound 31.3 (0.100 mmol, 68 mg) in a manner similar to Compound 41 to give product after purification by flash chromatography on silica gel, 81 mg (81% yield). MS (APCI): calculated for C₆₄H₅₇BF₂N₂O₆ (M−H)=997; found: 997.

### Example 2.43 PC-43

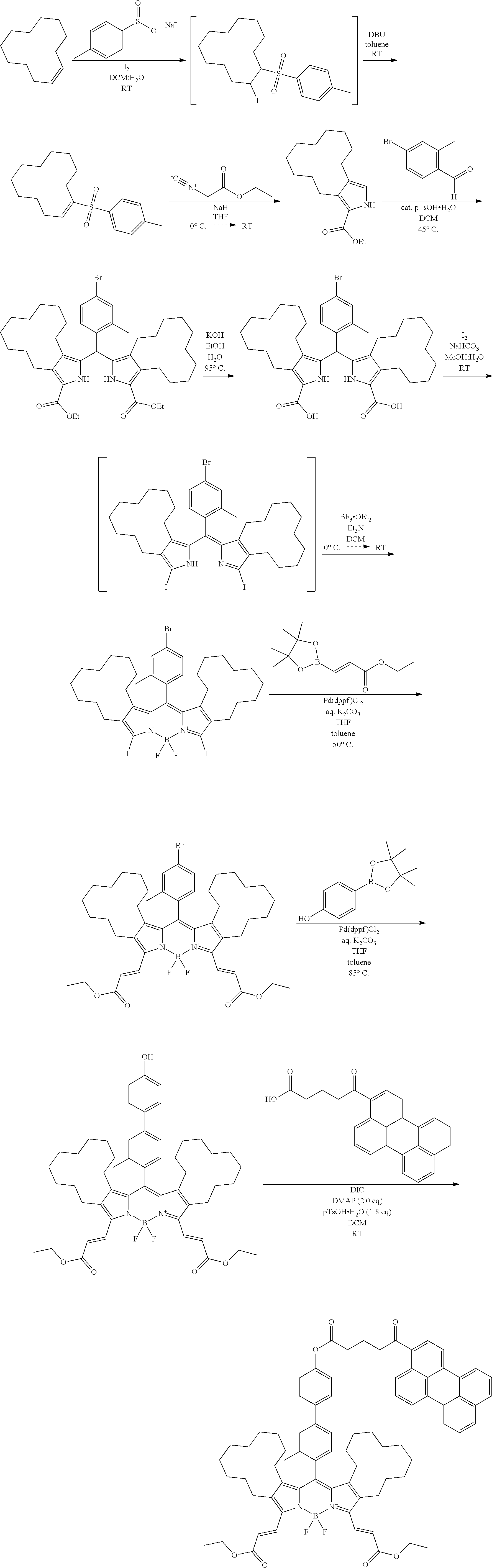

Compound 43.1 ((E)-1-tosylcyclododec-1-ene): Compound 43.1 was synthesized from E/Z-cyclododecene (150 mmol, 28.7 mL) sodium p-toluenesulfonate (249 mmol, 44.37 g), and iodine (150 mmol, 38.070 g) in a manner similar to Compound 39.1 to give product after crystallization and purification by flash chromatography on silica gel (xxx g). MS (APCI): calculated for C₁₉H₂₈O₂S (M−H)=319; found: 319.

Compound 43.2 (ethyl 4,5,6,7,8,9,10,11,12,13-decahydro-2H-cyclododeca[c]pyrrole-1-carboxylate): Compound 43.2 was synthesized from Compound 43.1 (45.0 mmol, 14.423 g) in a manner similar to Compound 39.2 to give product after purification by flash chromatography on silica gel, 10.441 g (84% yield). MS (APCI): calculated for C₁₇H₂₇NO₂ (M−H)=276; found: 276.

Compound 43.3 (diethyl 3,3′-((4-bromo-2-methylphenyl)methylene)bis(4,5,6,7,8,9,10,11,12,13-decahydro-2H-cyclododeca[c]pyrrole-1-carboxylate)): Compound 43.3 was synthesized from Compound 26.2 (15.0 mmol, 4.161 g) and 2-methyl-4-bromobenzaldehyde (9.0 mmol, 1.791 g) in a manner similar to Compound 39.3 to give the crude product which was used without further purification in the next step. MS (APCI): calculated for C₄₂H₅₉BrN₂O₄ (M−H)=733; found: 733.

Compound 43.4 (26-(4-bromo-2-methylphenyl)-13,13-difluoro-11,15-diiodo-1,3,4,5,6,7,8,9,10,13,16,17,18,19,20,21,22,23,24,25-icosahydro-2H-12|4,13|4-cyclododeca[3,4]pyrrolo[1,2-c]cyclododeca[3,4]pyrrolo[2,1-f][1,3,2]diazaborinine): Compound 43.4 was synthesized from crude Compound 43.3 (assumed 7.50 mmol) to give the desired product after several steps and purification by flash chromatography, 844 mg (13% yield). MS (APCI): calculated for C₃₆H₄₆BBrF₂I₂N₂ (M−H)=887; found: 887.

Compound 43.5 (diethyl 3,3′-(26-(4-bromo-2-methylphenyl)-13,13-difluoro-1,3,4,5,6,7,8,9,10,13,16,17,18,19,20,21,22,23,24,25-icosahydro-2H-12|4,13|4-cyclododeca[3,4]pyrrolo[1,2-c]cyclododeca[3,4]pyrrolo[2,1-f][1,3,2]diazaborinine-11,15-diyl)(2E,2′E)-diacrylate): Compound 43.5 was synthesized from Compound 43.4 (0.949 mmol, 844 mg) in a manner similar to Compound 39.5 to give product after purification by flash chromatography on silica gel, 279 mg (35% yield). MS (APCI): calculated for C₄₆H₆₀BBrF₂N₂O₄ (M−H)=831; found: 831.

Compound 43.6 (diethyl 3,3′-(13,13-difluoro-26-(4′-hydroxy-3-methyl-[1,1′-biphenyl]-4-yl)-1,3,4,5,6,7,8,9,10,13,16,17,18,19,20,21,22,23,24,25-icosahydro-2H-12|4,13|4-cyclododeca[3,4]pyrrolo[1,2-c]cyclododeca[3,4]pyrrolo[2,14][1,3,2]diazaborinine-11,15-diyl)(2E,2′E)-diacrylate): Compound 43.6 was synthesized from Compound 43.5 (0.335 mmol, 279 mg) and 4-(4,4,5,5-tetramethyl-1,3,2-dioxaborolan-2-yl)phenol (1.004 mmol, 221 mg) in a manner similar to Compound 39.6 to give product after purification by flash chromatography on silica gel, 229 mg (81% yield). MS (APCI): calculated for C₅₂H₆₅BF₂N₂O₅ (M−H)=845; found: 845.

PC-43 (diethyl 3,3′-(13,13-difluoro-26-(3-methyl-4′-((5-oxo-5-(perylen-3-yl)pentanoyl)oxy)-[1,1′-biphenyl]-4-yl)-1,3,4,5,6,7,8,9,10,13,16,17,18,19,20,21,22,23,24,25-icosahydro-2H-12|4,13|4-cyclododeca[3,4]pyrrolo[1,2-c]cyclododeca[3,4]pyrrolo[2,1-f][1,3,2]diazaborinine-11,15-diyl)(2E,2′E)-diacrylate): PC-43 was synthesized from Compound 43.6 (0.100 mmol, 85 mg) and Compound 40.2 (0.130 mmol, 48 mg) in a manner similar to Compound 39 to give product after purification by flash chromatography on silica gel, 93 mg (77% yield). MS (APCI): calculated for C₇₇H₈₁BF₂N₂O₇ (M−H)=1193; found: 1193.

### Example 2.44 PC-44

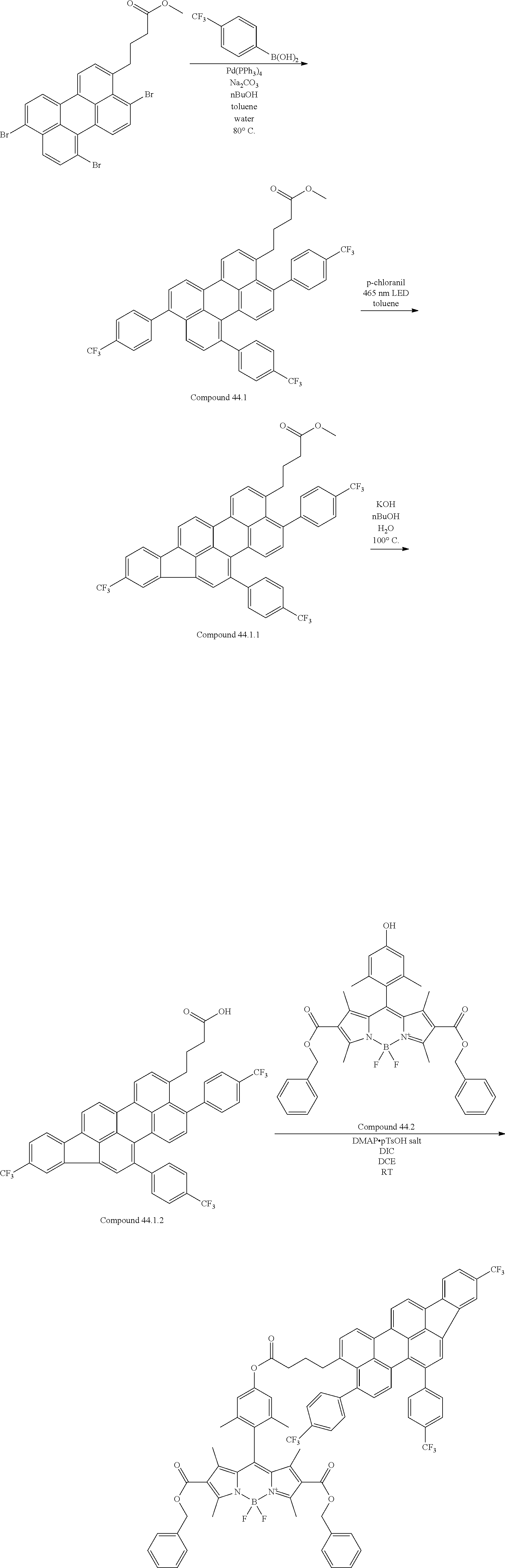

### Methyl 4-(4,9,10-tribromoperylen-3-yl) butanoate/methyl 4-(4,10-dibromo-4,12b-dihydroperylen-3-yl) butanoate/methyl 4-(5,9,10-tribromoperylen-3-yl) butanoate

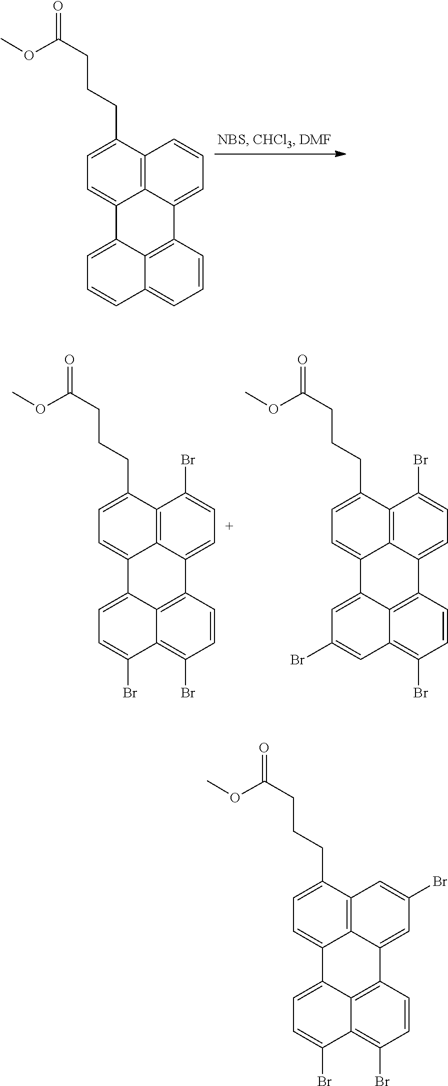 [SMILES: COC(=O)CCCc1ccc2c3cccc4cccc(c5cccc1c52)c43 ; COC(=O)CCCc1ccc2c3ccc(Br)c4c(Br)ccc(c5ccc(Br)c1c52)c43 ; COC(=O)CCCc1ccc2c3cc(Br)cc4c(Br)ccc(c5ccc(Br)c1c52)c43 ; COC(=O)CCCc1ccc2c3ccc(Br)c4c(Br)ccc(c5cc(Br)cc1c25)c43]

A mixture of methyl 4-(4,12b-dihydroperylen-3-yl) butanoate (1.00 g, 2.837 mmol, 1 eq), in anhydrous chloroform (20 mL) was placed in a two necks flask and kept in dark. The mixture was purged with Argon for 15 minutes, and NBS (1.767 g, 9.929 mmol 3.5 eq) was added in small portions then stirred at room temperature for 15 min. DMF anhydrous (10 mL) was added. The resulting mixture was stirred at room temperature under protection of argon for 4 hours. TLC and LCMS showed starting materials were consumed. 25 mL water was added and the organic layer was separated; the water layer was re-extracted with ethyl acetate, washed several times with water, dried with MgSO₄ and concentrated. The crude product was purified by SiO₂ column chromatography, eluted with Hexanes/DCM (9:1) to (1:4) resulting in 0,655 g of a mixture of three isomers (tribromo-perylene derivatives, dibromo-perylene derivatives, and tetrabromo-perylene derivatives (7:1:05)). The products were used without any further purification. Yield 38%. LCMS (APCI+), calculated for Formula: C₂₅H₁₇Br₃O₂; found: 589.

Compound 44.1 (Methyl 4-(4,7,10-tris(4-(trifluoromethyl)phenyl)perylen-3-yl)butanoate): To a 250 mL 2 neck round bottom flask was charged with a stir bar and fitted with a finned condenser and gas adapter. The flask was flushed with argon. To this flak was added methyl 4-(4,7,10-tribromoperylen-3-yl)butanoate (0.849 mmol, 500 mg) (mixture of isomers) and (4-(trifluoromethyl)phenyl)boronic acid (5.94 mmol, 1128 mg), n-butanol (20 mL), toluene (6 mL), and water (6 mL). The flask was heated to 45° C. in a heat block and sparged with argon for 30 minutes. Then added (4-(diphenylamino)phenyl)boronic acid (13.8 mmol, 3.994 g), sodium carbonate (37.68 mmol, 3.994 g), and Pd(PPh₃)₄ (0.628 mmol, 726 mg) while sparging with argon. Stopped the flask and raised the heat block temperature to 80° C. under argon atmosphere. Stirred and heated at this temperature overnight. The reaction mixture was worked up and purified by flash chromatography on silica gel (100% hexanes (1 CV)→30% toluene/hexanes (0 CV)→100% toluene (10 CV)). The crude product was purified by flash chromatography on silica gel (40% 100% hexanes (1 CV)→40% DCM/hexanes (0 CV)→100% DCM (10 CV)). Fractions containing product were evaporated to dryness to give 540 mg (81% yield) as a mixture of isomers. MS (APCI): calculated for Chemical Formula: C₄₆H₂₉F₉O₂ (M−)=784 found: 784.

Compound 44.1.1 (Methyl-4-(10-(trifluoromethyl)-4,7-bis(4-(trifluoromethyl)phenyl)indeno[1,2,3-cd]perylen-3-yl)butanoate): A 300 mL beaker was charged with a stir bar. (methyl 4-(4,7,10-tris(4-(trifluoromethyl)phenyl)perylen-3-yl)butanoate) (0.688 mmol, 540 mg) was added, followed by toluene (250 mL) and p-chloranil (0.688 mmol, 169 mg). The reaction mixture was stirred open to air and irradiated by an array of 465 nm LEDs (commercially available strip) for 24 hours. The solvents were evaporated to dryness and the reaction mixture purified by flash chromatography on silica gel (100% hexanes (1 CV)→75% toluene/hexanes (0 CV)→100% toluene (10 CV)). Fractions containing product were evaporated to dryness to give 118 mg (22% yield) as a mixture of isomers. MS (APCI): calculated for Chemical Formula: C₄₆H₂₇F₉O₂ (M−)=782 found: 782.

Compound 44.1.2 (4-(10-(trifluoromethyl)-4,7-bis(4-(trifluoromethyl)phenyl)indeno[1,2,3-cd]perylen-3-yl)butanoic acid): To A 250 mL 2 neck round bottom flask was charged with a stir bar and fitted with a finned condenser and a gas adapter. The flask was flushed with argon. To this flask was added (methyl-4-(10-(trifluoromethyl)-4,7-bis(4-(trifluoromethyl)phenyl)indeno[1,2,3-cd]perylen-3-yl)butanoate) (0.151 mmol, 118 mg), followed by n-butanol (100 mL), followed by KOH (5.0 M in water, 1.740 mmol, 0.350 mL). The flask was stoppered and heated with stirring in a heat block at 115° C. overnight under argon. The reaction mixture was cooled to room temperature and water (10 mL) was added. Trifluoroacetic acid was added until the pH was about 1. The reaction was evaporated to dryness. The portion soluble in dichloromethane was evaporated to dryness to give the product in quantitative yield at 100° C. The crude precipitate was isolated in quantitative yield and used in the next step without further purification. MS (APCI): calculated for Chemical Formula: C₄₅H₂₅F₉O₂ (M−)=768 found: 768.

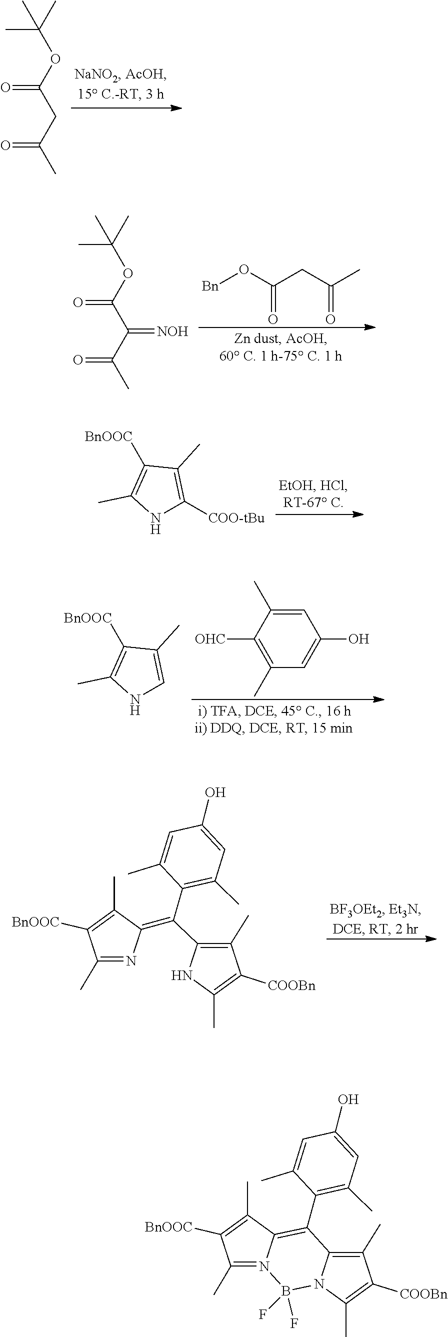

Compound 44.2 (dibenzyl 5,5-difluoro-10-(4-hydroxy-2,6-dimethylphenyl)-1,3,7,9-tetramethyl-5H-4|4,5|4-dipyrrolo[1,2-c:2′,1′4][1,3,2]diazaborinine-2,8-dicarboxylate): To a 250 mL round bottom flask 40 mL (241 mmol) of tert-butyl-3-oxobutanoate was dissolved in 80 mL of acetic acid. The mixture was cooled in an ice water bath to about 10° C. Sodium nitrite (18 g, 262 mmol) was added over 1 h while the temperature was kept under 15° C. The cold bath was removed and the mixture was stirred for 3.5 h at room temperature. The un-soluble material was fileted off to give a crude solution of oxime, which was used without further purification in the next step. Next, 50 g of zinc dust (0.76 mol) was added portion wise to a mixture of 13.7 mL (79 mmol) benzyl-3-oxobutyrate and 100 mL of acetic acid. The resulting mixture was stirred in an oil bath and heated to 60° C. The cured tert-butyl-2-(hydroxyimino-3-oxobutanoate solution was added slowly. The temperature was then increased to 75° C. and stirred for 1 h. Next, the reaction mixture was poured into water (4 L). The precipitate was collected and filtered to yield benzyl 2,4-dimethyl-1H-pyrrole-3-carboxylate, which was recrystallized from MeOH as a white solid, gained 15 g, yield 65% based on benzyl 3-oxobutyrate. ¹H NMR (400 MHz, CDCl₃): 8.88 (br, s, 1H, NH), 7.47-7.33 (m, 5H, C═CH), 5.29 (s, 2H, CH₂), 2.53, 2.48 (2s, 6H, 2CH₃), 1.56 (s, 9H, 3CH₃).

Next, in a 25 mL vial, a mixture of 1 g (4.36 mmol) of benzyl 2,4-dimethyl-1H-pyrrole-3-carboxylate, 0.524 g (4.36 mmol) of MgSO4, was dissolved in 8 mL of anhydrous DCE and stirred at room temperature in the presence of argon gas, for 15 min. 0.327 g of 2,6 dimethyl 4-hydroxybenzaldehyde (2.18 mmol) was added in small portions; the final was closed with a Teflon cap. The resulting mixture was continued to purge with argon for 15 min and TFA (3 drops, cat. Amount) was added. The reaction mixture was stirred at 65° C. for 16 h. TLC and LCMS showed starting materials were consumed. To the crude product, 0.544 g (2.398 mmol) of DDQ was added in one portion. The resulting mixture was stirred at room temperature for ½ h. TLC and LCMS shoed the starting materials were consumed. The resulting mixture was filtered through a short path celite; the filtrate was concentrated to dryness, the residue was re-dissolved into 50 mL of DCE stirred with trimethylamine (1.4 mL, 19 mmol) at room temperature for 15 min then cooled to 0° C. 3 mL of BF₃ (18.36 mmol) was added slowly. The resulting mixture was stirred at room temperature for ½ h the heated to 86° C. for 45 min. the reaction mixture was then diluted with 150 mL of CHCL₃, quenched with 50 mL brine. The organic layers were separated and dried over MgSO₄, the solvents were removed and rotavapored. The residue was chromatographed on a column of silica gel using CH₂Cl₂/EtOAc as eluent to afford a 1 g pure dibenzyl 5,5-difluoro-10-(4-hydroxy-2,6-dimethylphenyl)-1,3,7,9-tetra methyl-5H-4|4,5|4-dipyrrolo[1,2-c:2′,1′-f][1,3,2]diazaborinine-2,8-dicarboxylate), as a red orange solid, 72% yield based on 2,6 dimethyl 4-hydroxybenzaldehyde. LCMS (APCI−), calcd M− for C₃₇H₃₅BF₂N₂O₅: 636.26; found: 636, ¹H NMR (400 MHz, Chloroform-d) δ 7.42-7.28 (m, 4H), 6.66 (d, J=0.7 Hz, 1H), 5.29 (d, J=11.3 Hz, 2H), 2.82 (s, 3H), 2.04 (d, J=5.4 Hz, 3H), 1.72 (s, 3H).

PC-44 dibenzyl (10-(2,6-dimethyl-4-((4-(8-(trifluoromethyl)-11,14-bis(4-(trifluoromethyl)phenyl)indeno[1,2,3-cd]perylen-1-yl)butanoyl)oxy)phenyl)-5,5-difluoro-1,3,7,9-tetra methyl-5H-4|4,5|4-dipyrrolo[1,2-c:2′,1′-f][1,3,2]diazaborinine-2,8-dicarboxylate): Was synthesized from compound 44.2 [5,5-difluoro-10-(4-hydroxy-2,6-dimethylphenyl)-1,3,7,9-tetramethyl-5H-4|4,5|4-dipyrrolo[1,2-c:2′,1′-f][1,3,2]diazaborinine-2,8-dicarbonitrile] (0.055 mmol, 35 mg) and compound 44.1.2 [4-(10-(trifluoromethyl)-4,7-bis(4-(trifluoromethyl)phenyl)indeno[1,2,3-cd]perylen-3-yl)butanoic acid]: (0.050 mmol, 38 mg). The crude product was purified by flash chromatography on silica gel (100% DCM (1 CV)→10% EtOAc/DCM (10 CV)). Fractions containing product were evaporated to give A 40 mL screw cap vial was charged with a stir bar 5,5-difluoro-10-(4-hydroxy-2,6-dimethylphenyl)-1,3,7,9-tetra methyl-5H-4|4,5|4-dipyrrolo[1,2-c:2′,1′-f][1,3,2]diazaborinine-2,8-dicarbonitrile (0.055 mmol, 35 mg) 4-(10-(trifluoromethyl)-4,7-bis(4-(trifluoromethyl)phenyl)indeno[1,2,3-cd]perylen-3-yl)butanoic acid (0.050 mmol, 38 mg), and DMAP:pTsOH 1:1 salt (0.200 mmol, 59 mg). The vial was flushed with argon and anhydrous dichloromethane (20 mL) was added. Diisopropylcarbodiimide (0.300 mmol, 47 uL) was added and the reaction was stirred under argon at room temperature overnight. The next morning, added anhydrous tetrahydrofuran (10 mL) and sonicated for 30 seconds. Added an additional portion of 4-(perylen-3-yl) butanoic acid (0.150 mmol, 51 mg) and stirred at 50° C. under argon overnight. The solvents were evaporated to dryness and the product purified by flash chromatography on silica gel (100% hexanes (1 CV)→5% EtOAc/hexanes (0 CV)→40% EtOAc/hexanes (10 CV)). Fractions containing product were evaporated to dryness and subjected to further purification by flash chromatography on silica gel (100% hexanes (1 CV)→10% EtOAc/hexanes (0 CV)→30% EtOAc/hexanes (10 CV). Fractions containing product were evaporated to dryness to give 47 mg (68% yield) as a mixture of isomers. MS (APCI): calculated for Chemical Formula: C₈₂H₅₈BF₁₁N₂O₆ (M−)=1386 found: 1386.

### Example 2.45 PC-45

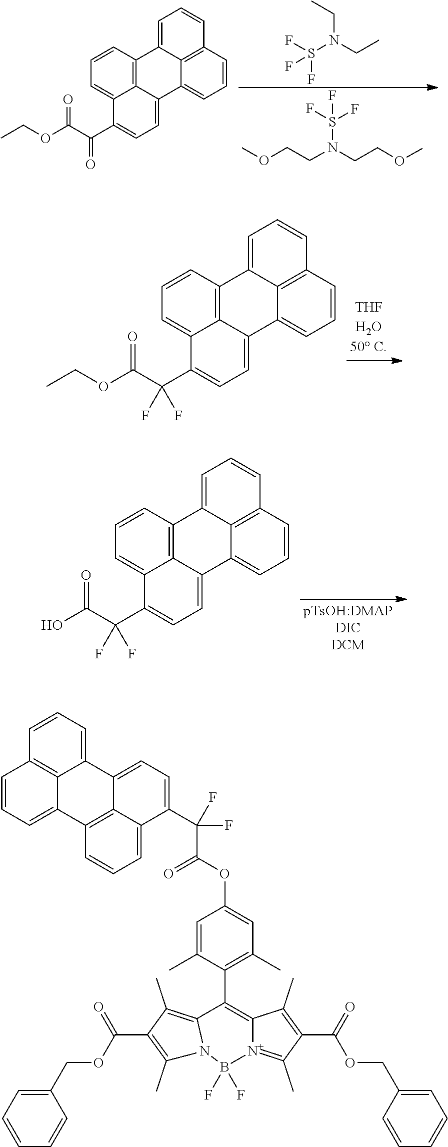

Ethyl 2,2-difluoro-2-(perylen-3-yl)acetate: A 40 mL screw cap vial was charged with a stir bar and fitted with a screw-cap septum. The vial was flushed with argon and anhydrous dichloromethane (10 mL) was added, followed by ethyl 2-oxo-2-(perylen-3-yl)acetate (1.0 mmol, 352 mg). The reaction was stirred at room temperature and diethylsulfur trifluoride (2.5 mmol, 0.328 mL) was added via pipet. The vial was sealed and stirred under argon at room temperature overnight. The reaction was then heated to 4° C. and stirred for 6 hours. Deoxo-Fluor (2.5 mmol, 0.461 mL) was added to the reaction mixture and it was stirred at 40° C. for three hours. Added additional Deoxo-Fluor (2.5 mmol, 0.461 mL) and stirred at 40° C. under argon overnight. The crude reaction mixture was purified by flash chromatography on silica gel (50% DCM/hexanes (2 CV)→100% DCM (8 CV)). Fractions containing product were evaporated to dryness to give 350 mg, 94% yield. MS (APCI): calculated for Chemical Formula: C₂₄H₁₆F₂O₂ (M−)=374; found: 374. ¹H NMR (400 MHz, THF-d8) δ 8.41-8.36 (m, 3H), 8.35 (dd, J=7.6, 1.1 Hz, 1H), 8.01 (dq, J=8.3, 1.5 Hz, 1H), 7.85 (d, J=8.1 Hz, 1H), 7.78 (dd, J=13.3, 8.0 Hz, 2H), 7.59 (dd, J=8.6, 7.6 Hz, 1H), 7.53 (d, J=5.1 Hz, 1H), 7.53 (dd, J=15.6, 5.1 Hz, 1H), 4.28 (q, J=7.1 Hz, 2H), 1.20 (t, J=7.1 Hz, 3H).

2,2-difluoro-2-(perylen-3-yl)acetic acid: A 40 mL screw cap vial was charged with a stir bar and fitted with a screw cap septum. The vial was flushed with argon and ethyl 2,2-difluoro-2-(perylen-3-yl)acetate (0.500 mmol, 187 mg) was added, followed by anhydrous THF (20 mL). KOH (5.0 M in H₂O, 2.50 mmol, 0.5 mL) was added with stirring, the vial sealed, and the reaction heated in a heat block at 50° C. under argon. After heating overnight at 50° C., the reaction was cooled to room temperature and quenched by the addition of excess trifluoroacetic acid to a pH of 1-2. The reaction mixture was diluted with water (200 mL) and the precipitated product was filtered off, washing with water. The product was dissolved in tetrahydrofuran and evaporated to dryness to give the product in quantitative yield, contaminated by salts. This material was used in the next step without further purification. MS (APCI): calculated for Chemical Formula: C₂₂H₁₂F₂O₂ (M−)=346; found: 346.

PC-45: dibenzyl 10-(4-(2,2-difluoro-2-(perylen-3-yl)acetoxy)-2,6-dimethylphenyl)-5,5-difluoro-1,3,7,9-tetramethyl-5H-4|4,5|4-dipyrrolo[1,2-c:2′,1′-f][1,3,2]diazaborinine-2,8-dicarboxylate: A 40 mL screw cap vial was charged with a stir bar, 2,2-difluoro-2-(perylen-3-yl)acetic acid (0.100 mmol, 64 mg) and compound 44.2 [dibenzyl 5,5-difluoro-10-(4-hydroxy-2,6-dimethylphenyl)-1,3,7,9-tetramethyl-5H-4|4,5|4-dipyrrolo[1,2-c:2′,1′-f][1,3,2]diazaborinine-2,8-dicarboxylate] (0.130 mmol, 45 mg), and DMAP:pTsOH 1:1 salt (0.200 mmol, 59 mg). The vial was flushed with argon and anhydrous dichloromethane (20 mL) was added. Diisopropylcarbodiimide (0.300 mmol, 47 uL) was added and the reaction was stirred under argon at room temperature overnight. The next morning, added anhydrous tetrahydrofuran (10 mL) and sonicated for 30 seconds. Added an additional portion of 4-(perylen-3-yl)butanoic acid (0.150 mmol, 51 mg) and stirred at 50° C. under argon overnight. The solvents were evaporated to dryness and the product purified by flash chromatography on silica gel (100% hexanes (1 CV)→5% EtOAc/hexanes (0 CV)→40% EtOAc/hexanes (10 CV)). Fractions containing product were evaporated to dryness and subjected to further purification by flash chromatography on silica gel (100% hexanes (1 CV)→10% EtOAc/hexanes (0 CV)→30% EtOAc/hexanes (10 CV). Fractions containing product were evaporated to dryness to give 45 mg (47% yield). MS (APO): calculated for Chemical Formula: C₅₉H₄₅BF₄N₂O₆ (M−)=964; found: 964. ¹H NMR (400 MHz, Chloroform-d) δ 8.34-8.28 (m, 3H), 8.28-8.25 (m, 1H), 8.10 (d, J=8.5 Hz, 1H), 7.99 (d, J=8.0 Hz, 1H), 7.77 (dd, J=13.2, 8.1 Hz, 2H), 7.66 (dd, J=8.6, 7.6 Hz, 1H), 7.55 (td, J=7.8, 3.3 Hz, 2H), 7.37-7.29 (m, 10H), 6.89 (s, 2H), 5.24 (s, 4H), 2.80 (s, 6H), 2.07 (s, 6H), 1.63 (s, 6H).

### Example 2.46 PC-46

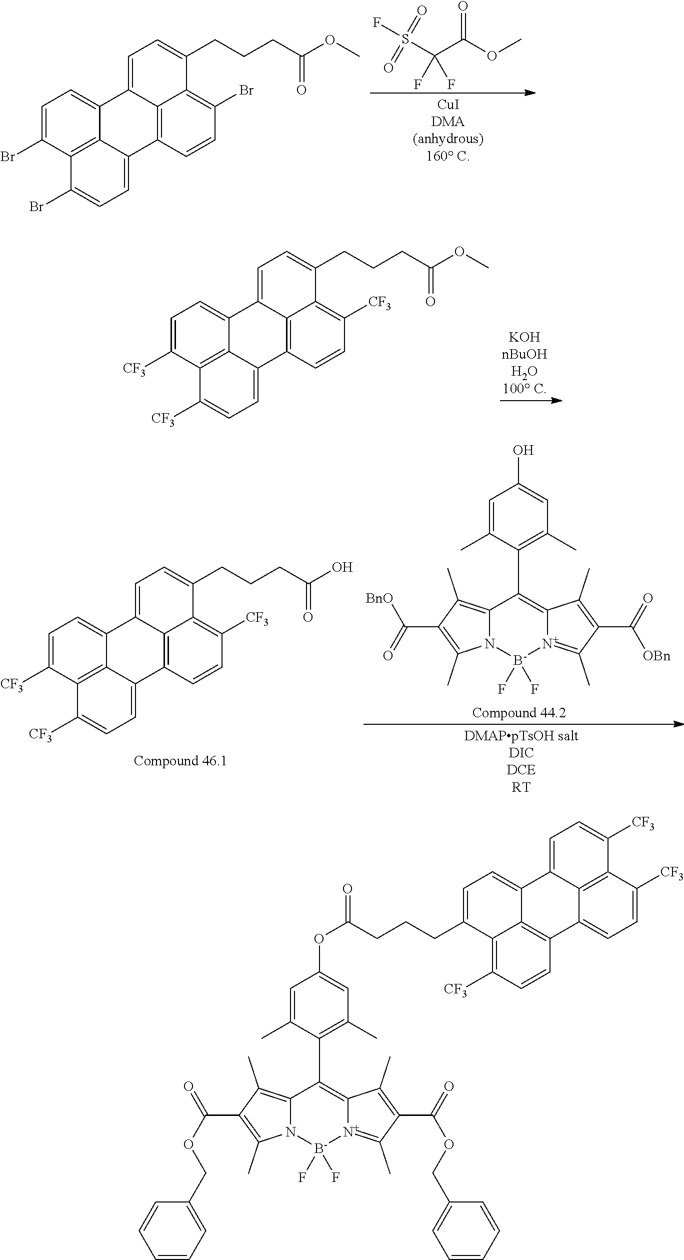

Methyl 4-(4,9,10-tris(trifluoromethyl)perylen-3-yl)butanoate: A 40 mL screw cap vial was charged with a stir bar and fitted with a screw cap septum. The vial was flushed with argon. To this vial was added methyl 4-(4,9,10-tribromoperylen-3-yl)butanoate (mixture of isomers (0.496 mmol, 292 mg), CuI (4.96 mmol, 944 mg), followed by anhydrous dimethylacetamide (10 mL). With stirring at room temperature was added methyl 2,2-difluoro-2-(fluorosulfonyl)acetate (4.96 mmol, 0.631 mL) via syringe at room temperature. The reaction was placed in a heat block set to 160° C. and stirred for 3 hours. Additional portions of CuI (4.96 mmol, 944 mg) and methyl 2,2-difluoro-2-(fluorosulfonyl)acetate (4.96 mmol, 0.631 mL) were added and the reaction stirred for an additional hour. The reaction mixture was cooled to room temperature and diluted to 100 mL total volume with water. The product was filtered off, washing with water. The precipitate was dried and washed with dichloromethane until the dichloromethane washes where colorless. The combined organic washings were evaporated to dryness and purified by flash chromatography on silica gel (50% toluene/hexanes (1 CV)→100% toluene (10 CV)). Fractions containing the desired product (as a mixture of isomers) were evaporated to dryness to give 90 mg (33% yield). MS (APCI): calculated for Chemical Formula: C₂₈H₁₇F₉O₂ (M−)=556; found: 556.

Compound 46.1: 4-(4,9,10-tris(trifluoromethyl)perylen-3-yl) butanoic acid: A 250 mL 2 neck round bottomed flask was charged with a stir bar and flushed with argon. To this flask was added 4-(4,9,10-tris(trifluoromethyl)perylen-3-yl)butanoic acid (3.00 mmol, 1.141 g) and KOH (30.0 mmol, 1.683 g), followed by ethanol (200 proof, 200 mL). The flask was fitted with a finned air condenser and heated in a heat block at 95° C. under argon with stirring for two hours. The reaction mixture was cooled to room temperature and diluted with water (to 500 mL total volume) in an Erlenmeyer flask and quenched with aqueous 6N HCl (5 mL). The resulting precipitate was collected and concentrated in vacuo to give a crude precipitate in quantitative yield. MS (APCI): calculated for Chemical Formula: C₂₇H₁₅F₉O₂ (M−)=542; found: 542.

PC-46 (dibenzyl 10-(2,6-dimethyl-4-((4-(4,9,10-tris(trifluoromethyl)perylen-3-yl)butanoyl)oxy)phenyl)-5,5-difluoro-1,3,7,9-tetramethyl-5H-4|4,5|4-dipyrrolo[1,2-c:2′,1′-f][1,3,2]diazaborinine-2,8-dicarboxylate): A 40 mL screw cap vial was charged with a stir bar, compound 46.1 [4-(4,9,10-tris(trifluoromethyl)perylen-3-yl)butanoic acid] (0.164 mmol, 89 mg) and compound 44.2 [dibenzyl 5,5-difluoro-10-(4-hydroxy-2,6-dimethylphenyl)-1,3,7,9-tetramethyl-5H-4|4,5|4-dipyrrolo[1,2-c:2′,1′-f][1,3,2]diazaborinine-2,8-dicarboxylate], and DMAP:pTsOH 1:1 salt (0.200 mmol, 59 mg). The vial was flushed with argon and anhydrous dichloromethane (20 mL) was added. Diisopropylcarbodiimide (0.300 mmol, 47 uL) was added and the reaction was stirred under argon at room temperature overnight. The next morning, added anhydrous tetrahydrofuran (10 mL) and sonicated for 30 seconds. Added an additional portion of 4-(perylen-3-yl)butanoic acid (0.150 mmol, 51 mg) and stirred at 50° C. under argon overnight. The crude product was purified by flash chromatography on silica gel (100% toluene (2 CV)→10% EtOAc/toluene (10 CV)). Fractions containing product (as a mixture of isomers) were evaporated to dryness to give 128 mg (67% yield). MS (APCI): calculated for Chemical Formula: C₆₄H₄₈BF₁₁N₂O₆ (M−)=1160; found: 1160.

### Example 2.47 PC-47

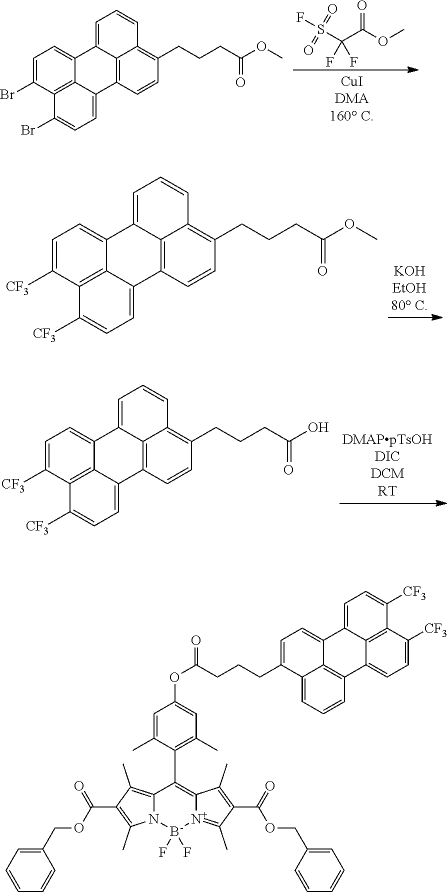

Methyl 4-(9,10-bis(trifluoromethyl)perylen-3-yl)butanoate: NOTE: only one isomer is drawn for illustration. The real reaction of brominated isomers for starting material and trifluoromethylated isomers for the product. Set up a 100 mL 2-neck round-bottom flask with a stir bar, finned condenser, and a gas adapter. The flask and condenser were flushed with argon. While stirring under argon protection 10 eq (13.6 mmol, 2.586 g) of CuI was added to the flask. 1 eq of brominated perylene isomers (1.36 mmol, 800 mg) were dissolved in 5 mL of anhydrous DMA under argon atmosphere and transferred to the flask via syringe. The vial was rinsed with dry DMA (2×5 mL) under argon atmosphere and these DMA aliquots were also added to the reaction flask. Another 15 mL of anhydrous DMA was added to the reaction flask (total DMA=30 mL). Methyl 2-(fluorosulfonyl)-2,2-difluoroacetate (10 eq, 13.6 mmol, 2.609 g, 1.509 g/mL, 1.73 mL) was added to the flask via syringe and the second neck was sealed with a glass stopper. The mixture was stirred and heated with a heat block set to 160° C. After 2 h, LCMS indicated the reaction was about 90% completed. 1295 mg of CuI (5.0 eq, 6.80 mmol) and 1306 mg of methyl 2-(fluorosulfonyl)2,2-difluoroacetate (5.0 eq, 6.80 mmol, 1.509 g/mL, 0.866 mL) was added to the reaction stirred for 2 h at 160° C., then at room temperature overnight. The reaction mixture was worked up by pouring it into 700 mL of stirred water, washing the reaction flask with water and a small amount of methanol. The volume was adjusted to 900 mL with water and the suspension was filtered through a thin layer of celite (slow filtration) and the cake was washed with water. The wet cake and filter paper were broken up and stirred first in 20 mL acetone, then 500 mL of DCM was added to the mixture while stirring. The organic layer was filtered through a second thin pad of celite, transferred to a separatory funnel and separated from water, dried over MgSO4, filtered and concentrated to dryness. The mixture was purified by flash chromatography (first wavelength=300 nm, 2^{nd} wavelength=440 nm), 220 g column, equilibrate 50% toluene/hexanes, dissolve and load in hexanes: toluene (2:1), eluting 50% (1 CV)→100% toluene (10 CV). Desired fractions showed strong UV peak at 440 nm.

Fractions were grouped into early-eluting mixture, middle peak, and later-eluting fractions. Early-eluting fractions were traces of mixed Br/CF₃ isomers and were discarded. The middle peak was mostly tri-CF₃-isomers, 204 mg (26.0% yield). Later-eluting fractions were di-CF₃, tri-CF₃, and tetra-CF₃ mixed isomers, 75 mg (10% yield).

4-(9,10-bis(trifluoromethyl)perylen-3-yl)butanoic acid: A 100 mL 2 neck round bottomed flask was charged with methyl 4-(9,10-bis(trifluoromethyl)perylen-3-yl)butanoate (0.084 mmol, 41 mg) and suspended in absolute ethanol (80 mL). The flask was fitted with a finned reflux condenser and flushed with argon. The reaction mixture was treated with potassium hydroxide (12.7 mmol, 713 mg) and was heated to 80° C. and stirred under argon for 6 hours at this temperature. The reaction was cooled to room temperature and the reaction mixture was evaporated to dryness. The crude product was isolated by C₁₈-capture after acidification, eluting with acetonitrile The fractions were evaporated to dryness to give 40 mg (100% yield). This material was used without further purification. MS (APCI): calculated for Chemical Formula: C₂₆H₁₆F₆O₂ (M⁻)=474; found: 474.

PC-47 (dibenzyl 10-(4-((4-(9,10-bis(trifluoromethyl)perylen-3-yl)butanoyl)oxy)-2,6-dimethylphenyl)-5,5-difluoro-1,3,7,9-tetramethyl-5H-4|4,5|4-dipyrrolo[1,2-c:2′,1′-f][1,3,2]diazaborinine-2,8-dicarboxylate): A 40 mL screw cap vial was charged with a stir bar 4-(9,10-bis(trifluoromethyl)perylen-3-yl)butanoic acid (0.084 mmol, 40 mg), compound 44.2 [4 dibenzyl 5,5-difluoro-10-(4-hydroxy-2,6-dimethylphenyl)-1,3,7,9-tetramethyl-5H-4|4,5|4-dipyrrolo[1,2-c:2′,1′-f][1,3,2]diazaborinine-2,8-dicarboxylate] (0.0924 mmol, 59 mg), and DMAP:pTsOH 1:1 salt (0.200 mmol, 59 mg). The vial was flushed with argon and anhydrous dichloromethane (20 mL) was added. Diisopropylcarbodiimide (0.300 mmol, 47 uL) was added and the reaction was stirred under argon at room temperature overnight. The next morning, added anhydrous tetrahydrofuran (10 mL) and sonicated for 30 seconds. Added an additional portion of 4-(perylen-3-yl)butanoic acid (0.150 mmol, 51 mg) and stirred at 50° C. under argon overnight. The solvents were evaporated to dryness and the product purified by flash chromatography on silica gel (100% hexanes (1 CV)→5% EtOAc/hexanes (0 CV)→40% EtOAc/hexanes (10 CV)). Fractions containing product were evaporated to dryness and subjected to further purification by flash chromatography on silica gel (100% hexanes (1 CV)→10% EtOAc/hexanes (0 CV)→30% EtOAc/hexanes (10 CV). Fractions containing product were evaporated to dryness to give 72 mg (78% yield). MS (APCI): calculated for Chemical Formula: C₆₃H₄₉BF₈N₂O₆ (M⁻)=1092; found: 1092.

### Example 2.48 PC-48

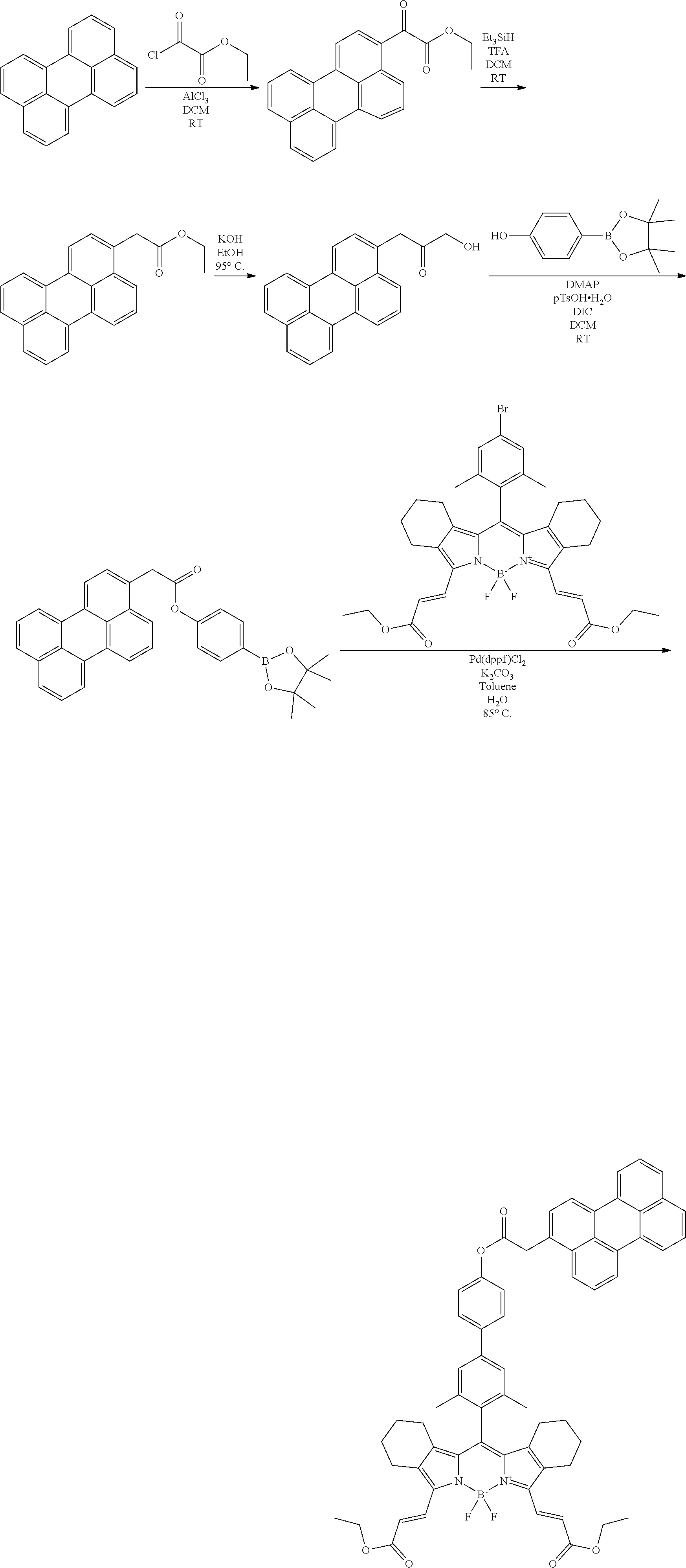

Ethyl 2-oxo-2-(perylen-3-yl)acetate: A 100 mL 2 neck round bottom flask was charged with a stir bar and flushed with argon. To this flask was added AlCl₃ (15.0 mmol, 2.00 g, followed by anhydrous dichloroethane (150 mL). The solution was stirred at room temperature and ethyl 2-chloro-2-oxoacetate (12.0 mmol, 1.34 mL) was added, followed by perylene (10.0 mmol, 2.523 g). More anhydrous dichloroethane was added (50 mL) and the reaction was stirred at room temperature under argon for two hours. The reaction was quenched by the addition of water (100 mL) and aqueous 6N HCl (50 mL) with vigorous stirring. The layers were separated and the water layer extracted with DCM (3×25 mL). The organic layers were dried with MgSO₄, filtered, and evaporated to dryness. The product was purified by flash chromatography on silica gel (60% DCM/hexane (2 CV)→100% DCM (8 CV)→100% DCM). Fractions containing product were evaporated to dryness to give 3.323 g (94% yield). MS (APCI): calculated for C₂₄H₁₆O₃ (M+H)=353; found: 353.

Ethyl 2-(perylen-3-yl)acetate: A 40 mL screw-cap vial was charged with ethyl 2-oxo-2-(perylen-3-yl)acetate (3.00 mmol, 1057 mg) and a stir bar. The vial was flushed with argon. To this vial was added anhydrous dichloromethane (10 mL) and trifluoroacetic acid (10 mL). The vial was sealed with a screw-cap septum and triethylsilane (6.6 mmol, 1.05 mL) was added with stirring. The reaction was stirred at room temperature under argon for four hours, at which point the reduction was complete by LCMS. The reaction mixture was evaporated to dryness and azeotroped with toluene to remove residual trifluoroacetic acid. The reaction mixture was purified by flash chromatography on silica gel (60% DCM/hexane (2 CV)→100% DCM (8 CV)→100% DCM). Fractions containing product were evaporated to dryness to give 433 mg (43% yield). MS (APCI): calculated for C₂₄H₁₈O₂ (M−H)=337; found: 337.

2-(perylen-3-yl)acetic acid: A 100 mL 2 neck round bottomed flask was charged with ethyl 2-(perylen-3-yl)acetate (1.27 mmol, 430 mg) and suspended in absolute ethanol (80 mL). The flask was fitted with a finned reflux condenser and flushed with argon. The reaction mixture was treated with potassium hydroxide (12.7 mmol, 713 mg) and was heated to 95° C. and stirred under argon for 6 hours at this temperature. The reaction was cooled to room temperature and the reaction mixture was evaporated to dryness. The crude product was dispersed in water (250 mL) and acidified with 6 N HCl to pH ^{˜}1. The product was isolated by centrifugation, washed with water, and dried in vacuo. The crude product was isolated with salt contamination but was pure enough to take to the next step. The yield was assumed to be quantitative.

4-(4,4,5,5-tetramethyl-1,3,2-dioxaborolan-2-yl)phenyl 2-(perylen-3-yl)acetate: A 40 mL screw cap vial was charged with a stir bar and flushed with argon. To this vial was added crude 2-(perylen-3-yl)acetic acid from the previous step (assumed 1.27 mmol, 394 mg), 4-(4,4,5,5-tetramethyl-1,3,2-dioxaborolan-4-yl)phenol (1.91 mmol, 419 mg), DMAP (2.54 mmol, 310 mg), and para-toluenesulfonic acid monohydrate (2.29 mmol, 434 mg). Anhydrous dichloromethane was added to the vial (30 mL) and the reaction mixture stirred, then treated with diisopropylcarbodiimide (6.35 mmol, 994 uL). The vial was sealed with a screw cap septum and stirred under argon at room temperature overnight. The volume was reduced to about 5 mL by rotary evaporation and the mixture was loaded directly on to a prepared silica gel column and eluted (100% DCM (5 CV)→5% EtOAc/DCM (10 CV)). Fractions containing product fractions were evaporated to dryness to give 422 mg (65% yield). MS (APCI): calculated for C₃₄H₂₉BO₄ (M−H)=511; found: 511.

PC-48 diethyl 3,3′-(14-(3,5-dimethyl-4′-(2-(perylen-3-yl)acetoxy)-[1,1′-biphenyl]-4-yl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate: A 40 mL screw cap vial was charged with 4-(4,4,5,5-tetramethyl-1,3,2-dioxaborolan-2-yl)phenyl 2-(perylen-3-yl)acetate (0.150 mmol, 77 mg), diethyl 3,3′-(14-(4-bromo-2,6-dimethyl phenyl)-7,7-difluoro-1,3,4,7,10,11,12,13-octahydro-2H-6|4,7|4-[1,3,2]diazaborinino[4,3-a:6,1-a′]diisoindole-5,9-diyl)(2E,2′E)-diacrylate (see PC-32 above for synthesis) (0.100 mmol, 68 mg), and Pd(dppf)Cl₂ (0.015 mmol, 11 mg), followed by K₂CO₃ (1.0 M in H2O, 0.150 mmol, 0.15 mL). The vial was sealed with a screw cap septum and was sparged with argon for 30 minutes. The reaction mixture was heated at 85° C. overnight. The crude mixture was evaporated to dryness, dispersed in dichloromethane, and purified on silica gel (100% DCM (1 CV)→10% EtOAc/DCM (10 CV)). Fractions containing product were evaporated to dryness and subjected to a second purification by flash chromatography on silica gel (20% EtOAc/hexanes (2 CV)→60% EtOAc/hexanes (15 CV). Fractions containing product were evaporated to dryness to give 24 mg, 32% yield. MS (APCI): calculated for C₆₃H₅₅BF₂N2O₆ (M−H)=983; found: 983.

### Example 2.49 PC-49

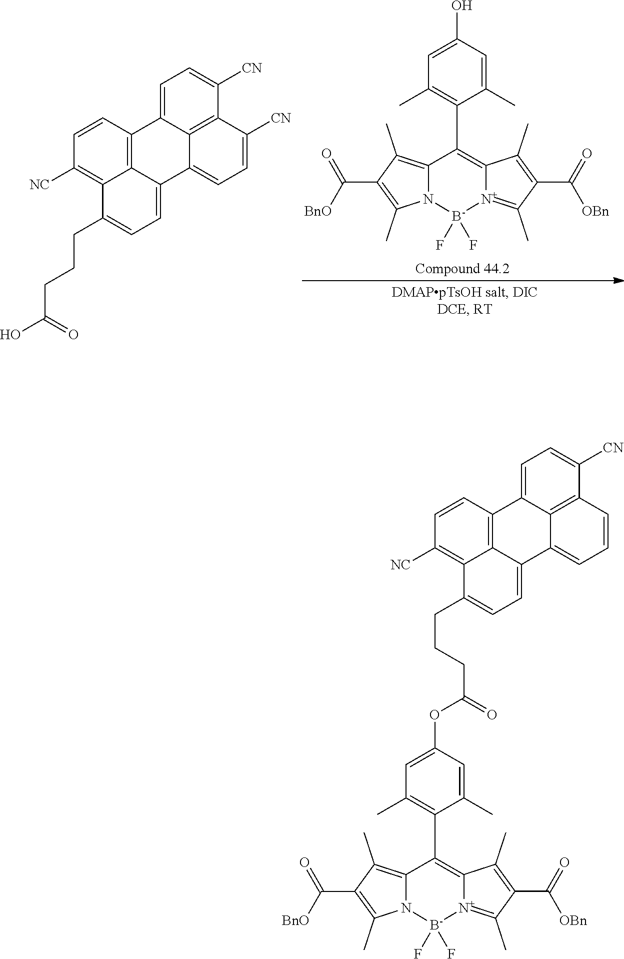 [SMILES: N#Cc1ccc2c3ccc(C#N)c4c(CCCC(=O)O)ccc(c5ccc(C#N)c1c25)c43 ; CC1=C(C(=O)OCc2ccccc2)C(C)=[N+]2C1=C(c1c(C)cc(O)cc1C)c1c(C)c(C(=O)OCc3ccccc3)c(C)n1[B-]2(F)F ; CC1=C(C(=O)OCc2ccccc2)C(C)=[N+]2C1=C(c1c(C)cc(OC(=O)CCCc3ccc4c5cccc6c(C#N)ccc(c7ccc(C#N)c3c74)c65)cc1C)c1c(C)c(C(=O)OCc3ccccc3)c(C)n1[B-]2(F)F]

### Methyl 4-(dicyanoperylen-3-yl) butanoate

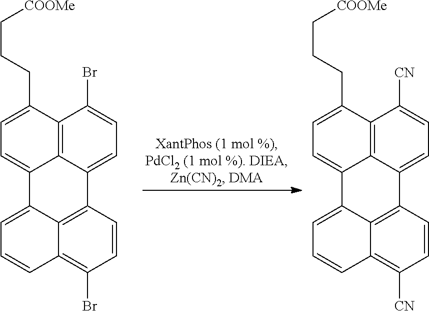 [SMILES: COC(=O)CCCc1ccc2c3cccc4c(Br)ccc(c5ccc(Br)c1c52)c43 ; COC(=O)CCCc1ccc2c3cccc4c(C#N)ccc(c5ccc(C#N)c1c52)c43]

Under protection of an argon atmosphere, a mixture of 356 mg (1.01 mmol) di-bromo perylene intermediate (described above in example 2.44), mixture of regioisomers, 142 mg (0.245 mmol) of xantphos, 45 mg, (0.253 mmol) of PdCl₂, 285 mg, (2.427 mmol) Zn(CN)₂, in degassed DMA anhydrous was place in a 50 mL vial and stirred and bubbling with argon at room temperature for 15 min. 0.348 mL (2.04 mmol) DIEA was added. The vial was closed with Teflon cap and stirred at 85° C. for 48 h. After cooling to room temperature, a dark color insoluble material was poured into 50 mL of water, extracted into 150 mL of DCM, the organic layer was separated, dried with MgSO₄, and concentrated. The crude produce was loaded onto a SiO₂ column and eluted with DCM:hexanes (1:1) then DCM only gain 240 mg a brown solid (mixture of three isomers of dicyanoperylene derivatives) yield 59%. LCMS (APCI+), calcd M+H for formula C₂₇H₁₉N₁₂O₂: 401.13; found: 403

### 4-(dicyanoperylen-3-yl) butanoic acid

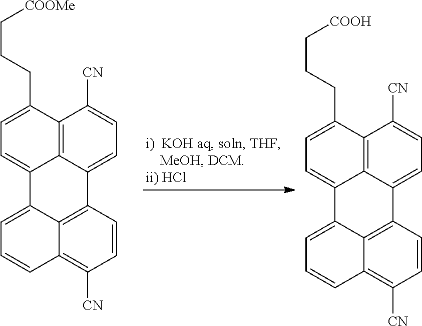 [SMILES: COC(=O)CCCc1ccc2c3cccc4c(C#N)ccc(c5ccc(C#N)c1c52)c43 ; N#Cc1ccc2c3ccc(C#N)c4c(CCCC(=O)O)ccc(c5cccc1c25)c43]

To a mixture of 138 mg (0.343 mmol) methyl 4-(dicyanoperylen-3-yl) butanoate was added 0.5 mL (2.5 mmol) of 5N KOH aq, 3 mL of THF, 0.5 mL of MeOH, 0.5 mL of DCM. The resulting mixture was stirred at room temperature for 16 h, LCMS showed desired compound. 0.6 mL of 6N HCl aq solution (3.6 mmol) was added slowly to acidify the mixture. The resulting mixture was concentrated to the volume of 1 mL. 10 mL of DCM was added; the mixture was washed with water (2 mL×2). The organic layer was separated, dried with MgSO₄ and concentrated to a dryness to gain 120 mg of brown color solid, yield 90%. LCMS (APCI−), calcd M⁻ for formula C₂₆H₁₆N₂O₂: 388,12; found: 388

PC-49: dibenzyl 10-(4-((4-(4,9-dicyanoperylen-3-yl) butanoyl)oxy)-2,6-dimethylphenyl)-5,5-difluoro-1,3,7,9-tetramethyl-5H-4|4,5|4-dipyrrolo[1,2-c:2′,1′-f][1,3,2]diazaborinine-2,8-dicarboxylate: The mixture of 4-(4,9-dicyanoperylen-3-yl) butanoic acid (120 mg, 0.308 mmol), compound 44.2 [dibenzyl 5,5-difluoro-10-(4-hydroxy-2,6-dimethylphenyl)-1,3,7,9-tetramethyl-5H4|4,5|4-dipyrrolo[1,2-c:2′,1′-f][1,3,2]diazaborinine-2,8-dicarboxylate] (196 mg, 0.308 mmol), DCE anhydrous (4 ml) was placed in a vial and bubbling with argon at room temperature for 15 minutes. DMAP-pTSA salt (39.04 mg, 0.012 mmol) was added and the vial was dosed with teflon cap, MC (192.25 mg, 0.616 mmol) was added via syringe. The resulting reaction mixture was stirred at room temperature for 16 hours under argon atmosphere. TLC and LCMS shown the reaction was completed. The reaction was concentrated to dryness. The residue was stirred with toluene (15 mL for 10 minutes, the precipitated was filtered and washed with 10 mL toluene. The filtrated and washing were collected and concentrated down to the volume of 10 mL. The solution of crude product in toluene was injected into 24 g SiO₂ column, Flash column chromatography by eluting with toluene: ethyl acetate (95:5) to (9:1), gained 257 mg orange color solid, 82% yield, LCMS (APCI−), calcd M⁻ for formula C₆₃H₄₉BF₂N₄O₆: 1006.37; found: 1006

### Example 2.50 PC-50

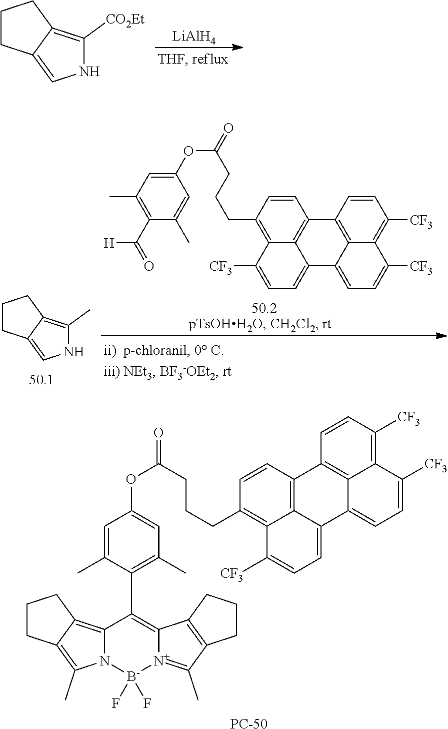

Compound 50.1 (1-methyl-2,4,5,6-tetrahydrocyclopenta[c]pyrrole): To LiAlH₄ (2.07 mmol, 827 μL of a 2.5 M solution in THF) at 0° C. was slowly added a solution of ethyl 2,4,5,6-tetrahydrocyclopenta[c]pyrrole-1-carboxylate (0.686 mmol, 123 mg) in THF (3.00 mL). The reaction mixture was warmed up to r.t., then heated to reflux for 1 h. It was then cooled to r.t., saturated aqueous solution of potassium sodium tartrate (10.0 mL) and CH₂Cl₂ (10.0 mL) were added and the mixture was stirred for 16 h at r.t. before it was extracted with CH₂Cl₂ (3×10.0 mL). The combined organics were dried (MgSO₄) and concentrated under reduced pressure. Flash chromatography gave 44 mg of compound 50.1 (53% yield) as a yellow oil. ¹H NMR (400 MHz, Chloroform-d) δ 7.56 (br s, 1H), 6.30 (s, 1H), 2.63 (t, J=7.1 Hz, 2H), 2.54 (t, J=7.1 Hz, 2H), 2.31 (apparent p, J=7.2 Hz, 2H), 2.19 (s, 3H); ¹³C NMR (101 MHz, Chloroform-d) δ 130.5, 127.0, 118.3, 106.8, 31.8, 25.1, 24.0, 11.9.

Compound 50.2 (4-formyl-3,5-dimethylphenyl 4-(4,9,10-tris(trifluoromethyl)perylen-3-yl)butonate): Compound 50.2 was synthesized from 4-(4,9,10Tris(trifluoromethyl)phenylen-3-yl)butanoic acid (1.438 mmol, 780 mg) and 4-hydroxy-2,6-dimethylbenzaldehyde (2.157 mmol, 324 mg) in a manner similar to Compound 42.3. The crude product was purified by flash chromatography on silica gel (isocratic toluene). Fractions containing product (as a mixture of isomers) were evaporated to dryness to give 765 mg (78.9%). MS (APO): calculated for Chemical Formula: C₃₆H₂₃F₉O₃ (M−)=674; found: 674. ¹H NMR (400 MHz) δ 10.54 (s, 1H), 8.44-7.58 (m, 8H), 6.93-6.81 (m, 2H), 3.42-3.25 (m, 2H), 2.85-2.72 (m, 2H), 2.67-2.56 (m, 6H), 2.38-2.20 (m, 2H).

PC-50 (4-(6,6-difluoro-4,8-dimethyl-2,3,6,9,10,11-hexahydro-1H-5λ⁴,6λ⁴-cyclopenta[3,4]pyrrolo[1,2-c]cyclopenta[3,4]pyrrolo[2,1-f][1,3,2]diazaborinin-12-yl)-3,5-dimethylphenyl 4-(4,9,10-tris(trifluoromethyl)perylen-3-yl)butanoate): To a solution of compound 50.1 (0.182 mmol, 22.0 mg), and pTsOH.H₂O (0.009 mmol, 1.00 mg) in anhydrous CH₂Cl₂ (1.80 mL) at r.t. under argon atmosphere was added compound 50.2 (0.083 mmol, 56.0 mg). The reaction mixture was stirred at r.t. for 2.5 h, then it was cooled to 0° C., p-chloranil (0.083 mmol, 21.0 mg) was added in one portion and the stirring was continued for 15 min. Triethylamine (0.495 mmol, 69.0 μL) was added and the mixture was warmed up to r.t. over 10 min before BF₃.OEt₂ (0.750 mmol, 92.0 μL) was added and the stirring was continued for further 45 min. The reaction mixture was diluted with EtOAc (5.00 mL), washed with 1M HCl (3×5.00 mL) and saturated aqueous solution of NaCl (5.00 mL), dried (MgSO₄) and concentrated under reduced pressure. Flash chromatography (1:1 hexanes/CH₂Cl₂) gave 27.0 mg of PC-50 (35% yield) as an orange powder. ¹H NMR (400 MHz, Chloroform-d) δ 8.42-7.55 (m, 8H), 6.95-6.78 (m, 2H), 3.46-3.27 (m, 2H), 2.82-2.60 (m, 2H), 2.59-2.36 (m, 10H), 2.36-2.24 (m, 2H), 2.24-2.00 (m, 11H), 1.96-1.83 (m, 4H).

### Example 2.51 PC-51

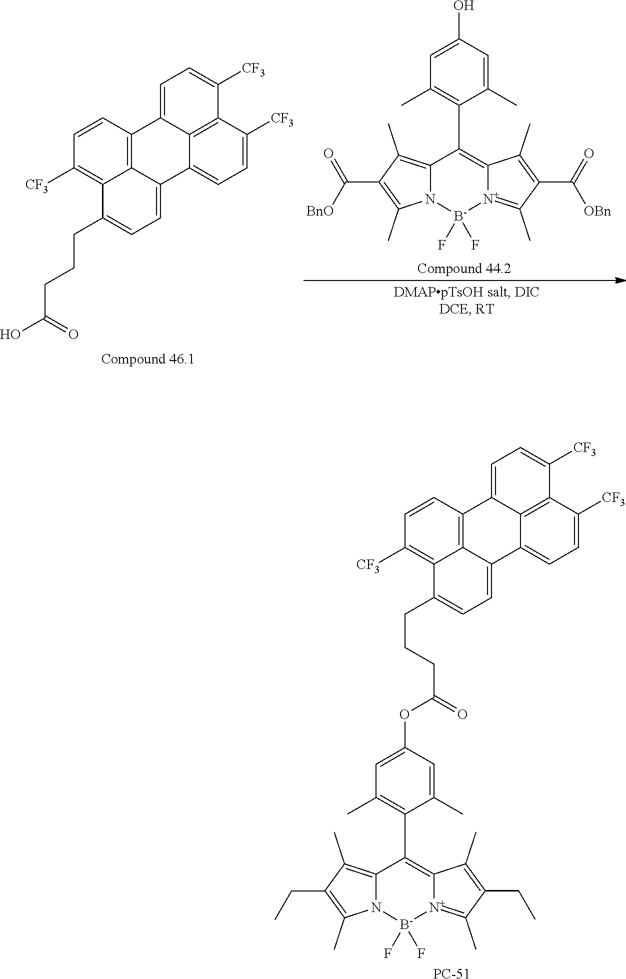

PC-51 (4-(2,8-diethyl-5,5-difluoro-1,3,7,9-tetramethyl-5H-4|4,5|4-dipyrrolo[1,2-c:2′,1′-f][1,3,2]diazaborinin-10-yl)-3,5-dimethylphenyl 4-(4,9,10-tris(trifluoromethyl)perylen-3-yl)butanoate): A mixture of compound 46.1. [4-(4,9,10-tris(trifluoromethyl)perylen-3-yl) butanoic acid] (77.5 mg, 0.143 mmol), compound 44.2 [4-(28-diethyl-5,5-difluoro-1,3,7,9-tetramethyl-5H-4|4,5|4-dipyrrolo[1,2-c:2′,1′-f][1,3,2]diazaborinin-10-yl)-3,5-dimethylphenoldicarboxylate] (61.0 mg, 0.143 mmol), DCE anhydrous (5 mL) was placed in a vial and bubbling with Argon at room temperature for 15 minutes. DMAP-pTSA salt (89.25 mg, 0.286 mmol) was added and the vial was closed with Teflon cap. DIC (0.109 mL, 0.286 mmol) was added via syringe and needle. The resulting reaction mixture was stirred at room temperature for 2 hours under Argon atmosphere. TLC and LCMS shown the reaction was completed. The reaction was loaded onto silica gel column, eluting with toluene: ethyl acetate (9:1), gained 117 mg red-orange color, 86% yield. LCMS (APCI−), calcd M⁻ for formula C₅₂H₄₄BF₁₁N₂O₂: 948.33; found: 948.

### Example 2.52 PC-52

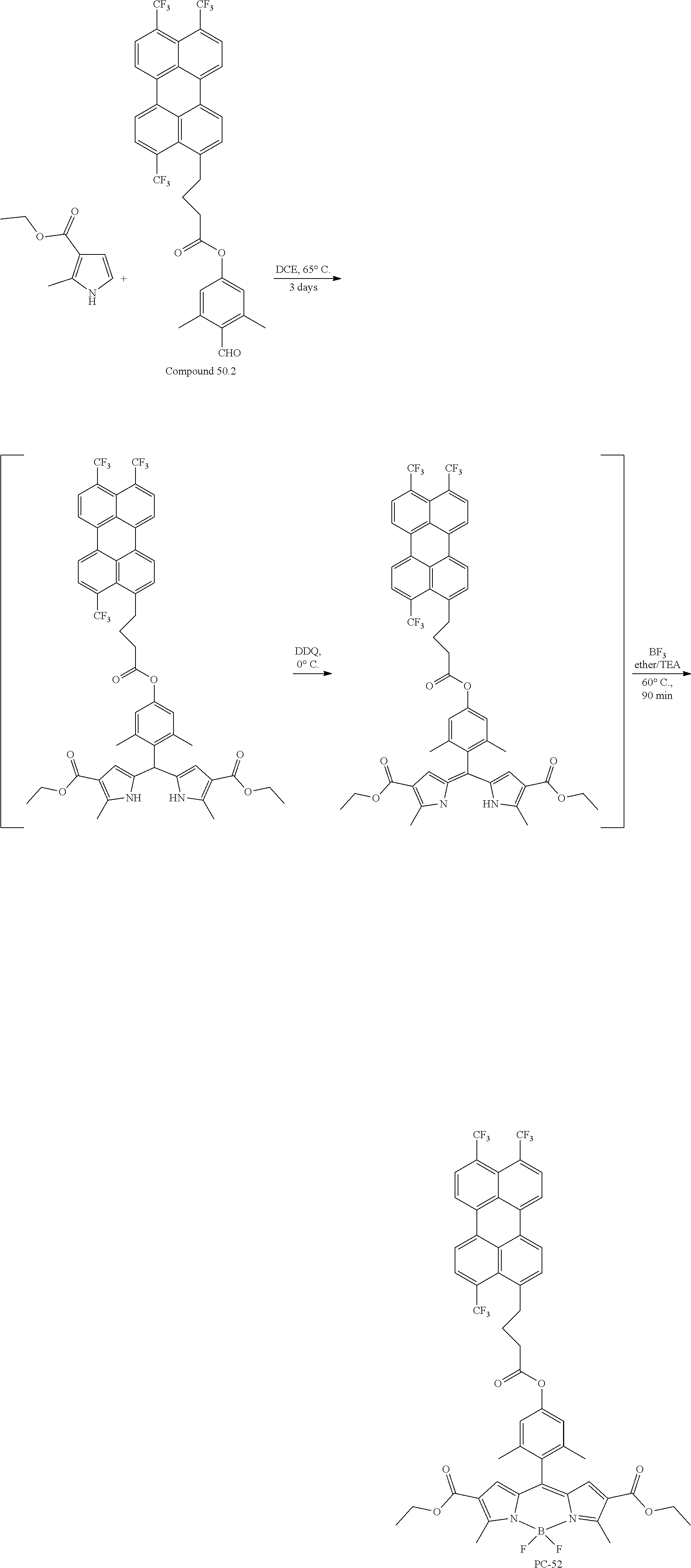

PC-52: A mixture of ethyl 2-methyl-1H-pyrrole-3-carboxylate (100 mg, 0.65 mmol), Compound 50.2 [4-formyl-3,5-dimethyl phenyl 4-(4,9,10-tris(trifluoromethyl)perylen-3-yl)butanoate] (100 mg, 0.146 mmol) in 5 mL dichloroethane with 120 mg MgSO₄ and 3 drops TFA, was heated at 65° C. for 3 days. After cooled with ice-batch, to the mixture was added DDQ (35 mg, 0.15 mmol) and stirred for 10 min., then triethylamine (0.13 mL, 0.9 mmol) and BF₃-ether (0.09 mL, 0.5 mmol) was added. The mixture was heated at 60° C. for 60 min, then another batch of triethylamine (0.13 mL, 0.9 mmol) and BF₃-ether (0.09 mL, 0.5 mmol) was added and the mixture was heated for additional 30 min. The resulted mixture was submitted to silica gel column and purified by flash chromatography using eluents of DCM/ethyl acetate (0%-10% ethyl acetate). The main fraction was collected and removal of solvents under reduced pressure gave an orange-red solid of PC-52 (90 mg, in 60% yield). LCMS (APCI): calcd for C₅₂H₄₀BF₁₁N₂O₆ (M−): 1008.2; Found: 1008. ¹H NMR (400 MHz, TCE-d₂) δ 8.48-7.48 (m, 8H), 6.99 (two singlet, 2H), 6.92-6.83 (m, 2H), 4.29-4.10 (m, 4H), 3.27 (s, 2H), 2.84 (s, 6H), 2.79-2.47 (m, 2H), 2.33-2.14 (m, 2H), 2.06 (two singlet, 6H), 1.23 (m, 6H).

### Example 2.53 PC-53

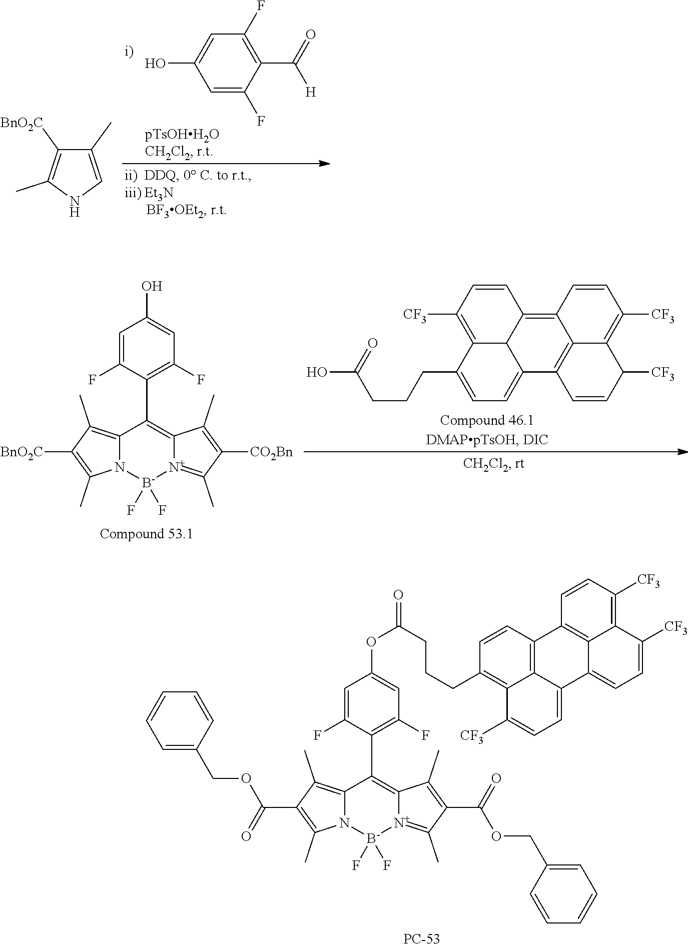

Compound 53.1 [Dibenzyl 10-(2,6-difluoro-4-hydroxyphenyl)-5,5-difluoro-1,3,7,9-tetramethyl-5H-4λ⁴,5λ⁴-dipyrrolo[1,2-c:2′,1′-f][1,3,2]diazaborinine-2,8-dicarboxylate]: To a solution of benzyl 2,4-dimethyl-1H-pyrrole-3-carboxylate (1.05 mmol, 241 mg) and 2,6-difluoro-4-hydroxybenzaldehyde (0.500 mmol, 79 mg) in CH₂Cl₂ (10.0 mL) was added pTsOH.H₂O (0.050 mmol, 6 mg) and the reaction mixture was stirred at r.t. for 45 min. It was then cooled to 0° C., DDQ (0.600 mmol, 136 mg) was added and the mixture was stirred at r.t. for 1 h. Triethylamine (3.00 mmol, 417 μL) was added, the mixture was stirred at 0° C. for 10 min before BF₃.OEt₂ (4.50 mmol, 555 μL) was added and the mixture was stirred at r.t. for 2 h. More triethylamine (3.00 mmol, 417 μL) and, after 5 min stirring at r.t., BF₃.OEt₂ (4.50 mmol, 555 μL) were added and the mixture was stirred at r.t. for further 1 h. It was then diluted with EtOAc (30.0 mL), washed with 3 M HCl (3×30.0 mL), dried (MgSO₄) and concentrated under reduced pressure. Flash chromatography (9:1, toluene/EtOAc) gave 175 mg of compound 53.1 (54% yield) as an orange solid. ¹H NMR (400 MHz, Chloroform-d) δ 7.41-7.30 (m, 10H), 6.59-6.53 (m, 2H), 5.30 (s, 4H), 2.82 (s, 6H), 1.92 (s, 6H).

PC-53 [Dibenzyl 10-(2,6-difluoro-4-((4-(tris(trifluoromethyl)perylen-3-yl)butanoyl)oxy)phenyl)-5,5-difluoro-1,3,7,9-tetramethyl-5H-4λ⁴,5λ⁴-dipyrrolo[1,2-c:2′,1′-f][1,3,2]diazaborinine-2,8-dicarboxylate]): To a solution of compound 53.1 (0.078 mmol, 50.0 mg), compound 46.1 (0.085 mmol, 46.0 mg) and DMAP.pTsOH salt (0.078 mmol, 23.0 mg) in CH₂Cl₂ (0.50 mL) was added DIC (0.312 mmol, 49.0 μL) and the reaction mixture was stirred at r.t. for 3 h. It was then filtered through celite and concentrated under reduced pressure. Flash chromatography (4:1, hexanes/EtOAc→3:2, hexanes/EtOAc) gave 46.0 mg of PC-53 (51% yield) as an orange/red solid. ¹H NMR (400 MHz, Chloroform-d) δ 8.34-7.73 (m, 8H), 7.42-7.28 (m, 10H), 7.02-6.89 (m, 2H), 5.31-5.23 (m, 4H), 3.43-3.29 (m, 2H), 2.87-2.73 (m, 8H), 2.37-2.24 (m, 2H), 1.97-1.83 (m, 6H).

### Example 2.54 PC-54

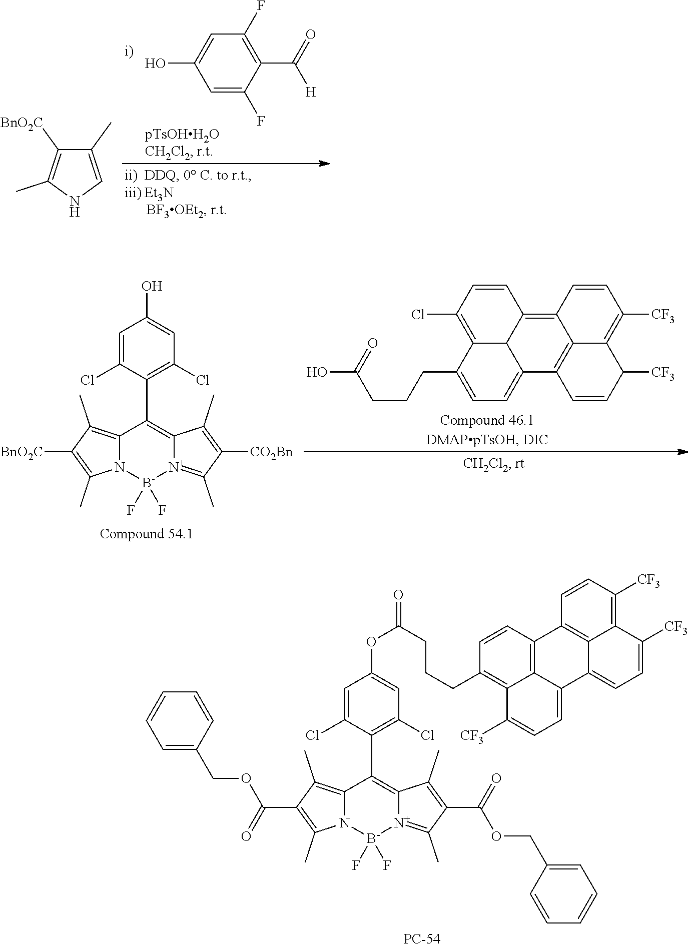

Compound 54.1 [Dibenzyl 10-(2,6-dichloro-4-hydroxyphenyl)-5,5-difluoro-1,3,7,9-tetramethyl-5H-4λ⁴,5λ⁴-dipyrrolo[1,2-c:2′,1′-f][1,3,2]diazaborinine-2,8-dicarboxylate]: To a solution of benzyl 2,4-dimethyl-1H-pyrrole-3-carboxylate (1.05 mmol, 241 mg) and 2,6-difluoro-4-hydroxybenzaldehyde (0.500 mmol, 96 mg) in CH₂Cl₂ (10.0 mL) was added pTsOH.H₂O (0.050 mmol, 6 mg) and the reaction mixture was stirred at r.t. for 1.5 h. DDQ (0.600 mmol, 136 mg) was added and the mixture was stirred at r.t. for 2 h. Triethylamine (3.00 mmol, 417 μL) was then added, the mixture was stirred at r.t. for 30 min before BF₃.OEt₂ (4.50 mmol, 555 μL) was added and the mixture was stirred at r.t. for 1 h. It was then diluted with EtOAc (30.0 mL), washed with 3 M HCl (3×30.0 mL), dried (MgSO₄) and concentrated under reduced pressure. Flash chromatography (toluene→19:1, toluene/EtOAc) gave 211 mg of compound 54.1 (62% yield) as an orange solid. ¹H NMR (400 MHz, Chloroform-d) δ 7.42-7.30 (m, 10H), 6.98 (s, 2H), 5.29 (s, 4H), 2.83 (s, 6H), 1.84 (s, 6H).

PC-54 [Dibenzyl 10-(2,6-dichloro-4-((4-(tris(trifluoromethyl)perylen-3-yl)butanoyl)oxy)phenyl)-5,5-difluoro-1,3,7,9-tetramethyl-5H-4λ⁴,5λ⁴-dipyrrolo[1,2-c:2′,1′-f][1,3,2]diazaborinine-2,8-dicarboxylate]: To a solution of compound 54.1 (0.074 mmol, 50.0 mg), compound 46.1 (0.081 mmol, 44.0 mg) and DMAP.pTsOH salt (0.074 mmol, 23.0 mg) in CH₂Cl₂ (0.50 mL) was added DIC (0.312 mmol, 49.0 μL) and the reaction mixture was stirred at r.t. for 3 h. It was then filtered through celite and concentrated under reduced pressure. Flash chromatography (toluene→19:1, toluene/EtOAc) gave 78.0 mg of PC-54 (88% yield) as an orange/red solid. ¹H NMR (400 MHz, Chloroform-d) δ 8.37-7.71 (m, 8H), 7.39-7.29 (m, 10H), 5.32-5.23 (m, 4H), 3.42-3.29 (m, 2H), 2.89-2.69 (m, 8H), 2.39-2.20 (m, 2H), 1.91-1.76 (m, 6H).

### Example 2.55 PC-55

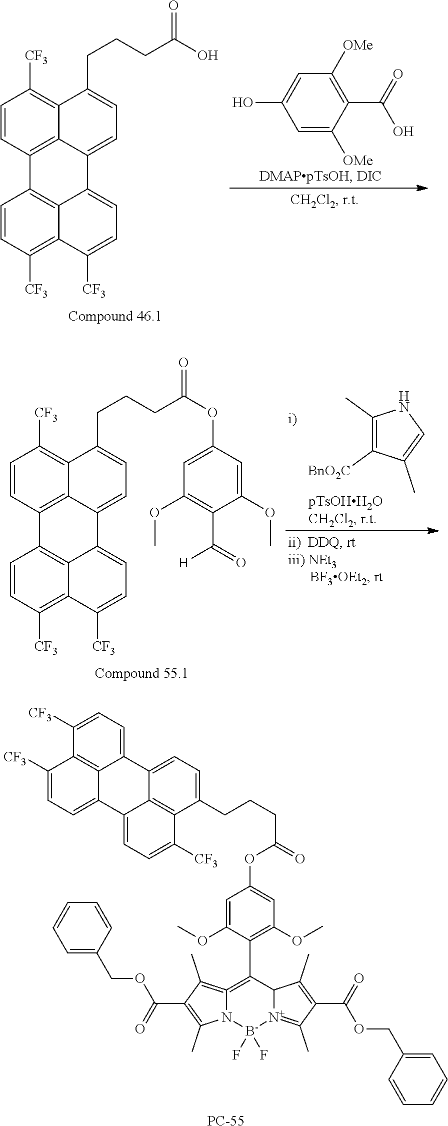

Compound 55.1 [4-Formyl-3,5-dimethoxyphenyl 4-(tris(trifluoromethyl)perylen-3-yl)butanoate]: To a solution of 2,6-dimethoxy-4-hydroxybenzaldehyde (0.246 mmol, 45.0 mg), compound 46.1 (0.369 mmol, 200 mg) and DMAP.pTsOH salt (0.246 mmol, 72.0 mg) in CH₂Cl₂ (1.25 mL) was added DIC (0.984 mmol, 154 μL) and the reaction mixture was stirred at r.t. for 1.5 h. It was then filtered through celite and concentrated under reduced pressure. Flash chromatography (19:1, toluene/EtOAc→9:1, toluene/EtOAc) gave 149 mg of compound 55.1 (86% yield) as an orange solid. ¹H NMR (400 MHz, Chloroform-d) δ 10.51-10.36 (m, 1H), 8.34-7.60 (m, 8H), 6.45-6.26 (m, 2H), 4.03-3.76 (m, 6H), 3.43-3.29 (m, 2H), 2.82-2.61 (m, 2H), 2.34-2.06 (m, 2H).

PC-55 [Dibenzyl 10-(2,6-dimethoxy-4-((4-(tris(trifluoromethyl)perylen-3-yl)butanoyl)oxy)phenyl)-5,5-difluoro-1,3,7,9-tetramethyl-5H-4λ⁴,5λ⁴-dipyrrolo[1,2-c:2′,1′-f][1,3,2]diazaborinine-2,8-dicarboxylate]: To a solution of benzyl 2,4-dimethyl-1H-pyrrole-3-carboxylate (0.311 mmol, 71.0 mg) and compound 55.1 (0.142 mmol, 100 mg) in CH₂Cl₂ (3.00 mL) was added pTsOH.H₂O (0.014 mmol, 1.70 mg) and the reaction mixture was stirred at r.t. for 1.5 h. DDQ (0.170 mmol, 39 mg) was then added and the mixture was stirred at r.t. for 1 h. Triethylamine (0.852 mmol, 118 μL) was added, the mixture was stirred at r.t. for 30 min before BF₃.OEt₂ (1.28 mmol, 158 μL) was added and the mixture was stirred at r.t. for 75 min. It was then diluted with EtOAc (20.0 mL), washed with 3 M HCl (3×20.0 mL), dried (MgSO₄) and concentrated under reduced pressure. Flash chromatography (toluene→19:1, toluene/EtOAc) gave 74.0 mg of PC-55 (44% yield) as an orange solid. ¹H NMR (400 MHz, Chloroform-d) δ 8.35-7.64 (m, 8H), 7.40-7.27 (m, 10H), 6.52-6.44 (m, 2H), 5.29-5.23 (m, 4H), 3.73-3.63 (m, 6H), 3.45-3.29 (m, 2H), 2.84-2.63 (m, 8H), 2.36-2.23 (m, 2H), 1.90-1.81 (m, 6H).

### Example 2.56 PC-56

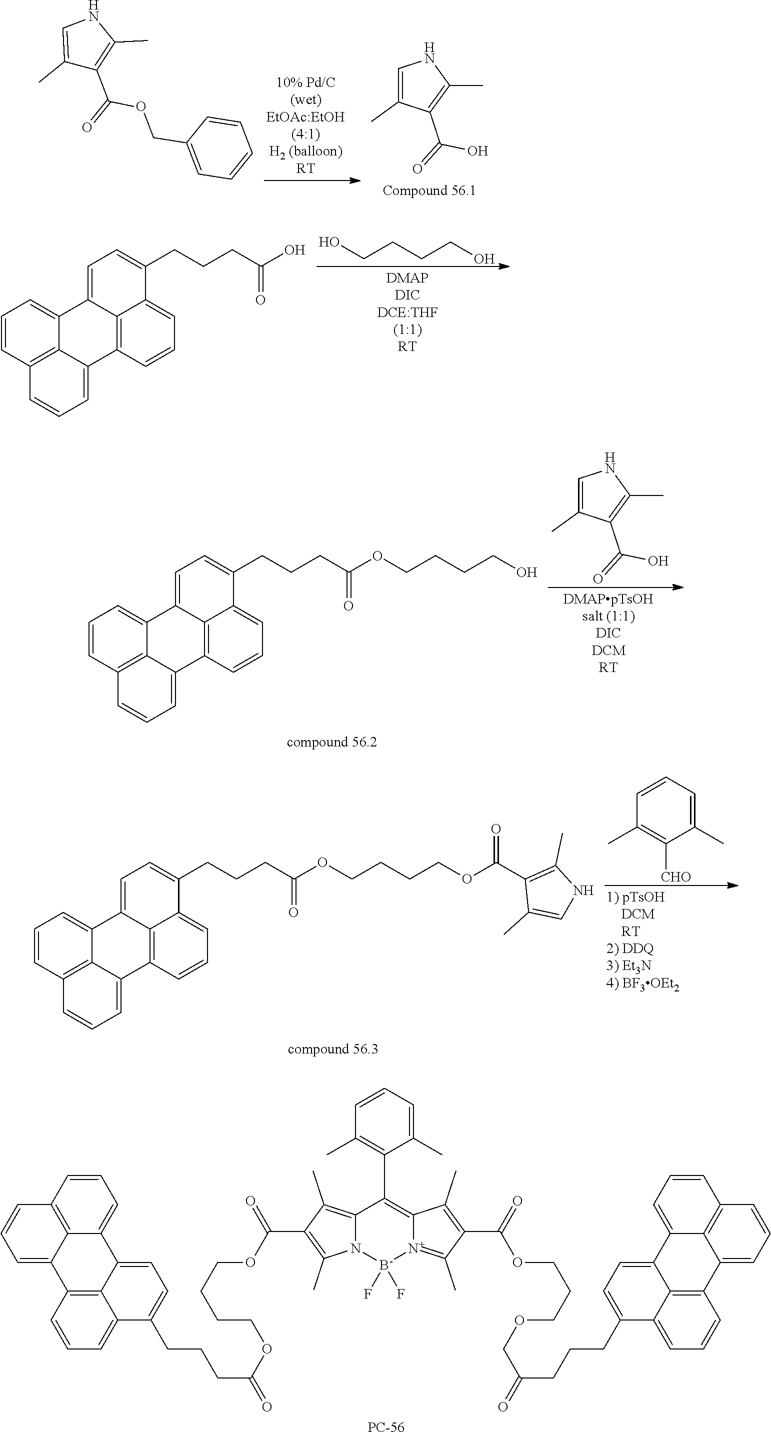

Compound 56.1 (2,4-dimethyl-1H-pyrrole-3-carboxylic acid): Benzyl 2,4-dimethyl-1H-pyrrole-3-carboxylate (5.0 mmol, 1146 mg), 10% Pd/C (wet, 500 mg), and a stir bar were charged into a 500 mL pear-shaped flask. To the flask was added EtOAc (100 mL) and ethanol (200 proof, 20 mL). The flask was sealed with a septum and the head space evacuated under vacuum with stirring at room temperature. The atmosphere was replaced with hydrogen from a balloon. The vacuum/backfill-H₂ procedure was repeated twice more, then the flask stirred under a hydrogen balloon at room temperature for 3 hours. LCMS indicates complete consumption of starting material. The reaction flask was flushed with argon and the reaction mixture filtered through a pad of Celite. The solvents were evaporated to dryness to give the product in pure form. Gives 696 mg (100% yield). MS (APCI): calculated for Chemical Formula: C₇H₉NO₂ (M+H)=140 found: 140. ¹H NMR (400 MHz, TCE-d₂) δ 11.07 (br s, 1H), 8.06 (br s, 1H), 6.41 (s, 1H), 2.52 (s, 3H), 2.26 (s, 3H).

Compound 56.2 (4-hydroxybutyl 4-(perylen-3-yl)butanoate): A 40 mL screw cap vial was charged with a stir bar Compound 56.2 was synthesized from 4-(perylen-3-yl)butanoic acid (1.0 mmol, 338 mg), 1,4-butanediol 50.0 mmol, and DMAP (0.200 mmol, 59 mg), in 4.42 mL in anhydrous THF (50 mL) and anhydrous DCM (50 mL). Diisopropylcarbodiimide (0.300 mmol, 47 uL) was added and the reaction was stirred under argon at room temperature overnight. The next morning, added anhydrous tetrahydrofuran (10 mL) and sonicated for 30 seconds. The crude product was purified by flash chromatography on silica gel (10% EtOAc/DM (1 CV)→40% EtOAc/DCM (20 CV)). Fractions containing product were evaporated to dryness to give a yellow solid. Gives 374 mg (91.0% yield). MS (APCI): calculated for Chemical Formula: C₂₈H₂₆O₃ (M−)=410 found: 410. ¹H NMR (400 MHz, TCE-d₂) δ 8.24 (d, J=7.5 Hz, 1H), 8.20 (d, J=7.7 Hz, 1H), 8.18 (d, J=7.7 Hz, 1H), 8.14 (d, J=7.7 Hz, 1H), 7.92 (d, J=8.5 Hz, 1H), 7.71 (d, J=5.9 Hz, 1H), 7.69 (d, J=5.9 Hz, 1H), 7.56 (t, J=7.9 Hz, 1H), 7.51 (t, J=7.8 Hz, 1H), 7.50 (t, J=7.8 Hz, 1H), 7.37 (d, J=7.7 Hz, 1H), 4.12 (t, J=6.5 Hz, 2H), 3.65 (q, J=6.0 Hz, 2H), 3.07 (t, J=7.7 Hz, 2H), 2.46 (t, J=7.3 Hz, 2H), 2.10 (p, J=7.4 Hz, 2H), 1.78-1.67 (m, 2H), 1.67-1.58 (m, 2H), 1.34 (t, J=5.3 Hz, 1H).

Compound 56.3 (4-((4-(perylen-3-yl)butanoyl)oxy)butyl 2,4-dimethyl-1H-pyrrole-3-carboxylate): A 40 mL screw cap vial was charged with a stir bar, Compound 56.1 (600 μmol, 84 mg) and Compound 56.2 (500 μmol, 205 mg), and DMAP:pTsOH 1:1 salt (0.200 mmol, 59 mg). The vial was flushed with argon and anhydrous dichloromethane (20 mL) was added. Diisopropylcarbodiimide (0.300 mmol, 47 uL) was added and the reaction was stirred under argon at room temperature overnight. The next morning, added anhydrous tetrahydrofuran (10 mL) and sonicated for 30 seconds. Added an additional portion of 4-(perylen-3-yl)butanoic acid (0.150 mmol, 51 mg) and stirred at 50° C. under argon overnight. To force the reaction closer to completion, the reaction was heated to 50° C. and more of Compound 56.1 (2×600 μmol, 84 mg) were added. The conversion plateaued, so the crude product was purified by flash chromatography on silica gel (100% DCM (1 CV)→10% EtOAc/DCM (10 CV)). Fractions containing product were evaporated to dryness to give a yellowish solid. Gives 158 mg (59.4% yield). MS (APCI): calculated for Chemical Formula: C₃₅H₃₃NO₄ (M−)=531 found: 531. ¹H NMR (400 MHz, TCE-d₂) δ 8.23 (dd, J=7.6, 0.7 Hz, 1H), 8.20 (dd, J=7.7, 1.0 Hz, 1H), 8.17 (dd, J=7.7, 1.0 Hz, 1H), 8.14 (d, J=7.7 Hz, 1H), 7.94 (s, 1H), 7.92 (d, J=8.5 Hz, 1H), 7.71 (d, J=5.8 Hz, 1H), 7.69 (d, J=5.7 Hz, 1H), 7.57 (d, J=7.7 Hz, 1H), 7.55 (d, J=7.6 Hz, 1H), 7.51 (t, J=7.6 Hz, 1H), 7.50 (t, J=7.8 Hz, 1H), 7.36 (d, J=7.7 Hz, 1H), 6.36 (dd, J=2.3, 1.2 Hz, 1H), 4.28-4.20 (m, 2H), 4.19-4.11 (m, 2H), 3.12-3.04 (m, 2H), 2.46 (t, J=7.3 Hz, 2H), 2.46 (s, 3H), 2.22 (d, J=1.1 Hz, 3H), 2.10 (p, J=7.4 Hz, 2H), 1.85-1.76 (m, 4H).

PC-56 [bis(4-((4-(perylen-3-yl)butanoyl)oxy)butyl) 10-(2,6-dimethylphenyl)-5,5-difluoro-1,3,7,9-tetramethyl-5H-4|4,5|4-dipyrrolo[1,2-c:2′,1′-f][1,3,2]diazaborinine-2,8-dicarboxylate]: A 40 mL screw cap vial was fitted with a screw-cap septum and charged with a stir bar. Compound 56.3 (150 μmol, 80 mg) and 2,6-dimethylbenzaldehyde (82.5 μmol, 11.1 mg), pTsOH.H₂O (15 μmol, 3 mg) in anhydrous DCM (5 mL). The reaction mixture was sparged with argon for 5 minutes, then DDQ (97.5 μmol, 22 mg) was added. The reaction was stirred under argon overnight at room temperature. The next morning, added DDQ (97.5 μmol, 22 mg), and stirred at room temperature for 20 minutes. To the reaction was added triethylamine (450 μmol, 63 uL), and BF₃.OEt₂ (675 μmol, 83 uL) and stirred for 30, then an additional triethylamine (450 μmol, 63 uL), and BF₃.OEt₂ (675 μmol, 83 uL) were added. The reaction was stirred at room temperature for 4 hours, then diluted with EtOAc (50 mL) and washed with 1.25N HCl in water (2×5 mL), saturated NaHCO₃ in water (2×5 mL), 1M NaOH in water (2×5 mL), and brine (1×5 mL). The organic layer was dried with MgSO₄, filtered, and evaporated to dryness. The crude reaction mixture was diluted with EtOAc (100 mL) and extracted with 2N NaOH in water solution (4×20 mL), 2N HCl in water (20 mL), and brine (20 mL). The organic layer was dried over MgSO4, filtered, and evaporated to dryness. The crude product was purified by flash chromatography on silica gel (36% EtOAc/hexanes (1.1 CV)→56% EtOAc/hexanes (3.1 CV), then isocratic 56% EtOAc/hexanes). Fractions containing product were evaporated to dryness to give an orange solid, then dried in a vacuum oven overnight at 50° C. Gives 46 mg (50.0% yield, based on pyrrole). MS (APO): calculated for Chemical Formula: C₇₉H₇₁BF₂N₂O₈ (M−)=1224 found: 1224. ¹H NMR (400 MHz, Chloroform-d) δ 8.22-8.19 (m, 2H), 8.18 (dd, J=7.7, 0.8 Hz, 2H), 8.15 (dd, J=7.6, 0.9 Hz, 2H), 8.11 (d, J=7.7 Hz, 2H), 7.89 (dd, J=8.4, 0.7 Hz, 2H), 7.67 (d, J=5.3 Hz, 2H), 7.65 (d, J=5.3 Hz, 2H), 7.52 (d, J=7.6 Hz, 1H), 7.50 (d, J=7.6 Hz, 1H), 7.49-7.42 (m, 2H), 7.50-7.41 (m, 2H), 7.32 (d, J=7.7 Hz, 2H), 7.25 (dd, J=8.1, 7.1 Hz, 1H), 7.11 (d, J=7.5 Hz, 2H), 4.25 (t, J=6.0 Hz, 4H), 4.12 (t, J=6.0 Hz, 4H), 3.06 (dd, J=8.7, 6.7 Hz, 4H), 2.85 (s, 6H), 2.43 (t, J=7.3 Hz, 4H), 2.15-2.06 (m, 4H), 2.07 (s, 6H), 1.83-1.69 (m, 8H), 1.64 (s, 6H).

### Example 2.57 PC-57

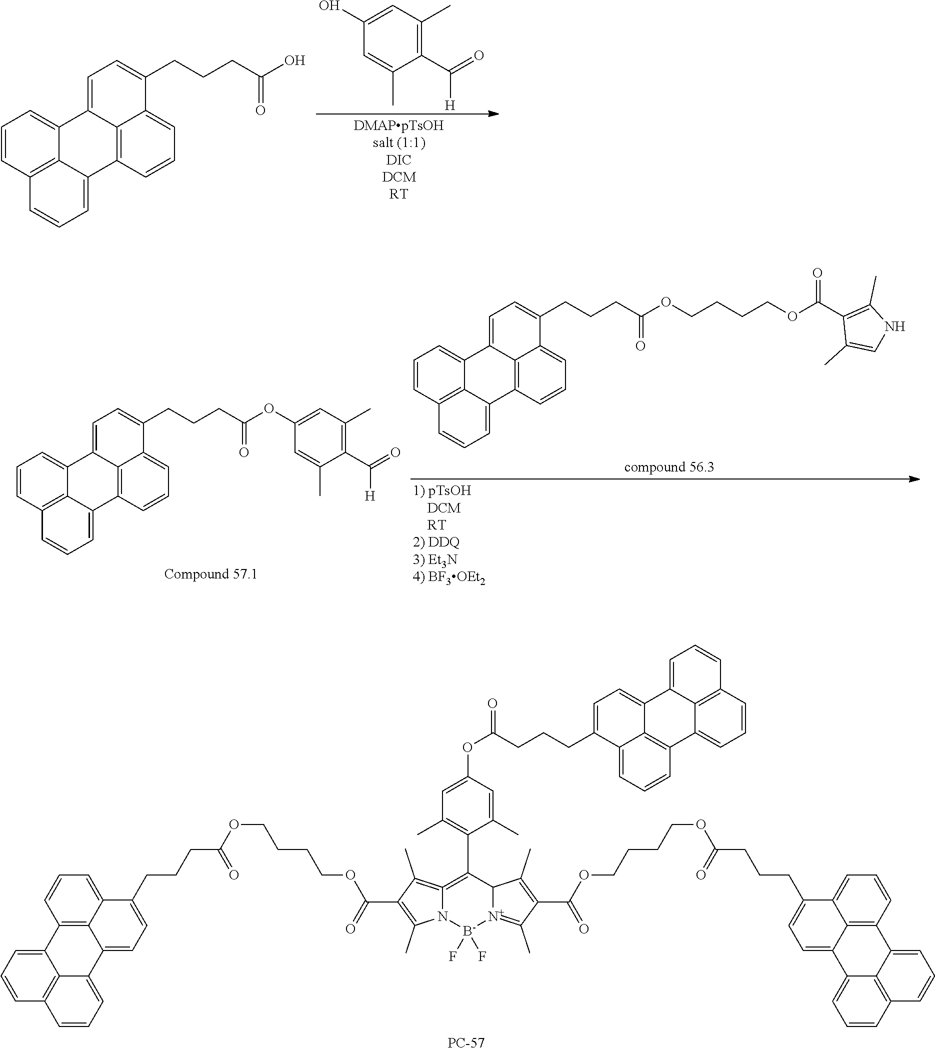

Compound 57.1 [(4-formyl-3,5-dimethylphenyl 4-(perylen-3-yl)butanoate)]: Compound 22.1 was synthesized from 4-hydroxy-2,6-dimethylbenzaldehyde (1.89 mmol, 284 mg) and 4-(perylen-3-yl)butanoic acid (0.946 mmol, 320 mg) in a manner similar to Compound 2. A 40 mL screw cap vial was charged with a stir bar, 4-hydroxy-2,6-dimethylbenzaldehyde (1.89 mmol, 284 mg) and 4-(perylen-3-yl)butanoic acid (0.946 mmol, 320 mg) and DMAP:pTsOH 1:1 salt (0.200 mmol, 59 mg). The vial was flushed with argon and anhydrous dichloromethane (20 mL) was added. Diisopropylcarbodiimide (0.300 mmol, 47 uL) was added and the reaction was stirred under argon at room temperature overnight. The next morning, added anhydrous tetrahydrofuran (10 mL) and sonicated for 30 seconds. Added an additional portion of 4-(perylen-3-yl)butanoic acid (0.150 mmol, 51 mg) and stirred at 50° C. under argon overnight. The crude product was purified by flash chromatography on silica gel (100% toluene, (5 CV)→10% EtOAc/toluene (10 CV). Fractions containing product were evaporated to dryness. Gives 296 mg (66.5% yield) of an orange solid. MS (APO): calculated for Chemical Formula: C₃₃H₂₆O₃ (M−)=470 found: 470. ¹H NMR (400 MHz, TCE-d₂) δ 10.52 (s, 1H), 8.25 (d, J=7.5 Hz, 1H), 8.23-8.17 (m, 2H), 8.16 (d, J=7.8 Hz, 1H), 7.94 (d, J=8.4 Hz, 1H), 7.72 (d, J=5.1 Hz, 1H), 7.70 (d, J=5.1 Hz, 1H), 7.57 (t, J=8.0 Hz, 1H), 7.51 (t, J=7.8 Hz, 1H), 7.51 (t, J=7.8 Hz, 1H), 7.40 (d, J=7.7 Hz, 1H), 6.84 (s, 2H), 3.17 (t, J=7.6 Hz, 2H), 2.72 (t, J=7.2 Hz, 2H), 2.58 (s, 6H), 2.23 (p, J=7.3 Hz, 2H).

PC-57 [bis(4-((4-(perylen-3-yl)butanoyl)oxy)butyl) 10-(2,6-dimethyl-4-((4-(perylen-3-yl)butanoyl)oxy)phenyl)-5,5-difluoro-1,3,7,9-tetramethyl-5H-4|4,5|4-dipyrrolo[1,2-c:2′,1′-f][1,3,2]diazaborinine-2,8-dicarboxylate]: PC-57 was synthesized from Compound 56.3 (130 μmol, 69.3 mg) and Compound 57.1 (65.2 μmol, 30.7 mg) in a manner similar to PC-56, including a double addition of 6 eq triethylamine and 9 eq of BF₃.OEt₂. The crude reaction mixture was worked up in the same way as PC-56. The crude product was purified by flash chromatography on silica gel (36% EtOAc/hex (1.1 CV)→60% EtOAc/hexanes (4 CV)→60% isocratic). Compound elutes with impurities. Fractions containing product were evaporated to dryness and repurified by flash chromatography on silica gel (100% toluene (1 CV)→10% EtOAc/toluene (10 CV)). Still eluted with some impurities. Fractions containing product were evaporated to dryness and repurified by flash chromatography on silica gel (100% DCM (1 CV)→1% EtOAc/DCM (1 CV), isocratic 1% EtOAc/DCM (1 CV)→2% EtOAc/DCM (0 CV)→isocratic 2% EtOAc/DCM (3 CV)→4% EtOAc/DCM (0 CV)→isocratic 4% EtOAc/DCM (1 CV)→6% EtOAc/DCM (0 CV)→6% isocratic until compound elutes). Fractions containing pure PC-57 were evaporated to dryness to give an orangish solid. Givers 13 mg (12.7% yield, based on pyrrole). MS (APCI): calculated for Chemical Formula: C₁₀₃H₈₇BF₂N₂O₁₀ (M−)=1560 found: 1560. ¹H NMR (400 MHz, Chloroform-d) δ 8.19-8.05 (m, 12H), 7.90-7.84 (m, 3H), 7.65 (d, J=5.5 Hz, 3H), 7.63 (d, J=5.3 Hz, 3H), 7.46 (dtd, J=19.4, 7.8, 2.8 Hz, 9H), 7.33 (d, J=7.7 Hz, 1H), 7.29 (d, J=7.7 Hz, 2H), 6.88 (s, 2H), 4.26 (t, J=6.0 Hz, 4H), 4.12 (t, J=5.9 Hz, 4H), 3.13 (t, J=7.6 Hz, 2H), 3.04 (dd, J=8.7, 6.7 Hz, 4H), 2.85 (s, 6H), 2.66 (t, J=7.2 Hz, 2H), 2.43 (t, J=7.3 Hz, 4H), 2.21 (p, J=7.3 Hz, 2H), 2.15-2.06 (m, 4H), 2.04 (s, 6H), 1.83-1.70 (m, 7H), 1.69 (s, 6H).

### Example 3 Fabrication of Color Conversion Film

A glass substrate was prepared in substantially the following manner. A 1.1 mm thick glass substrate measuring 1-inch×1-inch was cut to size. The glass substrate was then washed with detergent and deionized (DI) water, rinsed with fresh DI water, and sonicated for about 1 hour. The glass was then soaked in isopropanol (IPA) and sonicated for about 1 hour. The glass substrate was then soaked in acetone and sonicated for about 1 hour. The glass was then removed from the acetone bath and dried with nitrogen gas at room temperature.

A 20 wt % solution of Poly(methylmethacrylate) (PMMA) (average M.W. 120,000 by GPC from MilliporeSigma, Burlington, Mass., USA) copolymer in cyclopentanone (99.9% pure) was prepared. The prepared copolymer was stirred overnight at 40° C. [PMMA] CAS: 9011-14-7; [Cyclopentanone] CAS: 120-92-3

The 20% PMMA solution prepared above (4 g) was added to 3 mg of the photoluminescent complex made as described above in a sealed container and mixed for about 30 minutes. The PMMA/lumiphore solution was then spin coated onto a prepared glass substrate at 1000 RPM for 20 s and then 500 RPM for 5 s. The resulting wet coating had a thickness of about 10 μm. Any suitable thickness of the coating may be used, for example about 10-20 μm, about 20-30 μm, about 30-40 μm, about 40-50 μm, about 50-60 μm, about 20-40 μm, about 40-80 μm, about 20 μm, about 30 μm, or about 40 μm. The samples were covered with aluminum foil before spin coating to protect them from exposure to light. Three samples each were prepared in this manner for each for Emission/FWHM and quantum yield. The spin coated samples were baked in a vacuum oven at 80° C. for 3 hours to evaporate the remaining solvent.

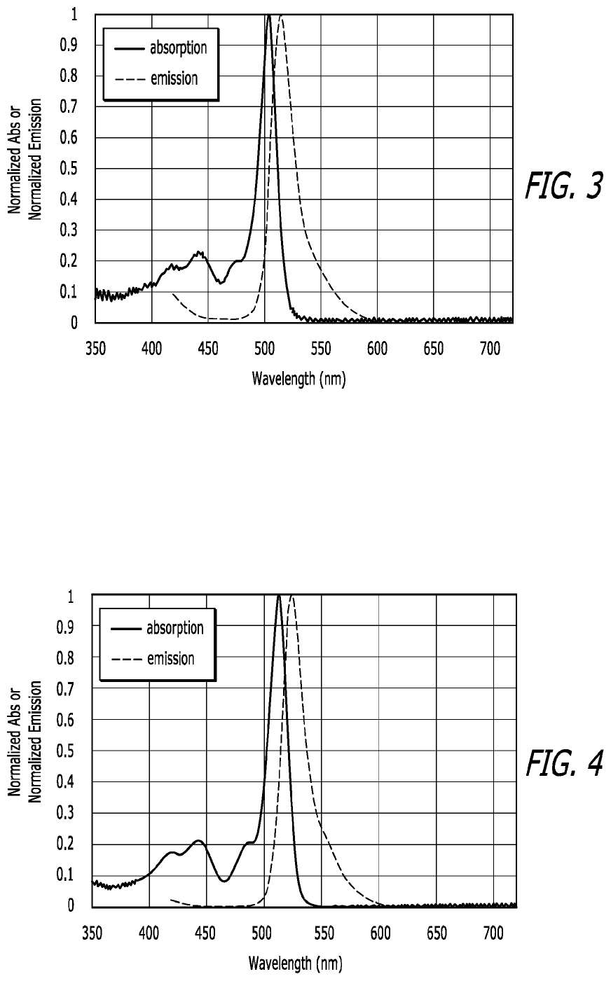

The 1-inch×1-inch sample was inserted into a Shimadzu, UV-3600 UV-VIS-NIR spectrophotometer (Shimadzu Instruments, Inc., Columbia, Md., USA). All device operations were performed inside a nitrogen-filled glove-box. The resulting absorption/emission spectrum for PC-8 is shown in FIG. 1, while the resulting absorption/emission spectrum for PC-33 is shown in FIG. 2, PC-46 is shown in FIG. 3, and PC-56 is shown in FIG. 4.

The fluorescence spectrum of a 1-inch×1-inch film sample prepared as described above was determined using a Fluorolog spectrofluorometer (Horiba Scientific, Edison, N.J., USA) with the excitation wavelength set at the respective maximum absorbance wavelength. The maximum emission and FWHM are shown in Table 1.

The quantum yield of a 1-inch×1-inch sample prepared as described above were determined using a Quantarus-QY spectrophotometer (Hamamatsu Inc., Campbell Calif., USA) was excited at the respective maximum absorbance wavelength. The results are reported in Table 1.

The results of the film characterization (absorbance peak wavelength, FWHM, and quantum yield) are shown in Table 1, below.

### Example 4 Photostability

Photostability of the photoluminescent complexes were performed on 1-inch×1-inch samples; comprising PMMA as described above herein. The photoluminescent complexes were individually included with PMMA film samples at a concentration of 2×10⁻³ M. The samples were then exposed to a blue LED light source (Inspired LED, Tempe, Ariz., USA) with an emission peak of 465 nm, at room temperature. The Blue LED light was incorporated into a 1-inch×12-inch U channel with commercial diffuser film placed on top of the U channel to give a uniform light distribution. The 1-inch×1-inch samples were placed on top of the diffuser. The average irradiance at the sample was ˜1.5 mW/cm².

Absorption at peak absorption wavelength was measured before and after film had been exposed to the LED light for 165 h, 330 h, 500 h respectively. The samples absorption was measured using a UV-vis 3600 (Shimadzu Manufacturing Company, Kyoto, Japan) Photostability was measured by dividing the absorption remaining after exposure by the absorption before exposure time. The results are shown in Table 2, below.

TABLE 1

| | | | | | Quantum |
|---|---|---|---|---|---|
| | | | | Φ@450 | Yield in |
| | | Emis- | | nm | Film |
| | | sion | FWHM | excitation | (PMMA) |
| Cpd. | Structure | (nm) | (nm) | (Toluene) | @450 nm |
| CE-1 | 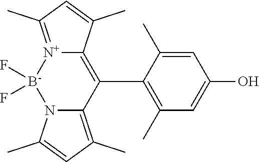 [SMILES: CC1=CC(C)=[N+]2C1=C(c1c(C)cc(O)cc1C)c1c(C)cc(C)n1[B-]2(F)F] | 512 | 24 | <1% | |
| CE-2 | 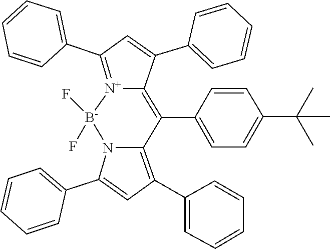 [SMILES: CC(C)(C)c1ccc(C2=C3C(c4ccccc4)=CC(c4ccccc4)=[N+]3[B-](F)(F)n3c(-c4ccccc4)cc(-c4ccccc4)c32)cc1] | 592 | 37 | <1% | |
| PC-1 | 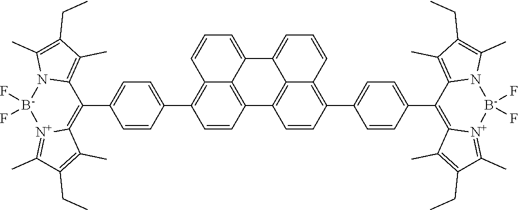 [SMILES: CCC1=C(C)C2=C(c3ccc(-c4ccc5c6ccc(-c7ccc(C8=C9C(C)=C(CC)C(C)=[N+]9[B-](F)(F)n9c(C)c(CC)c(C)c98)cc7)c7cccc(c8cccc4c85)c76)cc3)c3c(C)c(CC)c(C)n3[B-](F)(F)[N+]2=C1C] | 539 | 32 | 72% | 68.6% |
| PC-2 | 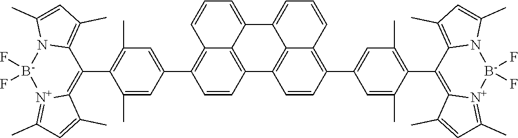 [SMILES: CC1=CC(C)=[N+]2C1=C(c1c(C)cc(-c3ccc4c5ccc(-c6cc(C)c(C7=C8C(C)=CC(C)=[N+]8[B-](F)(F)n8c(C)cc(C)c87)c(C)c6)c6cccc(c7cccc3c74)c65)cc1C)c1c(C)cc(C)n1[B-]2(F)F] | 516 | 29 | 83% | 75% |
| PC-3 | 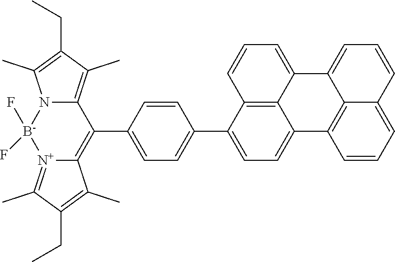 [SMILES: CCC1=C(C)C2=C(c3ccc(-c4ccc5c6cccc7cccc(c8cccc4c85)c76)cc3)c3c(C)c(CC)c(C)n3[B-](F)(F)[N+]2=C1C] | 533 | 33 | 66% | |
| PC-4 | 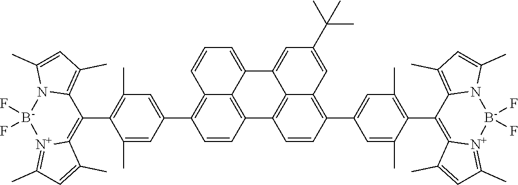 [SMILES: CC1=CC(C)=[N+]2C1=C(c1c(C)cc(-c3ccc4c5ccc(-c6cc(C)c(C7=C8C(C)=CC(C)=[N+]8[B-](F)(F)n8c(C)cc(C)c87)c(C)c6)c6cc(C(C)(C)C)cc(c7cccc3c47)c65)cc1C)c1c(C)cc(C)n1[B-]2(F)F] | 511 | 22 | 80% | 57.4% |
| PC-5 | 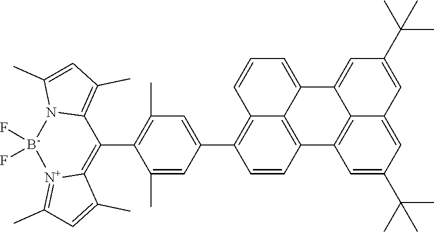 [SMILES: CC1=CC(C)=[N+]2C1=C(c1c(C)cc(-c3ccc4c5cc(C(C)(C)C)cc6cc(C(C)(C)C)cc(c7cccc3c74)c65)cc1C)c1c(C)cc(C)n1[B-]2(F)F] | 510 | 21 | 81.3% | 60.3% |
| PC-6 | 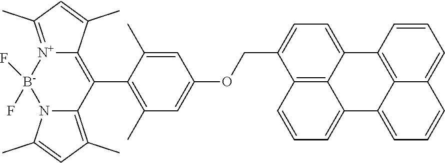 [SMILES: CC1=CC(C)=[N+]2C1=C(c1c(C)cc(OCc3ccc4c5cccc6cccc(c7cccc3c74)c65)cc1C)c1c(C)cc(C)n1[B-]2(F)F] | 514 | 23 | 83.7% | 70.3% |
| PC-7 | 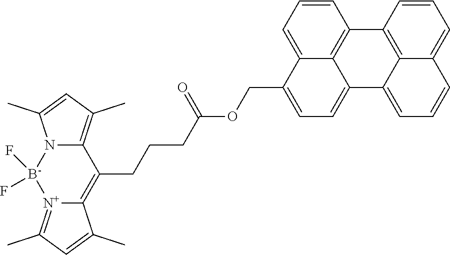 [SMILES: CC1=CC(C)=[N+]2C1=C(CCCC(=O)OCc1ccc3c4cccc5cccc(c6cccc1c63)c54)c1c(C)cc(C)n1[B-]2(F)F] | 510 | 26 | 79.4% | 48.1% |
| PC-8 | 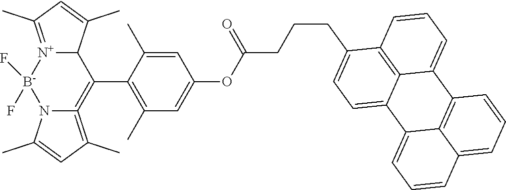 | 518 | 23 | 90% | 66.7% |
| PC-9 | 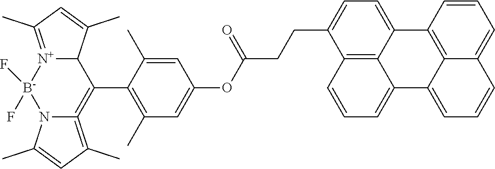 | 514 | 23 | 88.4% | 73.8% |
| PC-10 | 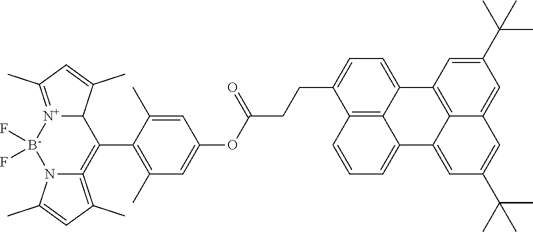 | 513 | 24 | 96.7% | 66.7% |
| PC-11 | 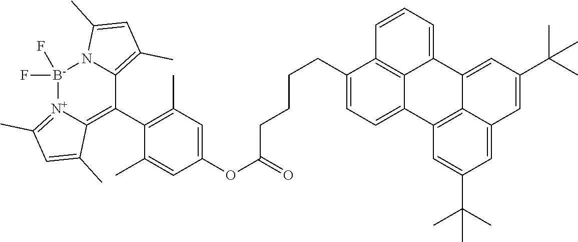 [SMILES: CC1=CC(C)=[N+]2C1=C(c1c(C)cc(OC(=O)CCCCc3ccc4c5cc(C(C)(C)C)cc6cc(C(C)(C)C)cc(c7cccc3c74)c65)cc1C)c1c(C)cc(C)n1[B-]2(F)F] | 513 | 21 | 98.5% | 60% |
| PC-12 | 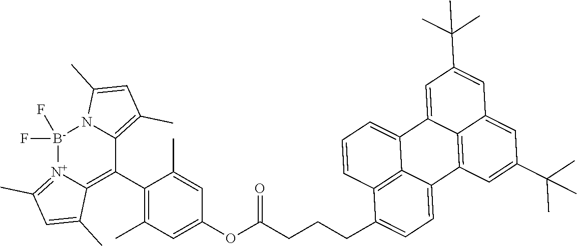 [SMILES: CC1=CC(C)=[N+]2C1=C(c1c(C)cc(OC(=O)CCCc3ccc4c5cc(C(C)(C)C)cc6cc(C(C)(C)C)cc(c7cccc3c74)c65)cc1C)c1c(C)cc(C)n1[B-]2(F)F] | 513 | 25 | 100% | 63.5% |
| PC-13 | 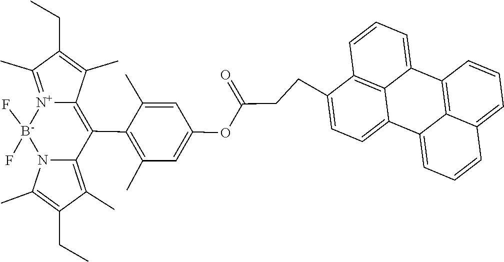 [SMILES: CCC1=C(C)C2=C(c3c(C)cc(OC(=O)CCc4ccc5c6cccc7cccc(c8cccc4c85)c76)cc3C)c3c(C)c(CC)c(C)n3[B-](F)(F)[N+]2=C1C] | 536 | 25 | 85% | 65.2% |
| PC-14 | 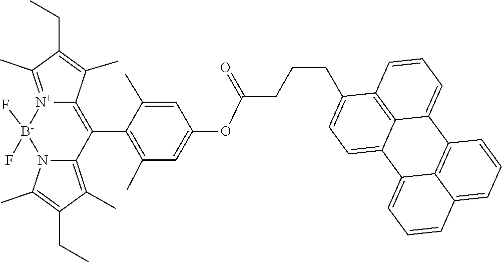 [SMILES: CCC1=C(C)C2=C(c3c(C)cc(OC(=O)CCCc4ccc5c6cccc7cccc(c8cccc4c85)c76)cc3C)c3c(C)c(CC)c(C)n3[B-](F)(F)[N+]2=C1C] | 536 | 26 | 83.5% | 65.5% |
| PC-15 | 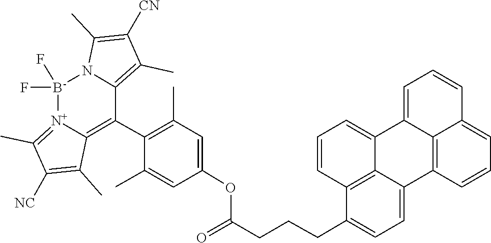 [SMILES: CC1=C(C#N)C(C)=[N+]2C1=C(c1c(C)cc(OC(=O)CCCc3ccc4c5cccc6cccc(c7cccc3c74)c65)cc1C)c1c(C)c(C#N)c(C)n1[B-]2(F)F] | 521 | 21 | 12% | 15% |
| PC-16 | 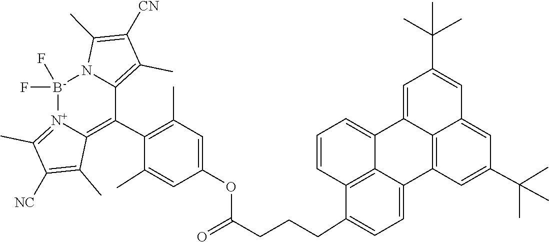 [SMILES: CC1=C(C#N)C(C)=[N+]2C1=C(c1c(C)cc(OC(=O)CCCc3ccc4c5cc(C(C)(C)C)cc6cc(C(C)(C)C)cc(c7cccc3c74)c65)cc1C)c1c(C)c(C#N)c(C)n1[B-]2(F)F] | 515 | 22 | 9.5% | |
| PC-17 | 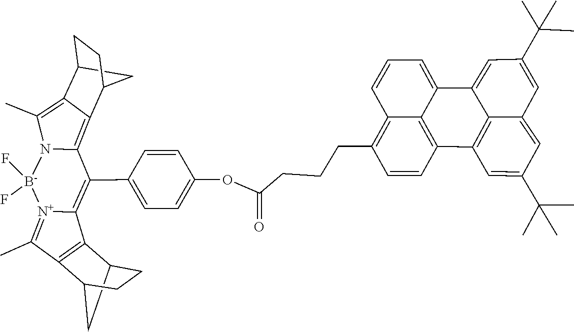 [SMILES: C/C1=[NH+]\[B-](F)(F)n2c(C)c3c(c2/C(c2ccc(OC(=O)CCCc4ccc5c6cc(C(C)(C)C)cc7cc(C(C)(C)C)cc(c8cccc4c85)c76)cc2)=C(\C)C2=C1C1CCC2C1)C1CCC3C1] | 876 | 32 | 82.3% | 50% |
| PC-18 | 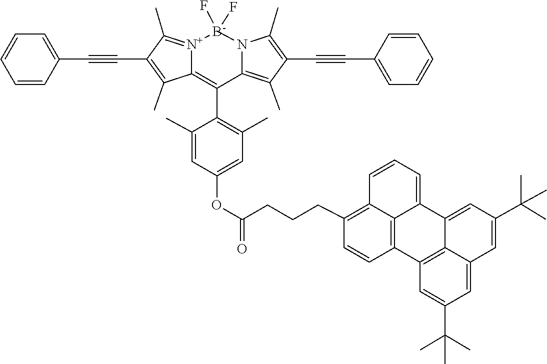 | 596 | 40 | 76.7% | 12.6% |
| PC-19 | 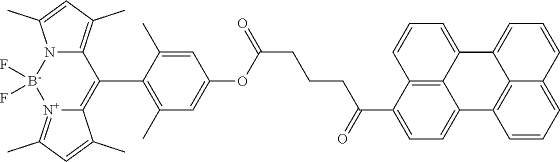 [SMILES: CC1=CC(C)=[N+]2C1=C(c1c(C)cc(OC(=O)CCCC(=O)c3ccc4c5cccc6cccc(c7cccc3c74)c65)cc1C)c1c(C)cc(C)n1[B-]2(F)F] | 716 | 23 | 96% | 69.2% |
| PC-20 | 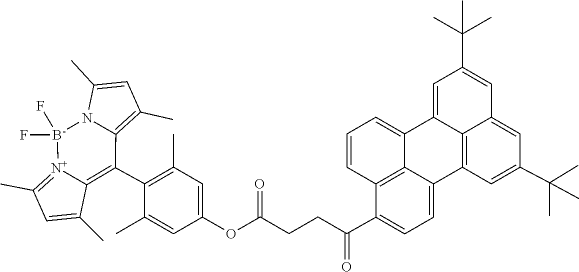 [SMILES: CC1=CC(C)=[N+]2C1=C(c1c(C)cc(OC(=O)CCC(=O)c3ccc4c5cc(C(C)(C)C)cc6cc(C(C)(C)C)cc(c7cccc3c74)c65)cc1C)c1c(C)cc(C)n1[B-]2(F)F] | 512 | 22 | 100% | 68% |
| PC-31 | 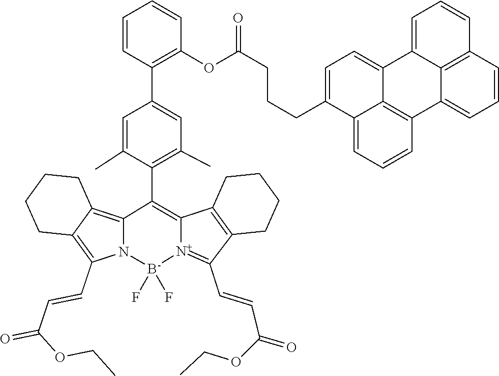 [SMILES: CCOC(=O)/C=C/C1=[N+]2C(=C(c3c(C)cc(-c4ccccc4OC(=O)CCCc4ccc5c6cccc7cccc(c8cccc4c85)c76)cc3C)c3c4c(c(/C=C/C(=O)OCC)n3[B-]2(F)F)CCCC4)C2=C1CCCC2] | 617 | 27 | 12.3% | 0% |
| PC-32 | 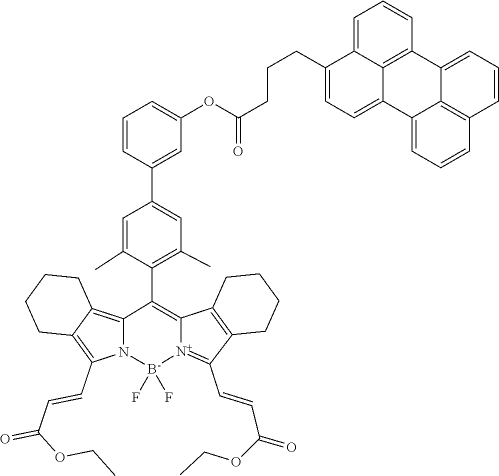 [SMILES: CCOC(=O)/C=C/C1=[N+]2C(=C(c3c(C)cc(-c4cccc(OC(=O)CCCc5ccc6c7cccc8cccc(c9cccc5c96)c87)c4)cc3C)c3c4c(c(/C=C/C(=O)OCC)n3[B-]2(F)F)CCCC4)C2=C1CCCC2] | 617 | 26 | 90% | 42% |
| PC-33 | 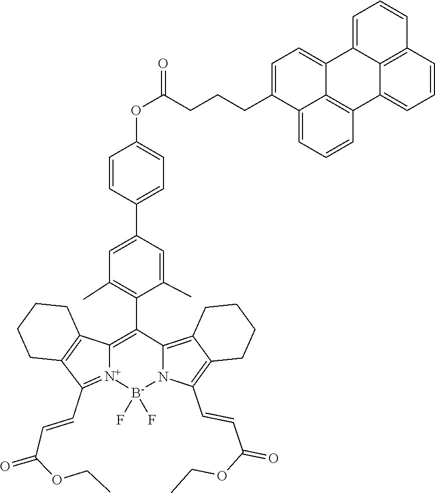 [SMILES: CCOC(=O)/C=C/C1=[N+]2C(=C(c3c(C)cc(-c4ccc(OC(=O)CCCc5ccc6c7cccc8cccc(c9cccc5c96)c87)cc4)cc3C)c3c4c(c(/C=C/C(=O)OCC)n3[B-]2(F)F)CCCC4)C2=C1CCCC2] | 618 | 27 | 93.2% | 50% |
| PC-34 | 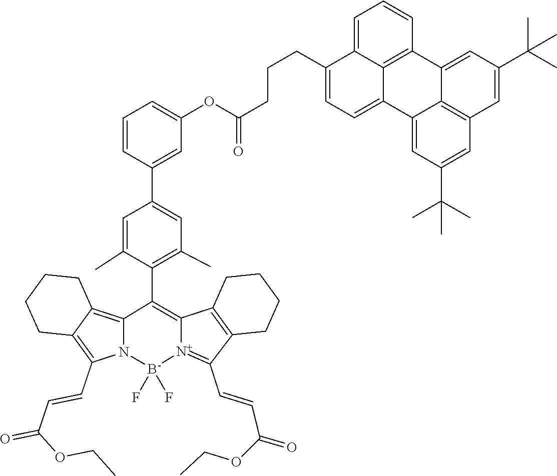 [SMILES: CCOC(=O)/C=C/C1=[N+]2C(=C(c3c(C)cc(-c4cccc(OC(=O)CCCc5ccc6c7cc(C(C)(C)C)cc8cc(C(C)(C)C)cc(c9cccc5c96)c87)c4)cc3C)c3c4c(c(/C=C/C(=O)OCC)n3[B-]2(F)F)CCCC4)C2=C1CCCC2] | 618 | 26 | 86% | 41.4% |
| PC-35 | 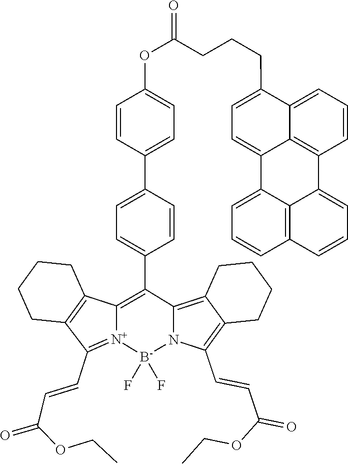 [SMILES: CCOC(=O)/C=C/C1=[N+]2C(=C(c3ccc(-c4ccc(OC(=O)CCCc5ccc6c7cccc8cccc(c9cccc5c96)c87)cc4)cc3)c3c4c(c(/C=C/C(=O)OCC)n3[B-]2(F)F)CCCC4)C2=C1CCCC2] | 619 | 26 | 93.4% | 41.3% |
| PC-36 | 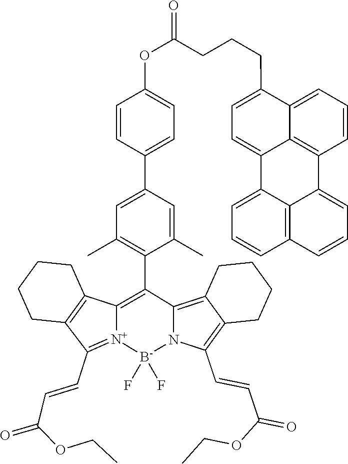 [SMILES: CCOC(=O)/C=C/C1=[N+]2C(=C(c3c(C)cc(-c4ccc(OC(=O)CCCc5ccc6c7cccc8cccc(c9cccc5c96)c87)cc4)cc3C)c3c4c(c(/C=C/C(=O)OCC)n3[B-]2(F)F)CCCC4)C2=C1CCCC2] | 615 | 24 | 96.6% | 38% |
| PC-37 | 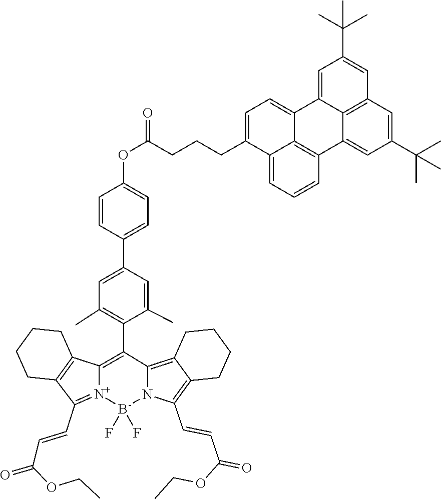 [SMILES: CCOC(=O)/C=C/C1=[N+]2C(=C(c3c(C)cc(-c4ccc(OC(=O)CCCc5ccc6c7cc(C(C)(C)C)cc8cc(C(C)(C)C)cc(c9cccc5c96)c87)cc4)cc3C)c3c4c(c(/C=C/C(=O)OCC)n3[B-]2(F)F)CCCC4)C2=C1CCCC2] | 619 | 25 | 89.8% | 46.6% |
| PC-38 | 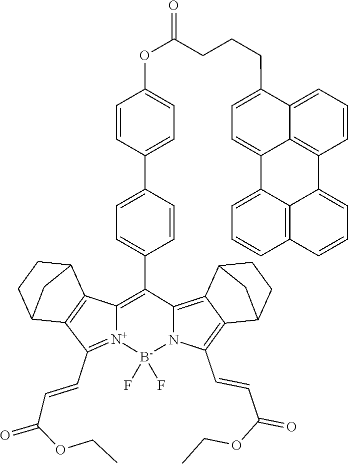 [SMILES: CCOC(=O)/C=C/C1=[N+]2C(=C(c3ccc(-c4ccc(OC(=O)CCCc5ccc6c7cccc8cccc(c9cccc5c96)c87)cc4)cc3)c3c4c(c(/C=C/C(=O)OCC)n3[B-]2(F)F)C2CCC4C2)C2=C1C1CCC2C1] | 620 | 27 | 88.8% | 44.6% |
| PC-39 | 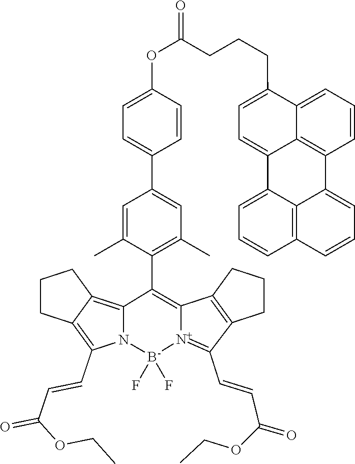 [SMILES: CCOC(=O)/C=C/C1=[N+]2C(=C(c3c(C)cc(-c4ccc(OC(=O)CCCc5ccc6c7cccc8cccc(c9cccc5c96)c87)cc4)cc3C)c3c4c(c(/C=C/C(=O)OCC)n3[B-]2(F)F)CCC4)C2=C1CCC2] | 615 | 24 | 96.6% | 38% |
| PC-40 | 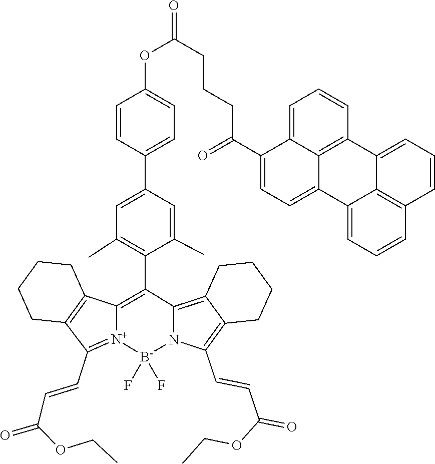 [SMILES: CCOC(=O)/C=C/C1=[N+]2C(=C(c3c(C)cc(-c4ccc(OC(=O)CCCC(=O)c5ccc6c7cccc8cccc(c9cccc5c96)c87)cc4)cc3C)c3c4c(c(/C=C/C(=O)OCC)n3[B-]2(F)F)CCCC4)C2=C1CCCC2] | 620 | 25 | 100% | 49.5% |
| PC-41 | 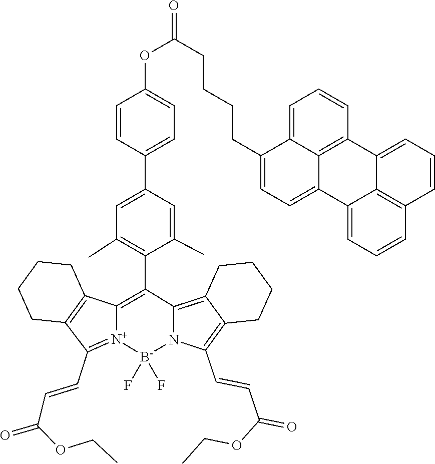 [SMILES: CCOC(=O)/C=C/C1=[N+]2C(=C(c3c(C)cc(-c4ccc(OC(=O)CCCCc5ccc6c7cccc8cccc(c9cccc5c96)c87)cc4)cc3C)c3c4c(c(/C=C/C(=O)OCC)n3[B-]2(F)F)CCCC4)C2=C1CCCC2] | 619 | 26 | 85.2% | 45.1% |
| PC-42 | 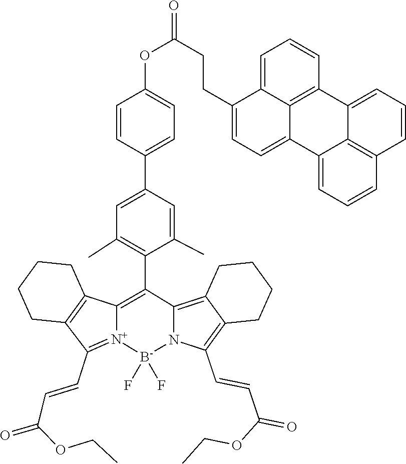 [SMILES: CCOC(=O)/C=C/C1=[N+]2C(=C(c3c(C)cc(-c4ccc(OC(=O)CCc5ccc6c7cccc8cccc(c9cccc5c96)c87)cc4)cc3C)c3c4c(c(/C=C/C(=O)OCC)n3[B-]2(F)F)CCCC4)C2=C1CCCC2] | 618 | 26 | 98.6% | 48.1% |
| PC-43 | 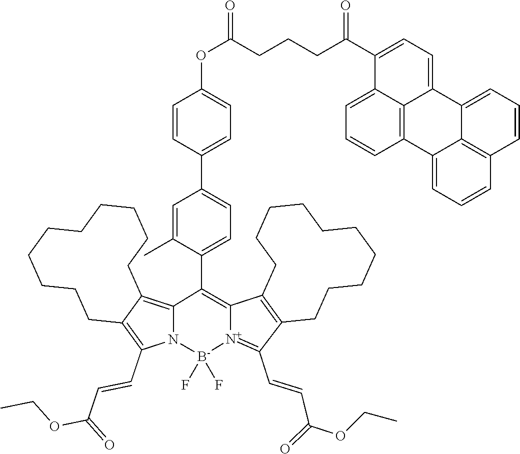 [SMILES: CCOC(=O)/C=C/C1=[N+]2C(=C(c3ccc(-c4ccc(OC(=O)CCCC(=O)c5ccc6c7cccc8cccc(c9cccc5c96)c87)cc4)cc3C)c3c4c(c(/C=C/C(=O)OCC)n3[B-]2(F)F)CCCCCCCCCC4)C2=C1CCCCCCCCCC2] | 614 | 30 | 90.2% | 51.5% |
| PC-44 | 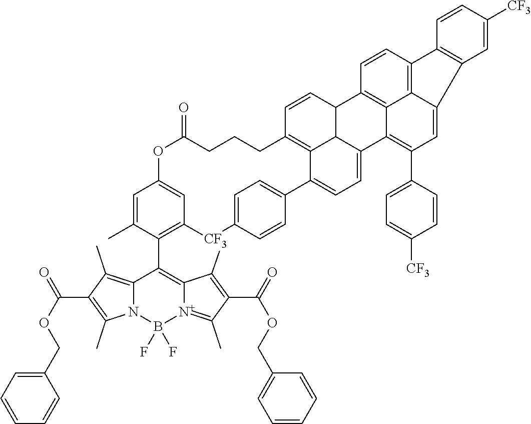 | 514 | 22 | | 70% |
| PC-45 | 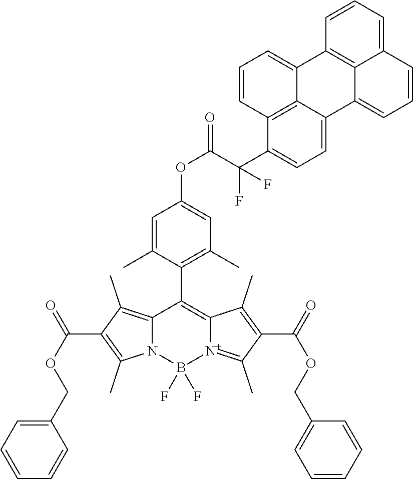 | 515 | 22 | | 77% |
| PC-46 | 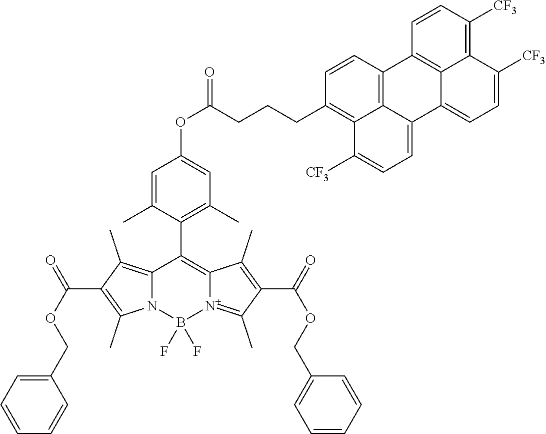 | 514 | 23 | | 96% |
| PC-47 | 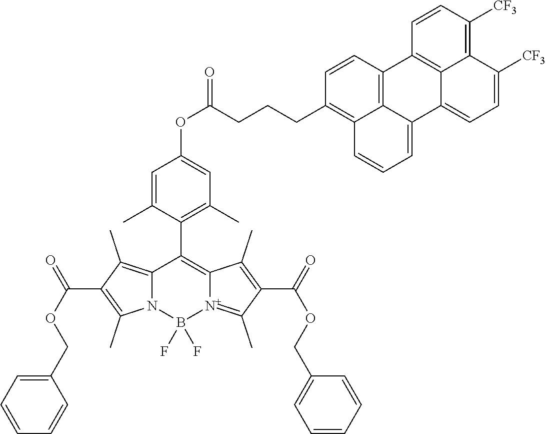 | 514 | 22 | | 94% |
| PC-48 | 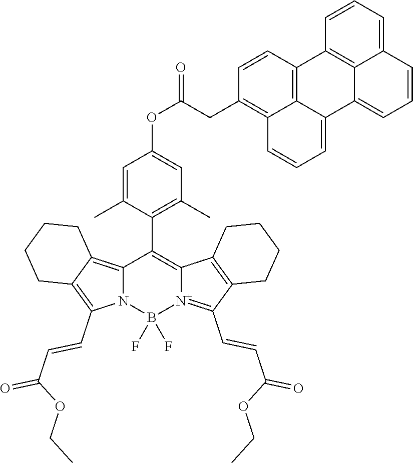 | 618 | 26 | 86% | 73% |
| PC-49 | 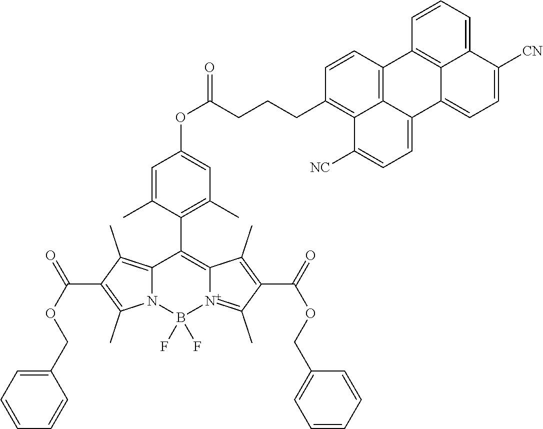 | 515 | 23 | | 82% |
| PC-50 | 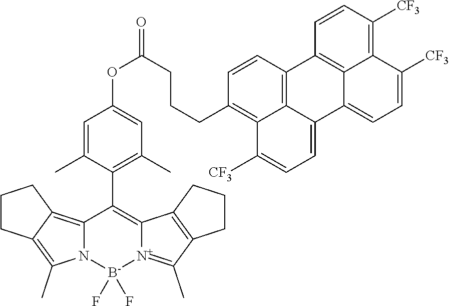 [SMILES: CC1=[N+]2C(=C(c3c(C)cc(OC(=O)CCCc4ccc5c6ccc(C(F)(F)F)c7c(C(F)(F)F)ccc(c8ccc(C(F)(F)F)c4c58)c76)cc3C)c3c4c(c(C)n3[B-]2(F)F)CCC4)C2=C1CCC2] | 537 | 27 | | 87% |
| PC-51 | 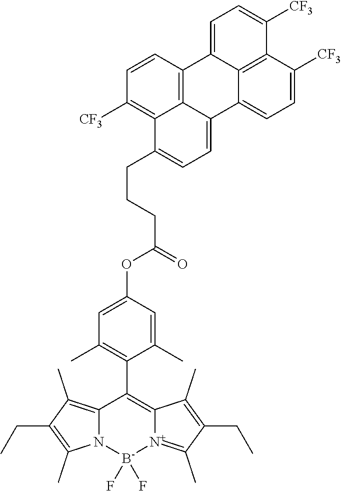 [SMILES: CCC1=C(C)C2=C(c3c(C)cc(OC(=O)CCCc4ccc5c6ccc(C(F)(F)F)c7c(C(F)(F)F)ccc(c8ccc(C(F)(F)F)c4c58)c76)cc3C)c3c(C)c(CC)c(C)n3[B-](F)(F)[N+]2=C1C] | 538 | 26 | | 92% |
| PC-52 | 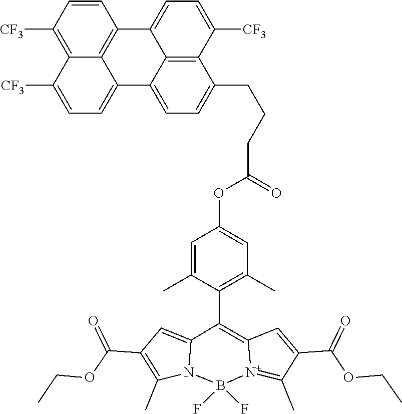 | 524 | 23 | | 96.7% |
| PC-53 | 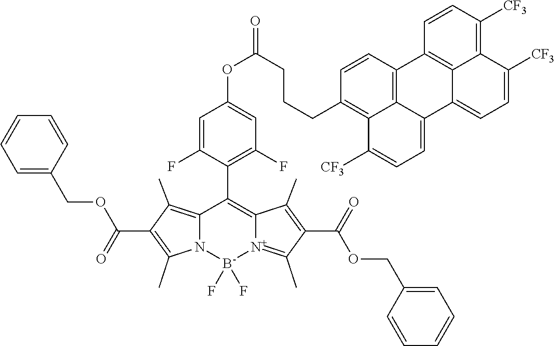 [SMILES: CC1=C(C(=O)OCc2ccccc2)C(C)=[N+]2C1=C(c1c(F)cc(OC(=O)CCCc3ccc4c5ccc(C(F)(F)F)c6c(C(F)(F)F)ccc(c7ccc(C(F)(F)F)c3c47)c65)cc1F)c1c(C)c(C(=O)OCc3ccccc3)c(C)n1[B-]2(F)F] | 527 | 27 | | 93.9% |
| PC-54 | 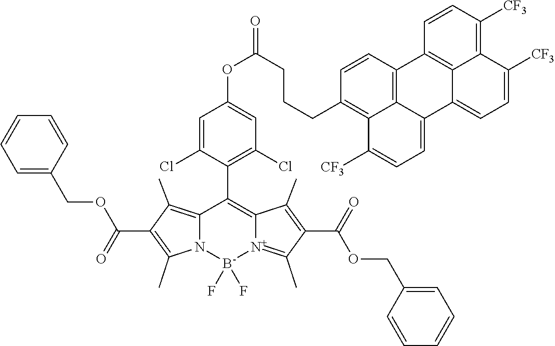 [SMILES: CC1=C(C(=O)OCc2ccccc2)C(C)=[N+]2C1=C(c1c(Cl)cc(OC(=O)CCCc3ccc4c5ccc(C(F)(F)F)c6c(C(F)(F)F)ccc(c7ccc(C(F)(F)F)c3c47)c65)cc1Cl)c1c(C)c(C(=O)OCc3ccccc3)c(C)n1[B-]2(F)F] | 527 | 26 | | 89.8% |
| PC-55 | 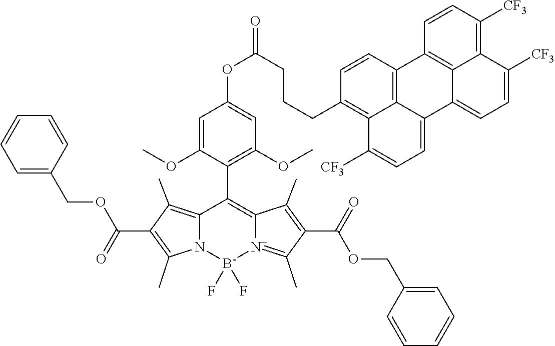 [SMILES: COc1cc(OC(=O)CCCc2ccc3c4ccc(C(F)(F)F)c5c(C(F)(F)F)ccc(c6ccc(C(F)(F)F)c2c36)c54)cc(OC)c1C1=C2C(C)=C(C(=O)OCc3ccccc3)C(C)=[N+]2[B-](F)(F)n2c(C)c(C(=O)OCc3ccccc3)c(C)c21] | 520 | 25 | | 93% |
| PC-56 | 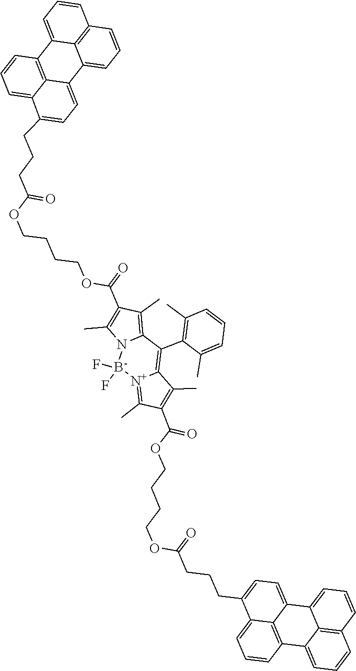 [SMILES: CC1=C(C(=O)OCCCCOC(=O)CCCc2ccc3c4cccc5cccc(c6cccc2c63)c54)C(C)=[N+]2C1=C(c1c(C)cccc1C)c1c(C)c(C(=O)OCCCCOC(=O)CCCc3ccc4c5cccc6cccc(c7cccc3c74)c65)c(C)n1[B-]2(F)F] | 513 | 23 | | 16.9% |
| PC-57 | 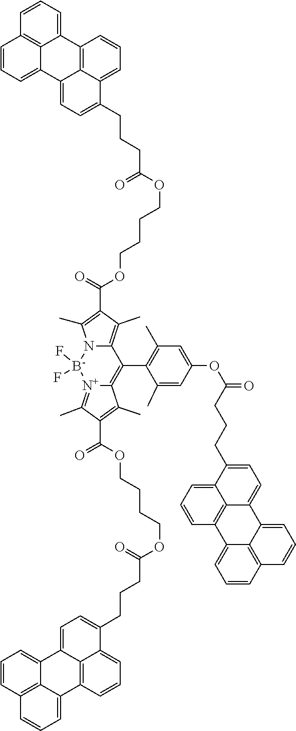 [SMILES: CC1=C(C(=O)OCCCCOC(=O)CCCc2ccc3c4cccc5cccc(c6cccc2c63)c54)C(C)=[N+]2C1=C(c1c(C)cc(OC(=O)CCCc3ccc4c5cccc6cccc(c7cccc3c74)c65)cc1C)c1c(C)c(C(=O)OCCCCOC(=O)CCCc3ccc4c5cccc6cccc(c7cccc3c74)c65)c(C)n1[B-]2(F)F] | 515 | 23 | | 12.1% |

TABLE 2

| | Composition | | | | | |
|---|---|---|---|---|---|---|
| | in | | | | | Drop |
| | PMMA | | | | | % |
| | (0.2%) | | 0 h | 165 h | 330 h | (330 h) |
| 1 | PC-12 | Abs % (λmax) | 100% | 74% | 51% | −49% |
| | | QY (450 nm) | 0.764 | 0.453 | 0.379 | |
| 2 | PC-14 | Abs % (λmax) | 100% | 60% | 49% | −51% |
| | | QY (450 nm) | 0.874 | 0.284 | 0.264 | |
| 3 | PC-16 | Abs % (λmax) | 100% | 93% | 83% | −17% |
| | | QY (450 nm) | 0.095 | 0.297 | 0.411 | |
| 4 | PC-44 | Abs % (λmax) | 100% | 84% | 82% | −18% |
| | | QY (450 nm) | 0.699 | 0.573 | 0.602 | |
| 5 | PC-45 | Abs % (λmax) | 100% | 87% | 81% | −19% |
| | | QY (450 nm) | 0.765 | 0.472 | 0.42 | |
| 6 | PC-46 | Abs % (λmax) | 100% | 91% | 80% | −20% |
| | | QY (450 nm) | 0.96 | 0.821 | 0.732 | |
| 7 | PC-47 | Abs % (λmax) | 100% | 88% | 82% | −18% |
| | | QY (450 nm) | 0.943 | 0.707 | 0.646 | |
| 8 | PC-49 | Abs % (λmax) | 100% | 92% | 83% | −17% |
| | | QY (450 nm) | 0.554 | 0.468 | 0.441 | |
| 9 | PC-50 | Abs % (λmax) | 100% | 50% | 32% | −68% |
| | | QY (450 nm) | 0.87 | 0.673 | 0.671 | |
| 10 | PC-51 | Abs % (λmax) | 100% | 53% | 37% | −63% |
| | | QY (450 nm) | 0.914 | 0.754 | 0.676 | |
| 11 | PC-52 | Abs % (λmax) | 100% | 91% | 86% | −14% |
| | | QY (450 nm) | 0.967 | 0.873 | 0.838 | |

1. A photoluminescent complex comprising:
a blue light absorbing moiety, wherein the blue light absorbing moiety comprises an optionally substituted perylene;
a first linker moiety that covalently links the optionally substituted perylene and a boron-dipyrromethene (BODIPY) moiety;
wherein the optionally substituted perylene absorbs light energy of a first excitation wavelength and transfers part of the absorbed light energy to the BODIPY moiety;
wherein the BODIPY moiety emits part of the transferred energy as light energy of a second higher wavelength; and
wherein the photoluminescent complex has an emission quantum yield greater than 80%.

2. The photoluminescent complex of claim 1, having an emission band having a full width half maximum (FWHM) of up to 40 nm.

3. The photoluminescent complex of claim 1, wherein the difference between the excitation peak of the blue light absorbing moiety and the emission peak of the BODIPY moiety is at least 45 nm.

4. The photoluminescent complex of claim 1, wherein the complex has an absorbance maximum of about 400 nm to about 480 nm.

5. The photoluminescent complex of claim 1, wherein the photoluminescent complex is represented by the following formula: 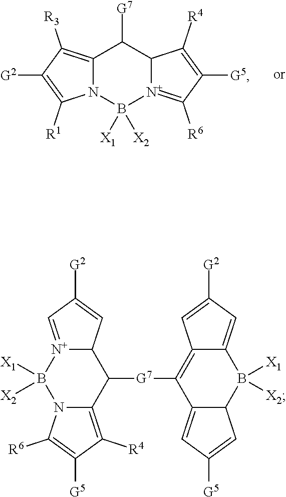
wherein R¹ and R⁶ are independently H or C₁₋₆ H₃₋₁₃O₀₋₂;
G² is H, a C₁-C₅ alkyl, CN, an aryl alkynyl, an aryl ester, an alkyl ester, or —C(═O)O—(CH₂)₄—OC(═O)—(CH₂)₃—Z¹;
R³ and R⁴ are independently H or C₁-C₅ alkyl;
G⁵ is H, a C₁-C₅ alkyl, CN, an aryl alkynyl, an aryl ester, an alkyl ester, or —C(═O)O—(CH₂)₄—OC(═O)—(CH₂)₃—Z²;
G² and R³ may link together to form an additional monocyclic hydrocarbon ring structure or polycyclic hydrocarbon ring structure;
R⁴ and G⁵ may link together to form an additional monocyclic hydrocarbon ring structure or polycyclic hydrocarbon ring structure;
G⁷ is an optionally substituted aryl group, -L₃-Z³, —Ar-L₃-Z³, -L₃-Z³-L₃-, or —Ar-L₃-Z³-L₃-Ar—, wherein Ar is optionally substituted aryl;
L₃ is a single bond, or a linker moiety containing a —C(═O)O— or a —O— group;
X₁ and X₂ are independently F, Cl, Br, or I; and
Z¹, Z², and Z³ are independently: 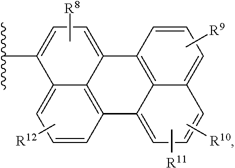
wherein R⁸, R⁹, R¹¹ and R¹² are independently H, a bond to L₃, a branched C₄-C₅ alkyl, CN, CF₃, or a 4-(trifluoromethyl)phenyl;
wherein R¹⁰ is H when: R⁹ is H, a branched C₄-C₅ alkyl, CN, F, or CF₃;
wherein when R⁹ is a 4-(trifluoromethyl)phenyl, R¹⁰ is H or forms a direct bond to the 4-(trifluoromethyl)phenyl group, forming a (trifluoromethyl)indeno[1,2,3-cd]perylene.

6.-7. (canceled)

8. The photoluminescent complex of claim 5, wherein G⁵ is —C(═O)O—(CH₂)₄—OC(═O)—(CH₂)₃—Z².

9. The photoluminescent complex of claim 5, wherein G⁵ is H, a C₁-C₅ alkyl, CN, an aryl alkynyl, an aryl ester, or an alkyl ester.

10. The photoluminescent complex of claim 5, wherein G² is an optionally substituted aryl group.

11. The photoluminescent complex of claim 5, wherein G⁷ is -L₃-Z³ or —Ar-L₃-Z³, wherein Ar is optionally substituted aryl.

12. The photoluminescent complex of claim 5, wherein G⁷ is a direct bond to the linker moiety,

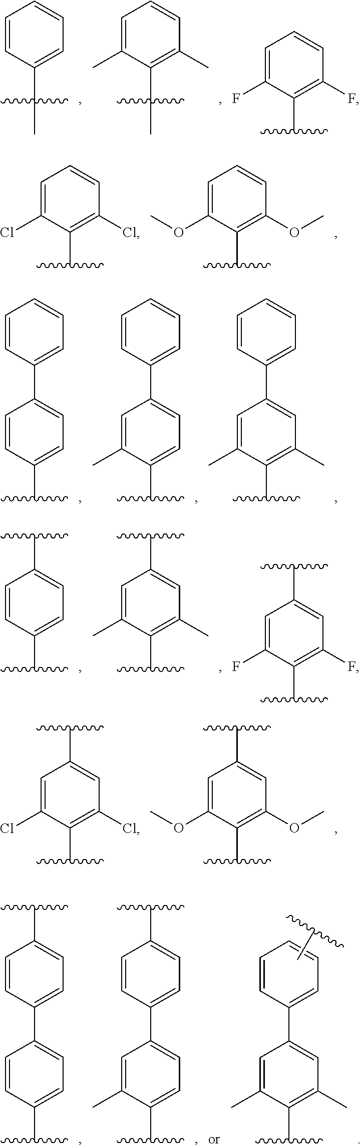

13. The photoluminescent complex of claim 5, wherein L3 is:

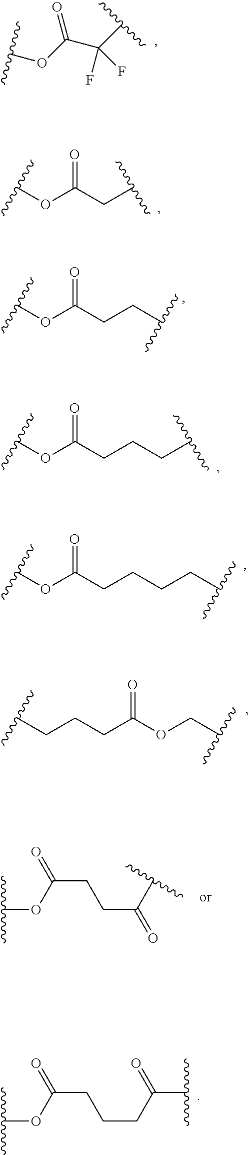

14. (canceled)

15. The photoluminescent complex of claim 5, wherein G² and G⁵ are independently 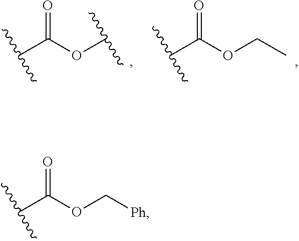
wherein Ph is phenyl.

16. The photoluminescent complex of claim 5, wherein R⁸, R⁹, R¹¹ or R¹² is:

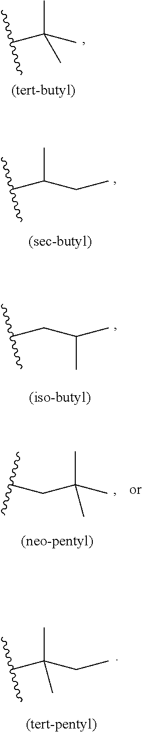

17.-18. (canceled)

19. A color conversion film comprising:
a color conversion layer, wherein the color conversion layer includes a resin matrix and the photoluminescent complex of claim 1 is dispersed within the resin matrix.

20. The color conversion film of claim 19, wherein the film has a thickness of between about 1 μm to about 200 μm.

21. The color conversion film of claim 19, wherein the film absorbs light in about 400 nm to about 480 nm wavelength range and emits light in about 510 nm to about 560 nm wavelength range.

22. The color conversion film of claim 19, wherein the film absorbs light in about 400 nm to about 480 nm wavelength range and emits light in about 575 nm to about 645 nm wavelength range.

23. The color conversion film of claim 19, further comprising:
a transparent substrate layer, wherein the transparent substrate layer comprises two opposing surfaces, and wherein the color conversion film is disposed on one of the opposing surfaces.

24. (canceled)

25. A backlight unit including the color conversion film of claim 19.

26. A display device including the backlight unit of claim 25.
